(19) United States
(12) Patent Application Publication
(10) Pub. No.: US 2012/0322007 A1
(43) Pub. Date: Dec. 20, 2012

(54) PATTERN FORMING METHOD, CHEMICAL AMPLIFICATION RESIST COMPOSITION AND RESIST FILM

(75) Inventors: Keita Kato, Shizuoka (JP); Shinji Tarutani, Shizuoka (JP); Sou Kamimura, Shizuoka (JP); Yuichiro Enomoto, Shizuoka (JP); Kaoru Iwato, Shizuoka (JP)

(73) Assignee: FUJIFILM CORPORATION, Tokyo (JP)

(21) Appl. No.: 13/579,733

(22) PCT Filed: Feb. 18, 2011
(86) PCT No.: PCT/JP2011/054213

§ 371 Date: Aug. 17, 2012

(30) Foreign Application Priority Data
Feb. 19, 2010 (JP) 2010-035463
Feb. 16, 2011 (JP) 2011-031438

(51) Int. Cl. G03F 7/027; G03F 7/20

(52) U.S. Cl. 430/285.1; 430/325; 430/281.1

(57) ABSTRACT

A pattern forming method comprising (i) a step of forming a film from a chemical amplification resist composition, (ii) a step of exposing the film, and (iii) a step of developing the exposed film by using a developer containing an organic solvent, wherein the resist composition contains (A) a resin, (B) a compound capable of generating a specific acid upon irradiation with an actinic ray or radiation, (C) a crosslinking agent, and (D) a solvent.

### TECHNICAL FIELD

The present invention relates to a pattern forming method, a chemical amplification resist composition and a resist film formed using the composition, which are used in lithography for the production of a semiconductor device such as IC, a liquid crystal device or a circuit board such as thermal head and further for other photofabrication processes. More specifically, the present invention relates to a pattern forming method and a chemical amplification resist composition, which are suitable for exposure by an ArF exposure apparatus or immersion projection exposure apparatus using a light source that emits far ultraviolet light at a wavelength of 300 nm or less.

### BACKGROUND ART

Along with miniaturization of a semiconductor device, the light source used for photolithography becomes shorter in wavelength and is shifted to a KrF excimer laser or an ArF excimer laser. To cope with this trend, an image forming method called chemical amplification is being used as an image forming method for a resist so as to compensate for the reduction in sensitivity due to light absorption. For example, the image forming method by positive chemical amplification that is predominating at present is an image forming method of decomposing an acid generator in the exposed area upon exposure to produce an acid, converting an alkali-insoluble group into an alkali-soluble group by using the generated acid as a reaction catalyst in the baking after exposure (PEB: Post Exposure Bake), and removing the exposed area by alkali development.

As to the developer used at present for g-line, i-line, KrF, ArF, EB or EUV lithography, various developers have been proposed, but an aqueous alkali developer of 2.38 mass % TMAH (an aqueous tetramethylammonium hydroxide) is used for general purposes.

Forming a pattern with overall good performance is of course preferred, but it is actually very difficult to find out an appropriate combination of a resist composition, a developer, a rinsing solution and the like necessary therefor, and improvements are being demanded. In particular, as the resolved line width of the resist becomes finer, the line edge roughness performance of a line pattern is required to be improved.

As well as the currently predominant positive resist, a negative chemical amplification resist composition for use in the pattern formation by alkali development is also being studied (see, for example, JP-A-2006-317803 (the term “JP-A” as used herein means an “unexamined published Japanese patent application”)). Because, in the production of a semiconductor device or the like, patterns having various profiles such as line, trench and hole need to be formed and some patterns are difficult to form by the current positive resist.

In the pattern formation by alkali development using the conventional negative resist composition, more improvements of resolution, line width variation (LWR) and other various performances are demanded.

Meanwhile, a double developing technique as a double patterning technology for further raising the resolution is described in JP-A-2008-292975. In this example, an image forming method by general chemical amplification is utilized, and by making use of a property that when exposed, the polarity of a resin in a resist composition maintains high polarity in a high light intensity region and maintains low polarity in a low light intensity region, development to dissolve a high exposure region of a specific resist film with a high-polarity developer and development to dissolve a low exposure region with a low-polarity developer are performed.

However, selecting an optimal combination of a resist composition and a low-polarity developer is very difficult, and in the example above, there is a problem that developability when using a low-polarity developer is worsened.

It is demanded to stably obtain a higher-definition fine pattern with excellent performance in terms of line width variation (LWR).

### SUMMARY OF INVENTION

An object of the present invention is to solve the above-described problems and for stably forming a high-definition fine pattern so as to produce a high-integration and high-precision electronic device, provide a pattern forming method, a chemical amplification resist composition and a resist film formed using the composition, enabling formation of a pattern with excellent resolution and small line width variation (LWR).

The present invention has the following configurations, and the object above of the present invention can be attained by these configurations. It is presumed that since the present invention includes a step of development using a developer containing an organic solvent, swelling during development is reduced and therefore, a pattern with high resolution and reduced line width variation can be obtained.

<1> A pattern forming method comprising:

(i) a step of forming a film from a chemical amplification resist composition,

(ii) a step of exposing the film, and

(iii) a step of developing the exposed film by using a developer containing an organic solvent,

wherein the resist composition contains:

(A) a resin,

(B) a compound capable of generating an acid represented by the following formula (I) upon irradiation with an actinic ray or radiation,

(C) a crosslinking agent, and

(D) a solvent:

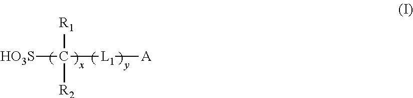

wherein each of R₁ and R₂ independently represents a hydrogen atom, a fluorine atom or an alkyl group, and when a plurality of R₁'s or R₂'s are present, each R₁ or R₂ may be the same as or different from every other R₁ or R₂,

L₁ represents a divalent linking group and when a plurality of L₁'s are present, each L₁ may be the same as or different from every other L₁,

A represents a cyclic organic group,

x represents an integer of 0 to 20, and

y represents an integer of 0 to 10.

<2> The pattern forming method according to <1>, wherein the content of the organic solvent in the developer containing the organic solvent is from 90 to 100 mass % based on the entire amount of the developer.
<3> The pattern forming method according to <1> or <2> above, wherein the compound (B) is a compound capable of generating an acid represented by the following formula (II) or (III) upon irradiation with an actinic ray or radiation:

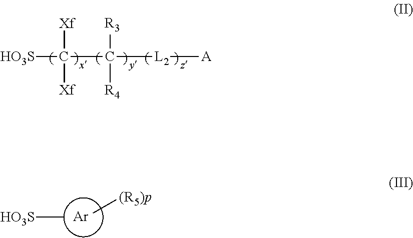

wherein each Xf independently represents a fluorine atom or an alkyl group substituted with at least one fluorine atom,

each of R₃ and R₄ independently represents a hydrogen atom or an alkyl group, and when a plurality of R₃'s or R₄'s are present, each R₃ or R₄ may be the same as or different from every other R₃ or R₄,

L₂ represents a divalent linking group and when a plurality of L₂'s are present, each L₂ may be the same as or different from every other L₂,

A represents a cyclic organic group,

x′ represents an integer of 1 to 20,

y′ represents an integer of 0 to 10,

z′ represents an integer of 0 to 10,

Ar represents an aryl group and may have a substituent other than the sulfonic acid group and R₅,

R₅ represents a group containing a hydrocarbon group, and

p represents an integer of 0 or more.

<4> The pattern forming method according to any one of <1> to <3> above, wherein the resin (A) contains a repeating unit having an acid-decomposable group.
<5> The pattern forming method according to any one of <1> to <4> above, wherein the resin (A) does not contain a repeating unit having an acid group or the content of a repeating unit having an acid group is 10 mol % or less based on all repeating units of the resin (A).
<6> The pattern forming method according to any one of <1> to <5> above, wherein the developer containing an organic solvent is a developer containing at least one kind of a solvent selected from a ketone-based solvent, an ester-based solvent, an alcohol-based solvent, an amide-based solvent and an ether-based solvent.
<7> A chemical amplification resist composition used in the pattern forming method according to any one of <1> to <6> above.
<8> A chemical amplification resist composition comprising:

(A) a resin,

(B) a compound capable of generating an acid represented by the following formula (I) upon irradiation with an actinic ray or radiation,

(C) a crosslinking agent, and

(D) a solvent.

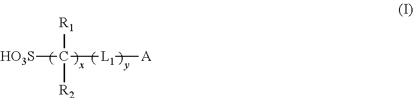

wherein each of R₁ and R₂ independently represents a hydrogen atom, a fluorine atom or an alkyl group, and when a plurality of R₁'s or R₂'s are present, each R₁ or R₂ may be the same as or different from every other R₁ or R₂,

L₁ represents a divalent linking group and when a plurality of L₁'s are present,

each L₁ may be the same as or different from every other L₁,

A represents a cyclic organic group,

x represents an integer of 0 to 20, and

y represents an integer of 0 to 10.

<9> The chemical amplification resist composition according to <8> above, wherein the compound (B) is a compound capable of generating an acid represented by the following formula (II) or (III) upon irradiation with an actinic ray or radiation:

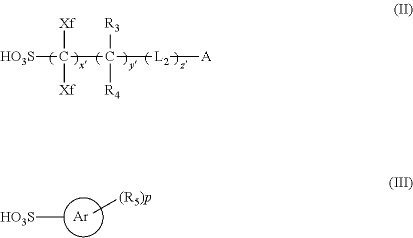

wherein each Xf independently represents a fluorine atom or an alkyl group substituted with at least one fluorine atom,

each of R₃ and R₄ independently represents a hydrogen atom or an alkyl group, and when a plurality of R₃'s or R₄'s are present, each R₃ or R₄ may be the same as or different from every other R₃ or R₄,

L₂ represents a divalent linking group and when a plurality of L₂'s are present, each L₂ may be the same as or different from every other L₂,

A represents a cyclic organic group,

x′ represents an integer of 1 to 20,

y′ represents an integer of 0 to 10,

z′ represents an integer of 0 to 10,

Ar represents an aryl group and may have a substituent other than the sulfonic acid group and R₅,

R₅ represents a group containing a hydrocarbon group, and

p represents an integer of 0 or more.

<10> The chemical amplification resist composition according to <8> or <9> above, wherein the resin (A) contains a repeating unit having an acid-decomposable group.
<11> The chemical amplification resist composition according to any one of <8> to <10> above, wherein the resin (A) does not contain a repeating unit having an acid group or the content of a repeating unit having an acid group is 10 mol % or less based on all repeating units of the resin (A).
<12> A resist film formed from the chemical amplification resist composition according to any one of <8> to <11> above.

According to the present invention, a pattern forming method, a chemical amplification resist composition and a resist film formed using the composition, enabling formation of a pattern with excellent resolution and small line width variation (LWR), can be provided.

### DESCRIPTION OF EMBODIMENTS

The best mode for carrying out the present invention is described below.

In the present invention, when a group (atomic group) is denoted without specifying whether substituted or unsubstituted, the group includes both a group having no substituent and a group having a substituent. For example, “an alkyl group” includes not only an alkyl group having no substituent (unsubstituted alkyl group) but also an alkyl group having a substituent (substituted alkyl group).

In the present invention, the term “actinic ray” or “radiation” indicates, for example, a bright line spectrum of mercury lamp, a far ultraviolet ray typified by excimer laser, an extreme-ultraviolet ray (EUV light), an X-ray or an electron beam. Also, in the present invention, the “light” means an actinic ray or radiation. In the present invention, unless otherwise indicated, the “exposure” includes not only exposure with a mercury lamp, a far ultraviolet ray typified by excimer laser, an X-ray, EUV light or the like but also lithography with a particle beam such as electron beam and ion beam.

The chemical amplification resist composition of the present invention contains (A) a resin, (B) a compound capable of generating an acid represented by formula (I) upon irradiation with an actinic ray or radiation, (C) a crosslinking agent, and (D) a solvent.

[1] (B) Compound Capable of Generating Acid Upon Irradiation with Actinic Ray or Radiation

The resist composition of the present invention contains a compound capable of generating an acid upon irradiation with an actinic ray or radiation (hereinafter, sometimes referred to as a “compound (B)” or “acid generator”).

The compound (B) is a compound capable of generating an acid represented by the following formula (I) upon irradiation with an actinic ray or radiation.

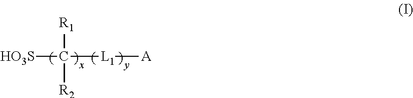

In formula (I), each of R₁ and R₂ independently represents a hydrogen atom, a fluorine atom or an alkyl group, and when a plurality of R₁'s or R₂'s are present, each R₁ or R₂ may be the same as or different from every other R₁ or R₂,

L₁ represents a divalent linking group and when a plurality of L₁'s are present, each L₁ may be the same as or different from every other L₁ (here, y represents a repetition number of L₁),

A represents a cyclic organic group,

x represents an integer of 0 to 20, and

y represents an integer of 0 to 10.

The alkyl group of R₁ and R₂ may have a substituent (preferably fluorine atom) and is preferably an alkyl group having a carbon number of 1 to 4, more preferably a perfluoroalkyl group having a carbon number of 1 to 4. Specific examples of R¹ and R² include —CF₃, —C₂F₅, —C₃F₇, —C₄F₉, —C₅F₁₁, —C₆F₁₃, —C₇F₁₅, —C₈F₁₇, —CH₂CF₃, —CH₂CH₂CF₃, —CH₂C₂F₅, —CH₂CH₂C₂F₅, —CH₂C₃F₇, —CH₂CH₂C₃F₇, —CH₂C₄F₉ and —CH₂CH₂C₄F₉. Among these, —CF₃ is preferable.

Each of R₁ and R₂ is preferably a fluorine atom or —CF₃.

L₁ is not particularly limited and examples of L₁ include —COO—, —COO—, —CO—, —O—, —S—, —SO—, —SO₂—, —NH—, an alkylene group, a cycloalkylene group, an alkenylene group and a linking group formed by connecting a plurality of these members. Among these, —COO—, —COO—, —CO—, —O—, —S—, —SO—, —SO₂—, an alkylene group (preferably having a carbon number of 1 to 6), a cycloalkylene group (preferably having a carbon number of 3 to 10), an alkenylene group (preferably having a carbon number of 2 to 6), and a linking group formed by connecting a plurality of these members are preferred, and a linking group having a total carbon number of 12 or less is preferred.

L₁ is preferably —COO—, —COO—, —CO—, —O—, —SO₂—, —CONH—, —NHCO—, —COO-alkylene group—, —OCO-alkylene group—, —CONH-alkylene group- or —NHCO-alkylene group—, more preferably —COO—, —COO—, —CO—, —O— or —SO₂—, still more preferably —COO—, —COO- or —SO₂—.

The cyclic organic group of A is not particularly limited and examples thereof include an alicyclic group, an aryl group and a heterocyclic group (including not only those having aromaticity but also those having no aromaticity).

The alicyclic group may be monocyclic or polycyclic and is preferably a monocyclic cycloalkyl group such as cyclopentyl group, cyclohexyl group and cyclooctyl group, or a polycyclic cycloalkyl group such as norbornyl group, tricyclodecanyl group, tetracyclodecanyl group, tetracyclododecanyl group and adamantyl group. Above all, an alicyclic group having a bulky structure with a carbon number of 7 or more, such as norbornyl group, tricyclodecanyl group, tetracyclodecanyl group, tetracyclododecanyl group and adamantyl group, is preferred from the standpoint that the diffusion in the film at the PEB (post-exposure baking) step can be suppressed and MEEF (mask error enhancement factor) can be improved.

The aryl group includes a phenyl group, a naphthyl group, a phenanthrenyl group and an anthracenyl group. Among these, naphthyl group having low absorbance is preferred in view of absorbance for light at 193 nm.

The heterocyclic group includes those derived from a furan ring, a thiophene ring, a benzofuran ring, a benzothiophene ring, a dibenzofuran ring, a dibenzothiophene ring, a pyridine ring and a piperidine ring. In particular, those derived from a furan ring, a thiophene ring, a pyridine ring and a piperidine ring are preferred.

The cyclic organic group also includes a lactone structure, and specific examples thereof include lactone structures represented by formulae (LC1-1) to (LC1-17), which the later-described resin (A) may have.

The above-described cyclic organic group may further have a substituent, and examples of the substituent include a halogen atom, a cyano group, a carboxyl group, an alkyl group (may be either linear or branched, preferably having a carbon number of 1 to 12), a cycloalkyl group (may be any of monocyclic, polycyclic or spirocyclic, preferably having a carbon number of 3 to 20), an aryl group (preferably having a carbon number of 6 to 14), a heterocyclic group (may be any of monocyclic, polycyclic or spirocyclic and may or may not be aromatic, preferably a 5- to 20-membered ring containing from 3 to 19 carbon atoms, for example, lactone structures represented by later described (LC1-1) to (LC1-17)), a hydroxyl group, an alkoxy group, an amide group (monosubstituted, disubstituted or unsubstituted), a urethane group (monosubstituted, disubstituted or unsubstituted), a ureido group (monosubstituted, disubstituted or unsubstituted), a substituted thioether group, a sulfonamide group (monosubstituted, disubstituted or unsubstituted), a substituted sulfonic acid ester group, a substituted oxycarbonyl group and a substituted carbonyloxy group. Examples of the substituent in the substituted amide group, substituted urethane group, substituted ureido group, substituted thioether group, substituted sulfonamide group, substituted sulfonic acid ester group, substituted oxycarbonyl group and substituted carbonyloxy group include an alkyl group (may be linear or branched, preferably having a carbon number of 1 to 12), a cycloalkyl group (may be monocyclic, polycyclic or spirocyclic, preferably having a carbon number of 3 to 20) and an aryl group (preferably having a carbon number of 6 to 14). Incidentally, the carbon constituting the cyclic organic group (the carbon contributing to ring formation) may be carbonyl carbon.

x is preferably an integer of 1 to 12, more preferably an integer of 1 to 4, still more preferably 1 or 2.

y is preferably an integer of 0 to 8, more preferably an integer of 0 to 4.

The compound (B) is preferably a compound capable of generating an acid represented by the following formula (II) or (III) upon irradiation with an actinic ray or radiation:

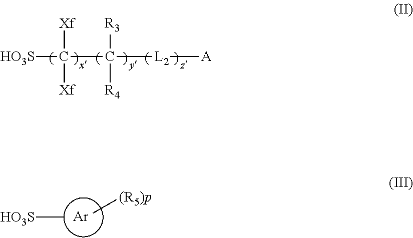

In formulae (II) and (III), each Xf independently represents a fluorine atom or an alkyl group substituted with at least one fluorine atom,

each of R₃ and R₄ independently represents a hydrogen atom or an alkyl group, and when a plurality of R₃'s or R₄'s are present, each R₃ or R₄ may be the same as or different from every other R₃ or R₄,

L₂ represents a divalent linking group and when a plurality of L₂'s are present,

each L₂ may be the same as or different from every other L₂,

A represents a cyclic organic group,

x′ represents an integer of 1 to 20,

y′ represents an integer of 0 to 10,

z′ represents an integer of 0 to 10,

Ar represents an aromatic ring and may have a substituent other than the sulfonic acid group and R₅,

R₅ represents a group containing a hydrocarbon group, and

p represents an integer of 0 or more.

The acid represented by formula (II) is described in detail below.

The alkyl group in the fluorine atom-substituted alkyl group of Xf is preferably an alkyl group having a carbon number of 1 to 10, more preferably from 1 to 4. Also, the fluorine atom-substituted alkyl group of Xf is preferably a perfluoroalkyl group.

Xf is preferably a fluorine atom or a perfluoroalkyl group having a carbon number of 1 to 4.

Specific examples of Xf include a fluorine atom, —CF₃, —C₂F₅, —C₃F₇, —C₄F₉, —C₅F₁₁, —C₆F₁₃, —C₇F₁₅, —C₈F₁₇, —CH₂CF₃, —CH₂CH₂CF₃, —CH₂C₂F₅, —CH₂CH₂C₂F₅, —CH₂C₃F₇, —CH₂CH₂C₃F₇, —CH₂C₄F₉ and —CH₂CH₂C₄F₉. Among these, a fluorine atom and —CF₃ are preferred. In particular, it is preferred that both Xfs are a fluorine atom.

Examples of the alkyl group of R₃ and R₄ are the same as those of the alkyl group in R₁ and R₂.

X′ is preferably an integer of 1 to 10, more preferably an integer of 1 to 5.

y′ is preferably an integer of 0 to 4, more preferably 0.

z′ is preferably an integer of 0 to 8, more preferably an integer of 0 to 4.

The divalent linking group of L₂ is not particularly limited and examples thereof are the same as those of the linking group in L₁ (here, z′ represents a repetition number of L₂).

Examples of the cyclic organic group of A are the same as those in formula (I).

The acid represented by formula (III) is described in detail below.

In formula (III), the aromatic ring of Ar is preferably an aromatic ring having a carbon number of 6 to 30.

Specific examples thereof include a benzene ring, a naphthalene ring, a pentalene ring, an indene ring, an azulene ring, a heptalene ring, an indecent ring, a perylene ring, a pentacene ring, an acenaphthalene ring, phenanthrene ring, an anthracene ring, a naphthacene ring, a pentacene ring, a chrysene ring, a triphenylene ring, an indene ring, a fluorene ring, a triphenylene ring, a naphthacene ring, a biphenyl ring, a pyrrole ring, a furan ring, a thiophene ring, an imidazole ring, an oxazole ring, a thiazole ring, a pyridine ring, a pyrazine ring, a pyrimidine ring, a pyridazine ring, an indolizine ring, an indole ring, a benzofuran ring, a benzothiophene ring, an isobenzofuran ring, a quinolizine ring, a quinoline ring, a phthalazine ring, a naphthylidine ring, a quinoxaline ring, a quinoxazoline ring, an isoquinoline ring, a carbazole ring, a phenanthridine ring, an acridine ring, a phenanthroline ring, a thianthrene ring, a chromene ring, a xanthene ring, a phenoxathiine ring, a phenothiazine ring and a phenazine ring. Among these, a benzene ring, a naphthalene ring and an anthracene ring are preferred, and a benzene ring is more preferred.

Examples of the substituent which the aromatic ring above may have other than the sulfonic acid group and R₅ include a halogen atom (e.g., fluorine atom, chlorine atom, bromine atom, iodine atom), a hydroxyl group, a cyano group, a nitro group and a carboxyl group. Moreover, in the case where the aromatic ring has two or more substituents, at least two substituents may combine with each other to form a ring.

The hydrocarbon group-containing group as R₅ includes, for example, an acyclic hydrocarbon group and a cyclic aliphatic group and is preferably a group having a carbon number of 3 to 20. Examples thereof include an alkoxy group such as methoxy group, ethoxy group and tert-butoxy group, an aryloxy group such as phenoxy group and p-tolyloxy group, an alkylthioxy group such as methylthioxy group, ethylthioxy group and tert-butylthioxy group, an arylthioxy group such as phenylthioxy group and p-tolylthioxy group, an alkoxycarbonyl group such as methoxycarbonyl group, butoxycarbonyl group and phenoxycarbonyl group, an acetoxy group, a linear or branched alkyl group such as methyl group, ethyl group, propyl group, butyl group, heptyl group, hexyl group, dodecyl group and 2-ethylhexyl group, an alkenyl group such as vinyl group, propenyl group and hexenyl group, an acetylene group, an alkynyl group such as propynyl group and hexynyl group, an aryl group such as phenyl group and tolyl group, and an acyl group such as benzoyl group, acetyl group and tolyl group.

As for R₅, the carbon atom adjacent to Ar is preferably a tertiary or quaternary carbon atom.

Examples of the acyclic hydrocarbon group as R₅ include an isopropyl group, a tert-butyl group, a tert-pentyl group, a neopentyl group, a s-butyl group an isobutyl group, an isohexyl group, a 3,3-dimethylpentyl group and a 2-ethylhexyl group. The upper limit of the carbon number of the alicyclic hydrocarbon group is preferably 12 or less, more preferably 10 or less.

Examples of the cyclic aliphatic group as R₅ include a cycloalkyl group such as cyclobutyl group, cyclopentyl group, cyclohexyl group, cycloheptyl group and cyclooctyl group, an adamantyl group, a norbornyl group, a bornyl group, a camphanyl group, a decahydronaphthyl group, a tricyclodecanyl group, a tetracyclodecanyl group, a camphoroyl group, a dicyclohexyl group and a pinenyl group. These groups may have a substituent. The upper limit of the carbon number of the cyclic aliphatic group is preferably 15 or less, more preferably 12 or less.

In the case where the alicyclic hydrocarbon group or cyclic aliphatic group has a substituent, examples of the substituent include a halogen atom such as fluorine atom, chlorine atom, bromine atom and iodine atom, an alkoxy group such as methoxy group, ethoxy group and tert-butoxy group, an aryloxy group such as phenoxy group and p-tolyloxy group, an alkylthioxy group such as methylthioxy group, ethylthioxy group and tert-butylthioxy group, an arylthioxy group such as phenylthioxy group and p-tolylthioxy group, an alkoxycarbonyl group such as methoxycarbonyl group, butoxycarbonyl group and phenoxycarbonyl group, an acetoxy group, a linear or branched alkyl group such as methyl group, ethyl group, propyl group, butyl group, heptyl group, hexyl group, dodecyl group and 2-ethylhexyl group, a cyclic alkyl group such as cyclohexyl group, an alkenyl group such as vinyl group, propenyl group and hexenyl group, an acetylene group, an alkynyl group such as propynyl group and hexynyl group, an aryl group such as phenyl group and tolyl group, a hydroxy group, a carboxy group, a sulfonic acid group, a carbonyl group and a cyano group.

Specific examples of the group having a cyclic aliphatic group or an alicyclic hydrocarbon group as R₅ are illustrated below. * indicates a bond to Ar.

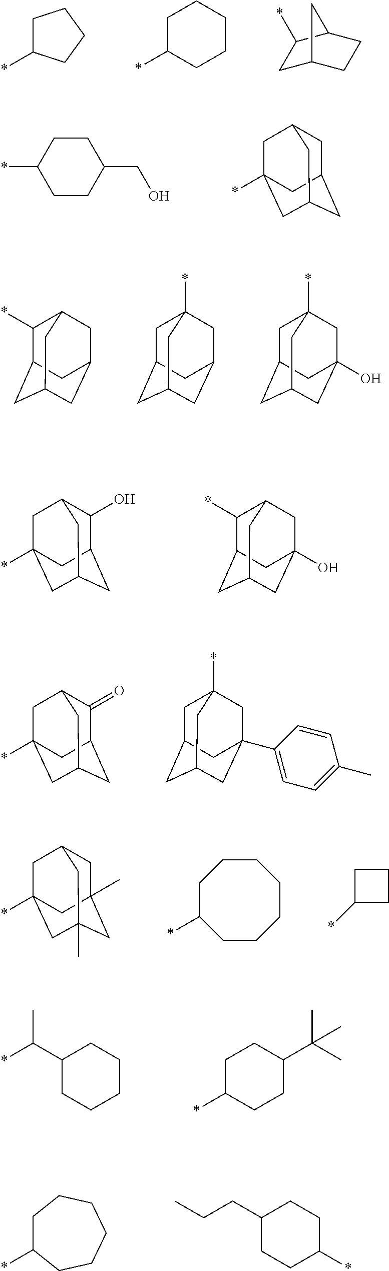

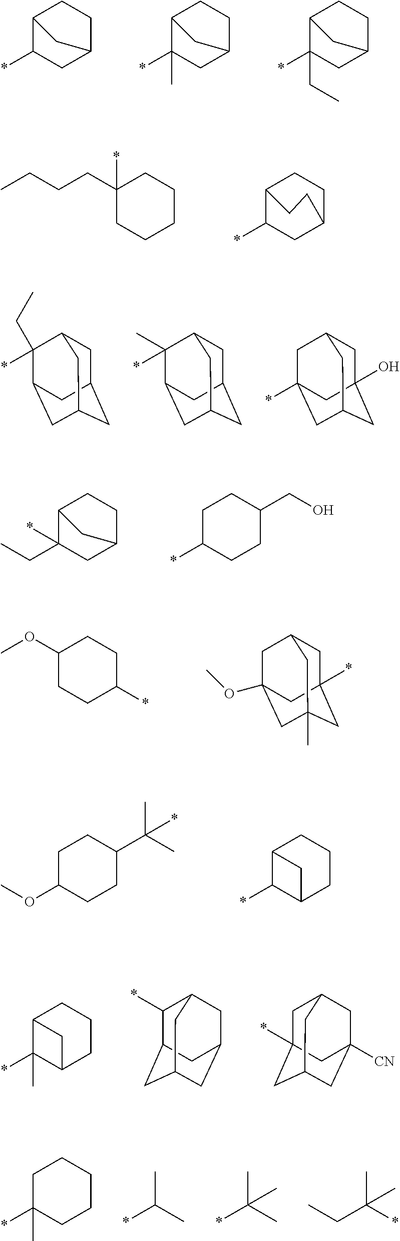

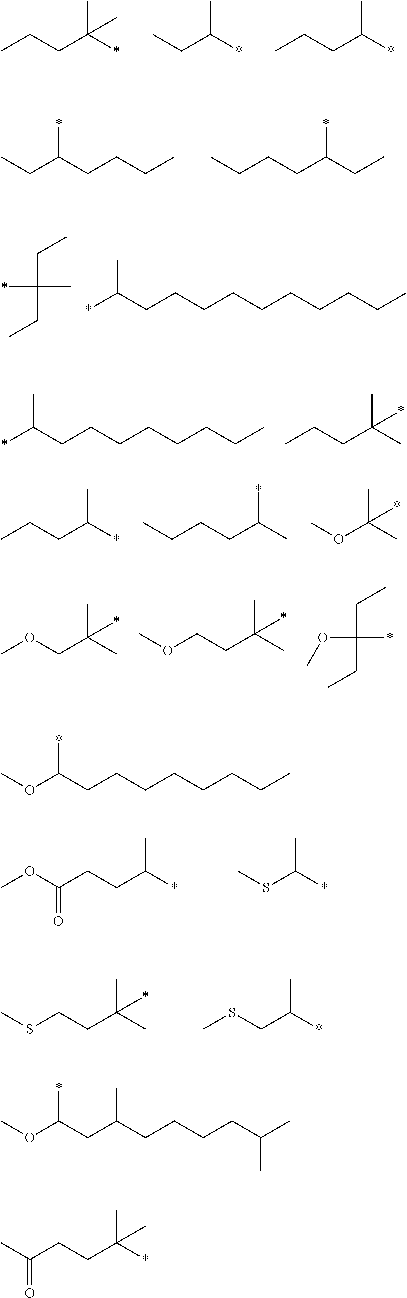

Among these, the following structures are more preferred in view of suppressing acid diffusion.

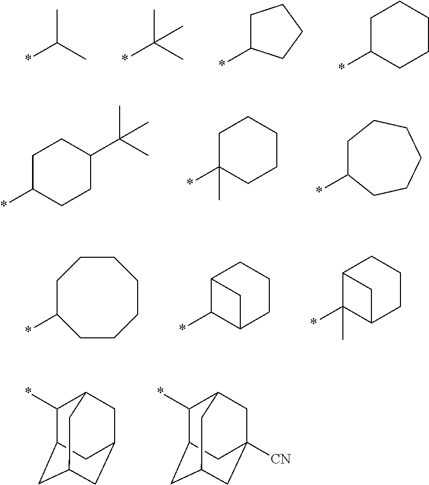

p represents an integer of 0 or more, and the upper limit thereof is not particularly limited as long as it is a chemically possible number. From the standpoint of suppressing acid diffusion, p is an integer of usually from 0 to 5, preferably from 1 to 4, more preferably 2 or 3, and most preferably 3.

In the light of suppressing acid diffusion, R₅ is preferably substituted on at least one o-position with respect to the sulfonic acid group, and a structure of being substituted on two o-positions is more preferred.

In one embodiment, the acid generator (B) for use in the present invention is a compound capable of generating an acid represented by the following formula (BII):

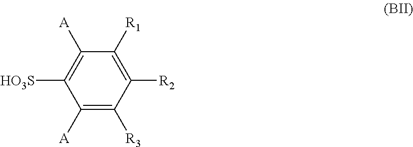

In the formula, A is the same as R₅ in formula (III), and two A's may be the same or different. Each of R₁ to R₃ independently represents a hydrogen atom, a hydrocarbon group-containing group, a halogen atom, a hydroxyl group, a cyano group or a nitro group. Specific examples of the hydrocarbon group-containing group are the same as the groups exemplified above.

Specific examples of the acid represented by formula (I) are illustrated below.

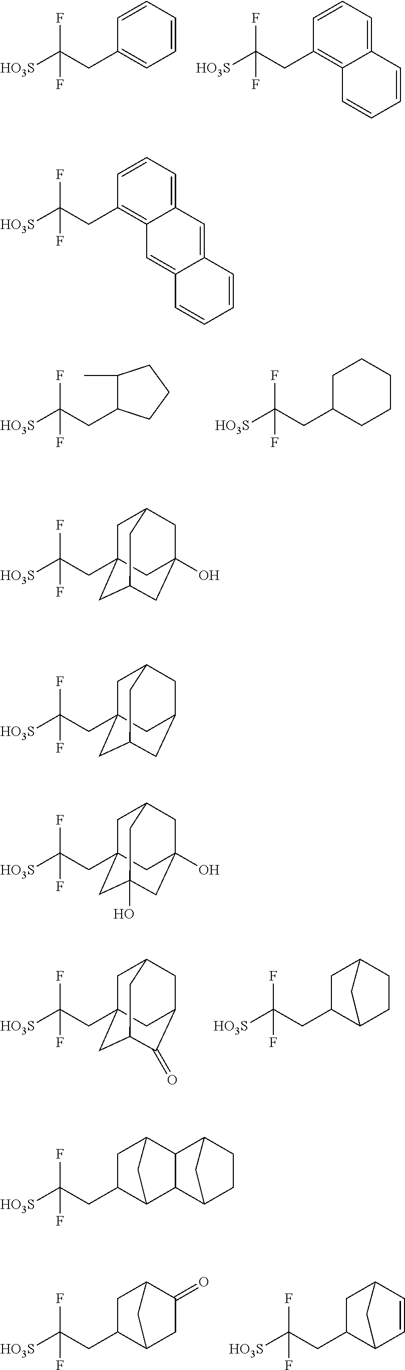

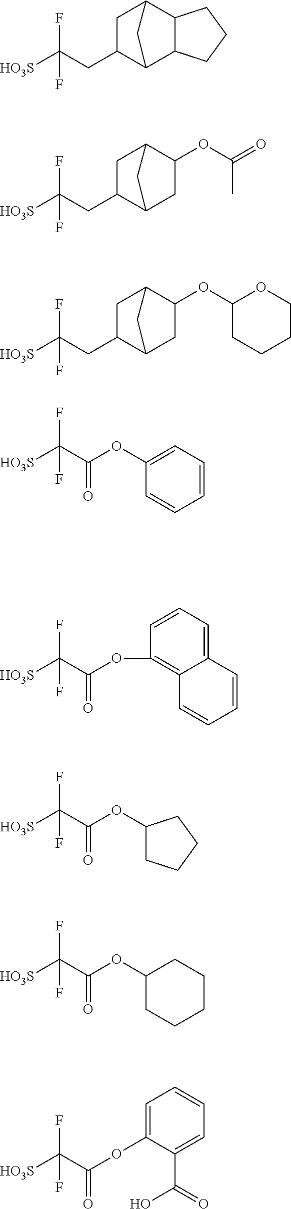

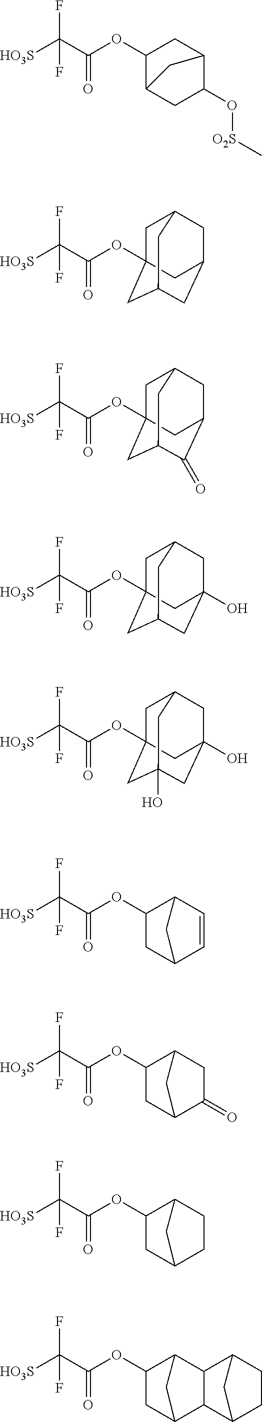

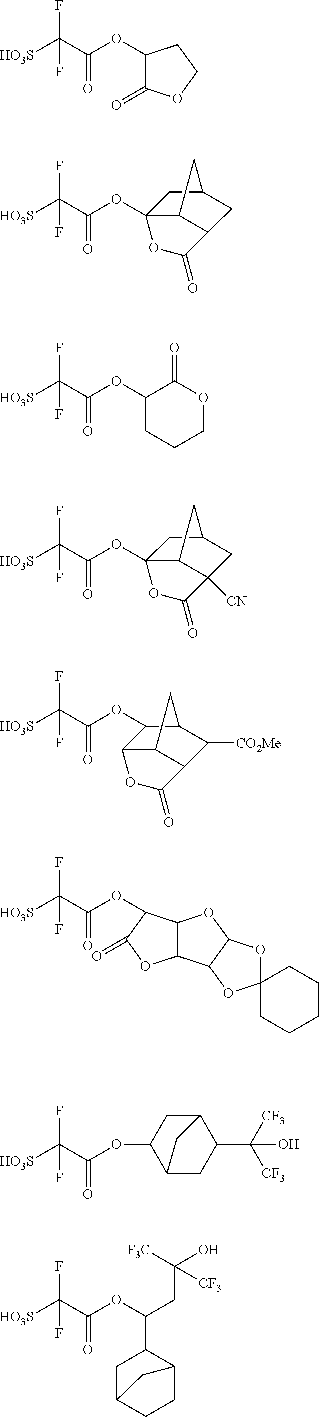

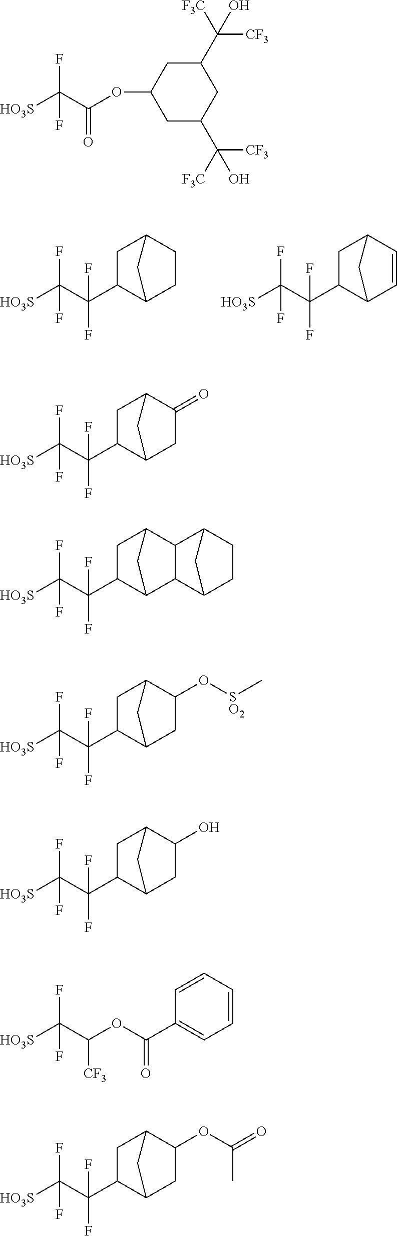

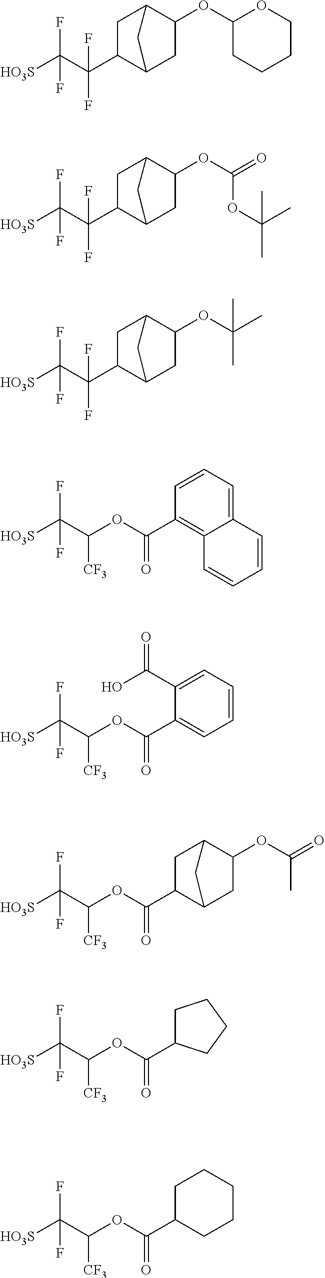

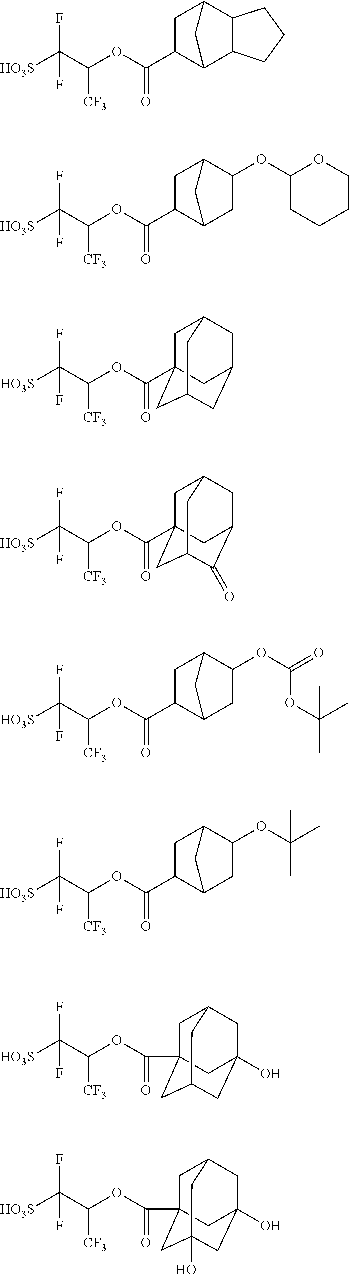

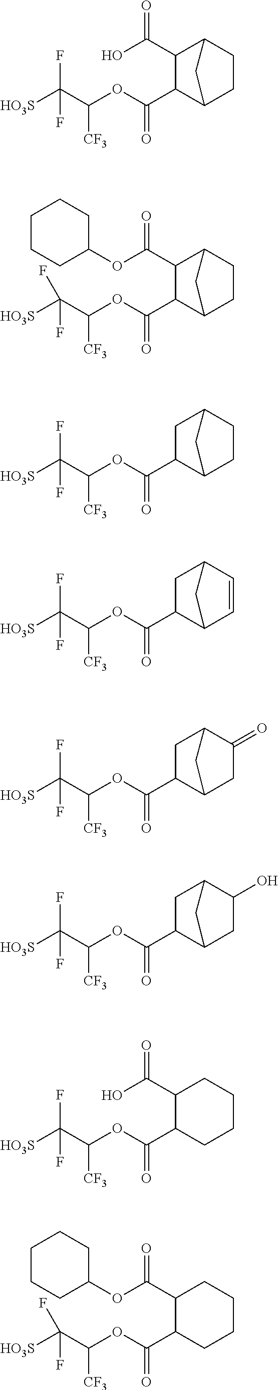

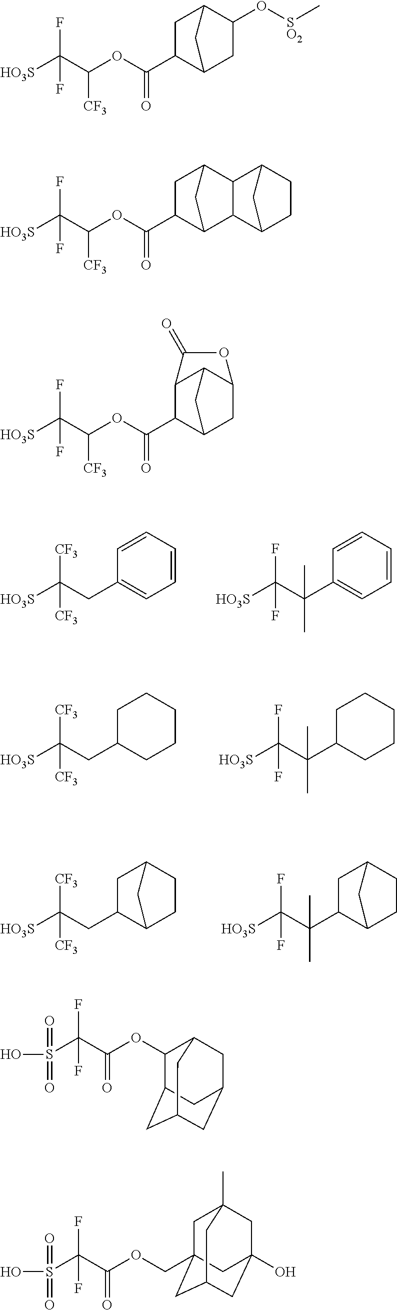

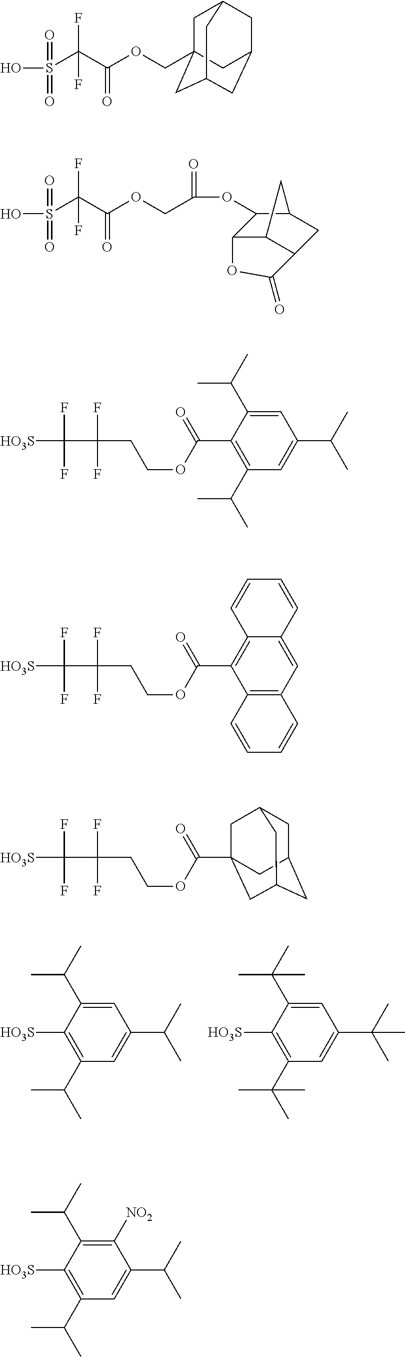

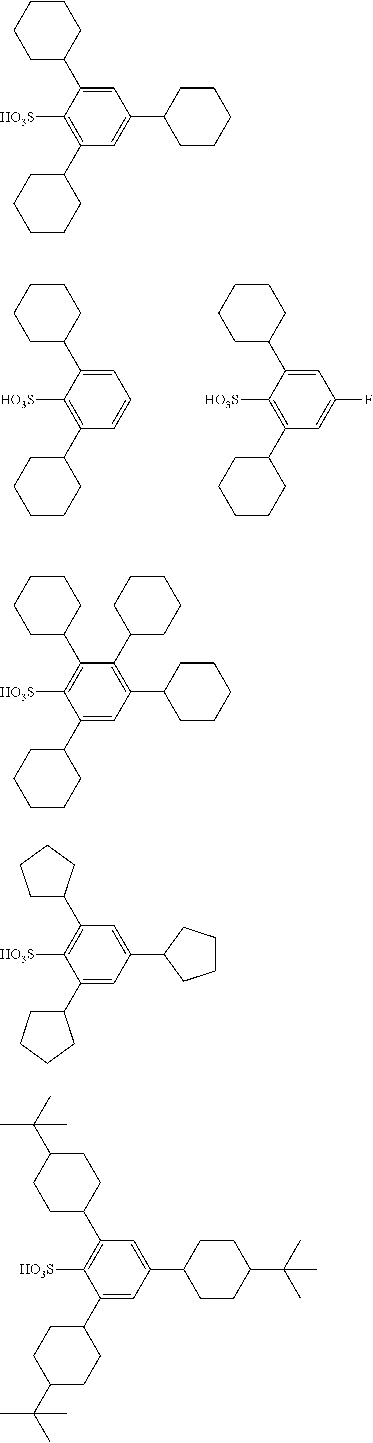

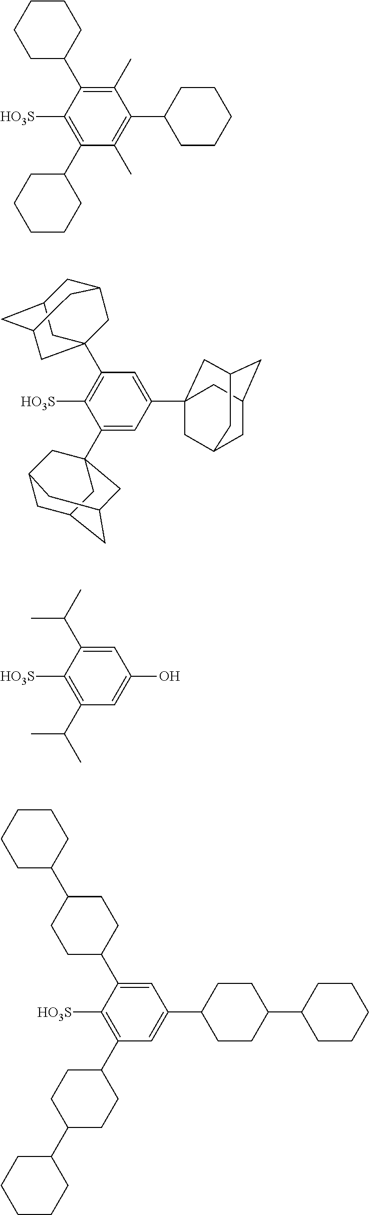

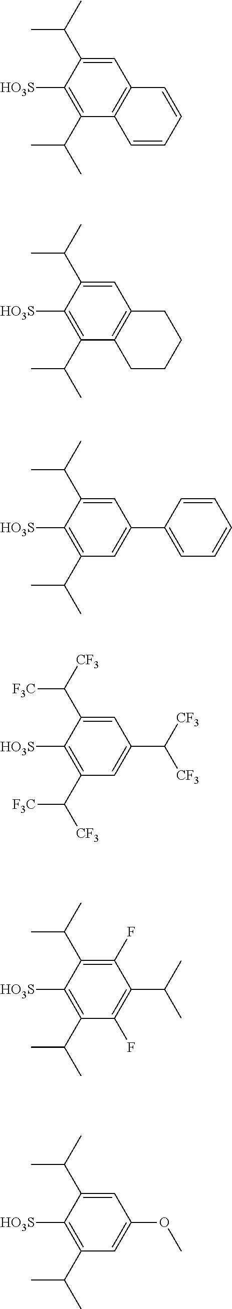

Among these specific examples, more preferred are the acids shown below.

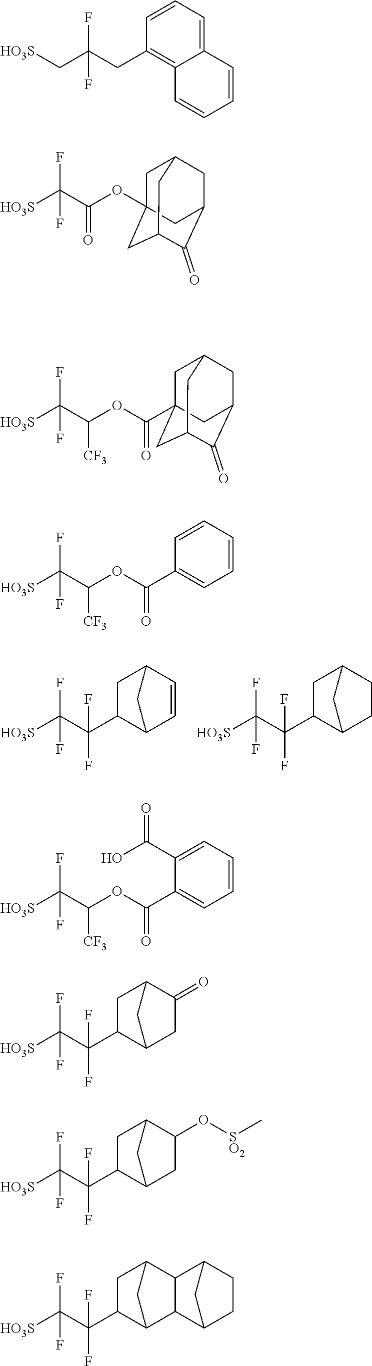

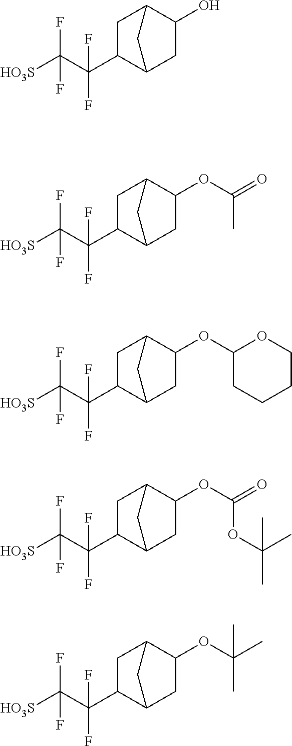

Out of the compounds capable of generating an acid represented by formula (I) upon irradiation with an actinic ray or radiation, a compound having an ionic structure, such as sulfonium salt and iodonium salt, and a compound having a nonionic compound structure, such as oxime ester and imide ester, are preferred.

Preferred examples of the compound having an ionic structure out of acid generators include compounds represented by the following formulae (ZI) and (ZII):

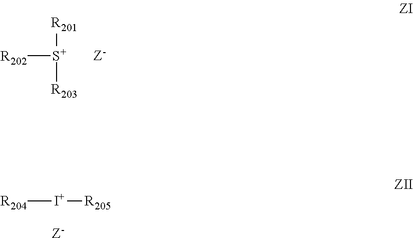

In formula (ZI), each of R₂₀₁, R₂₀₂ and R₂₀₃ independently represents an organic group. The carbon number of the organic group as R₂₀₁, R₂₀₂ and R₂₀₃ is generally from 1 to 30, preferably from 1 to 20. Two members out of R₂₀₁ to R₂₀₃ may combine to form a ring structure, and the ring may contain an oxygen atom, a sulfur atom, an ester bond, an amide bond or a carbonyl group. Examples of the group formed by combining two members out of R₂₀₁ to R₂₀₃ include an alkylene group (e.g., butylenes group, pentylene group). Z⁻ represents an anion corresponding to the acid represented by formula (I).

Examples of the organic group as R₂₀₁, R₂₀₂ and R₂₀₃ in formula (ZI) include corresponding groups in the later-described compounds (ZI-1) to (ZI-4).

The compound may be a compound having a plurality of structures represented by formula (ZI). For example, the compound may be a compound having a structure where at least one of R₂₀₁ to R₂₀₃ in the compound represented by formula (ZI) is bonded to at least one of R₂₀₁ to R₂₀₃ in another compound represented by formula (ZI).

Compounds (ZI-1) to (ZI-4) described below are more preferred as the compound represented by formula (ZI).

The compound (ZI-1) is an arylsulfonium compound where at least one of R₂₀₁ to R₂₀₃ in formula (ZI) is an aryl group, that is, a compound having an arylsulfonium as the cation.

In the arylsulfonium compound, all of R₂₀₁ to R₂₀₃ may be an aryl group or a part of R₂₀₁ to R₂₀₃ may be an aryl group, with the remaining being an alkyl group or a cycloalkyl group.

Examples of the arylsulfonium compound include a triarylsulfonium compound, a diarylalkylsulfonium compound, an aryldialkylsulfonium compound, a diarylcycloalkylsulfonium compound and an aryldicycloalkylsulfonium compound.

The aryl group in the arylsulfonium compound is preferably a phenyl group or a naphthyl group, more preferably a phenyl group. The aryl group may be an aryl group having a heterocyclic structure containing an oxygen, a nitrogen atom, a sulfur atom or the like. Examples of the heterocyclic structure include pyrrole, furan, thiophene, indole, benzofuran and benzothiophene. In the case where the arylsulfonium compound has two or more aryl groups, these two or more aryl groups may be the same or different.

The alkyl or cycloalkyl group which is present, if desired, in the arylsulfonium compound is preferably a linear or branched alkyl group having a carbon number of 1 to 15 or a cycloalkyl group having a carbon number of 3 to 15, and examples thereof include a methyl group, an ethyl group, a propyl group, an n-butyl group, a sec-butyl group, a tert-butyl group, a cyclopropyl group, a cyclobutyl group and a cyclohexyl group.

The aryl group, alkyl group and cycloalkyl group of R₂₀₁ to R₂₀₃ may have, as the substituent, an alkyl group (for example, having a carbon number of 1 to 15), a cycloalkyl group (for example, having a carbon number of 3 to 15), an aryl group (for example, having a carbon number of 6 to 14), an alkoxy group (for example, having a carbon number of 1 to 15), a halogen atom, a hydroxyl group or a phenylthio group. The substituent is preferably a linear or branched alkyl group having a carbon number of 1 to 12, a cycloalkyl group having a carbon number of 3 to 12, or a linear, branched or cyclic alkoxy group having a carbon number of 1 to 12, more preferably an alkyl group having a carbon number of 1 to 4, or an alkoxy group having a carbon number of 1 to 4. The substituent may be substituted on any one of three members R₂₀₁ to R₂₀₃ or may be substituted on all of these three members. In the case where R₂₀₁ to R₂₀₃ are an aryl group, the substituent is preferably substituted on the p-position of the aryl group.

The compound (ZI-2) is described below.

The compound (ZI-2) is a compound where each of R₂₀₁ to R₂₀₃ in formula (ZI) independently represents an aromatic ring-free organic group. The aromatic ring as used herein includes an aromatic ring containing a heteroatom.

The aromatic ring-free organic group as R₂₀₁ to R₂₀₃ has a carbon number of generally from 1 to 30, preferably from 1 to 20.

Each of R₂₀₁ to R₂₀₃ independently represents preferably an alkyl group, a cycloalkyl group, an allyl group or a vinyl group, more preferably a linear or branched 2-oxoalkyl group, a 2-oxocycloalkyl group or an alkoxycarbonylmethyl group, still more preferably a linear or branched 2-oxoalkyl group.

The alkyl group and cycloalkyl group of R₂₀₁ to R₂₀₃ are preferably a linear or branched alkyl group having a carbon number of 1 to 10, and a cycloalkyl group having a carbon number of 3 to 10. The alkyl group is more preferably a 2-oxoalkyl group or an alkoxycarbonylmethyl group. The cycloalkyl group is more preferably a 2-oxocycloalkyl group.

The 2-oxoalkyl group may be either linear or branched and is preferably a group having >C═O at the 2-position of the above-described alkyl group.

The 2-oxocycloalkyl group is preferably a group having >C═O at the 2-position of the above-described cycloalkyl group.

The alkoxy group in the alkoxycarbonylmethyl group is preferably an alkoxy group having a carbon number of 1 to 5.

R₂₀₁ to R₂₀₃ may be further substituted with a halogen atom, an alkoxy group (for example, having a carbon number of 1 to 5), a hydroxyl group, a cyano group or a nitro group.

The compound (ZI-3) is a compound represented by the following formula (ZI-3), and this is a compound having a phenacylsulfonium salt structure.

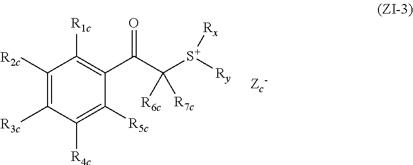

In formula (ZI-3), each of R_{1c} to R_{5c} independently represents a hydrogen atom, an alkyl group, a cycloalkyl group, an alkoxy group, an alkoxycarbonyl group, an alkylcarbonyloxy group, a cycloalkylcarbonyloxy group, an aryl group, an aryloxy group, a hydroxyl group, a nitro group, an alkylthio group, an arylthio group or a halogen atom.

Each of R_{6c} and R_{7c} independently represents a hydrogen atom, an alkyl group, a cycloalkyl group, a halogen atom, a cyano group or an aryl group. Each of Rₓ and R_{y} independently represents an alkyl group, a cycloalkyl group, an ally group, a 2-oxoalkyl group, a 2-oxocycloalkyl group, an alkoxycarbonylalkyl group or a vinyl group.

Any two or more members out of R_{1c} to R_{5c}, a pair of R_{6c} and R_{7c}, or a pair of Rₓ and R_{y} may combine together to form a ring structure. This ring structure may contain an oxygen atom, a sulfur atom, an ester bond or an amide bond. Examples of the group formed by combining any two or more members out of R_{1c} to R_{5c}, a pair of R_{6c} and R_{7c}, or a pair of Rₓ and R_{y} include a butylene group and a pentylene group.

The ring structure above includes an aromatic or non-aromatic hydrocarbon ring, an aromatic or non-aromatic heterocyclic ring, and a polycyclic condensed ring formed by combining two or more of these rings. The ring structure is a 3- to 10-membered ring, preferably a 4- to 8-membered ring, more preferably a 5- or 6-membered ring.

Zc⁻ represents an anion corresponding to the acid represented by formula (I).

The alkyl group as R_{1c} to R_{7c} and the alkyl group in the alkylcarbonyloxy group and alkylthio group may be either linear or branched and are, for example, an alkyl group having a carbon number of 1 to 20, preferably a linear or branched alkyl group having a carbon number of 1 to 12.

The cycloalkyl group as R_{1c} to R_{7c} and the cycloalkyl group in the cycloalkylcarbonyloxy group are, for example, a cycloalkyl group having a carbon number of 3 to 10.

The alkoxy group as R_{1c} to R_{5c} and the alkoxy group in the alkoxycarbonyl group may be linear, branched or cyclic and are, for example, an alkoxy group having a carbon number of 1 to 10, preferably a linear or branched alkoxy group having a carbon number of 1 to 5, or a cyclic alkoxy group having a carbon number of 3 to 10.

The aryl group as R_{6c} and R_{7c} and the aryl group in the aryloxy group and arylthio group are preferably an aryl group having a carbon number of 5 to 15, and examples thereof include a phenyl group and a naphthyl group.

In the case where R_{6c} and R_{7c} are combined to form a ring, the group formed by combining R_{6c} and R_{7c} is preferably an alkylene group having a carbon number of 2 to 10, and examples thereof include an ethylene group, a propylene group, a butylene group, a pentylene group and a hexylene group. Also, the ring formed by combining R_{6c} and R_{7c} may contain a heteroatom such as oxygen atom in the ring.

A compound where any one of R_{1c} to R_{5c} is a linear or branched alkyl group, a cycloalkyl group or a linear, branched or cyclic alkoxy group is preferred, and a compound where the sum of carbon numbers of R_{1c} to R_{5c} is from 2 to 15 is more preferred. Thanks to such a compound, the solvent solubility is more enhanced and production of particles during storage can be suppressed.

Examples of the alkyl group and cycloalkyl group as Rₓ and R_{y} are the same as those of the alkyl group and cycloalkyl group in R_{1c} to R_{7c}. Among these, a 2-oxoalkyl group, a 2-oxocycloalkyl group and an alkoxycarbonylmethyl group are preferred.

Examples of the 2-oxoalkyl group and 2-oxocycloalkyl group include a group having >C═O at the 2-position of the alkyl group or cycloalkyl group as R_{1c} to R_{7c}.

Examples of the alkoxy group in the alkoxycarbonylalkyl group are the same as those of the alkoxy group in R_{1c} to R_{5c}. The alkyl group is, for example, an alkyl group having a carbon number of 1 to 12, preferably a linear alkyl group having a carbon number of 1 to 5 (e.g., methyl group, ethyl group).

The allyl group is not particularly limited but is preferably an allyl group substituted with an unsubstituted, monocyclic or polycyclic cycloalkyl group.

The vinyl group is not particularly limited but is preferably a vinyl group substituted with an unsubstituted, monocyclic or polycyclic cycloalkyl group.

As for the ring structure which may be formed by combining Rₓ and R_{y} with each other, a 5- or 6-membered ring formed by divalent Rₓ and R_{y} (for example, a methylene group, an ethylene group or a propylene group) together with the sulfur atom in formula (ZI-3) is preferred, and a 5-membered ring (that is, a tetrahydrothiophene structure) is more preferred.

Each of Rₓ and R_{y} is preferably an alkyl or cycloalkyl group having a carbon number of 4 or more, more preferably 6 or more, still more preferably 8 or more.

The compound (ZI-4) is a compound represented by the following formula (ZI-4):

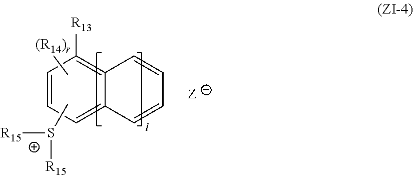

In formula (ZI-4), R₁₃ represents a hydrogen atom, a fluorine atom, a hydroxyl group, an alkyl group, a cycloalkyl group, an alkoxy group, an alkoxycarbonyl group, or a group having a cycloalkyl group. These groups may have a substituent.

R₁₄ represents, when a plurality of R₁₄'s are present, each independently represents, a hydroxyl group, an alkyl group, a cycloalkyl group, an alkoxy group, an alkoxycarbonyl group, an alkylcarbonyl group, an alkylsulfonyl group, a cycloalkylsulfonyl group, or a group having a cycloalkyl group. These groups may have a substituent.

Each R₁₅ independently represents an alkyl group, a cycloalkyl group or a naphthyl group. Two R₁₅'s may combine with each other to form a ring.

1 represents an integer of 0 to 2.

r represents an integer of 0 to 10.

Z⁻ represents an anion corresponding to the acid represented by formula (I).

In formula (ZI-4), the alkyl group of R₁₃, R₁₄ and R₁₅ is preferably a linear or branched alkyl group having a carbon number of 1 to 10, and examples thereof include a methyl group, an ethyl group, an n-propyl group, an i-propyl group, an n-butyl group, a 2-methylpropyl group, a 1-methylpropyl group, a tert-butyl group, an n-pentyl group, a neopentyl group, an n-hexyl group, an n-heptyl group, an n-octyl group, a 2-ethylhexyl group, an n-nonyl group and an n-decyl group. Among these alkyl groups, a methyl group, an ethyl group, an n-butyl group and a tert-butyl group are preferred.

The cycloalkyl group of R₁₃, R₁₄ and R₁₅ includes a monocyclic or polycyclic cycloalkyl group (preferably a cycloalkyl group having a carbon number of 3 to 20), and examples thereof include cyclopropyl, cyclobutyl, cyclopentyl, cyclohexyl, cycloheptyl, cyclooctyl, cyclododecanyl, cyclopentenyl, cyclohexenyl, cyclooctadienyl, norbornyl, tricyclodecanyl, tetracyclodecanyl and adamantyl. Above all, cyclopropyl, cyclopentyl, cyclohexyl, cycloheptyl and cyclooctyl are preferred.

The alkoxy group of R₁₃ and R₁₄ is preferably a linear or branched alkoxy group having a carbon number of 1 to 10, and examples thereof include a methoxy group, an ethoxy group, an n-propoxy group, an i-propoxy group, an n-butoxy group, a 2-methylpropoxy group, a 1-methylpropoxy group, a tert-butoxy group, an n-pentyloxy group, a neopentyloxy group, an n-hexyloxy group, an n-heptyloxy group, an n-octyloxy group, a 2-ethylhexyloxy group, an n-nonyloxy group and an n-decyloxy group. Among these alkoxy groups, a methoxy group, an ethoxy group, an n-propoxy group and an n-butoxy group are preferred.

The alkoxycarbonyl group of R₁₃ is preferably a linear or branched alkoxycarbonyl group having a carbon number of 2 to 11, and examples thereof include a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a tert-butoxycarbonyl group, an n-pentyloxycarbonyl group, a neopentyloxycarbonyl group, an n-hexyloxycarbonyl group, an n-heptyloxycarbonyl group, an n-octyloxycarbonyl group, a 2-ethylhexyloxycarbonyl group, an n-nonyloxycarbonyl group and an n-decyloxycarbonyl group. Among these alkoxycarbonyl groups, a methoxycarbonyl group, an ethoxycarbonyl group and an n-butoxycarbonyl group are preferred.

The group having a cycloalkyl group of R₁₃ and R₁₄ includes a monocyclic or polycyclic cycloalkyl group (preferably a cycloalkyl group having a carbon number of 3 to 20), and examples thereof include a monocyclic or polycyclic cycloalkyloxy group, and an alkoxy group having a monocyclic or polycyclic cycloalkyl group. These groups may further have a substituent.

The monocyclic or polycyclic cycloalkyloxy group of R₁₃ and R₁₄ preferably has a total carbon number of 7 or more, more preferably a total carbon number of 7 to 15, and preferably has a monocyclic cycloalkyl group. The monocyclic cycloalkyloxy group having a total carbon number of 7 or more indicates a monocyclic cycloalkyloxy group where a cycloalkyloxy group such as cyclopropyloxy group, cyclobutyloxy group, cyclopentyloxy group, cyclohexyloxy group, cyclobutyloxy group, cyclooctyloxy group and cyclododecanyloxy group arbitrarily has a substituent such as alkyl group (e.g., methyl group, ethyl group, propyl group, butyl group, pentyl group, hexyl group, heptyl group, octyl group, dodecyl group, 2-ethylhexyl group, isopropyl group, sec-butyl group, tert-butyl group, isoamyl group), hydroxyl group, halogen atom (e.g., fluorine, chlorine, bromine, iodine), nitro group, cyano group, amido group, sulfonamido group, alkoxy group (e.g., methoxy group, ethoxy group, hydroxyethoxy group, propoxy group, hydroxypropoxy group, butoxy group), alkoxycarbonyl group (e.g., methoxycarbonyl group, ethoxycarbonyl group), acyl group (e.g., formyl group, acetyl group, benzoyl group), acyloxy group (e.g., acetoxy group, butyryloxy group) and carboxy group and where the total carbon number inclusive of the carbon number of an arbitrary substituent on the cycloalkyl group is 7 or more.

Examples of the polycyclic cycloalkyloxy group having a total carbon number of 7 or more include a norbornyloxy group, a tricyclodecanyloxy group, a tetracyclodecanyloxy group and an adamantyloxy group.

The alkoxy group having a monocyclic or polycyclic cycloalkyl group of R₁₃ and R₁₄ preferably has a total carbon number of 7 or more, more preferably a total carbon number of 7 to 15, and is preferably alkoxy group having a monocyclic cycloalkyl group. The alkoxy group having a total carbon number of 7 or more and having a monocyclic cycloalkyl group indicates an alkoxy group where the above-described monocyclic cycloalkyl group which may have a substituent is substituted on an alkoxy group such as methoxy, ethoxy, propoxy, butoxy, pentyloxy, hexyloxy, heptoxy, octyloxy, dodecyloxy, 2-ethylhexyloxy, isopropoxy, sec-butoxy, tert-butoxy and isoamyloxy and where the total carbon number inclusive of the carbon number of the substituent is 7 or more. Examples thereof include a cyclohexylmethoxy group, a cyclopentylethoxy group and a cyclohexylethoxy group, with a cyclohexylmethoxy group being preferred.

Examples of the alkoxy group having a total carbon number of 7 or more and having a polycyclic cycloalkyl group include a norbornylmethoxy group, a norbornylethoxy group, a tricyclodecanylmethoxy group, a tricyclodecanylethoxy group, a tetracyclodecanylmethoxy group, a tetracyclodecanylethoxy group, an adamantylmethoxy group and an adamantylmethoxy group, with a norbornylmethoxy group and a norbornylethoxy group being preferred.

Specific examples of the alkyl group in the alkylcarbonyl group of R¹⁴ are the same as those of the alkyl group of R₁₃ to R₁₅ above.

The alkylsulfonyl or cycloalkylsulfonyl group of R₁₄ is preferably a linear, branched or cyclic alkylsulfonyl group having a carbon number of 1 to 10, and examples thereof include a methanesulfonyl group, an ethanesulfonyl group, an n-propanesulfonyl group, an n-butanesulfonyl group, a tert-butanesulfonyl group, an n-pentanesulfonyl group, a neopentanesulfonyl group, an n-hexanesulfonyl group, an n-heptanesulfonyl group, an n-octanesulfonyl group, a 2-ethylhexanesulfonyl group, an n-nonanesulfonyl group, an n-decanesulfonyl group, a cyclopentanesulfonyl group and a cyclohexanesulfonyl group. Among these alkylsulfonyl groups and cycloalkylsulfonyl groups, a methanesulfonyl group, an ethanesulfonyl group, an n-propanesulfonyl group, an n-butanesulfonyl group, a cyclopentanesulfonyl group and a cyclohexanesulfonyl group are preferred.

1 is preferably 0 or 1, more preferably 1. r is preferably an integer of 0 to 2.

Examples of the substituent which each of the groups of R₁₃, R₁₄ and R₁₅ may have include a halogen atom (e.g., fluorine atom), a hydroxyl group, a carboxyl group, a cyano group, a nitro group, an alkoxy group, an alkoxyalkyl group, an alkoxycarbonyl group and an alkoxycarbonyloxy group.

Examples of the alkoxy group include a linear, branched or cyclic alkoxy group having a carbon number of 1 to 20, such as methoxy group, ethoxy group, n-propoxy group, i-propoxy group, n-butoxy group, 2-methylpropoxy group, 1-methylpropoxy group, tert-butoxy group, cyclopentyloxy group and cyclohexyloxy group.

Examples of the alkoxyalkyl group include a linear, branched or cyclic alkoxyalkyl group having a carbon number of 2 to 21, such as methoxymethyl group, ethoxymethyl group, 1-methoxyethyl group, 2-methoxyethyl group, 1-ethoxyethyl group and 2-ethoxyethyl group.

Examples of the alkoxycarbonyl group include a linear, branched or cyclic alkoxycarbonyl group having a carbon number of 2 to 21, such as methoxycarbonyl group, ethoxycarbonyl group, n-propoxycarbonyl group, i-propoxycarbonyl group, n-butoxycarbonyl group, 2-methylpropoxycarbonyl group, 1-methylpropoxycarbonyl group, tert-butoxycarbonyl group, cyclopentyloxycarbonyl group and cyclohexyloxycarbonyl group.

Examples of the alkoxycarbonyloxy group include a linear, branched or cyclic alkoxycarbonyloxy group having a carbon number of 2 to 21, such as methoxycarbonyloxy group, ethoxycarbonyloxy group, n-propoxycarbonyloxy group, i-propoxycarbonyloxy group, n-butoxycarbonyloxy group, tert-butoxycarbonyloxy group, cyclopentyloxycarbonyloxy group and cyclohexyloxycarbonyloxy group.

As for the ring structure which may be formed by combining two R₁₅'s with each other, a group capable of forming a 5- or 6-membered ring together with the sulfur atom in formula (ZI-4) is preferred, and a group capable of forming a 5-membered ring (that is, a tetrahydrothiophene ring) is more preferred. Examples of the substituent on the divalent group include a hydroxyl group, a carboxyl group, a cyano group, a nitro group, an alkyl group, a cycloalkyl group, an alkoxy group, an alkoxyalkyl group, an alkoxycarbonyl group and an alkoxycarbonyloxy group. A plurality of substituents may be present on the ring structure, or these substituents may combine with each other to form a ring (for example, an aromatic or non-aromatic hydrocarbon ring, an aromatic or non-aromatic heterocyclic ring, or a polycyclic condensed ring formed by combining two or more of these rings).

In formula (ZI-4), R₁₅ is preferably, for example, a methyl group, an ethyl group, or a divalent group of forming a tetrahydrothiophene ring structure together with the sulfur atom when two R₁₅'s are combined.

The alkyl group, cycloalkyl group, alkoxy group and alkoxycarbonyl group of R₁₃ and the alkyl group, cycloalkyl group, alkoxy group, alkylsulfonyl group and cycloalkylsulfonyl group of R₁₄ may be substituted as described above, and the substituent is preferably a hydroxyl group, an alkoxy group, an alkoxycarbonyl group or a halogen atom (particularly fluorine atom).

Specific preferred examples of the cation in the compound represented by formula (ZI-4) are illustrated below.

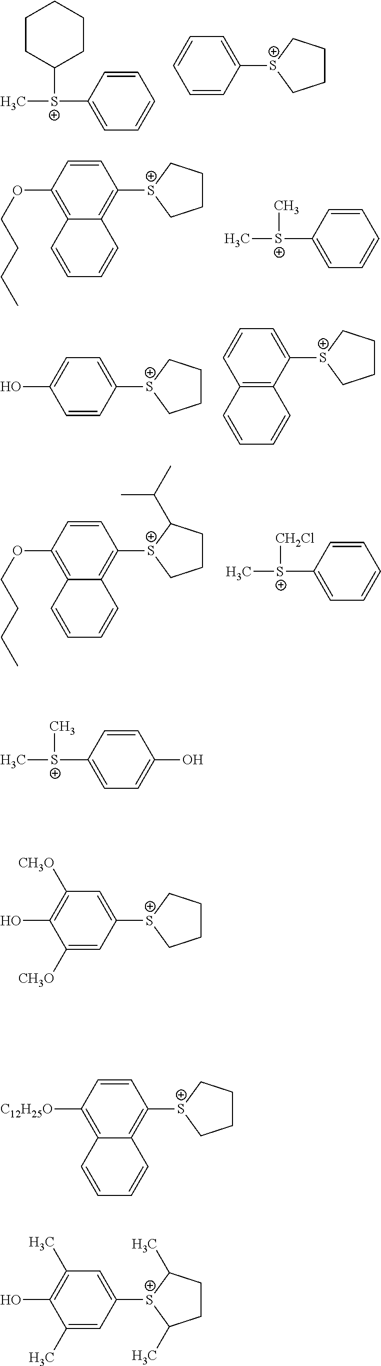

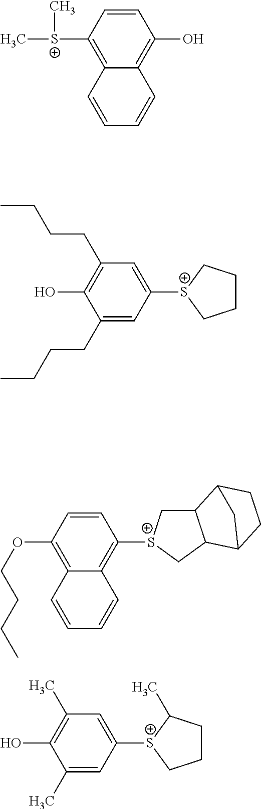

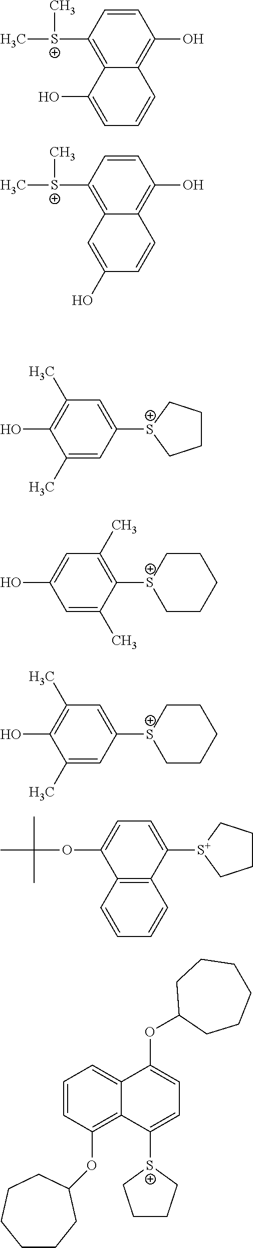

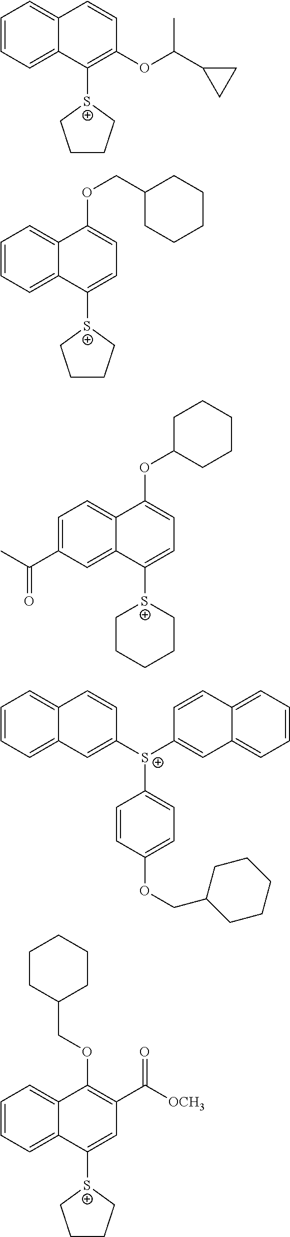

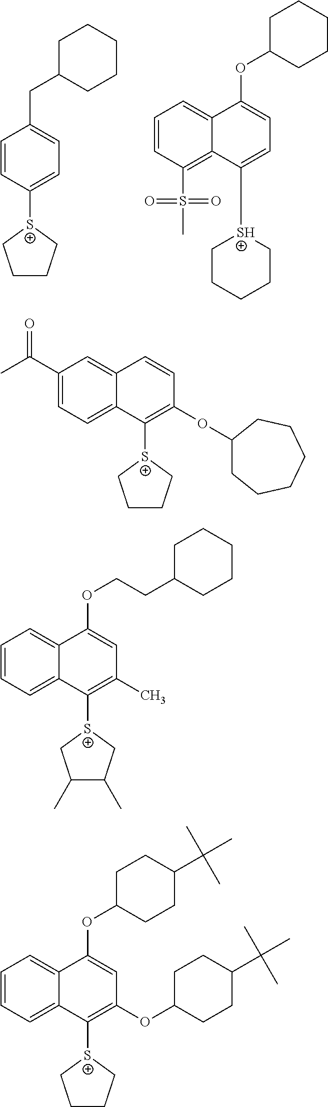

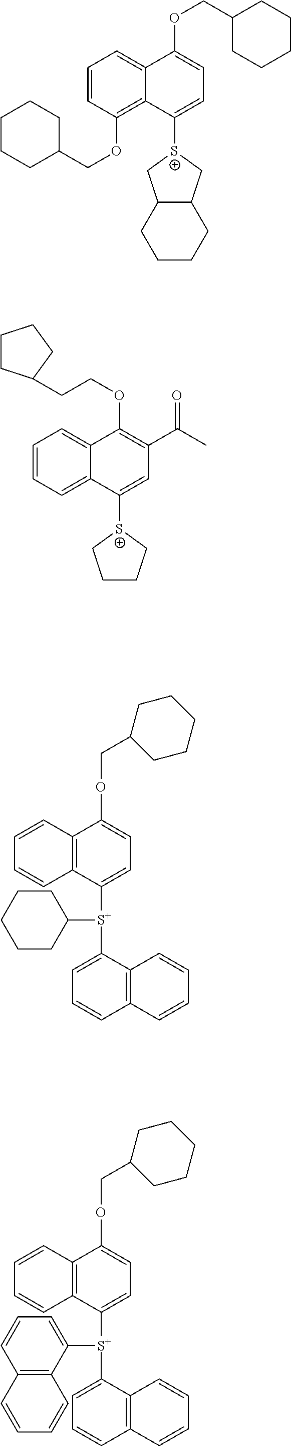

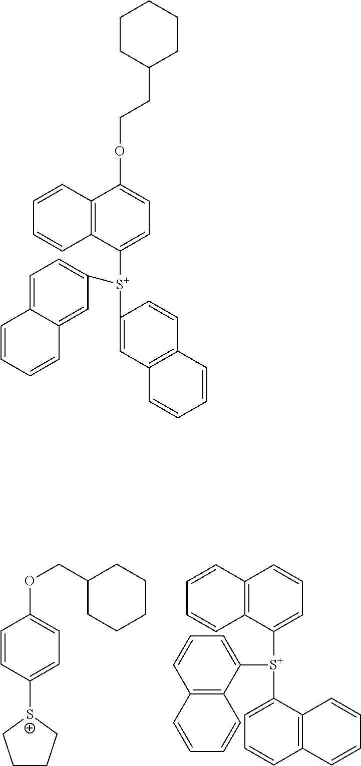

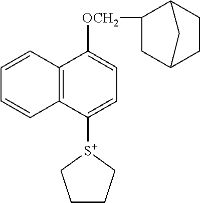

In formula (ZII), each of R₂₀₄ and R₂₀₅ independently represents an aryl group, an alkyl group or a cycloalkyl group.

In formula (ZII), the aryl group of R₂₀₄ and R₂₀₅ is preferably a phenyl group or a naphthyl group, more preferably a phenyl group. The aryl group of R₂₀₄ and R₂₀₅ may be an aryl group having a heterocyclic structure containing an oxygen atom, a nitrogen atom, a sulfur atom or the like. Examples of the heterocyclic structure include pyrrole, furan, thiophene, indole, benzofuran and benzothiophene.

The alkyl group and cycloalkyl group in R₂₀₄ and R₂₀₅ are preferably a linear or branched alkyl group having a carbon number of 1 to 10 and a cycloalkyl group having a carbon number of 3 to 10.

The aryl group, alkyl group and cycloalkyl group of R₂₀₄ and R₂₀₅ may have a substituent. Examples of the substituent which the aryl group, alkyl group and cycloalkyl group of R₂₀₄ and R₂₀₅ may have include an alkyl group (for example, having a carbon number of 1 to 15), a cycloalkyl group (for example, having a carbon number of 3 to 15), an aryl group (for example, having a carbon number of 6 to 15), an alkoxy group (for example, having a carbon number of 1 to 15), a halogen atom, a hydroxyl group and a phenylthio group.

Z⁻ represents an anion of the acid represented by formula (I).

Other examples of the acid generator include compounds represented by the following formulae (ZV) and (ZVI):

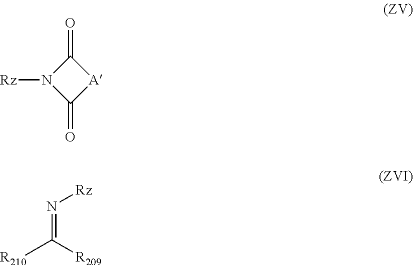

In formulae (ZV) and (ZVI), each of R₂₀₉ and R₂₁₀ independently represents an alkyl group, a cycloalkyl group, an aryl group or a cyano group. Examples of the aryl group, alkyl group and cycloalkyl group of R₂₀₉ and R₂₁₀ are the same as those of the aryl group, alkyl group and cycloalkyl group of R₂₀₁ to R₂₀₃ in formula (ZI-1). The aryl group, alkyl group and cycloalkyl group of R₂₀₉ and R₂₁₀ may have a substituent. Examples of this substituent are also the same as those of the substituent which the aryl group, alkyl group and cycloalkyl group of R₂₀₁ to R₂₀₃ in formula (ZI-1) may have.

A′ represents an alkylene group, an alkenylene group or an arylene group.

The alkylene group as A′ may have a substituent and is preferably an alkylene group having a carbon number of 1 to 8, such as methylene group, ethylene group, propylene group, butylene group, hexylene group and octylene group.

The alkenylene group as A′ may have a substituent and is preferably an alkenylene group having a carbon number of 2 to 6, such as ethenylene group, propenylene group and butenylene group.

The arylene group as A′ may have a substituent and is preferably an arylene group having a carbon number of 6 to 15, such as phenylene group, tolylene group and naphthylene group.

Examples of the substituent which A′ may have include those having active hydrogen, such as cycloalkyl group, aryl group, amino group, amido group, ureido group, urethane group, hydroxyl group and carboxyl group, a halogen atom (e.g., fluorine, chlorine, bromine, iodine), an alkoxy group (e.g., methoxy, ethoxy, propoxy, butoxy), a thioether group, an acyl group (e.g., acetyl, propanoyl, benzoyl), an acyloxy group (e.g., acetoxy, propanoyloxy, benzoyloxy), an alkoxycarbonyl group (e.g., methoxycarbonyl, ethoxycarbonyl, propoxycarbonyl), a cyano group and a nitro group. As for the arylene group, examples of the substituent further include an alkyl group (e.g., methyl, ethyl, propyl, butyl).

Rz represents a structure where H of the acid represented by formula (I) is dissociated, and is specifically a group represented by the following formula (I-s):

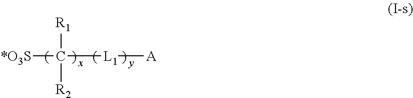

In the formula, R₁, R₂, L₁, A, x and y have the same meanings as in formula (I), and * represents a bonding site to the residue structure of the compound represented by formula (ZV) or (ZVI).

Specific examples of the residue structures of the compounds represented by formulae (ZV) and (ZVI) are illustrated below.

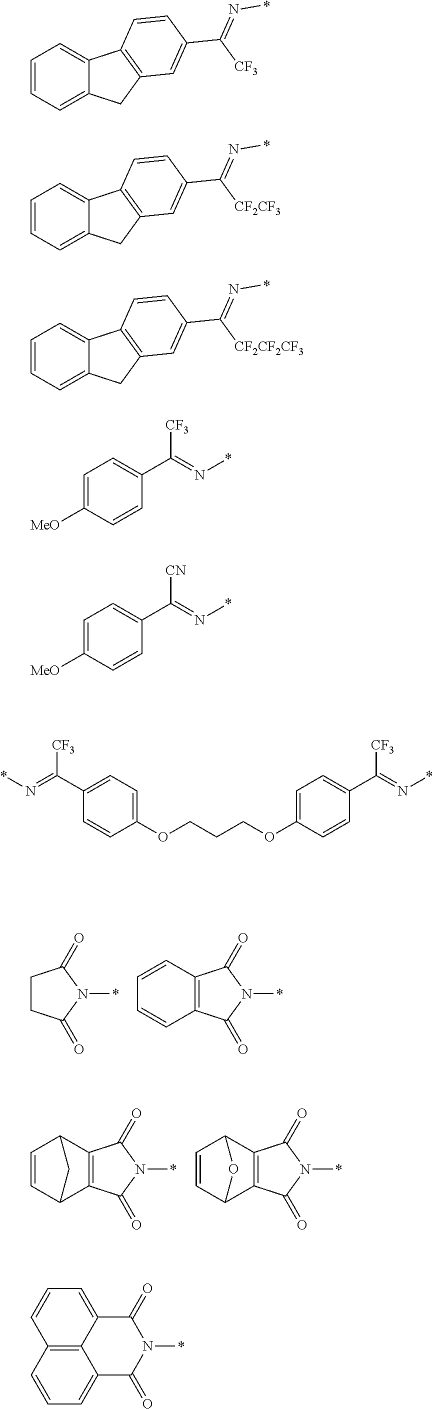

Specific examples of the compound capable of generating an acid represented by formula (I) include a combination of a cation structure as the specific structure illustrated for formulae (ZI) and (ZII) and an anion structure as the specific structure of the acid represented by formula (I), and a combination of a specific structure of (ZV) and (ZVI) and a structure where H of an acid as the specific structure of the acid represented by formula (I) is dissociated.

Specific examples of the compound capable of generating an acid represented by formula (I) are illustrated below, but the present invention is not limited to these compounds.

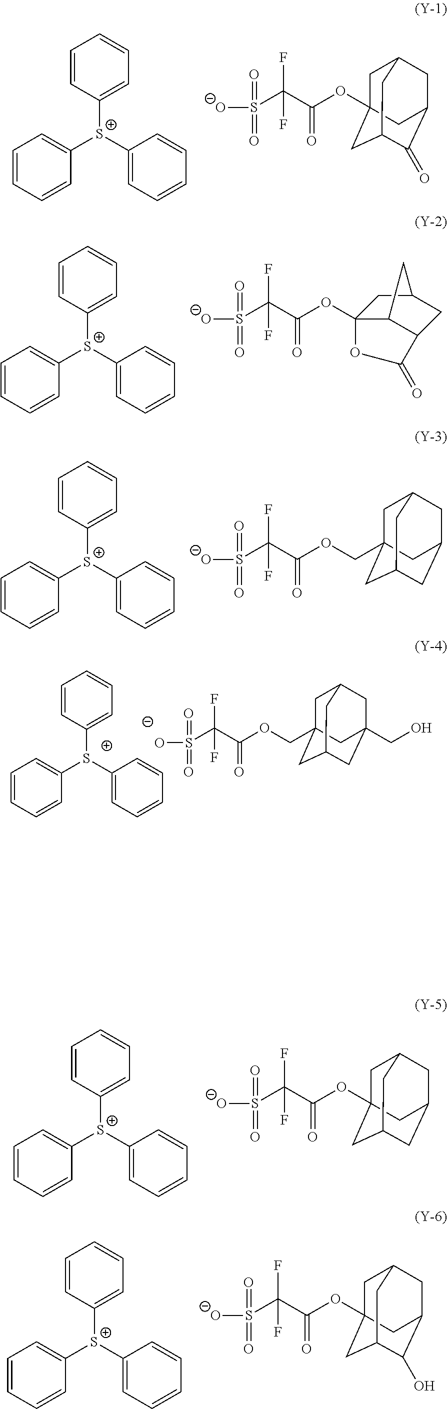

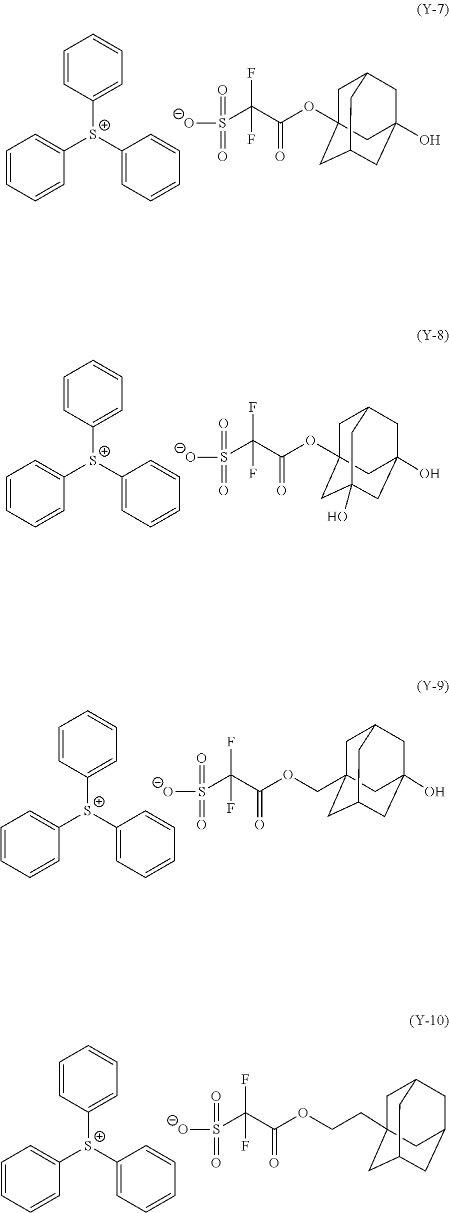

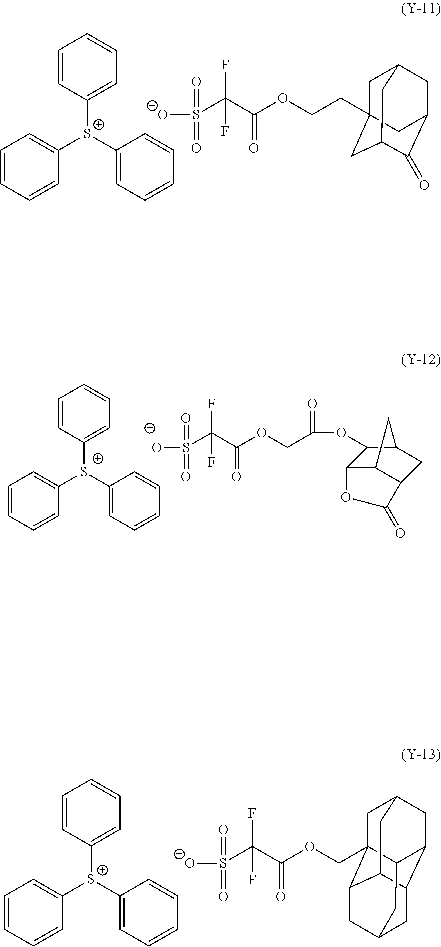

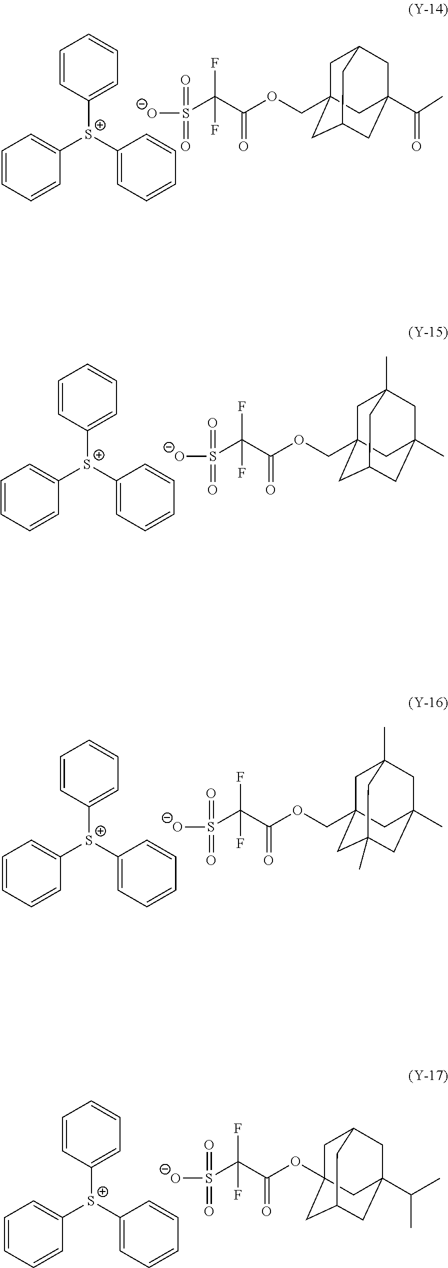

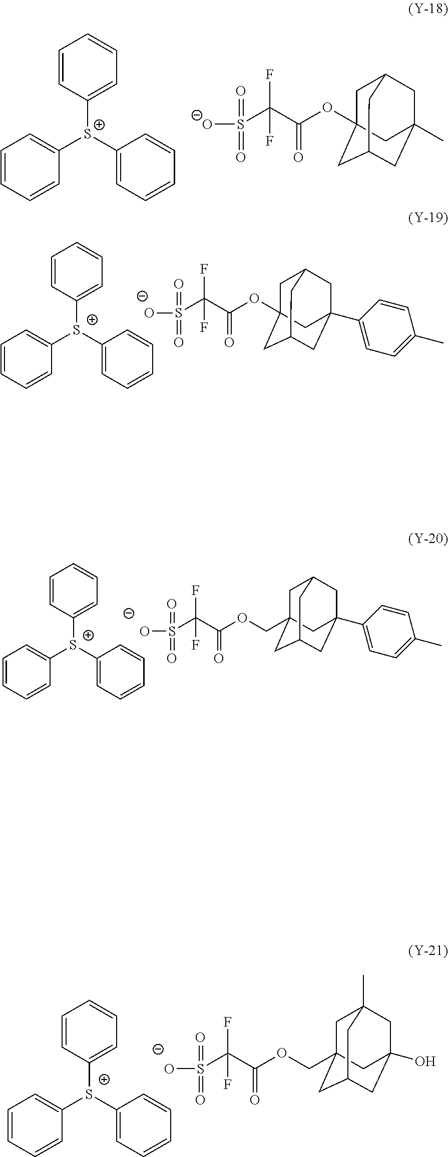

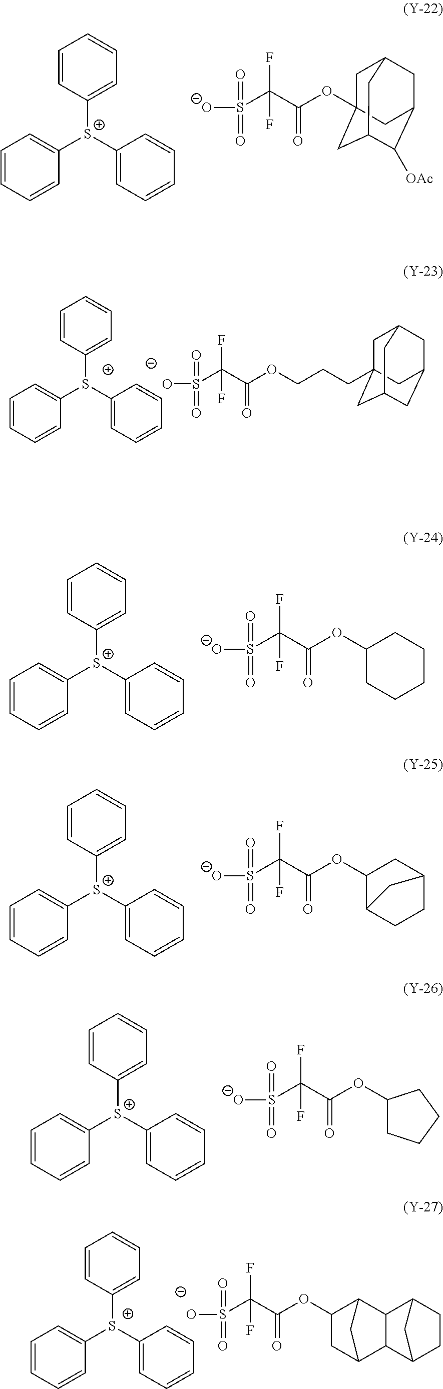

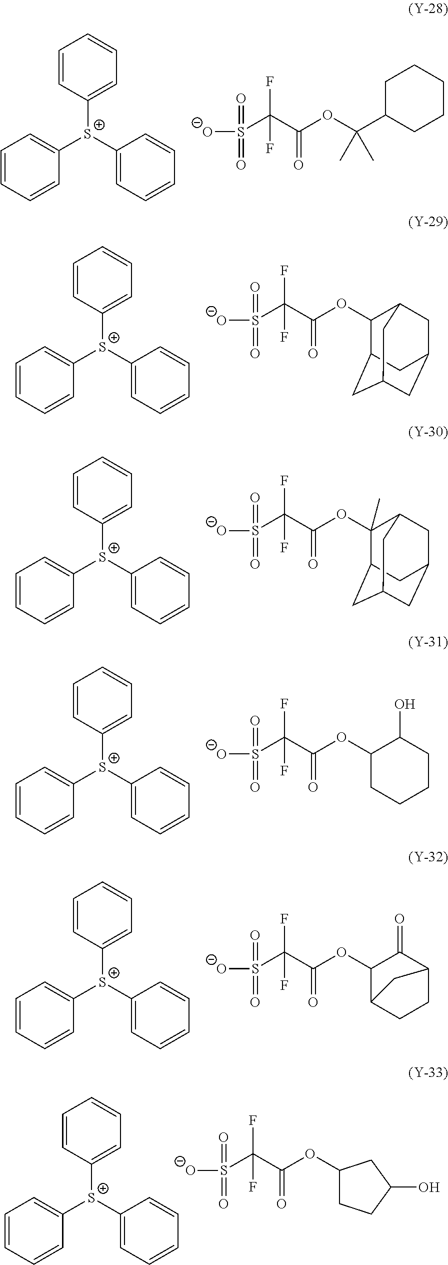

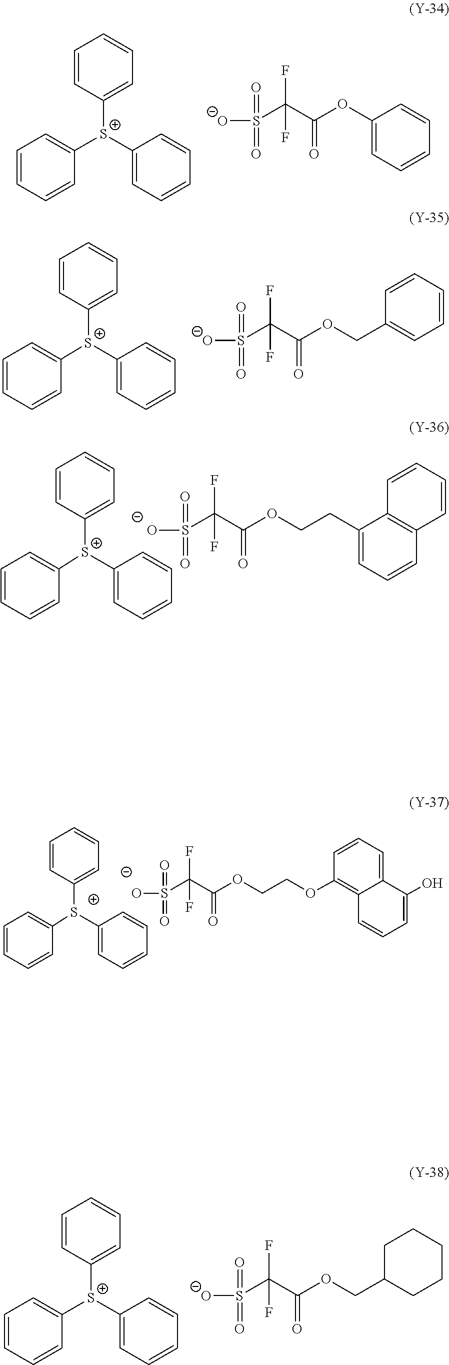

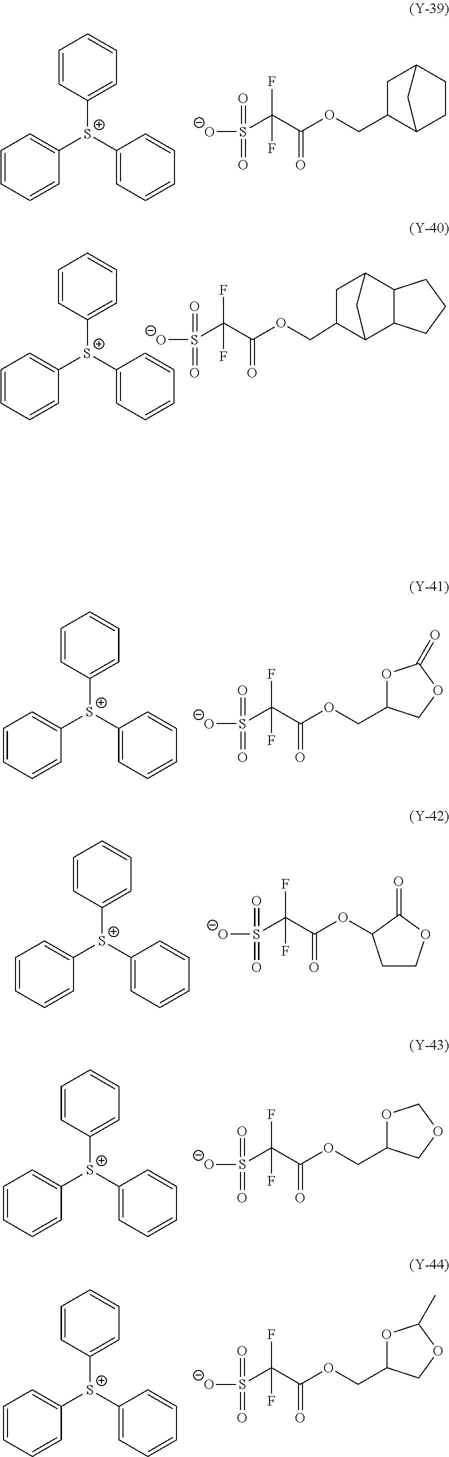

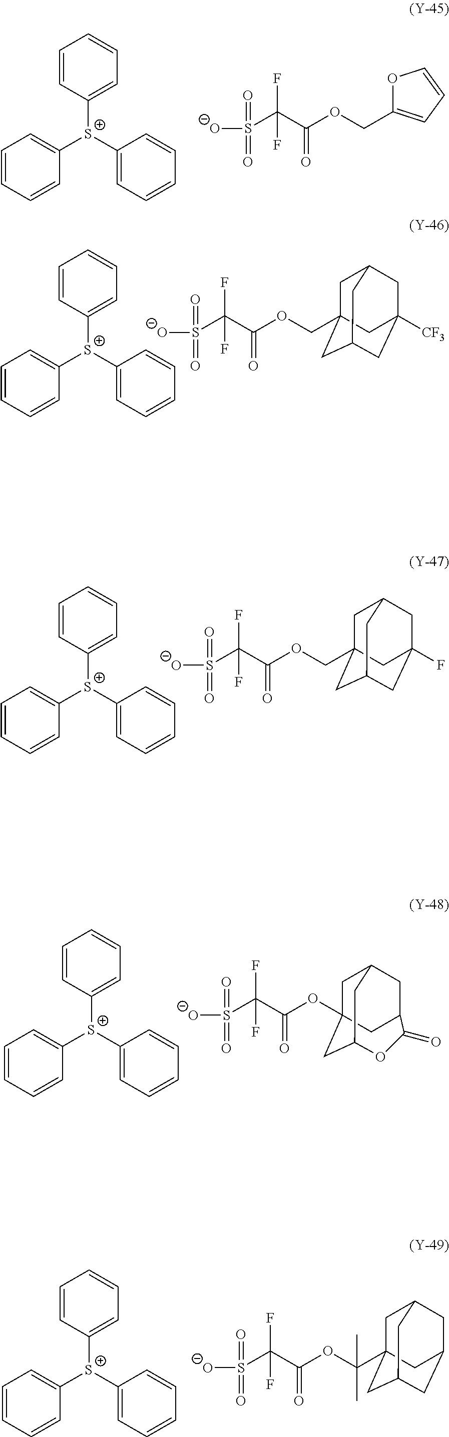

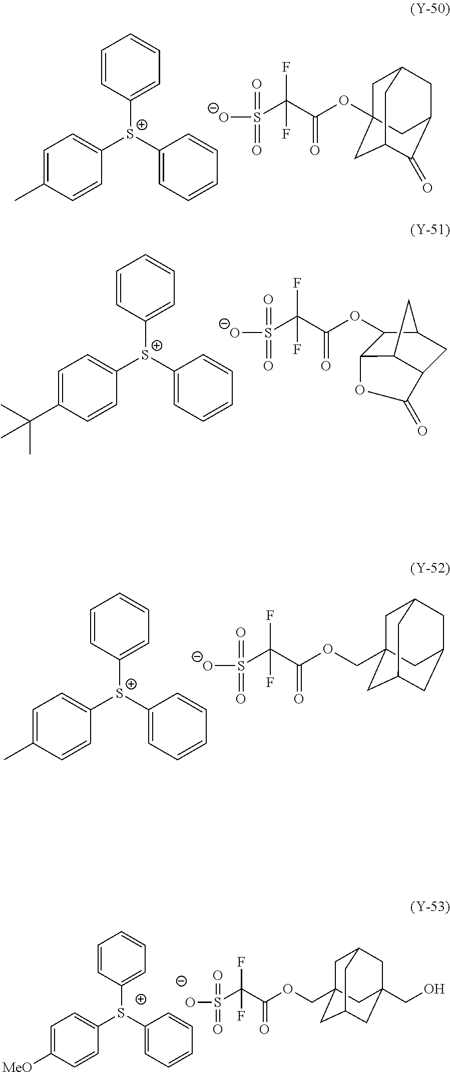

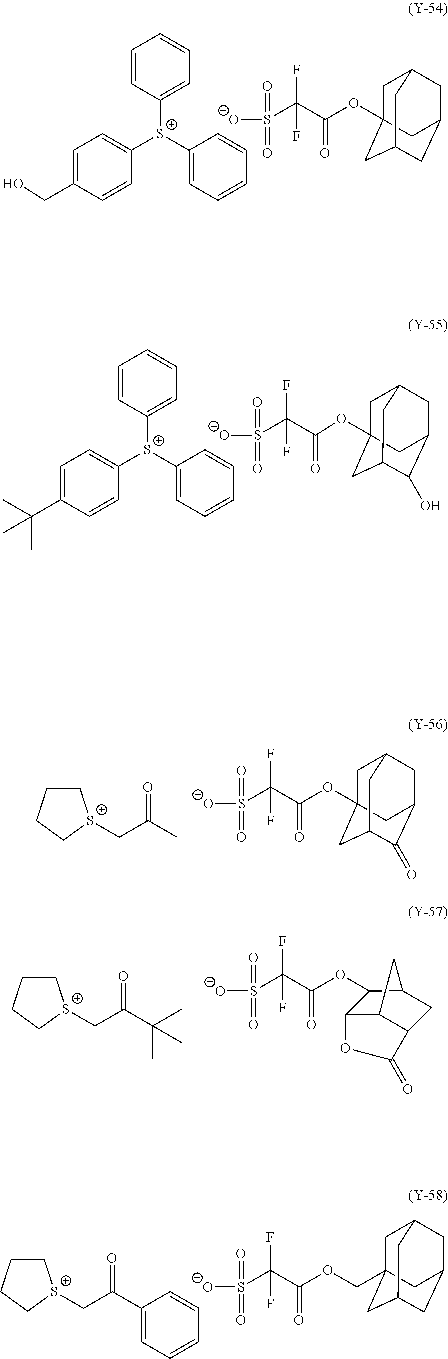

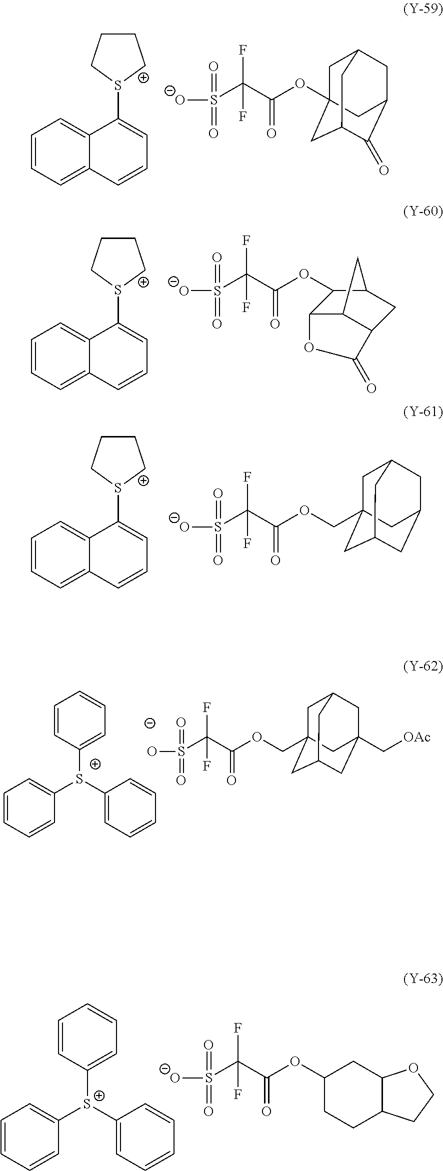

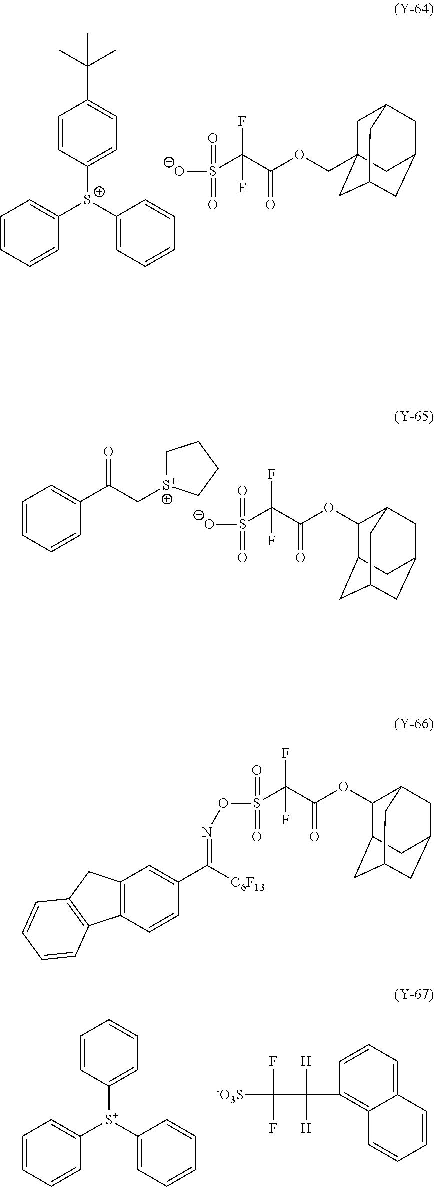

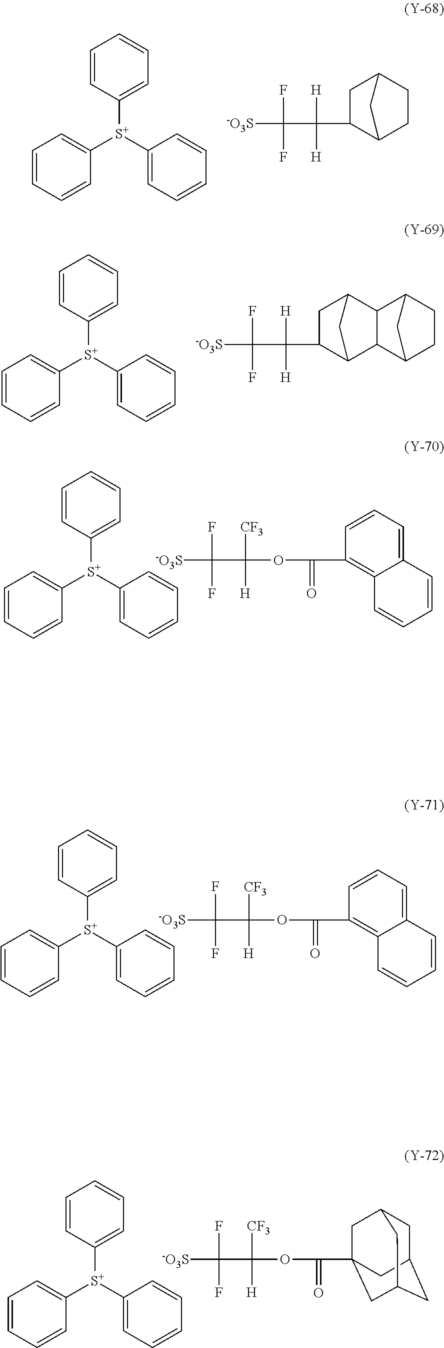

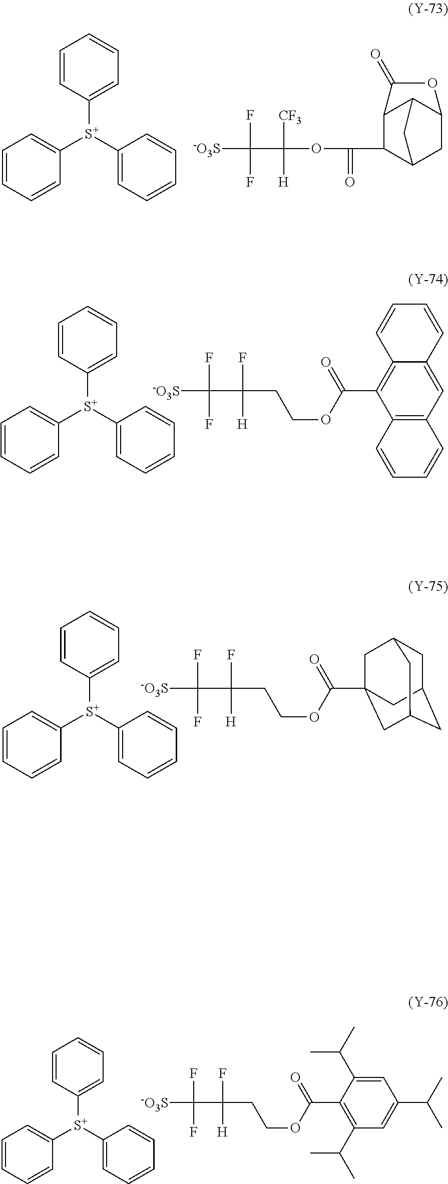

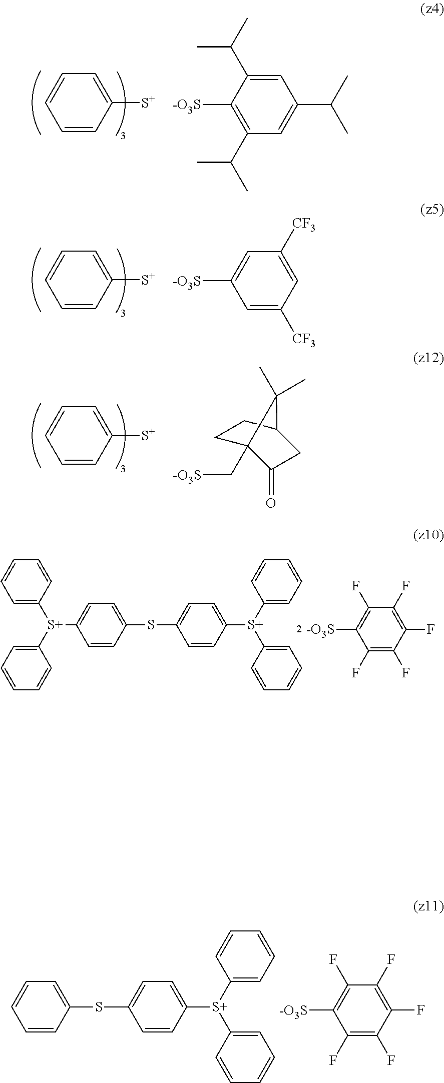

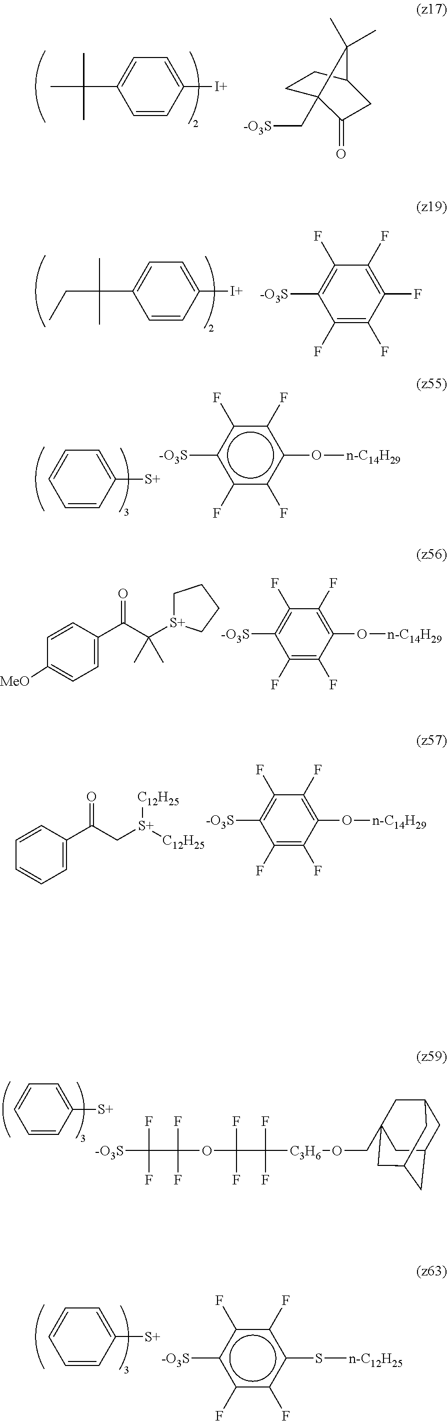

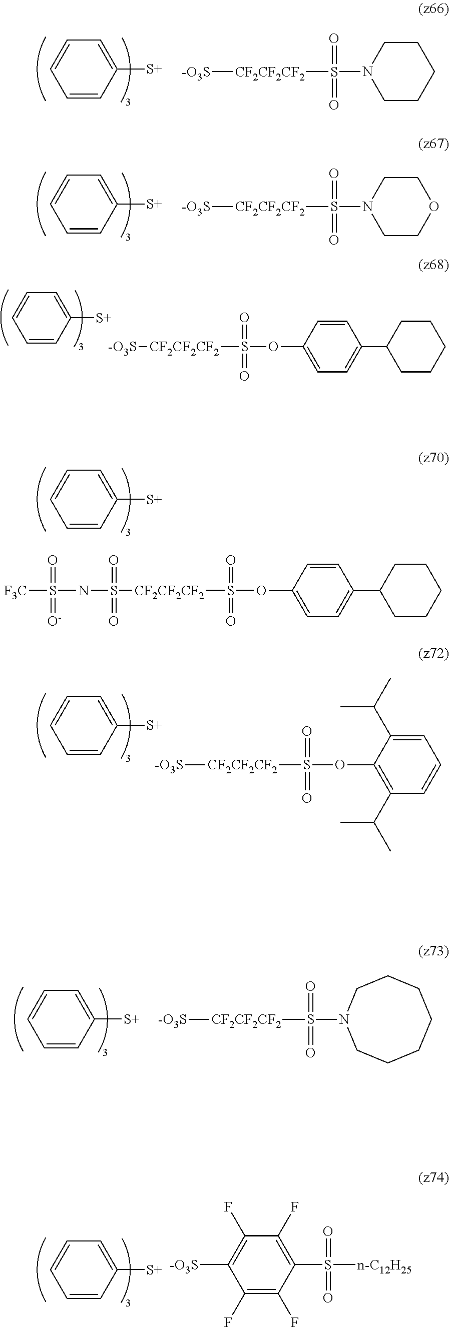

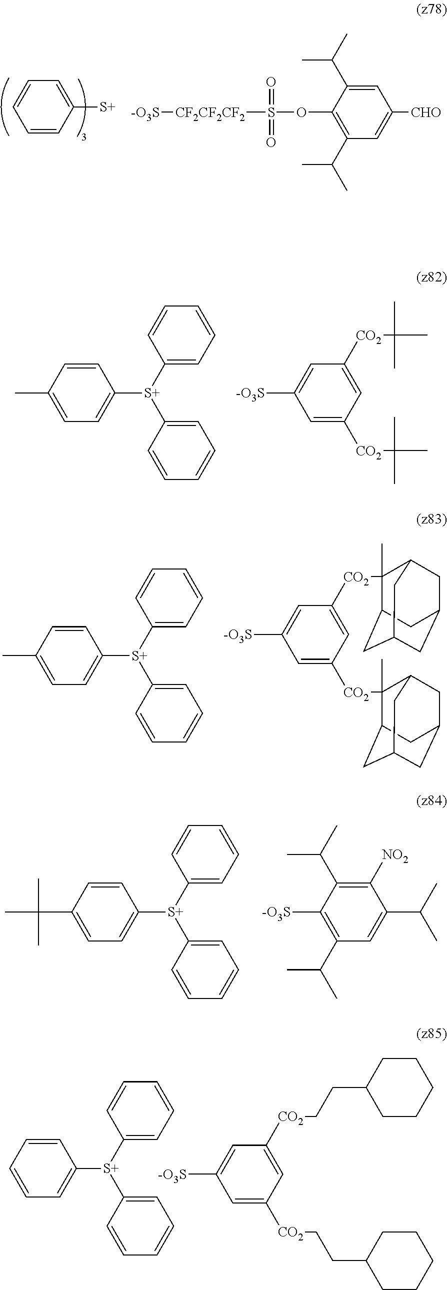

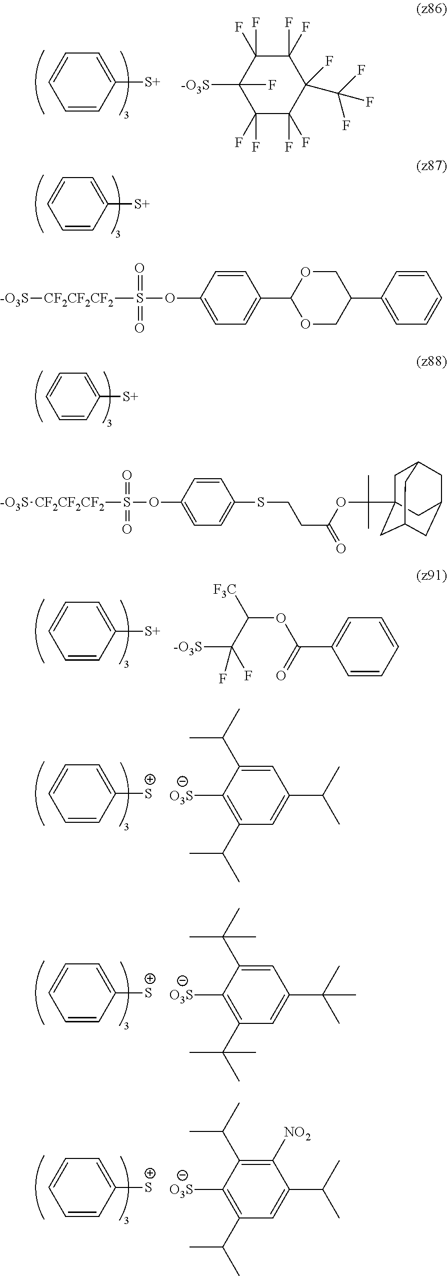

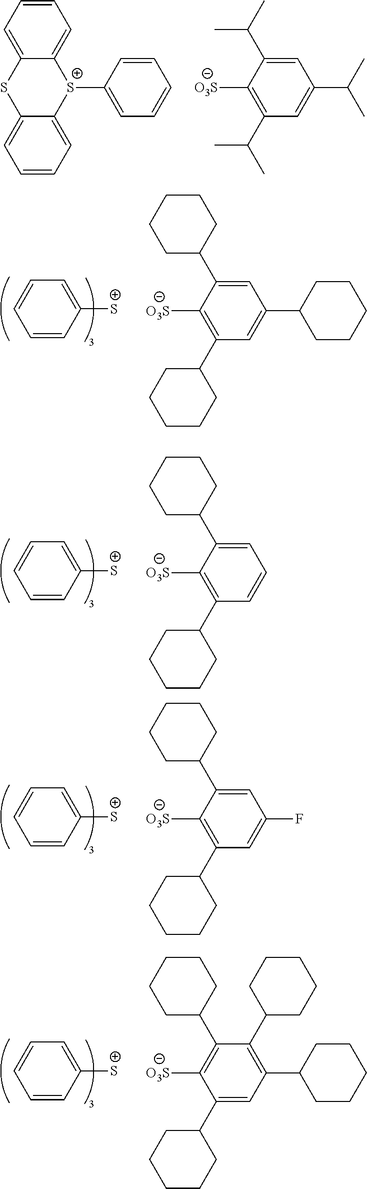

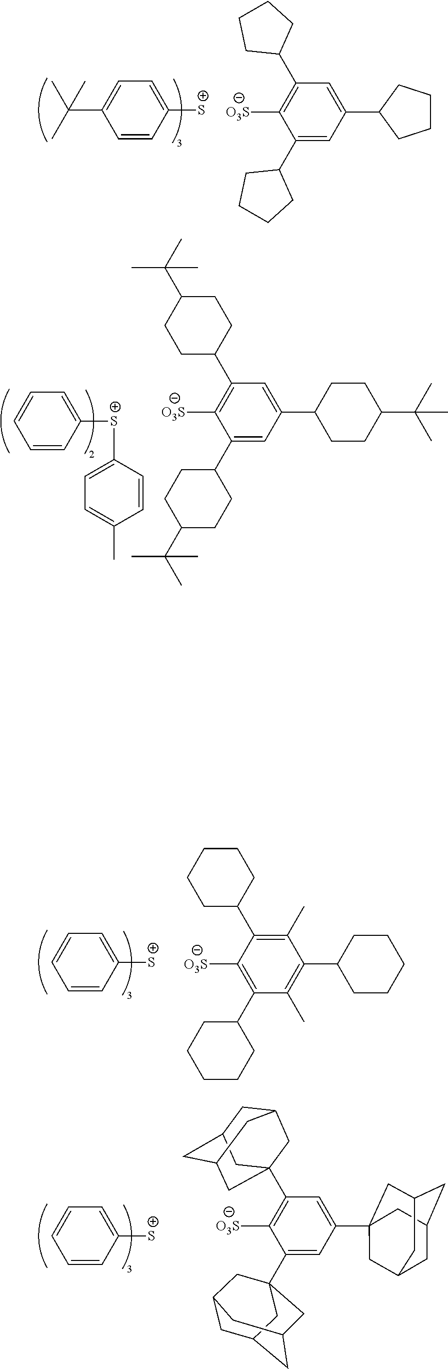

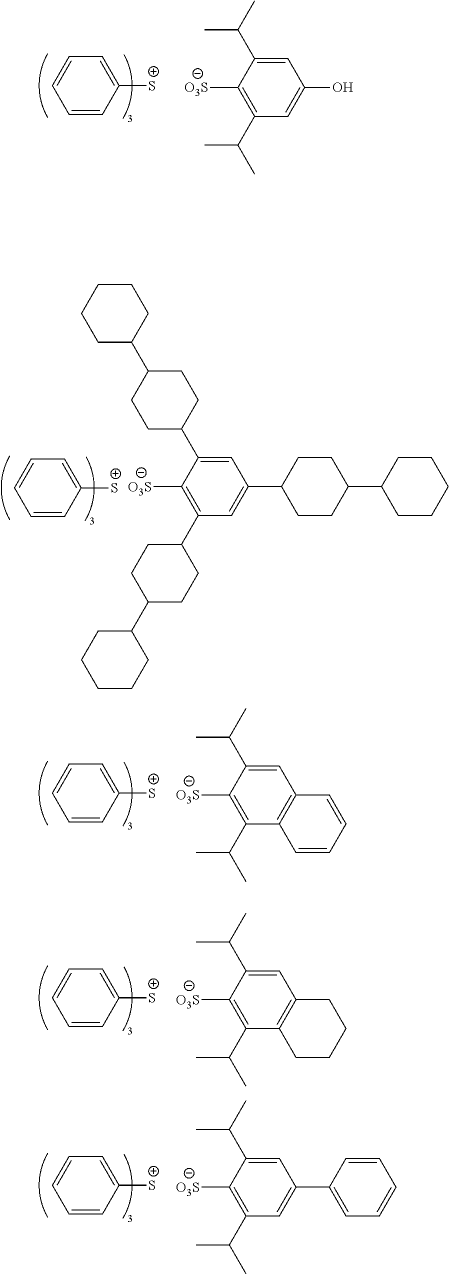

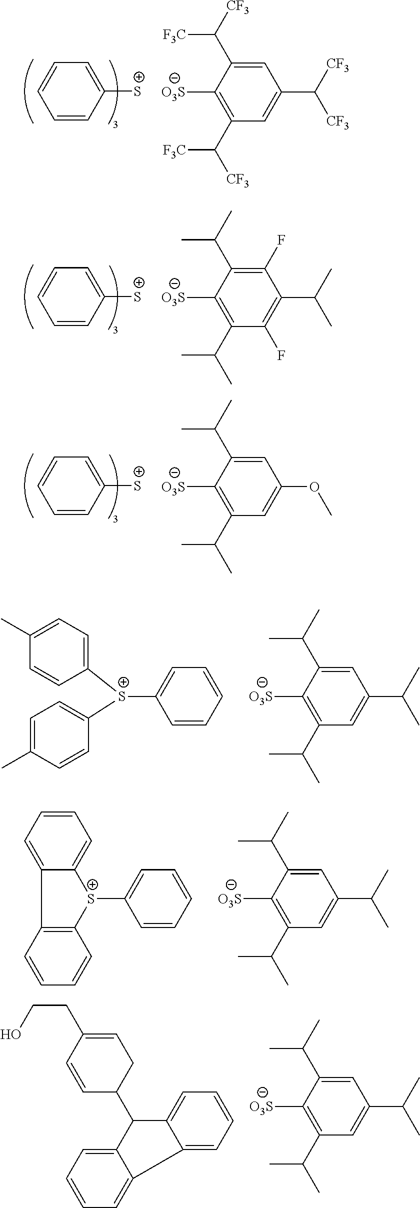

The compound capable of generating an acid represented by formula (I) can be synthesized by a known method, for example, can be synthesized in accordance with the methods described in JP-A-2007-161707 and U.S. Pat. No. 7,541,133.

As for the compound capable of generating an acid represented by formula (I), one kind may be used, or two or more kinds may be used in combination.

The content of the compound capable of generating an acid represented by formula (I) in the resist composition is preferably from 0.1 to 20 mass %, more preferably from 0.1 to 15 mass %, still more preferably from 0.5 to 15 mass %, yet still more preferably from 0.5 to 10 mass %, and most preferably from 1 to 7 mass %, based on the entire solid content of the resist composition.

The molecular weight of the compound capable of generating an acid represented by formula (I) is generally from 300 to 1,000, preferably from 400 to 800, more preferably from 500 to 700.

The compound (B) capable of generating an acid represented by formula (I) may be used in combination with other acid generators.

Examples of the acid generator other than the compound (B), which can be used in combination with the compound (B), include acid generators described in paragraph [0150] of U.S. Patent Application Publication No. 2008/0248425.

The acid generator other than the compound (B), which can be used in combination, may be appropriately selected from a photo-initiator for cationic photopolymerization, a photo-initiator for radical photopolymerization, a photo-decoloring agent for dyes, a photo-discoloring agent, a known compound that generates an acid upon irradiation with an actinic ray or radiation and is used for microresist or the like, and a mixture thereof.

Furthermore, other diazonium salt, phosphonium salt, sulfonium salt, iodonium salt, imidosulfonate, oxime sulfonate, diazodisulfone, disulfone or o-nitrobenzyl sulfonate may be used in combination, and a compound where such a group or compound capable of generating an acid upon irradiation with an actinic ray or radiation is introduced into the main or side chain of the polymer, for example, compounds described in U.S. Pat. No. 3,849,137, German Patent 3,914,407, JP-A-63-26653, JP-A-55-164824, JP-A-62-69263, JP-A-63-146038, JP-A-63-163452, JP-A-62-153853 and JP-A-63-146029, may be used.

Also, compounds capable of generating an acid by the effect of light described, for example, in U.S. Pat. No. 3,779,778 and European Patent 126,712 may be used.

Out of the acid generators (B) other than the acid generator (B), which can be used in combination with the acid generator (B) capable of generating an acid represented by formula (I), preferred compounds include compounds represented by the following formulae (ZI′) and (ZII′):

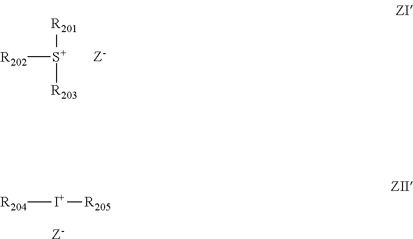

In formulae (ZI′) and (ZIP), R₂₀₁, R₂₀₂, R₂₀₃, R₂₀₄ and R₂₀₅ have the same meanings as in formulae (ZI) and (ZII).

Z⁻ represents a non-nucleophilic anion other than the anion of the acid represented by formula (I).

Examples of the non-nucleophilic anion as Z⁻ include a sulfonate anion, a carboxylate anion, a sulfonylimide anion, a bis(alkylsulfonyl)imide anion and a tris(alkylsulfonyl)methyl anion.

The non-nucleophilic anion is an anion having an extremely low ability of causing a nucleophilic reaction and this anion can suppress the decomposition with aging due to intramolecular nucleophilic reaction. Thanks to this anion, the aging stability of the resist is enhanced.

Examples of the sulfonate anion include an aliphatic sulfonate anion other than the anion of the acid represented by formula (I).

Examples of the carboxylate anion include an aliphatic carboxylate anion, an aromatic carboxylate anion and an aralkylcarboxylate anion.

The aliphatic moiety in the aliphatic sulfonate anion is preferably an alkyl group having a carbon number of 1 to 30, such as methyl group, ethyl group, propyl group, isopropyl group, n-butyl group, isobutyl group, sec-butyl group, pentyl group, neopentyl group, hexyl group, heptyl group, octyl group, nonyl group, decyl group, undecyl group, dodecyl group, tridecyl group, tetradecyl group, pentadecyl group, hexadecyl group, heptadecyl group, octadecyl group, nonadecyl group and eicosyl group.

The alkyl group in the aliphatic sulfonate anion may have a substituent. Examples of the substituent include a nitro group, a halogen atom (e.g., fluorine group, chlorine group, bromine group, iodine group), a carboxyl group, a hydroxyl group, an amino group, a cyano group, an alkoxy group (preferably having a carbon number of 1 to 15), an alkoxycarbonyl group (preferably having a carbon number of 2 to 7), an acyl group (preferably having a carbon number of 2 to 12), an alkoxycarbonyloxy group (preferably having a carbon number of 2 to 7), an alkylthio group (preferably having a carbon number of 1 to 15), an alkylsulfonyl group (preferably having a carbon number of 1 to 15), an alkylaminosulfonyl group (preferably having a carbon number of 1 to 15), and an alkyloxyalkyloxy group (preferably having a carbon number of 5 to 20).

The aliphatic moiety in the aliphatic carboxylate anion includes the same alkyl group or cycloalkyl group (preferably a cycloalkyl group having a carbon number of 3 to 30, more preferably a cyclopropyl group, a cyclopentyl group, a cyclohexyl group, an adamantyl group, a norbornyl group or a bornyl group) as in the aliphatic sulfonate anion.

The aromatic group in the aromatic carboxylate anion includes the same aryl group as in the aromatic sulfonate anion.

The aralkyl group in the aralkylcarboxylate anion is preferably an aralkyl group having a carbon number of 7 to 12, such as benzyl group, phenethyl group, naphthylmethyl group, naphthylethyl group and naphthylbutyl group.

The alkyl group, cycloalkyl group, aryl group and aralkyl group in the aliphatic carboxylate anion, aromatic carboxylate anion and aralkylcarboxylate anion may have a substituent. Examples of the substituent of the alkyl group, cycloalkyl group, aryl group and aralkyl group in the aliphatic carboxylate anion, aromatic carboxylate anion and aralkylcarboxylate anion include the same halogen atom, alkyl group, cycloalkyl group, alkoxy group and alkylthio group as those in the aromatic sulfonate anion.

Examples of the sulfonylimide anion include saccharin anion.

The alkyl group in the bis(alkylsulfonyl)imide anion and tris(alkylsulfonyl)methyl anion is preferably an alkyl group having a carbon number of 1 to 5, and examples thereof include a methyl group, an ethyl group, a propyl group, an isopropyl group, an n-butyl group, an isobutyl group, a sec-butyl group, a pentyl group and a neopentyl group. Examples of the substituent of such an alkyl group include a halogen atom, a halogen atom-substituted alkyl group, an alkoxy group, an alkylthio group, an alkyloxysulfonyl group, an aryloxysulfonyl group, and a cycloalkylaryloxysulfonyl group, with a fluorine atom-substituted alkyl group being preferred.

Other examples of the non-nucleophilic anion include fluorinated phosphorus, fluorinated boron and fluorinated antimony.

The non-nucleophilic anion of Z⁻ is preferably an aliphatic sulfonate anion substituted with a fluorine atom at the α-position of the sulfonic acid, an aromatic sulfonate anion substituted with a fluorine atom or a fluorine atom-containing group, a bis(alkylsulfonyl)imide anion in which the alkyl group is substituted with a fluorine atom, or a tris(alkylsulfonyl)methide anion in which the alkyl group is substituted with a fluorine atom. The non-nucleophilic anion is more preferably a perfluoroaliphatic sulfonate anion having a carbon number of 4 to 8, still more preferably nonafluorobutanesulfonate anion or perfluorooctanesulfonate anion.

The compound may be a compound having a plurality of structures represented by formula (ZI′). For example, the compound may be a compound having a structure where at least one of R₂₀₁ to R₂₀₃ in the compound represented by formula (ZI′) is bonded to at least one of R₂₀₁ to R₂₀₃ in another compound represented by formula (ZI′).

The component (ZI′) is more preferably a compound (ZI-1′), (ZI-2′) or (ZI-3′) described below.

The compound (ZI-1′) is an arylsulfonium compound where at least one of R₂₀₁ to R₂₀₃ in formula (ZI′) is an aryl group, that is, a compound having an arylsulfonium as the cation. R₂₀₁ to R₂₀₃ in the compound (ZI-1′) have the same meanings as R₂₀₁ to R₂₀₃ in the compound (ZI-1).

The compound (ZI-2′) is described below.

The compound (ZI-2′) is a compound where each of R₂₀₁ to R₂₀₃ in formula (ZI′) independently represents an aromatic ring-free organic group. R₂₀₁ to R₂₀₃ in the compound (ZI-2′) have the same meanings as R₂₀₁ to R₂₀₃ in the compound (ZI-2).

The compound (ZI-3′) is a compound represented by the following formula (ZI-3′), and this is a compound having a phenacylsulfonium salt structure.

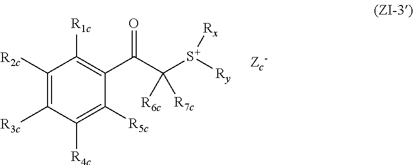

In formula (ZI-3), R_{1c} to R₇, Rₓ and R_{y} have the same meanings as those in formula (ZI-3).

Zc⁻ represents a non-nucleophilic anion other than the anion of the acid represented by formula (I), and the non-nucleophilic anion includes the same non-nucleophilic anion as Z⁻ in formula (ZI′).

Other examples of the acid generator include compounds represented by the following formulae (ZIV′), (ZV′) and (ZVI′):

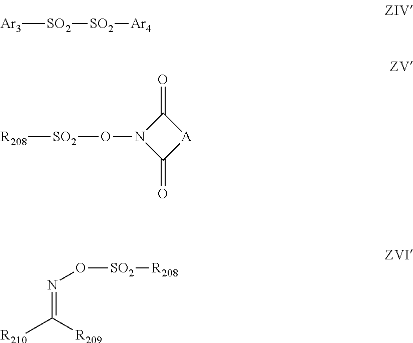

In formulae (ZIV′) to (ZVI′), each of Ar₃ and Ar₄ independently represents an aryl group.

Each of R₂₀₈, R₂₀₉ and R₂₁₀ independently represents an alkyl group.

A represents an alkylene group, an alkenylene group or an arylene group and has the same meaning as that in formula (ZV).

Among the acid generators (B′), more preferred are the compounds represented by formulae (ZI′) and (ZII′).

Specific examples of the aryl group of Ar₃ and Ar₄ are the same as specific examples of the aryl group as R₂₀₁, R₂₀₂ and R₂₀₃ in formula (ZI-1).

Specific examples of the alkyl group and cycloalkyl group of R₂₀₈, R₂₀₉ and R₂₁₀ are the same as specific examples of the alkyl group and cycloalkyl group of R₂₀₁, R₂₀₂ and R₂₀₃ in formula (ZI-2).

The acid generator (B′) is preferably a compound that generates an acid having one sulfonic acid group or imide group, more preferably a compound that generates a monovalent perfluoroalkanesulfonic acid, a compound that generates an aromatic sulfonic acid substituted with a monovalent fluorine atom or a fluorine atom-containing group, or a compound that generates an imide acid substituted with a monovalent fluorine atom or a fluorine atom-containing group, still more preferably a sulfonium salt of fluoro-substituted alkanesulfonic acid, fluorine-substituted benzenesulfonic acid, fluorine-substituted imide acid or fluorine-substituted methide acid. In particular; the acid generator which can be used is preferably a compound that generates a fluoro-substituted alkanesulfonic acid, a fluoro-substituted benzenesulfonic acid or a fluoro-substituted imide acid, where pKa of the acid generated is −1 or less, and in this case, the sensitivity is enhanced.

Among the acid generators (B′), particularly preferred examples are illustrated below.

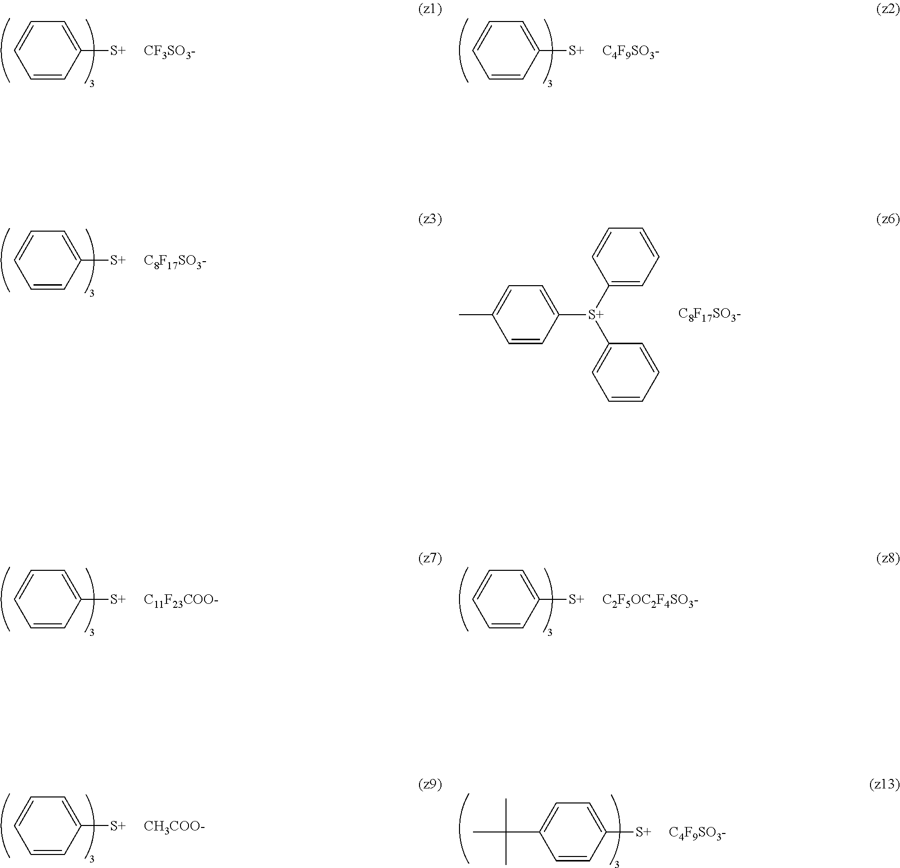

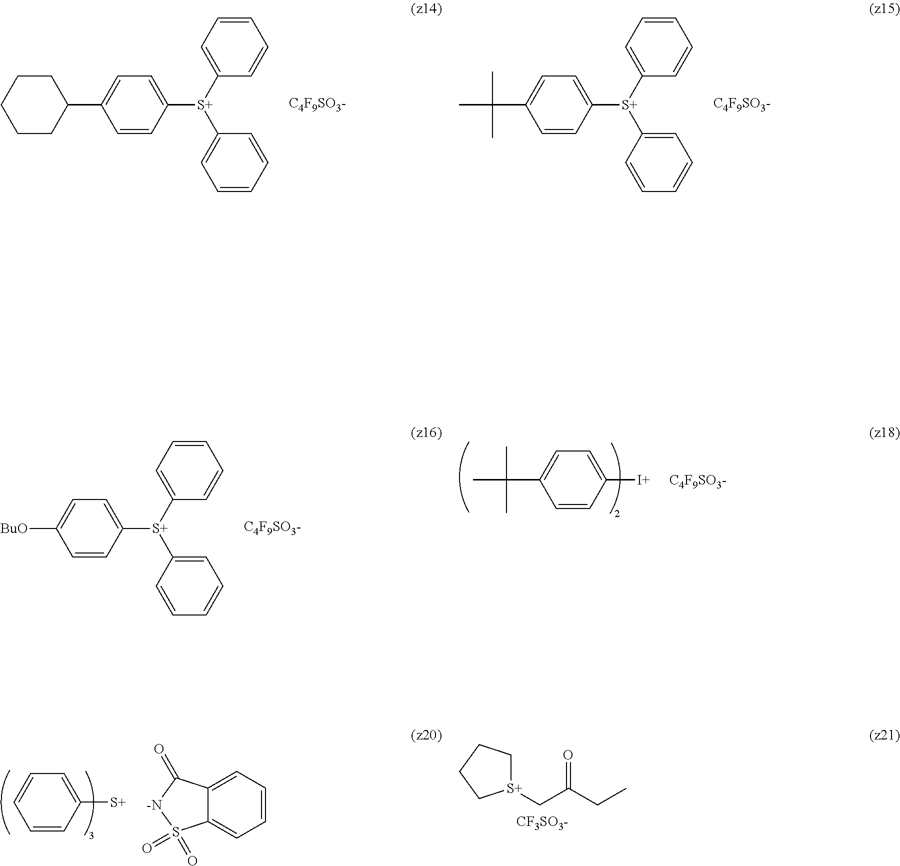

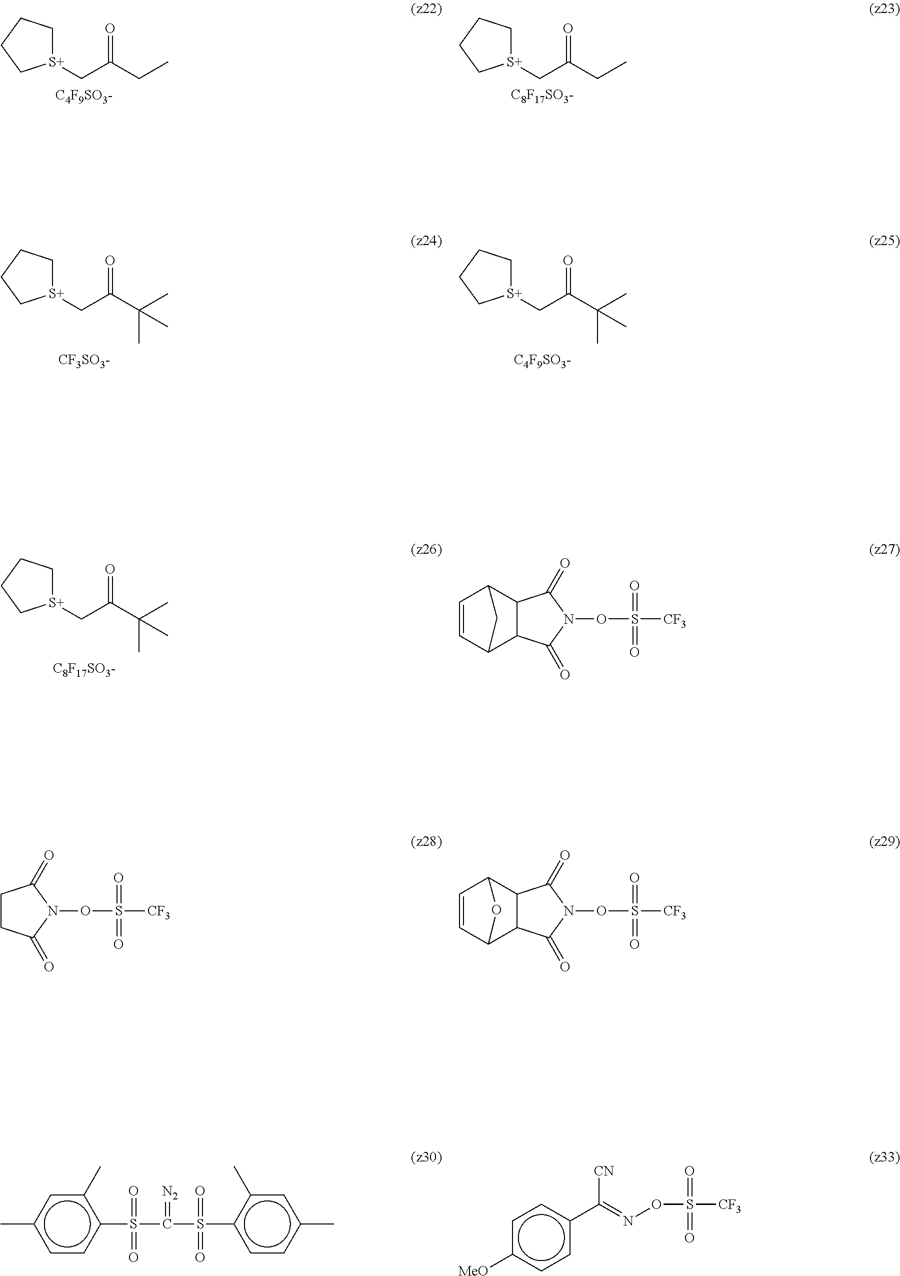

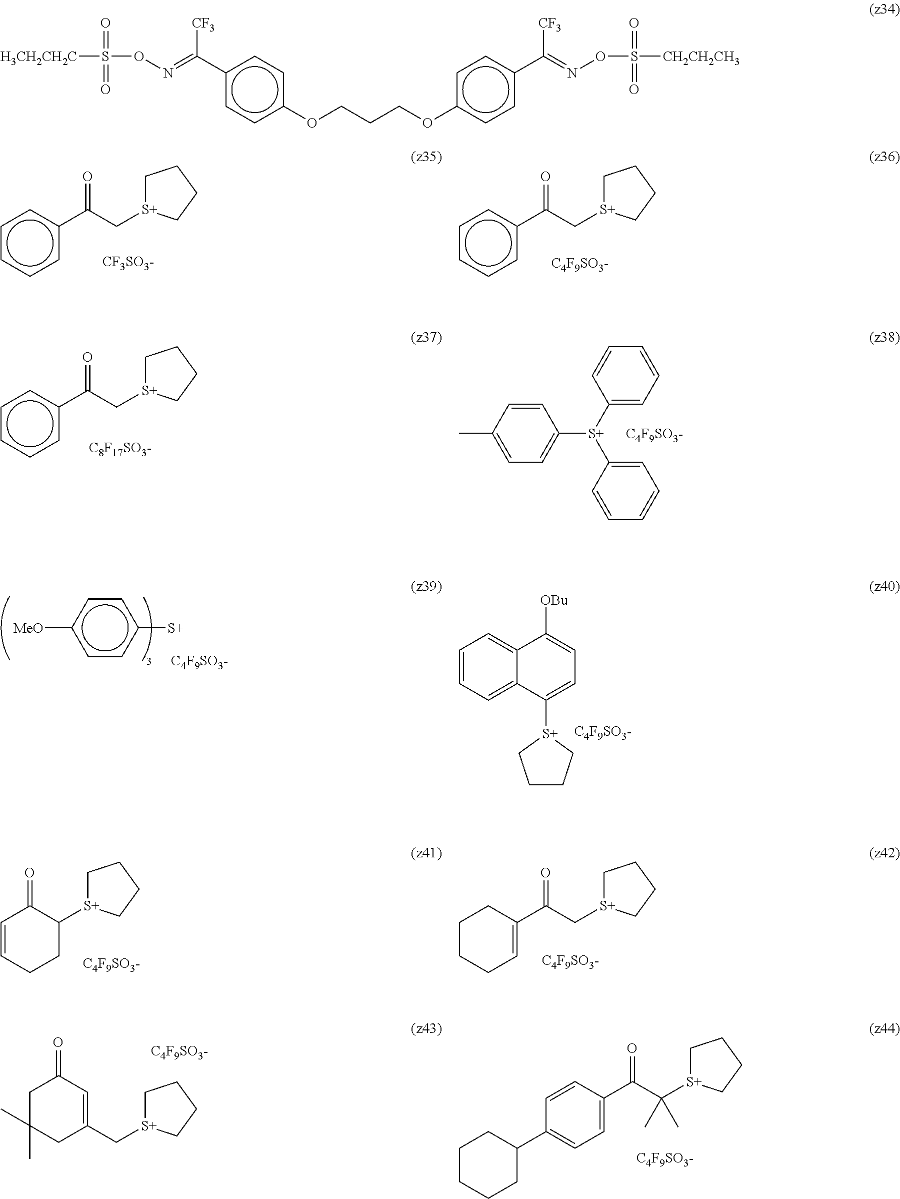

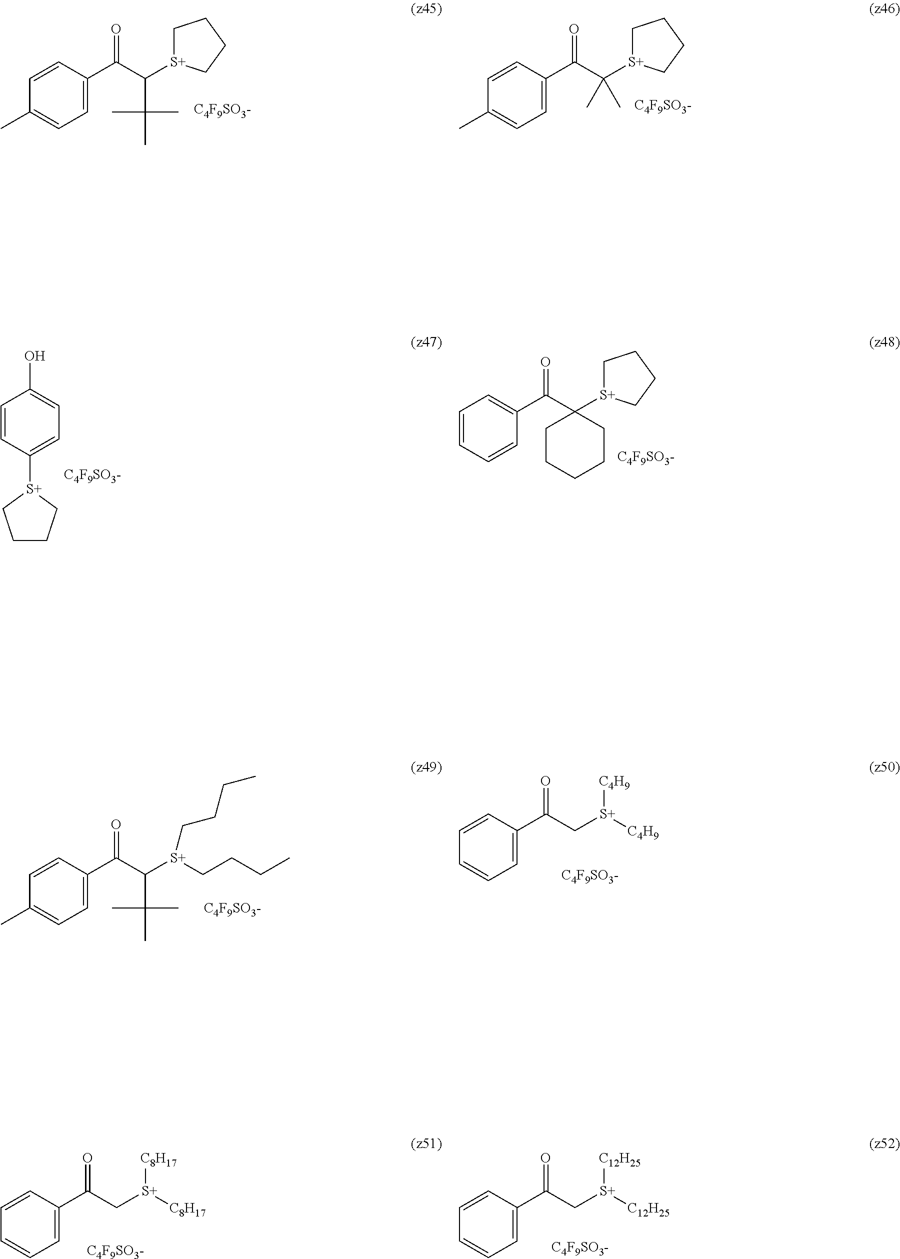

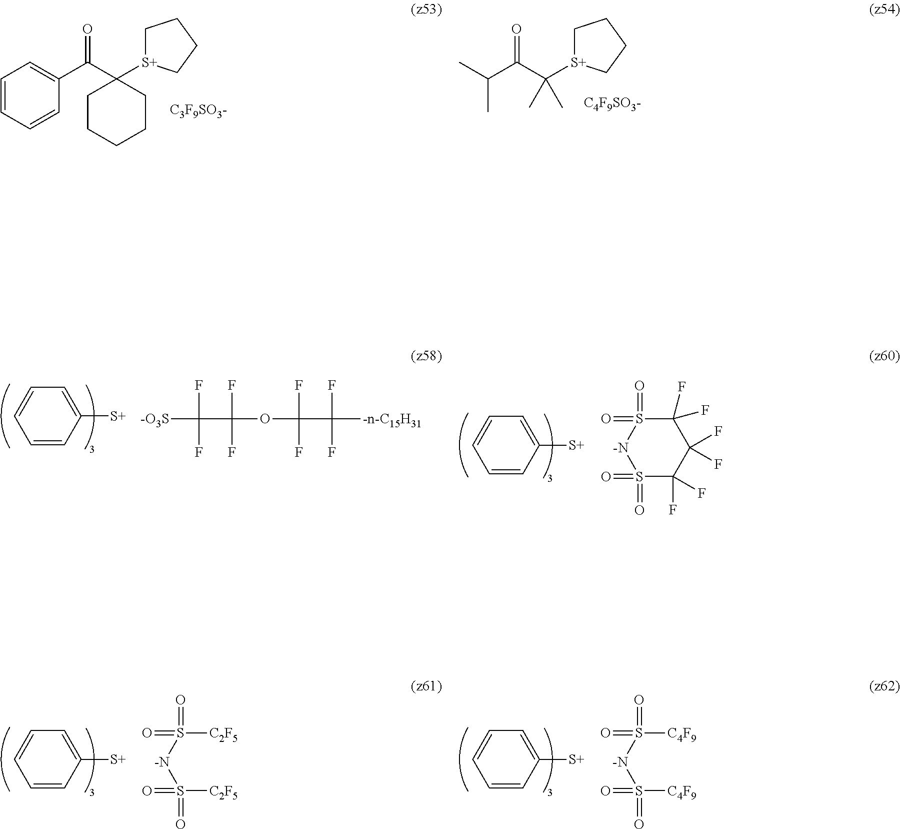

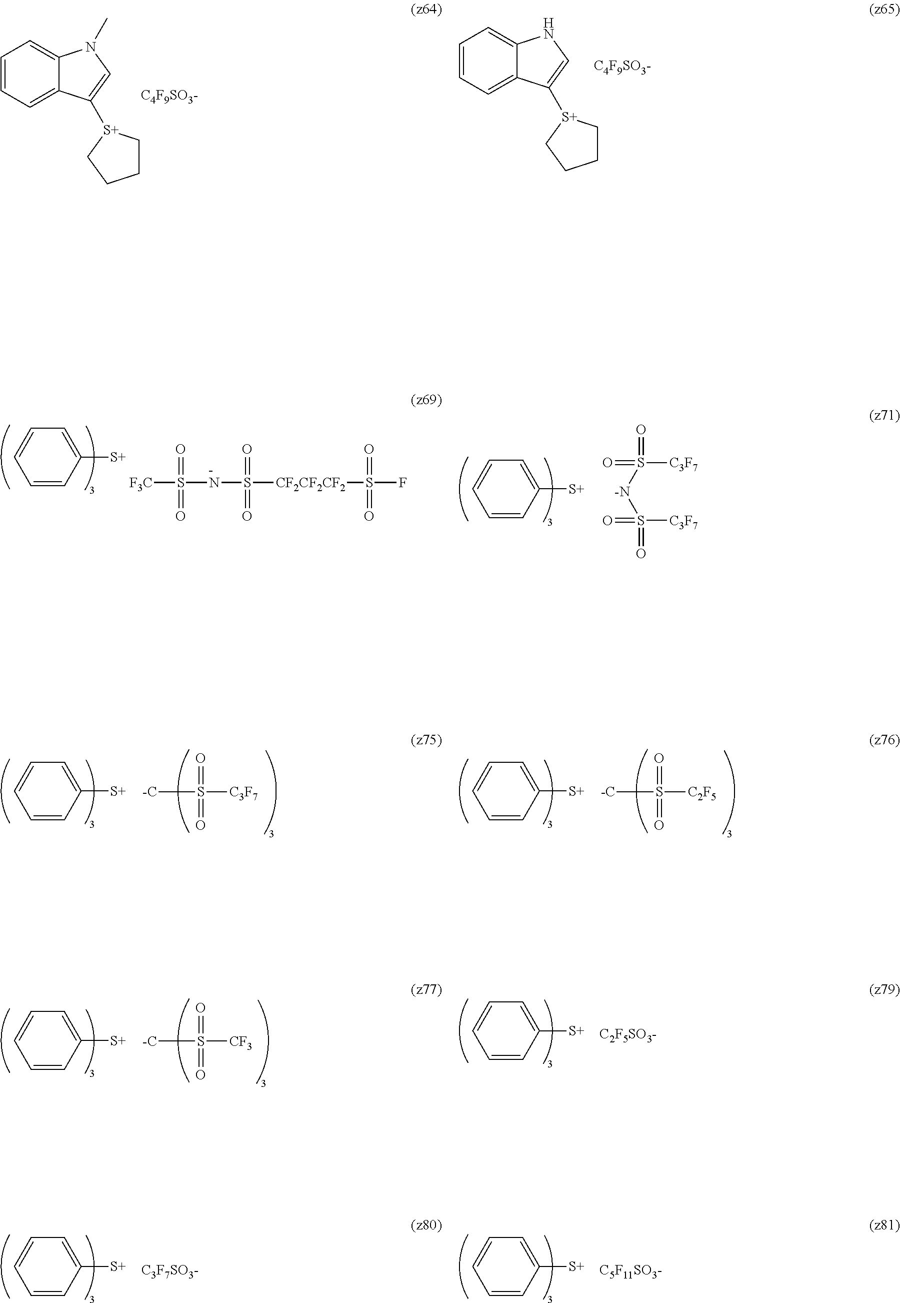

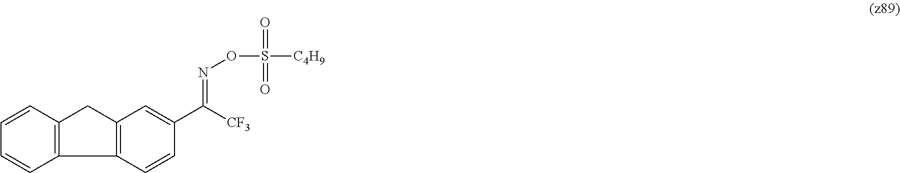

The total content of the photoacid generator (in the case of using an acid generator other than the compound (B) in combination, including the amount of this acid generator) is preferably from 0.1 to 25 mass %, more preferably from 0.1 to 20 mass %, still more preferably from 0.5 to 20 mass %, yet still more preferably from 0.5 to 10 mass %, even yet still more preferably from 1 to 10 mass %, particularly preferably from 1 to 7 mass %, based on the entire solid content of the resist composition.

In the case of using the compound (B) and an acid generator other than the compound (B) in combination, the amounts of acid generators used are, in terms of the molar ratio (compound (B)/other acid generators), usually from 99/1 to 20/80, preferably from 99/1 to 40/60, more preferably from 99/1 to 50/50.

### [2] Resin (A)

The resist composition of the present invention contains (A) a resin. The resin (A) is preferably substantially alkali-insoluble. The term “substantially alkali-insoluble” as used herein means that when a coating film (thickness: 100 nm) is formed by coating a composition prepared by dissolving only the resin (A) in a solvent such as butyl acetate to have a solid content concentration of 3.5 mass % and when the film is dipped in an aqueous 2.38 mass % tetramethylammonium hydroxide (TMAH) solution at room temperature (25° C.) for 1,000 seconds, the average dissolution rate (the rate of decrease in the film thickness) measured using a QCM (quartz crystal oscillator microbalance) sensor or the like is 1 nm/s or less, preferably 0.1 nm/s or less. Thanks to this resin, the resist film in the unexposed area exhibits good solubility in an organic solvent-containing developer.

The resin (A) may or may not contain a repeating unit having an acid group within a range keeping the resin to be substantially alkali-insoluble, but preferably does not contain the repeating unit.

Examples of the acid group include a carboxyl group, a sulfonamide group, a sulfonylimide group, a bisulfonylimide group, and an aliphatic alcohol substituted with an electron-withdrawing group at the α-position (for example, a hexafluoroisopropanol group and —C(CF₃)₂OH). The content of the repeating unit having an acid group in the resin (A) is preferably 10 mol % or less, more preferably 8 mol % or less, still more preferably 5 mol % or less, based on all repeating units. In the case where the resin (A) contains a repeating unit having an acid group, the content of the acid group-containing repeating unit in the resin (A) is usually 1 mol % or more.

Here, the electron-withdrawing group indicates a substituent having a propensity to attract an electron, for example, a substituent having a propensity to draw an electron from an atom located in proximity to the group in a molecule.

Specific examples of the electron-withdrawing group are the same as those in Zₖₐ₁ of formula (KA-1) described later.

The resin need not have solubility by itself in an organic solvent-containing developer as long as when a film is formed using the resist composition, the film dissolves in an organic solvent-containing developer. For example, depending on the property or content of other components contained in the resist composition, it may suffice if a film formed using the resist composition dissolves in an organic solvent-containing developer.

The resin (A) is generally synthesized by polymerization, for example, radical polymerization, of a monomer having a partial structure to be polymerized and contains a repeating unit derived from the monomer having a partial structure to be polymerized. Examples of the partial structure to be polymerized include an ethylenically polymerizable partial structure.

(a1) Repeating Unit Having Alcoholic Hydroxyl Group

The resin (A) for use in the present invention preferably contains (a1) a repeating unit having an alcoholic hydroxyl group at least either in the main chain or on the side chain When such a unit is contained, the hydroxyl group reacts with a crosslinking agent by the action of an acid, and this is expected to not only render the resist film substantially insoluble in an organic solvent-containing developer but also enhance the adherence to substrate.

The alcoholic hydroxyl group as used in the present invention is a hydroxyl group bonded to a hydrocarbon group and is not particularly limited as long as it is a hydroxyl group except for the hydroxyl group (phenolic hydroxyl group) bonded directly on an aromatic ring, but in the present invention, a hydroxyl group except for the hydroxyl group in the aliphatic alcohol substituted with an electron-withdrawing group at the α-position, described above as the acid group, is preferred. The hydroxyl group is preferably a primary alcoholic hydroxyl group (a group where the carbon atom on which a hydroxyl group is substituted has two hydrogen atoms separately from the hydroxyl group) or a secondary alcoholic hydroxyl group where another electron-withdrawing group is not bonded to the carbon atom on which a hydroxyl group is substituted, because the reaction efficiency with the crosslinking agent (C) is enhanced.

The repeating unit (a1) preferably has from one to three, more preferably one or two, alcoholic hydroxyl groups per the repeating unit.

Such a repeating unit includes a repeating unit represented by formula (2) or (3):

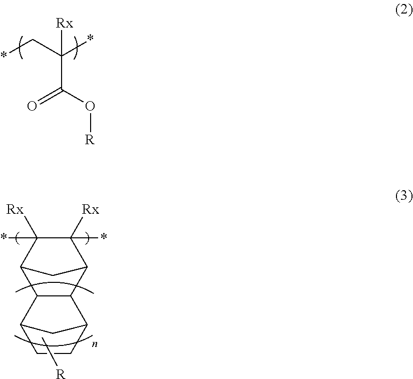

In formula (2), at least either one of Rx and R represents an alcoholic hydroxyl group-containing structure.

In formula (3), at least one of two Rx's and R represents an alcoholic hydroxyl group-containing structure. Two Rx's may be the same or different.

Examples of the alcoholic hydroxyl group-containing structure include a hydroxyalkyl group (preferably having a carbon number of 2 to 8, more preferably from 2 to 4), a hydroxycycloalkyl group (preferably having a carbon number of 4 to 14), a hydroxyalkyl group-substituted cycloalkyl group (preferably having a total carbon number of 5 to 20), a hydroxyalkoxy group-substituted alkyl group (preferably having a total carbon number of 3 to 15), and a hydroxyalkoxy group-substituted cycloalkyl group (preferably having a total carbon number of 5 to 20). As described above, a residue structure of primary alcohol is preferred, and a structure represented by —(CH₂)ₙ—OH (n is an integer of 1 or more, more preferably an integer of 2 to 4) is more preferred.

Rx represents a hydrogen atom, a halogen atom, a hydroxyl group, an alkyl group (preferably having a carbon number of 1 to 4) which may have a substituent, or a cycloalkyl group (preferably having a carbon number of 5 to 12) which may have a substituent. Preferred substituents which the alkyl group and cycloalkyl group of Rx may have include a hydroxyl group and a halogen atom. The halogen atom of Rx includes a fluorine atom, a chlorine atom, a bromine atom and an iodine atom. Rx is preferably a hydrogen atom, a methyl group, a hydroxymethyl group, a hydroxyl group or a trifluoromethyl group, more preferably a hydrogen atom or a methyl group. n represents an integer of 0 to 2.

In formula (3), at least one of two Rx's and R represents an alcoholic hydroxyl group-containing structure. Two Rx's may be the same or different.

R represents a hydrocarbon group which may have a hydroxyl group, or a hydrocarbon group which may have a hydroxyl group-containing organic group. The hydrocarbon group of R is preferably a saturated hydrocarbon group, and the saturated hydrocarbon group includes an alkyl group (preferably having a carbon number of 1 to 8, more preferably from 2 to 4) and a monocyclic or polycyclic hydrocarbon group (preferably having a carbon number of 3 to 20, for example, the later-described alicyclic group). The hydroxyl group-containing organic group includes a hydroxyl group-containing alkoxy group (for example, 2-hydroxyethoxy group) and a hydroxyl group-containing alkyl fluoride group (for example, a group represented by —CH₂C(CF₃)₂OH).

The repeating unit (a1) is preferably a repeating unit derived from an ester of acrylic acid, whose main chain may be substituted on the a-position (for example, Rx in formula (2)), and is more preferably derived from a monomer having a structure corresponding to formula (2). Also, it is preferred to contain an alicyclic group in the unit. The alicyclic group may be a monocyclic or polycyclic structure but in view of etching resistance, a polycyclic structure is preferred.

Specific examples of the alicyclic group include, as a monocyclic structure, cyclobutyl, cyclopentyl, cyclohexyl, cycloheptyl and cyclooctyl; and as a polycyclic structure, norbornyl, isobornyl, tricyclodecanyl, tetracyclododecanyl, hexacycloheptadecanyl, adamantyl, diamantyl, spirodecanyl and spiroundecanyl. Among these structures, adamantyl, diamantyl and norbornyl are preferred.

Examples of the repeating unit (a1) are illustrated below, but the present invention is not limited thereto. In specific examples, R^{x} represents a hydrogen atom or a methyl group.

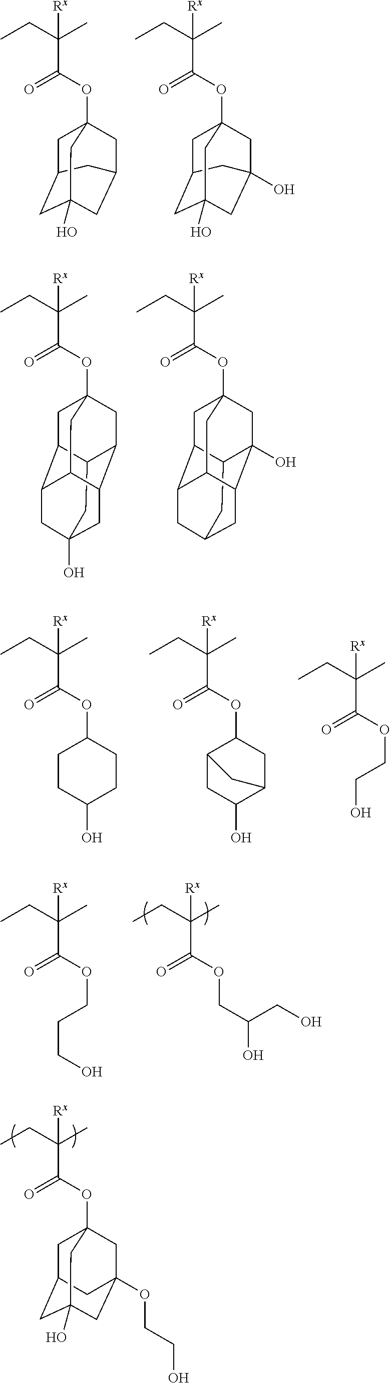

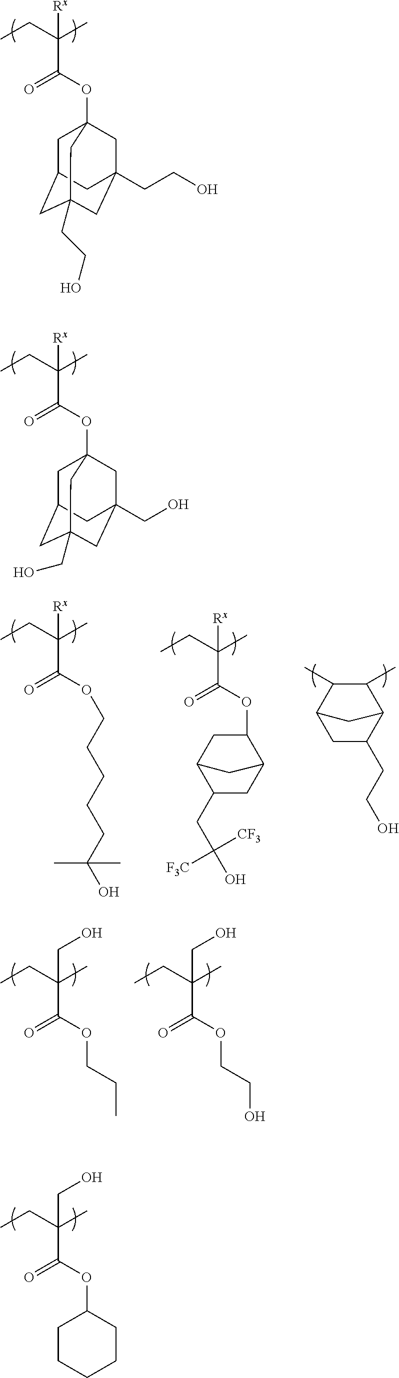

The repeating unit (a1) may have a structure where at least one of the later-described repeating units (a2) to (a4) has an alcoholic hydroxyl group. For example, in the (a4) repeating unit having an acid-decomposable group, the moiety capable of leaving by the action of an acid may have an alcoholic hydroxyl group. It is considered that the crosslinking efficiency can be optimized by containing such a repeating unit. Specific examples of such a structure include a structure where in formula (AI) described later, the moiety of atomic group —C(Rx₁)(Rx₂)(Rx₃) has a hydroxyl group, more specifically, a structure where in the repeating unit represented by formula (2-1) described later, R₁₀ is a hydroxyl group, a hydroxyl group-containing linear or branched alkyl group, or a hydroxyl group-containing cycloalkyl group.

(a2) Repeating Unit Having Nonpolar Group and Being Free From Acid-Decomposable Group and Lactone Structure

The resin (A) for use in the present invention preferably further contains (a2) a repeating unit having a nonpolar group and being free from an acid-decomposable group and a lactone structure. Here, the acid-decomposable group is an acid-decomposable group described later in (a4) a repeating unit having an acid-decomposable group. Also, the lactone structure is a lactone structure described later in (a3) a repeating unit having a lactone structure.

Thanks to this repeating unit, not only dissolving out of low molecular components from the resist film into the immersion liquid at the immersion exposure can be reduced but also the solubility of the resin at the development using an organic solvent-containing developer can be appropriately adjusted. The (a2) repeating unit having a nonpolar group and being free from an acid-decomposable group and a lactone structure is preferably a repeating unit not containing a polar group (for example, the above-described acid group, a hydroxyl group or a cyano group) in the repeating unit. Such a repeating unit includes a repeating unit represented by formula (4) or (5) free from an acid-decomposable group and a lactone structure.

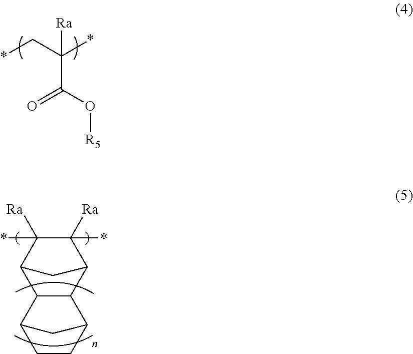

In the formulae, R₅ represents a hydrocarbon group having neither a hydroxyl group nor a cyano group.

The hydrocarbon group represented by R₅ is not a group capable of leaving by the action of an acid, which is described later in (a4) a repeating unit having an acid-decomposable group.

Ra represents, when a plurality of Ra's are present, each independently represents, a hydrogen atom, a hydroxyl group, a halogen atom or an alkyl group (preferably having a carbon number of 1 to 4). The alkyl group of Ra may have a substituent, and the substituent includes a hydroxyl group and a halogen atom. The halogen atom of Ra includes a fluorine atom, a chlorine atom, a bromine atom and an iodine atom. Ra is preferably a hydrogen atom, a methyl group, a trifluoromethyl group or a hydroxymethyl group, more preferably a hydrogen atom or a methyl group.

n represents an integer of 0 to 2.

R₅ preferably contains at least one cyclic structure. The hydrocarbon group in R₅ includes, for example, a chain or branched hydrocarbon group, a monocyclic hydrocarbon group and a polycyclic hydrocarbon group. In view of dry etching resistance, R₅ preferably contains a monocyclic hydrocarbon group or a polycyclic hydrocarbon group, more preferably a polycyclic hydrocarbon group.

R₅ is preferably a group represented by -L₄-A₄-(R₄)ₙ₄. L₄ represents a single bond or a divalent hydrocarbon group and preferably represents a single bond, an alkylene group (preferably having a carbon number of 1 to 3) or a cycloalkylene group (preferably having a carbon number of 5 to 7), more preferably a single bond. A₄ represents a (n4+1)-valent hydrocarbon group (preferably having a carbon number of 3 to 30, more preferably a carbon number of 3 to 14, still more preferably a carbon number of 6 to 12) and preferably represents a monocyclic or polycyclic alicyclic hydrocarbon group. n4 represents an integer of 0 to 5 and is preferably an integer of 0 to 3. R₄ represents a hydrocarbon group and preferably represents an alkyl group (preferably having a carbon number of 1 to 3) or a cycloalkyl group (preferably having a carbon number of 5 to 7).

Examples of the chain or branched hydrocarbon group include an alkyl group having a carbon number of 3 to 12, and examples of the monocyclic hydrocarbon group include a cycloalkyl group having a carbon number of 3 to 12, and a cycloalkenyl group having a carbon number of 3 to 12. The monocyclic hydrocarbon group is preferably a monocyclic hydrocarbon group having a carbon number of 3 to 7.

The polycyclic hydrocarbon group includes a ring-assembled hydrocarbon group (preferably having a carbon number of 6 to 50, more preferably a carbon number of 10 to 30; for example, a bicyclohexyl group) and a crosslinked cyclic hydrocarbon group (preferably having a carbon number of 4 to 25, more preferably a carbon number of 6 to 15). The crosslinked cyclic hydrocarbon group includes, for example, a bicyclic hydrocarbon ring, a tricyclic hydrocarbon ring and a tetracyclic hydrocarbon ring. The crosslinked cyclic hydrocarbon group includes a condensed cyclic hydrocarbon group (for example, a group formed by fusing a plurality of 5- to 8-membered cycloalkane rings). Preferred crosslinked cyclic hydrocarbon groups include a norbornyl group and an adamantyl group.

These groups may further have a substituent, and preferred examples of the substituent include a halogen atom and an alkyl group. The halogen atom is preferably bromine atom, chlorine atom or fluorine atom, and the alkyl group is preferably a methyl group, an ethyl group, a butyl group or a tert-butyl group. This alkyl group may further have a substituent, and the substituent which the alkyl group may further have includes a halogen atom and an alkyl group.

Specific examples of the repeating unit having a nonpolar group and being free from an acid-decomposable group and a lactone structure are illustrated below, but the present invention is not limited thereto. In the formulae, Ra represents a hydrogen atom, a hydroxyl group, a halogen atom, or an alkyl group having a carbon number of 1 to 4 which may have a substituent. The substituent which the alkyl group of Ra may have includes a hydroxyl group and a halogen atom. The halogen atom of Ra includes a fluorine atom, a chlorine atom, a bromine atom and an iodine atom. Ra is preferably a hydrogen atom, a methyl group, a hydroxymethyl group or a trifluoromethyl group, more preferably a hydrogen atom or a methyl group.

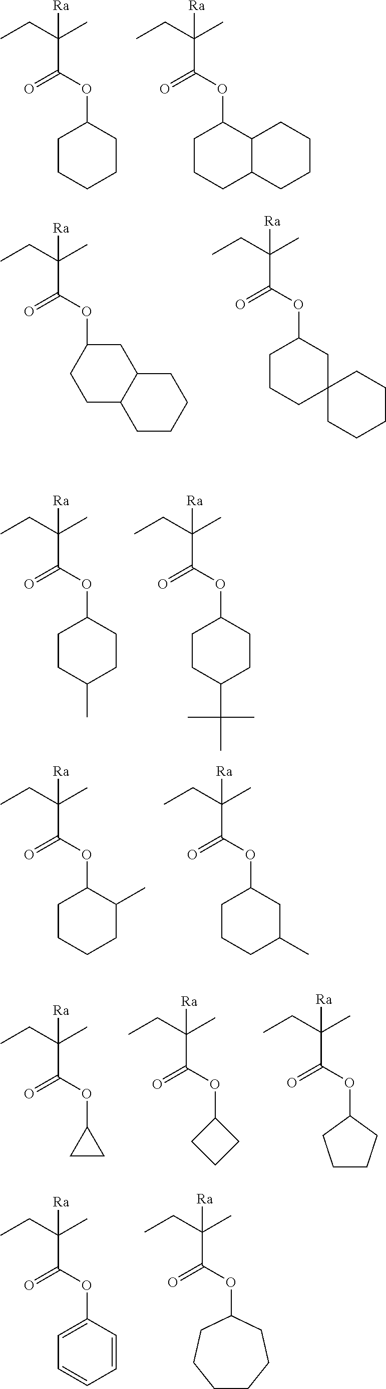

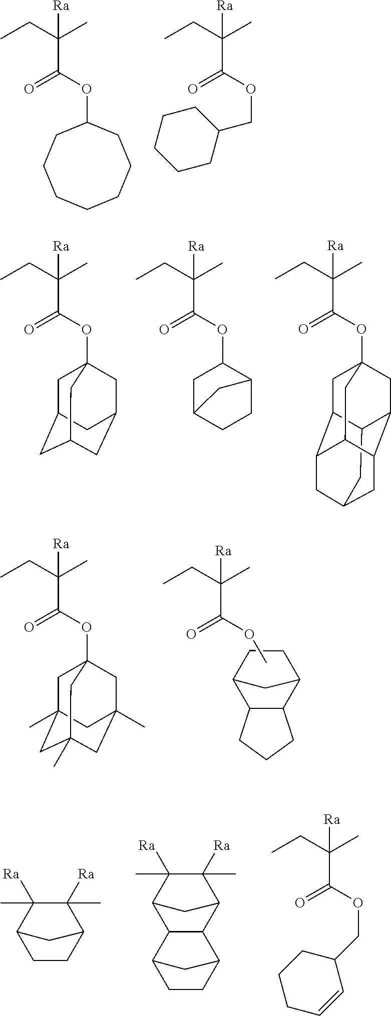

(a3) Repeating Unit Having Lactone Structure

The resin (A) may contain a repeating unit having a lactone structure.

Any lactone structure may be used, but a 5- to 7-membered ring lactone structure is preferred, and a 5- to 7-membered ring lactone structure to which another ring structure is fused to form a bicyclo structure or a Spiro structure is preferred. It is more preferred to contain a repeating unit having a lactone structure represented by any of the following formulae (LC1-1) to (LC1-17). The lactone structure may be bonded directly to the main chain. Preferred lactone structures are (LC1-1), (LC1-4), (LC1-5), (LC1-6), (LC1-13), (LC1-14) and (LC1-17). By using a specific lactone structure, LWR and development defect are improved.

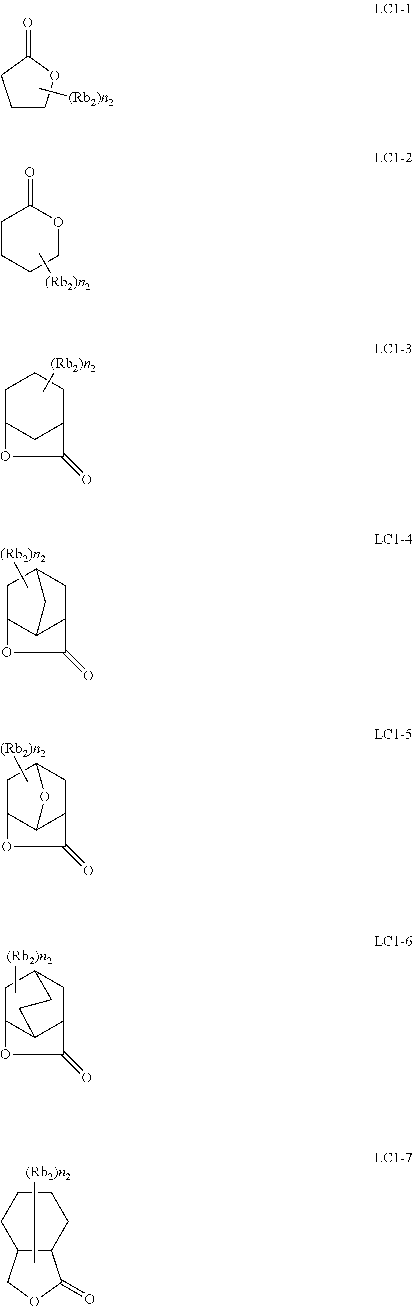

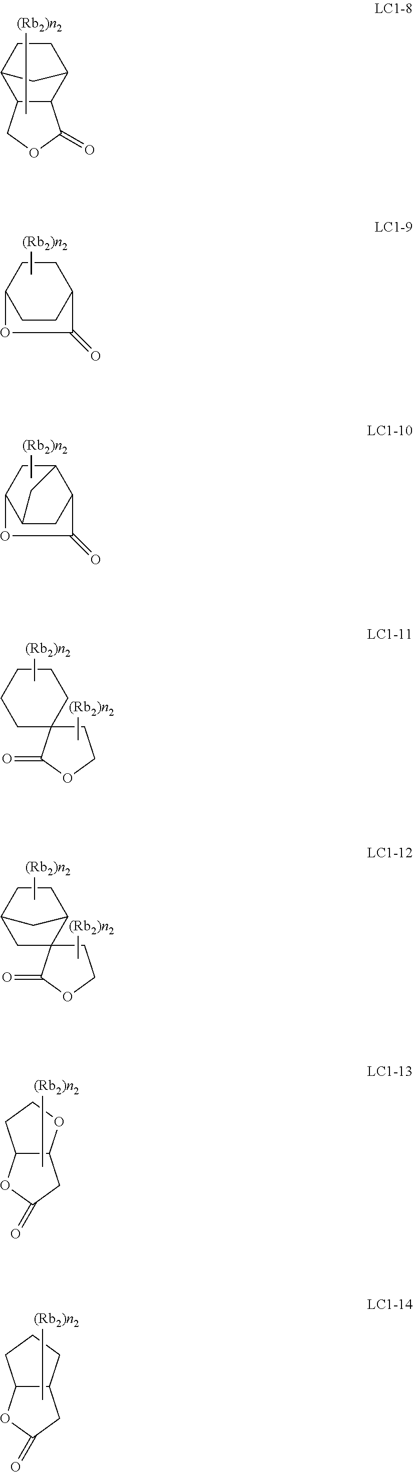

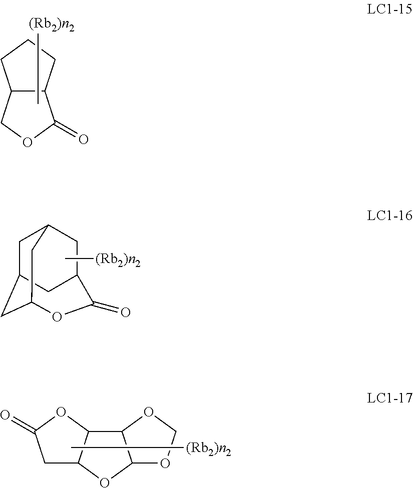

The lactone structure moiety may or may not have a substituent (Rb₂). Preferred examples of the substituent (Rb₂) include an alkyl group having a carbon number of 1 to 8, a cycloalkyl group having a carbon number of 4 to 7, an alkoxy group having a carbon number of 1 to 8, an alkoxycarbonyl group having a carbon number of 2 to 8, a carboxyl group, a halogen atom, a hydroxyl group, a cyano group and an acid-decomposable group. Among these, an alkyl group having a carbon number of 1 to 4, a cyano group and an acid-decomposable group are more preferred. n₂ represents an integer of 0 to 4. When n₂ is an integer of 2 or more, each substituent (Rb₂) may be the same as or different from every other substituents (Rb₂), and also, the plurality of substituents (Rb₂) may combine together to form a ring.

The repeating unit having a lactone group usually has an optical isomer, but any optical isomer may be used. One optical isomer may be used alone or a mixture of a plurality of optical isomers may be used. In the case of mainly using one optical isomer, the optical purity (ee) thereof is preferably 90% or more, more preferably 95% or more.

As for the repeating unit having a lactone structure, a repeating unit represented by the following formula (AII′) is preferred.

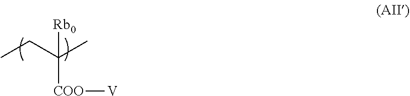

In formula (AII′), Rb₀ represents a hydrogen atom, a halogen atom or an alkyl group (preferably having a carbon number of 1 to 4). Preferred substituents which the alkyl group of Rb₀ may have include a hydroxyl group and a halogen atom. The halogen atom of Rb₀ includes a fluorine atom, a chlorine atom, a bromine atom and an iodine atom. Rb₀ is preferably a hydrogen atom, a methyl group, a hydroxymethyl group or a trifluoromethyl group, more preferably a hydrogen atom or a methyl group.

V represents a group having a structure indicated by any one of formulae (LC1-1) to (LC1-17).

Specific examples of the repeating unit having a lactone structure are illustrated below, but the present invention is not limited thereto.

(In the formulae, Rx represents H, CH₃, CH₂OH or CF₃.)

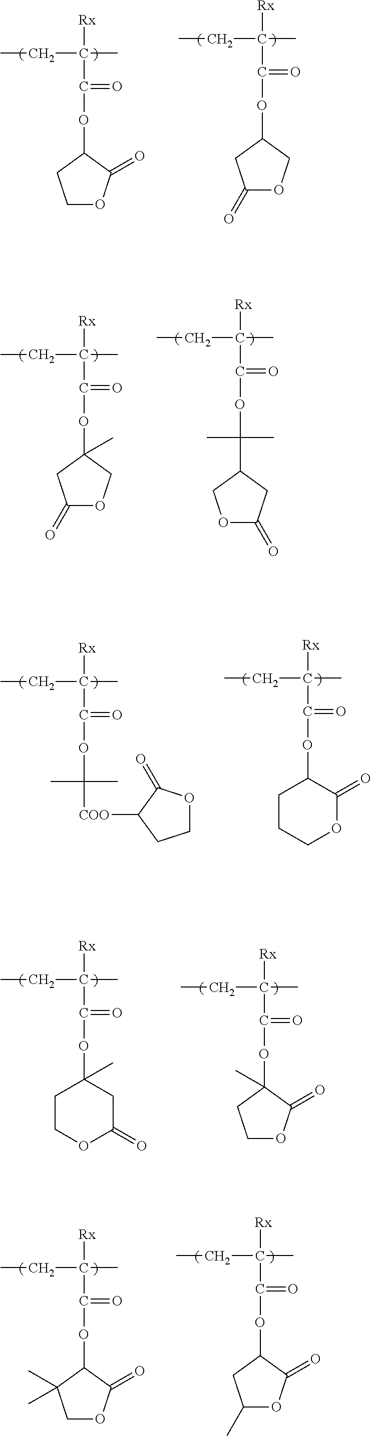

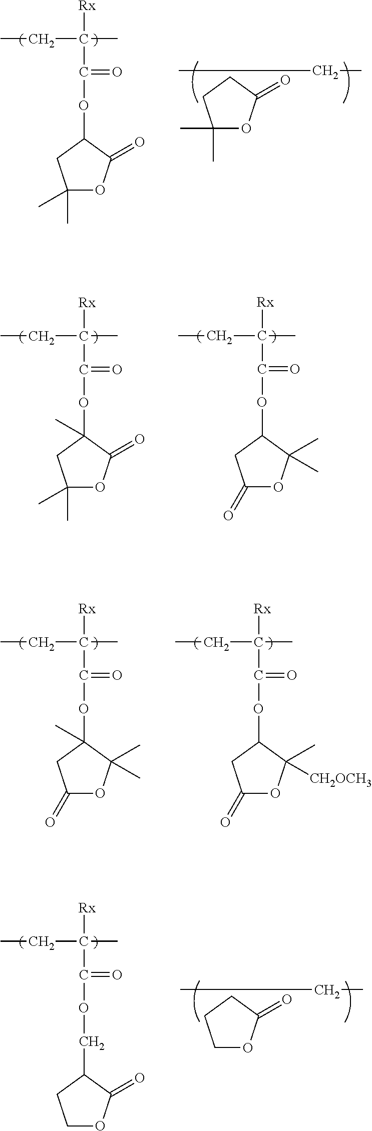

(In the formulae, Rx represents H, CH₃, CH₂OH or CF₃.)

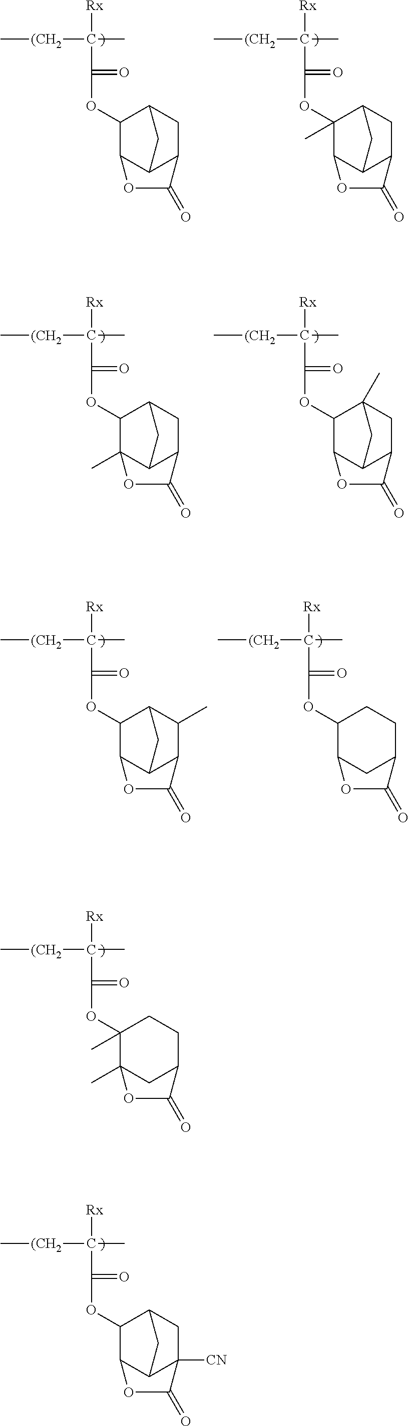

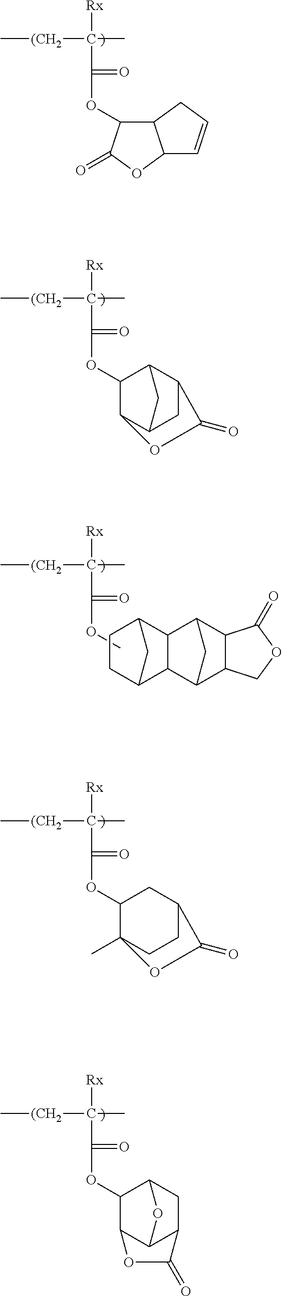

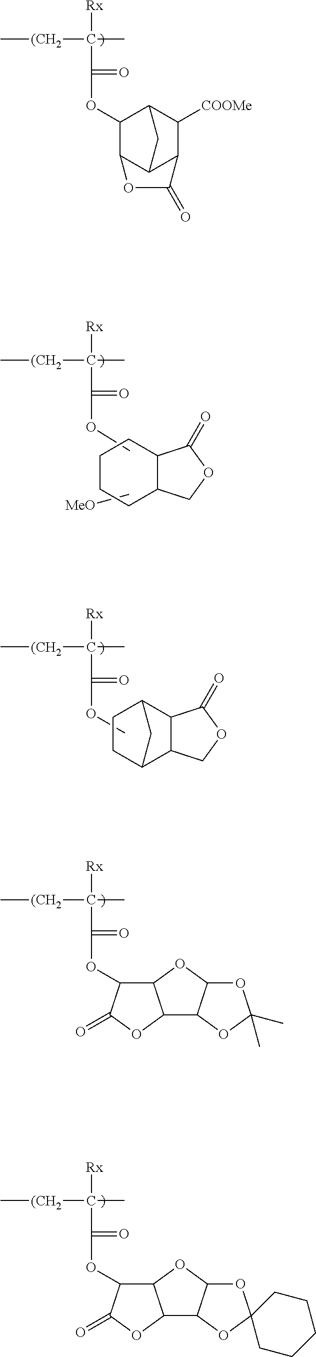

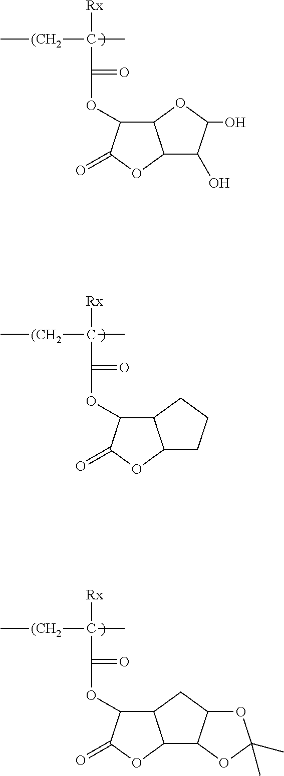

(In the formulae, Rx represents H, CH₃, CH₂OH or CF₃.)

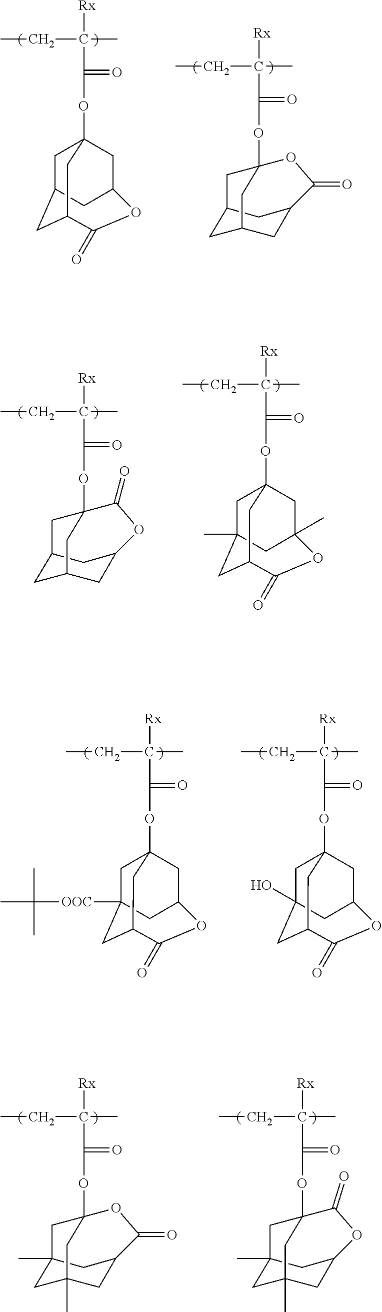

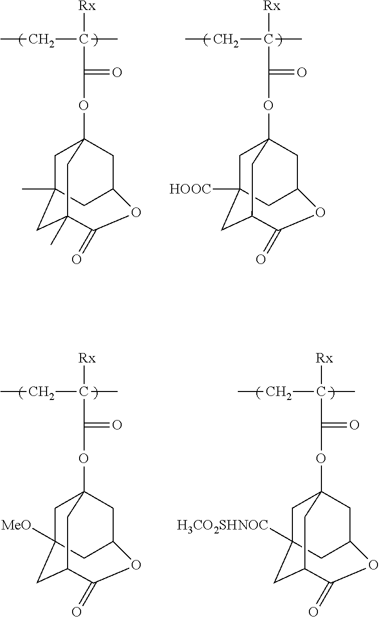

Particularly preferred repeating units having a lactone structure include the following repeating units. By selecting an optimal lactone structure, the pattern profile and the iso/dense bias are improved.

(In the formulae, Rx represents H, CH₃, CH₂OH or CF₃.)

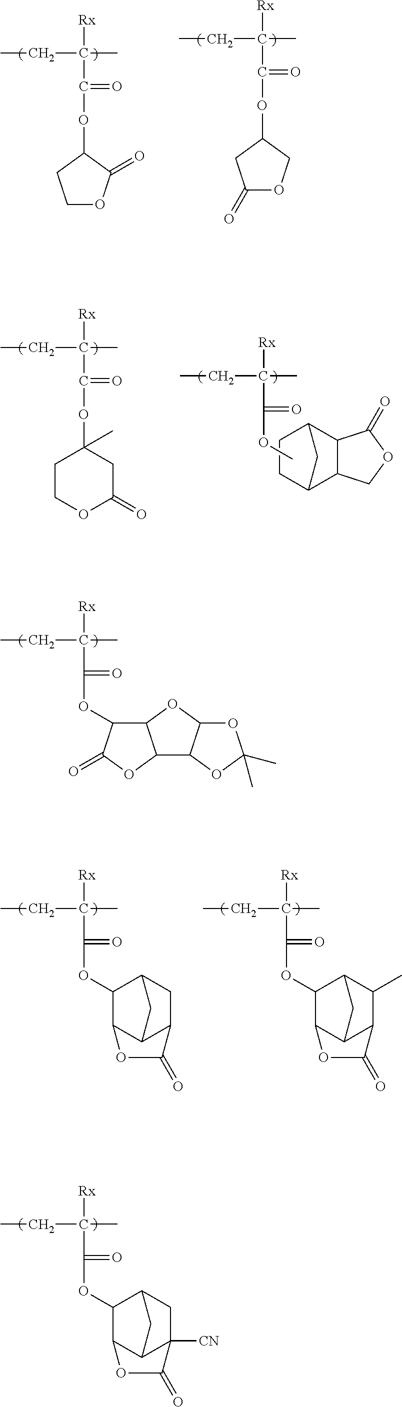

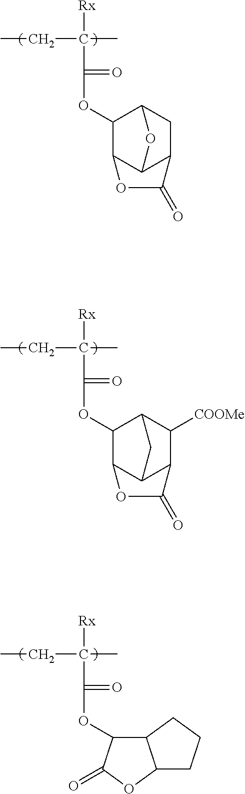

A unit represented by the following formula (III) is preferably contained as the lactone structure-containing repeating unit.

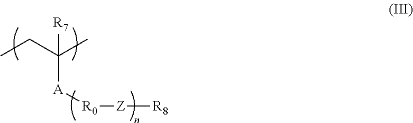

In formula (III), A represents an ester bond (a group represented by —COO—) or an amido bond (a group represented by —CONH—).

R₀ represents, when a plurality of R₀'s are present, each independently represents, an alkylene group, a cycloalkylene group or a combination thereof.

Z represents, when a plurality of Z's are present, each independently represents, an ether bond, an ester bond, an amide bond, a urethane bond

(a group represented by

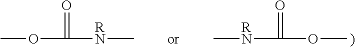

or a urea bond
(a group represented by

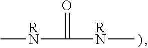

wherein each R independently represents a hydrogen atom, an alkyl group, a cycloalkyl group or an aryl group.

R₈ represents a monovalent organic group having a lactone structure.

n is a repetition number of the structure represented by —R₀—Z— and represents an integer of 1 to 5, preferably 1.

R₇ represents a hydrogen atom, a halogen atom or an alkyl group.

The alkylene group and cycloalkylene group of R₀ may have a substituent.

Z is preferably an ether bond or an ester bond, more preferably an ester bond.

The alkyl group of R₇ is preferably an alkyl group having a carbon number of 1 to 4, more preferably a methyl group or an ethyl group, still more preferably a methyl group.

The alkylene group and cycloalkylene group of R₀ and the alkyl group of R₇ may be each substituted, and examples of the substituent include a halogen atom such as fluorine atom, chlorine atom and bromine atom, a mercapto group, a hydroxyl group, an alkoxy group such as methoxy group, ethoxy group, isopropoxy group, tert-butoxy group and benzyloxy group, and an acyloxy group such as acetyloxy group and propionyloxy group.

R₇ is preferably a hydrogen atom, a methyl group, a trifluoromethyl group or a hydroxymethyl group.

The chain alkylene group in R₀ is preferably a chain alkylene group having a carbon number of 1 to 10, more preferably a carbon number of 1 to 5, and examples thereof include a methylene group, an ethylene group and a propylene group. The cycloalkylene group is preferably a cycloalkylene group having a carbon number of 3 to 20, and examples thereof include a cyclohexylene group, a cyclopentylene group, a norbornylene group and an adamantylene group. For bringing out the effects of the present invention, a chain alkylene group is more preferred, and a methylene group is still more preferred.

The lactone structure-containing monovalent organic group represented by R₈ is not limited as long as it has a lactone structure. Specific examples thereof include lactone structures represented by formulae (LC1-1) to (LC1-17) and among these, a structure represented by (LC1-4) is preferred. Also, structures where n₂ in (LC1-1) to (LC1-17) is an integer of 2 or less are more preferred.

R₈ is preferably a monovalent organic group having an unsubstituted lactone structure or a monovalent organic group having a lactone structure containing a methyl group, a cyano group or an alkoxycarbonyl group as the substituent, more preferably a monovalent organic group having a lactone structure containing a cyano group as the substituent (cyanolactone).

Specific examples of the repeating unit containing a group having a lactone structure represented by formula (III) are illustrated below, but the present invention is not limited thereto.

In specific examples, R represents a hydrogen atom, an alkyl group which may have a substituent, or a halogen atom, preferably a hydrogen atom, a methyl group, a hydroxymethyl group or an acetyloxymethyl group.

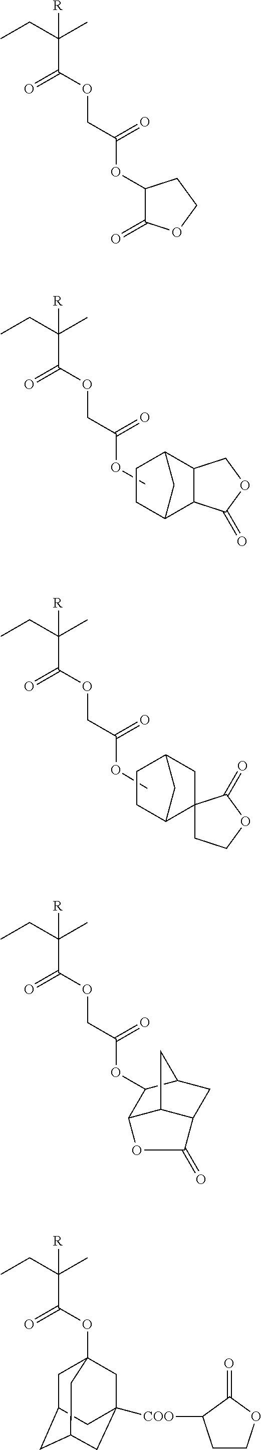

The lactone structure-containing repeating unit is more preferably a repeating unit represented by the following formula (III-1):

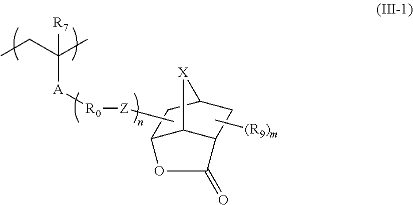

In formula (III-1), R₇, A, R₀, Z and n have the same meanings as in formula

R₉ represents, when a plurality of R₉'s are present, each independently represents, an alkyl group, a cycloalkyl group, an alkoxycarbonyl group, a cyano group, a hydroxyl group or an alkoxy group, and when a plurality of R₉'s are present, two members thereof may combine to form a ring.

X represents an alkylene group, an oxygen atom or a sulfur atom.

m is the number of substituents and represents an integer of 0 to 5. m is preferably 0 or 1.

The alkyl group of R₉ is preferably an alkyl group having a carbon number of 1 to 4, more preferably a methyl group or an ethyl group, and most preferably a methyl group. Examples of the cycloalkyl group include a cyclopropyl group, a cyclobutyl group, a cyclopentyl group and a cyclohexyl group. Examples of the alkoxycarbonyl group include a methoxycarbonyl group, an ethoxycarbonyl group, an n-butoxycarbonyl group and a tert-butoxycarbonyl group. Examples of the alkoxy group include a methoxy group, an ethoxy group, a propoxy group, an isopropoxy group and a butoxy group. These groups may have a substituent, and the substituent includes a hydroxy group, an alkoxy group such as methoxy group and ethoxy group, a cyano group, and a halogen atom such as fluorine atom. R₉ is preferably a methyl group, a cyano group or an alkoxycarbonyl group, more preferably a cyano group.

Examples of the alkylene group of X include a methylene group and an ethylene group. X is preferably an oxygen atom or a methylene group, more preferably a methylene group.

When m is an integer of 1 or more, at least one R₉ is preferably substituted on the α-position or β-position, more preferably on the α-position, of the carbonyl group of lactone.

Specific examples of the repeating unit having a lactone structure-containing group represented by formula (III-1) are illustrated below, but the present invention is not limited thereto. In specific examples, R represents a hydrogen atom, an alkyl group which may have a substituent, or a halogen atom, preferably a hydrogen atom, a methyl group, a hydroxymethyl group or an acetoxymethyl group.

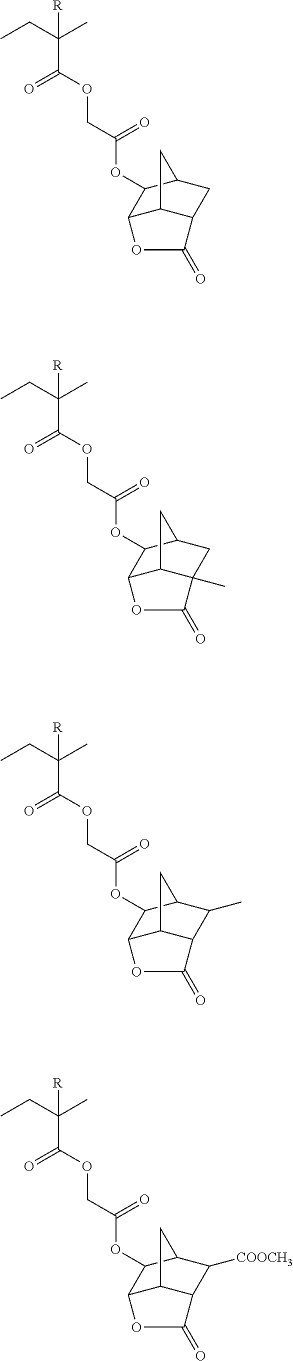

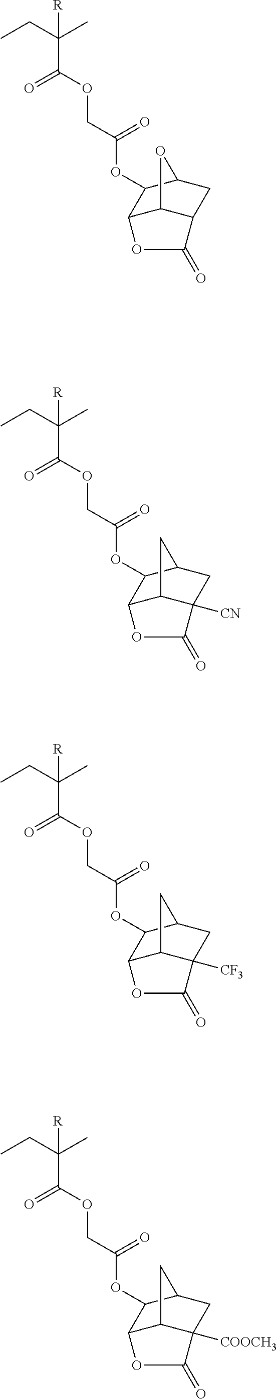

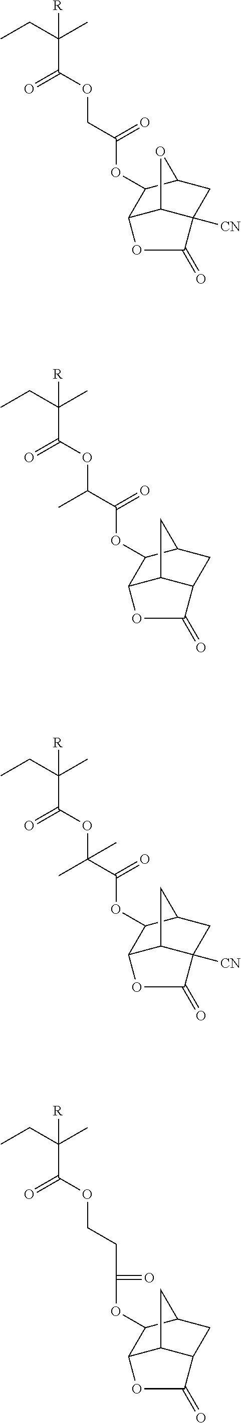

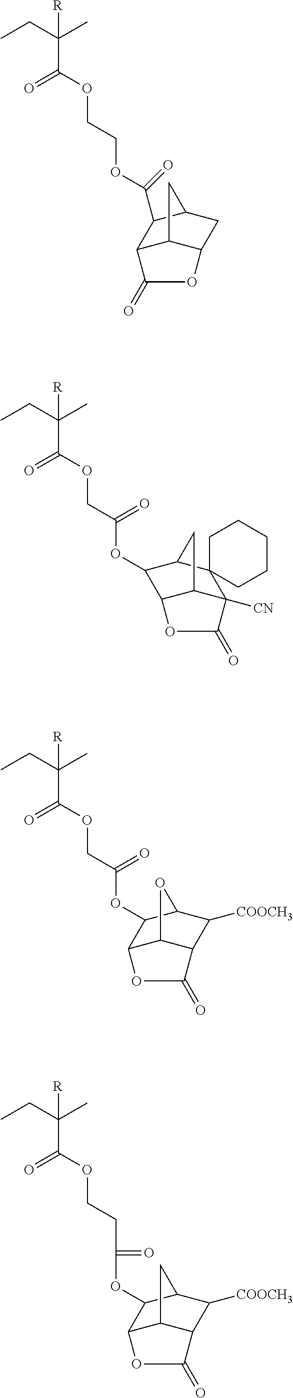

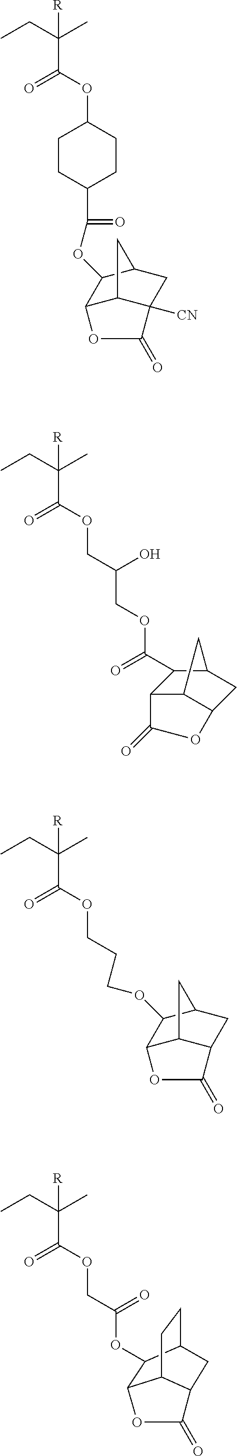

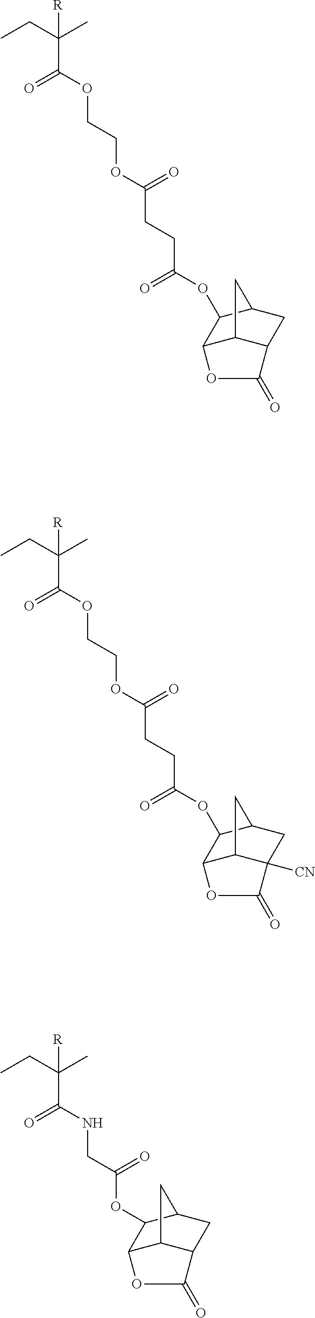

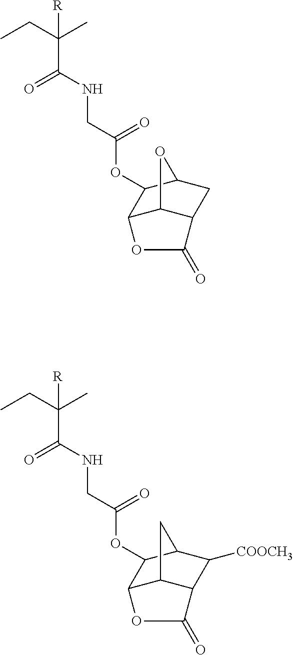

Two or more kinds of lactone repeating units may also be used in combination for raising the effects of the present invention. In the case of a combination use, it is also preferred that out of formula (III), two or more kinds of lactone repeating units where n is 1 are selected and used in combination.

(a4) Repeating Unit Having Acid-Decomposable Group

The resin (A) may further contain a repeating unit having a group capable of decomposing by the action of an acid to produce a polar group (hereinafter sometimes referred to as an “acid-decomposable group”), on either one or both of the main chain and the side chain of the resin. It is considered that when a polar group is produced in the resin (A), the affinity for the organic solvent-containing developer is reduced and insolubilization (negative conversion) is more accelerated. Also, by virtue of containing an acid-decomposable unit, line width roughness (LWR) performance is improved.

The acid-decomposable group preferably has a structure where the polar group is protected with a group capable of leaving by the action of an acid.

The polar group is not particularly limited as long as it is a group capable of being insolubilized in an organic solvent-containing developer, but an acidic group (a group capable of dissociating in an aqueous 2.38 mass % tetramethylammonium hydroxide solution which is conventionally used as the developer for resist) such as carboxyl group, fluorinated alcohol group (preferably hexafluoroisopropanol) and sulfonic acid group is preferred.

The group preferred as the acid-decomposable group is a group where a hydrogen atom of the group above is substituted for by a group capable of leaving by the action of an acid.

Examples of the group capable of leaving by the action of an acid include —C(R₃₆)(R₃₇)(R₃₈), —C(R₃₆)(R₃₇)(OR₃₉) and —C(R₀₁)(R₀₂)(OR₃₉).

In the formulae, each of R₃₆ to R₃₉ independently represents an alkyl group, a cycloalkyl group, an aryl group, an aralkyl group or an alkenyl group. R₃₆ and R₃₇ may combine with each other to form a ring.

Each of R₀₁ and R₀₂ independently represents a hydrogen atom, an alkyl group, a cycloalkyl group, an aryl group, an aralkyl group or an alkenyl group.

The acid-decomposable group is preferably a cumyl ester group, an enol ester group, an acetal ester group, a tertiary alkyl ester group or the like, more preferably a tertiary alkyl ester group.

The acid-decomposable group-containing repeating unit which can be contained in the resin (A) is preferably a repeating unit represented by the following formula (AI):

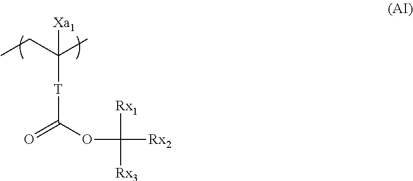

In formula (AI), Xa₁ represents a hydrogen atom, a methyl group which may have a substituent, or a group represented by —CH₂—R₉. R₉ represents a hydroxyl group or a monovalent organic group. Examples of the monovalent organic group include an alkyl group having a carbon number of 5 or less and an acyl group having a carbon number of 5 or less. Of these, an alkyl group having a carbon number of 3 or less is preferred, and a methyl group is more preferred. Xa₁ is preferably a hydrogen atom, a methyl group, a trifluoromethyl group or a hydroxymethyl group, more preferably a hydrogen atom, a methyl group or a hydroxymethyl group.

T represents a single bond or a divalent linking group.

Each of Rx₁ to Rx₃ independently represents an alkyl group (linear or branched) or a cycloalkyl group (monocyclic or polycyclic).

Rx₂ and Rx₃ may combine to form a cycloalkyl group (monocyclic or polycyclic).

Examples of the divalent linking group of T include an alkylene group, a —COO-Rt-group and a —O-Rt-group. In the formulae, Rt represents an alkylene group or a cycloalkylene group.

T is preferably a single bond or a —COO-Rt-group. Rt is preferably an alkylene group having a carbon number of 1 to 5, more preferably a —CH₂— group, —(CH₂)₂— group or a —(CH₂)₃— group.

The alkyl group of Rx₁ to Rx₃ is preferably an alkyl group having a carbon number of 1 to 4, such as methyl group, ethyl group, n-propyl group, isopropyl group, n-butyl group, isobutyl group and tert-butyl group.

The cycloalkyl group of Rx₁ to Rx₃ is preferably a monocyclic cycloalkyl group such as cyclopentyl group and cyclohexyl group, or a polycyclic cycloalkyl group such as norbornyl group, tetracyclodecanyl group, tetracyclododecanyl group and adamantyl group.

The cycloalkyl group formed by combining Rx₂ and Rx₃ is preferably a monocyclic cycloalkyl group such as cyclopentyl group and cyclohexyl group, or a polycyclic cycloalkyl group such as norbornyl group, tetracyclodecanyl group, tetracyclododecanyl group and adamantyl group. Above all, a monocyclic cycloalkyl group having a carbon number of 5 to 6 is preferred.

An embodiment where Rx₁ is a methyl group or an ethyl group and Rx₂ and Rx₃ are combined to form the above-described cycloalkyl group is preferred.

Each of the groups above may have a substituent, and examples of the substituent include an alkyl group (having a carbon number of 1 to 4), a cycloalkyl group (having a carbon number of 3 to 15), a halogen atom, a hydroxyl group, an alkoxy group (having a carbon number of 1 to 4), a carboxyl group and an alkoxycarbonyl group (having a carbon number of 2 to 6). The carbon number is preferably 8 or less.

Specific preferred examples of the repeating unit having an acid-decomposable group are illustrated below, but the present invention is not limited thereto.

In specific examples, each of Rx and Xa₁ represents a hydrogen atom, —CH₃, —CF₃ or —CH₂OH, and each of Rxa and Rxb represents an alkyl group having a carbon number of 1 to 4. Z represents a substituent containing a polar group, and when a plurality of Z's are present, each is independent from every others. p represents 0 or a positive integer. Specific examples and preferred examples of Z are the same as specific examples and preferred examples of R₁₀ in formula (2-1) described later.

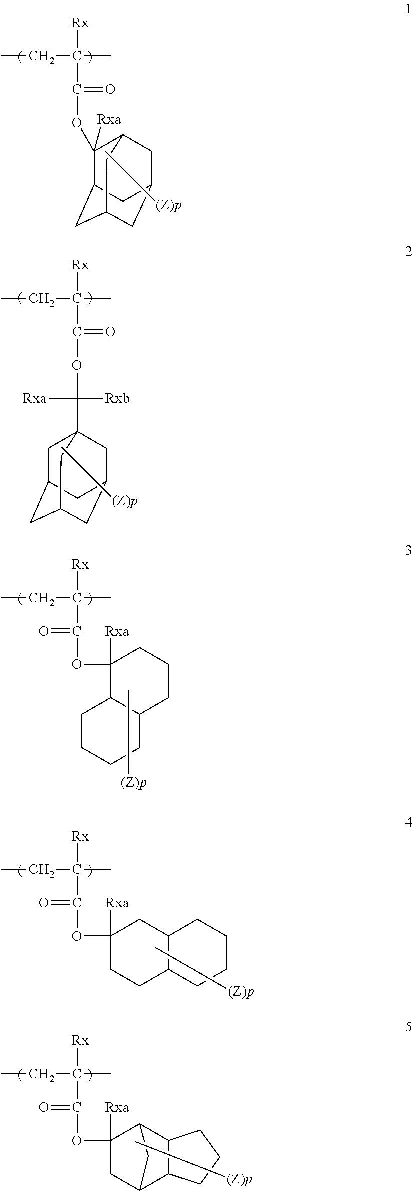

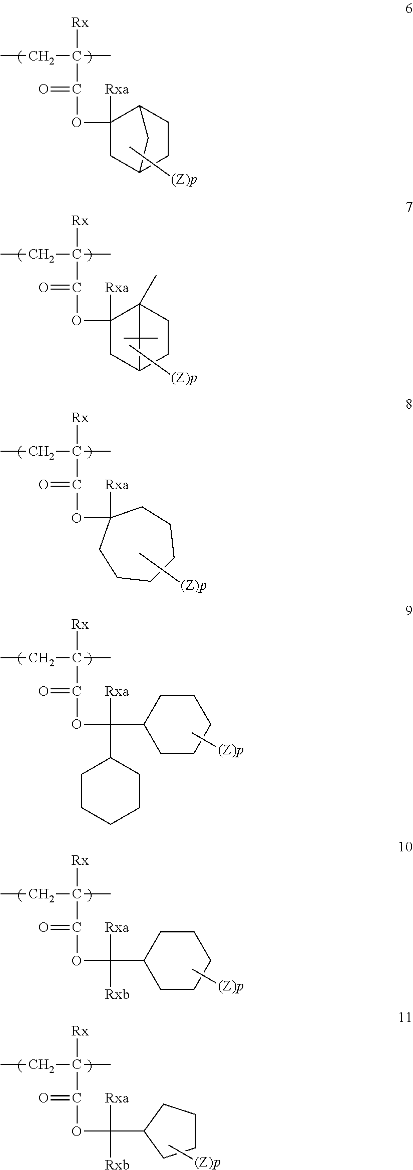

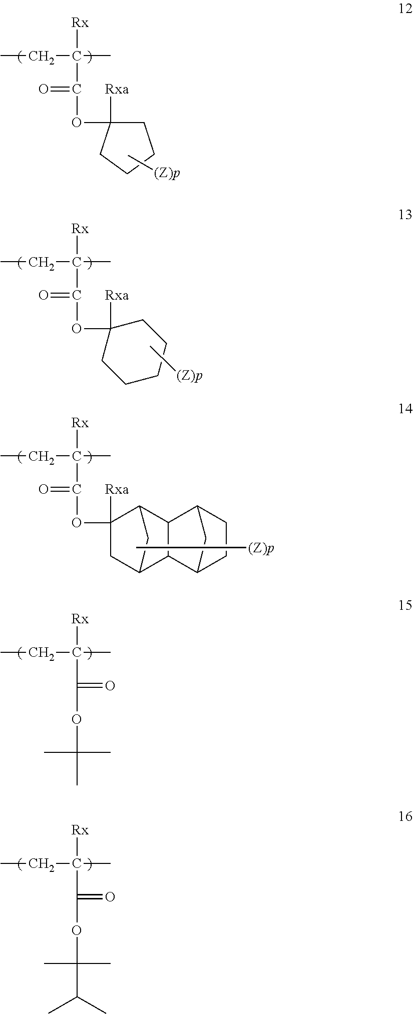

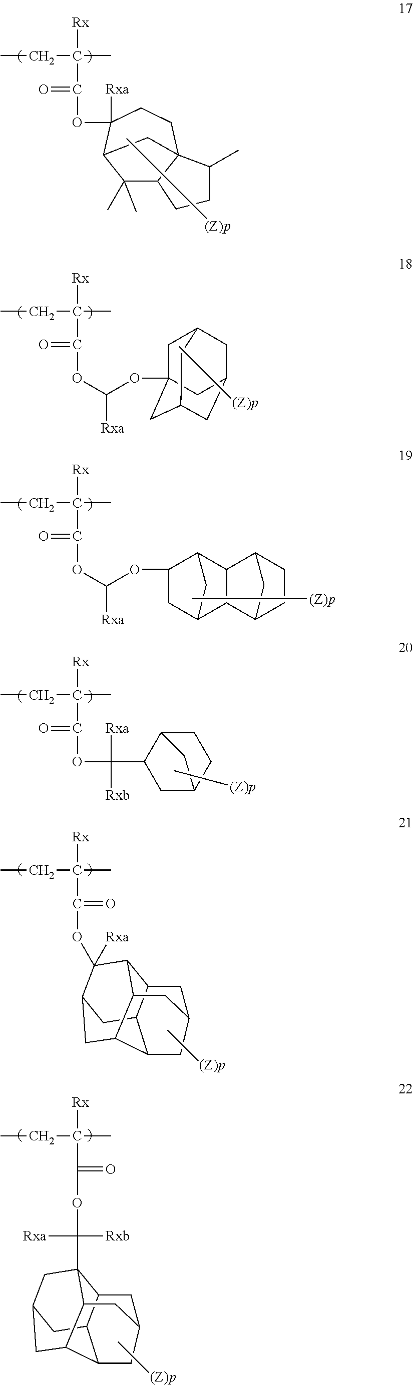

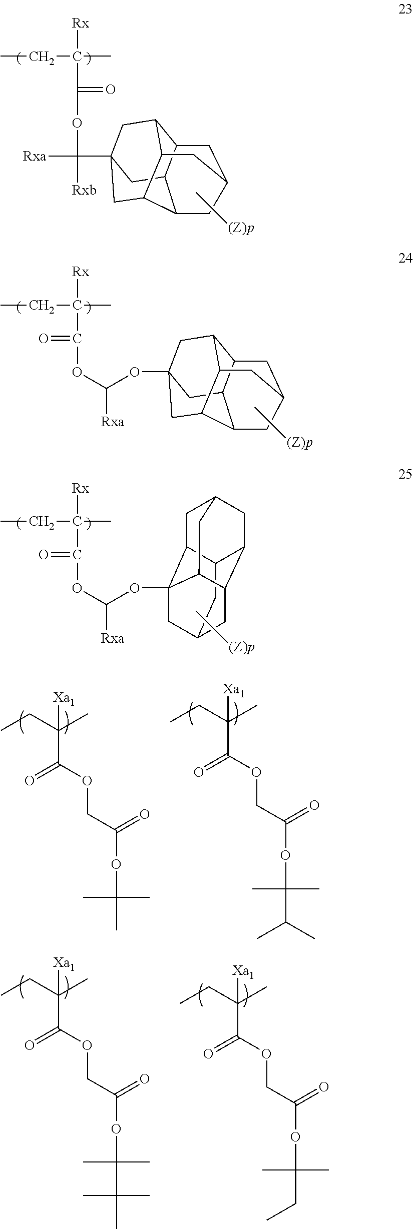

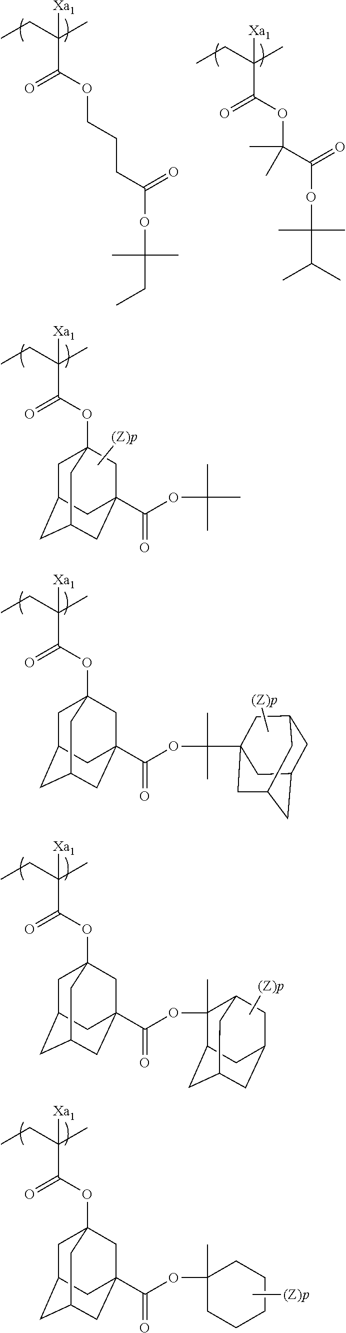

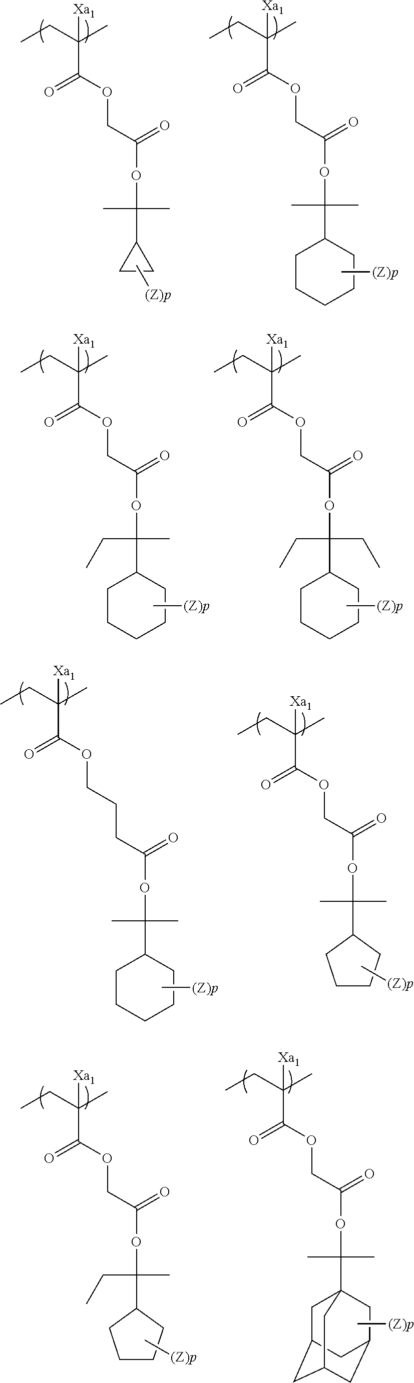

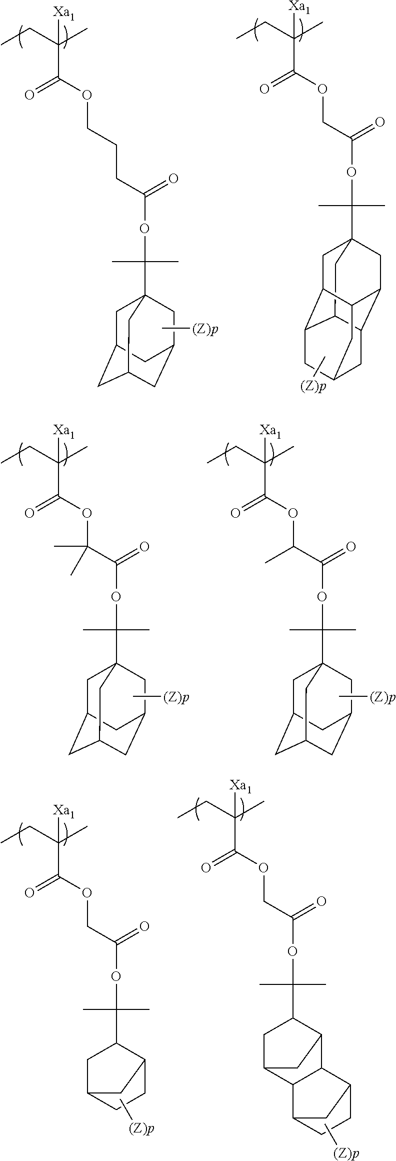

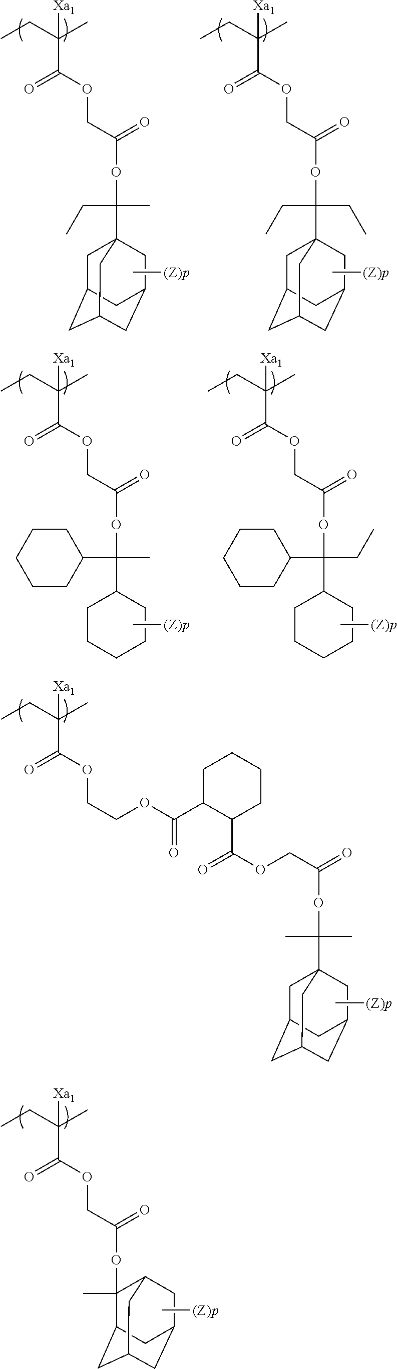

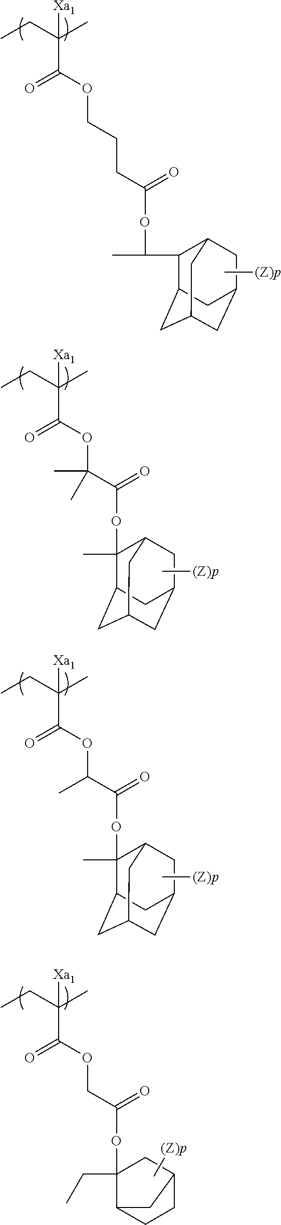

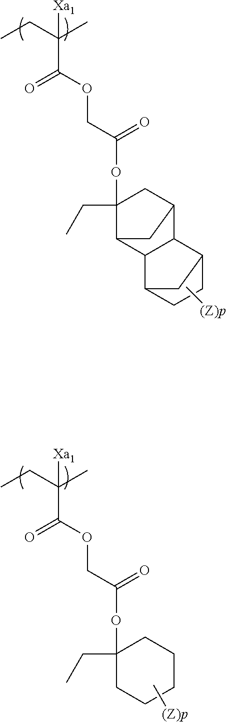

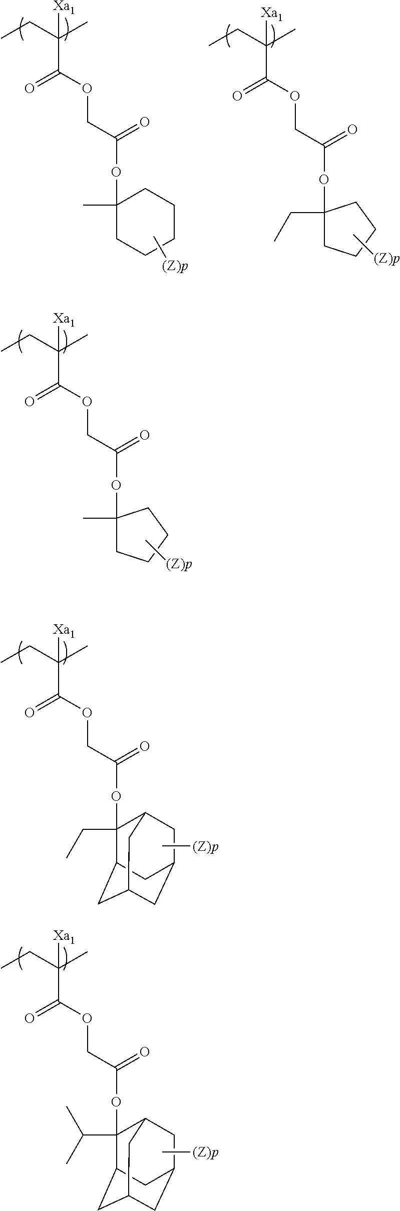

The resin (A) is more preferably a resin containing, as the repeating unit represented by formula (AI), at least either a repeating unit represented by formula (I) or a repeating unit represented by formula (2).

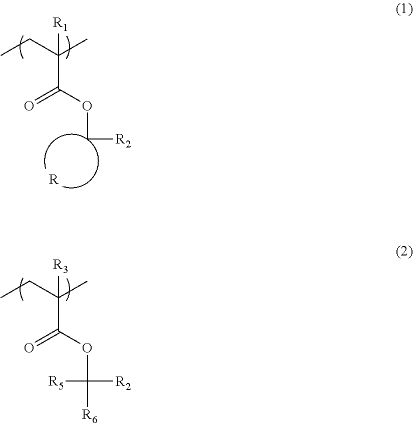

In formulae (1) and (2), each of R₁ and R₃ independently represents a hydrogen atom, a methyl group which may have a substituent, or a group represented by —CH₂—R₉. R₉ represents a hydroxyl group or a monovalent organic group.

Each of R₂, R₄, R₅ and R₆ independently represents an alkyl group or a cycloalkyl group.

R represents an atomic group necessary for forming an alicyclic structure together with the carbon atom.

Each of R₁ and R₃ is preferably a hydrogen atom, a methyl group, a trifluoromethyl group or a hydroxymethyl group. Specific examples and preferred examples of the monovalent organic group in R₉ are the same as those described for R₉ in formula (AI).

The alkyl group in R₂ may be linear or branched and may have a substituent.

The cycloalkyl group in R₂ may be monocyclic or polycyclic and may have a substituent.

R₂ is preferably an alkyl group, more preferably an alkyl group having a carbon number of 1 to 10, still more preferably an alkyl group having a carbon number of 1 to 5, and examples thereof include a methyl group and an ethyl group.

R represents an atomic group necessary for forming an alicyclic structure together with the carbon atom. The alicyclic structure formed by R together with the carbon atom is preferably a monocyclic alicyclic structure, and the carbon number thereof is preferably from 3 to 7, more preferably, 5 or 6.

The alkyl group in R₄, R₅ and R₆ may be linear or branched and may have a substituent. The alkyl group is preferably an alkyl group having a carbon number of 1 to 4, such as methyl group, ethyl group, n-propyl group, isopropyl group, n-butyl group, isobutyl group and tert-butyl group.

The cycloalkyl group in R₄, R₅ and R₆ may be monocyclic or polycyclic and may have a substituent. The cycloalkyl group is preferably a monocyclic cycloalkyl group such as cyclopentyl group and cyclohexyl group, or a polycyclic cycloalkyl group such as norbornyl group, tetracyclodecanyl group, tetracyclododecanyl group and adamantyl group.

Examples of the repeating unit represented by formula (1) include a repeating unit represented by the following formula (I-a). In the formula, R₁ and R₂ have the same meanings as those in formula (1).

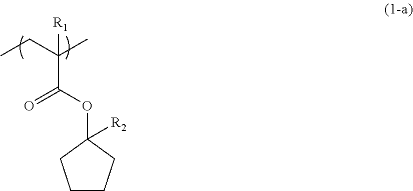

The repeating unit represented by formula (2) is preferably a repeating unit represented by the following formula (2-1):

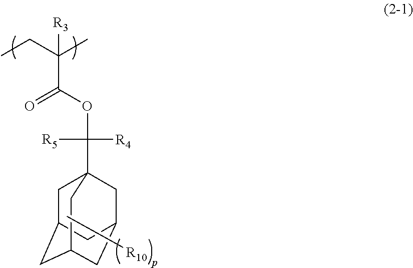

In formula (2-1), R₃ to R₅ have the same meanings as those in formula (2).

R₁₀ represents a polar group-containing substituent. In the case where a plurality of R₁₀'s are present, each R₁₀ may be the same as or different from every other R₁₀. Examples of the polar group-containing substituent include a hydroxyl group, a cyano group, an amino group, an alkylamide group, a sulfonamide group itself, and a linear or branched alkyl group or cycloalkyl group having at least one of these groups. An alkyl group having a hydroxyl group is preferred, and a branched alkyl group having a hydroxyl group is more preferred. The branched alkyl group is preferably an isopropyl group.

p represents an integer of 0 to 15. p is preferably an integer of 0 to 2, more preferably 0 or 1.

The resin (A) may contain a plurality of repeating units having an acid-decomposable group.

The resin (A) is preferably a resin containing, as the repeating unit represented by formula (AI), a repeating unit represented by formula (1) and a repeating unit represented by formula (2). In another embodiment, the resin is preferably a resin containing, as the repeating unit represented by formula (AI), at least two kinds of repeating units represented by formula (1).

It is also possible that the resist composition of the present invention contains a plurality of kinds of the resin (A) and the acid-decomposable group-containing repeating units in the plurality of resins (A) differ from each other. For example, a resin (A) containing a repeating unit represented by formula (1) and a resin (A) containing a repeating unit represented by formula (2) may be used in combination.

In the case where the resin (A) contains a plurality of acid-decomposable group-containing repeating units or where a plurality of resins (A) have different acid-decomposable group-containing repeating units, preferred examples of the combination are illustrated below. In the formulae below, each R independently represents a hydrogen atom or a methyl group.

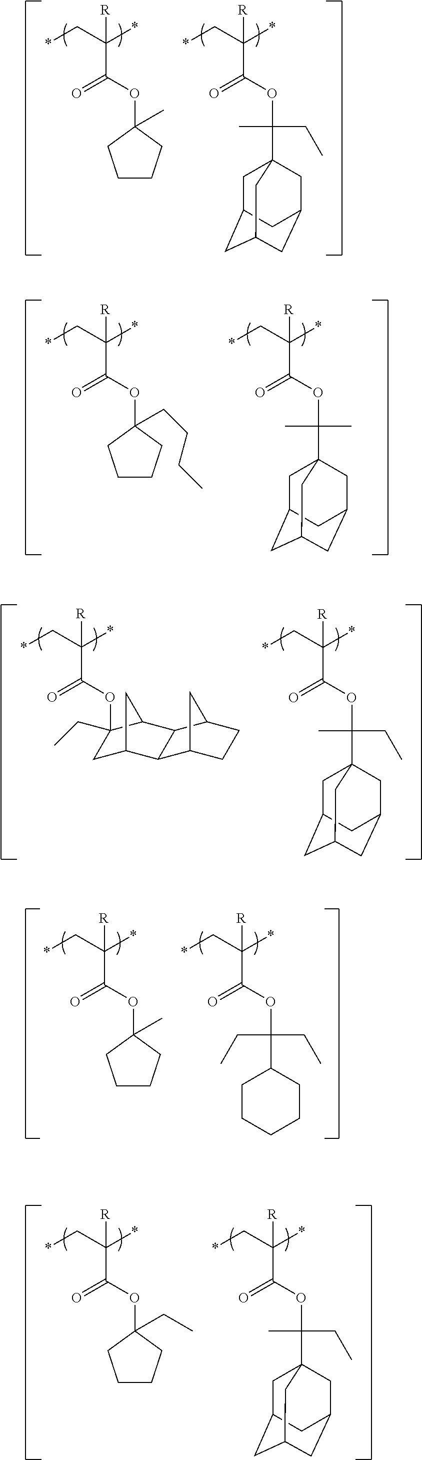

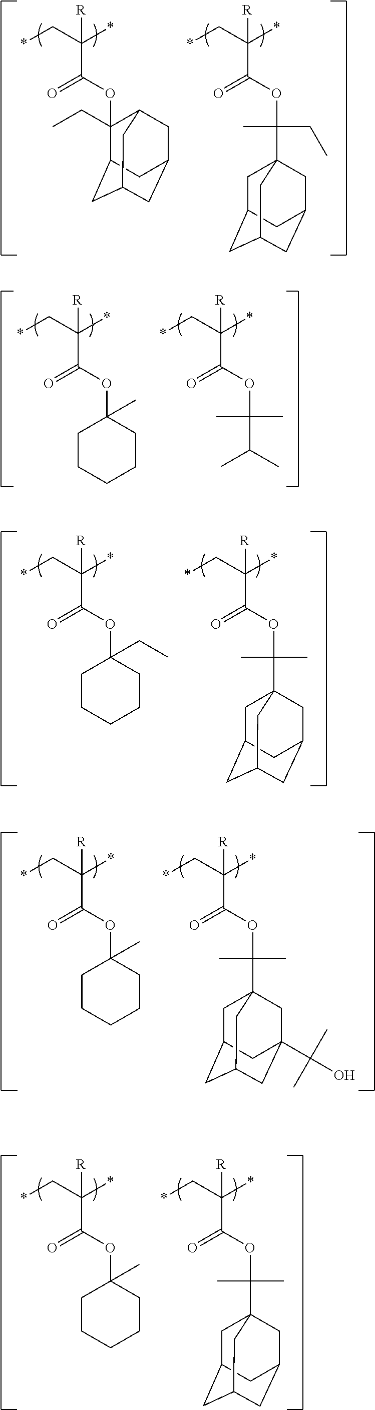

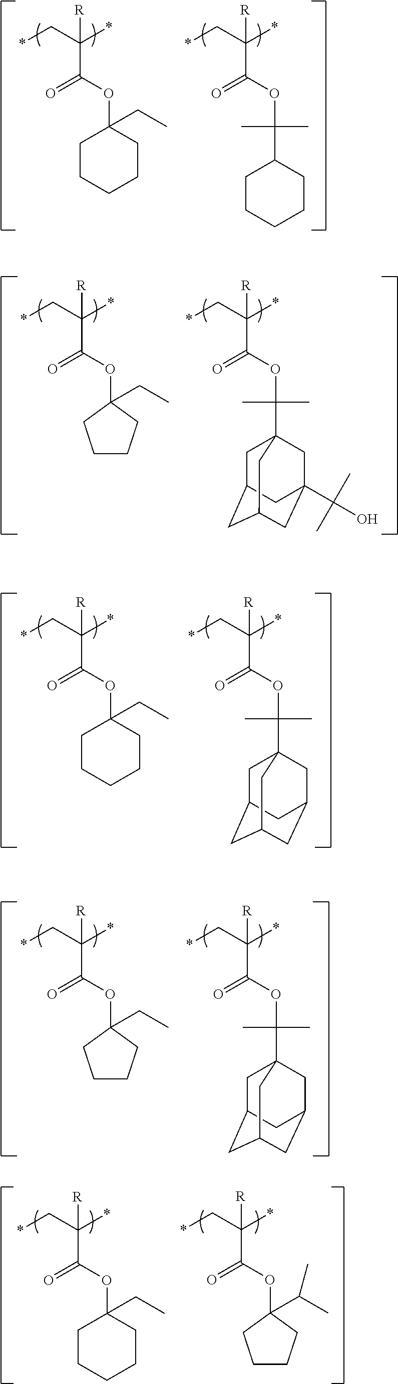

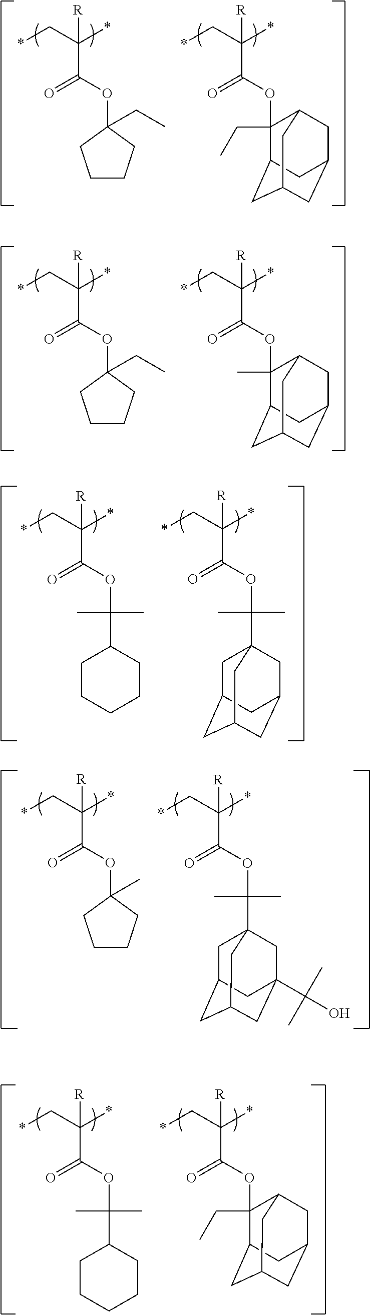

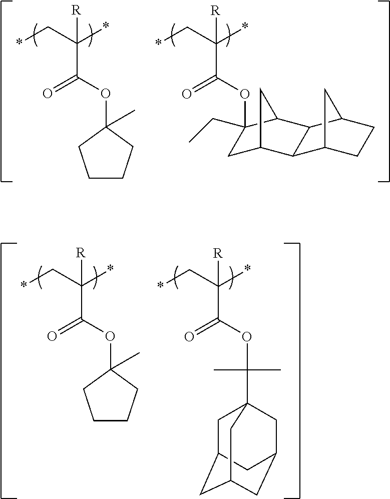

In view of defocus latitude characteristics, it is also preferred that the resin (A) does not contain (a4) a repeating unit having an acid-decomposable group.

The resin (A) may contain, in addition to the above-described repeating structural units, various repeating structural units for the purpose of controlling the dry etching resistance, suitability for standard developer, adherence to substrate, resist profile and properties generally required of a resist, such as resolution, heat resistance and sensitivity.

The resin (A) may be a resin obtained by mixing two or more kinds of resins and, for example, a resin obtained by mixing a resin containing the repeating unit (a1) and a resin containing the repeating unit (a2) may be used for the purpose of controlling the dry etching resistance, suitability for standard developer, adherence to substrate, resist profile and properties generally required of a resist, such as resolution, heat resistance and sensitivity.

It is also preferred to use a resin containing the repeating unit (a4) and a resin not containing the repeating unit (a4) by mixing these resins.

In the case where the composition of the present invention is used for ArF exposure, in view of transparency to ArF light, the resin (A) for use in the composition of the present invention preferably has substantially no aromatic group (specifically, the ratio of an aromatic group-containing repeating unit in the resin is preferably 5 mol % or less, more preferably 3 mol % or less, and ideally 0 mol %, that is, the resin does not have an aromatic group), and the resin (A) preferably has a monocyclic or polycyclic alicyclic hydrocarbon structure.

Incidentally, the resin (A) preferably contains no fluorine atom and no silicon atom in view of compatibility with the later-described hydrophobic resin.

In the present invention, the content of each repeating unit is as follows. As for each repeating unit, a plurality of kinds may be contained and in the case of containing a plurality of kinds of repeating units, the content below is their total amount.

The content of the (a1) repeating unit having an alcoholic hydroxyl group is generally from 10 to 80 mol %, preferably from 10 to 60 mol %, based on all repeating units constituting the resin (A).

In the case of containing (a2) a repeating unit having a nonpolar group and being free from an acid-decomposable group and a lactone structure, the content thereof is generally from 20 to 80 mol %, preferably from 30 to 60 mol %, based on all repeating units constituting the resin (A).

In the case of containing (a3) a repeating unit having lactone, the content thereof is preferably from 15 to 60 mol %, more preferably from 20 to 50 mol %, still more preferably from 30 to 50 mol %, based on all repeating units in the resin.

In the case of containing (a4) a repeating unit having an acid-decomposable group, the content thereof is preferably from 20 to 70 mol %, more preferably from 30 to 50 mol %, based on all repeating units in the resin.

In the resin (A), the molar ratio of respective repeating units contained can be appropriately set to control the dry etching resistance of resist, suitability for standard developer, adherence to substrate, resist profile and performances generally required of a resist, such as resolution, heat resistance and sensitivity.

The resin (A) can be synthesized by a conventional method (for example, radical polymerization). Examples of the general synthesis method include a batch polymerization method of dissolving monomer species and an initiator in a solvent and heating the solution, thereby effecting the polymerization, and a dropping polymerization method of adding dropwise a solution containing monomer species and an initiator to a heated solvent over 1 to 10 hours. A dropping polymerization method is preferred. With respect to details of the synthesis method, purification method and the like, the methods described, for example, in “Kobunshi Gosei (Polymer Synthesis)” of Dai 5-Han Jikken Kagaku Koza 26, Kobunshi Kagaku (Experimental Chemistry Lecture 26, Polymer Chemistry, 5th Edition), Chapter 2, Maruzen can be used.

The weight average molecular weight of the resin (A) is preferably from 1,000 to 200,000, more preferably from 2,000 to 20,000, still more preferably from 3,000 to 15,000, yet still more preferably from 3,000 to 10,000, in terms of polystyrene as measured by the GPC method. When the weight average molecular weight is from 1,000 to 200,000, reduction in the heat resistance and dry etching resistance can be avoided and at the same time, the film-forming property can be prevented from deterioration due to impairment of developability or increase in the viscosity.

The polydispersity (molecular weight distribution) is usually from 1 to 3, preferably from 1 to 2.6, more preferably from 1 to 2, still more preferably from 1.4 to 1.7. As the molecular weight distribution is smaller, the resolution and resist profile are more excellent, the side wall of the resist pattern is smoother, and the roughness is more improved.

In the resist composition of the present invention, the blending amount of the resin (A) in the entire composition is preferably from 65 to 97 mass %, more preferably from 78 to 95 mass %, still more preferably from 78 to 94 mass %, based on the entire solid content.

Also, in the present invention, as for the resin (A), one kind of a resin may be used or a plurality of kinds of resins may be used in combination.

### [3] Crosslinking Agent (C)

In the present invention, a compound capable of crosslinking the resin (A) by the action of an acid (hereinafter referred to as a “crosslinking agent”) is used together with the resin (A). Here, a known crosslinking agent can be effectively used.

The crosslinking agent (C) is a compound having a crosslinking group capable of crosslinking the resin (A), and examples of the crosslinking group include a hydroxymethyl group, an alkoxymethyl group, a vinyl ether group and an epoxy group. The crosslinking agent (C) preferably has two or more of such crosslinking groups. The crosslinking agent (C) is preferably a crosslinking agent of melamine-based compound, urea-based compound, alkylene urea-based compound or glycoluril-based compound.

Preferred examples of the crosslinking agent include a compound having an N-hydroxymethyl group, an N-alkoxymethyl group or an N-acyloxymethyl group.

The compound having an N-hydroxymethyl group, an N-alkoxymethyl group or an N-acyloxymethyl group is preferably a compound having two or more (more preferably from two to eight) partial structures represented by the following formula (CLNM-1):

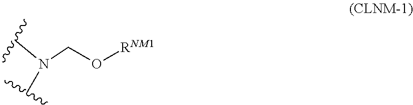

In formula (CLNM-1), R^{NM1} represents a hydrogen atom, an alkyl group, a cycloalkyl group or an oxoalkyl group. The alkyl group of R^{NM1} in formula (CLNM-1) is preferably a linear or branched alkyl group having a carbon number of 1 to 6, and the cycloalkyl group of R^{NM1} is preferably a cycloalkyl group having a carbon number of 5 to 6. The oxoalkyl group of R^{NM1} is preferably an oxoalkyl group having a carbon number of 3 to 6, and examples thereof include a β-oxopropyl group, a β-oxobutyl group, a β-oxopentyl group and a β-oxohexyl group.

More preferred embodiments of the compound having two or more partial structures represented by formula (CLNM-1) include a urea-based crosslinking agent represented by the following formula (CLNM-2), an alkylene urea-based crosslinking agent represented by the following formula (CLNM-3), a glycoluril-based crosslinking agent represented by the following formula (CLNM-4) and a melamine-based crosslinking agent represented by the following formula (CLNM-5).

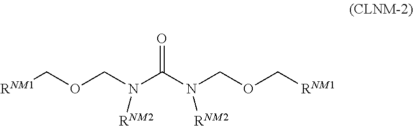

In formula (CLNM-2), each R^{NM1} independently has the same meaning as R^{NM1} in formula (CLNM-1).

Each R^{NM2} independently represents a hydrogen atom, an alkyl group (preferably having a carbon number of 1 to 6) or a cycloalkyl group (preferably having a carbon number of 5 to 6).

Specific examples of the urea-based crosslinking agent represented by formula (CLNM-2) include N,N-di(methoxymethyl)urea, N,N-di(ethoxymethyl)urea, N,N-di(propoxymethyl)urea, N,N-di(isopropoxymethyl)urea, N,N-di(butoxymethyl)urea, N,N-di(tert-butoxymethyl)urea, N,N-di(cyclohexyloxymethyl)urea, N,N-di(cyclopentyloxymethyl)urea, N,N-di(adamantyloxymethyl)urea and N,N-di(norbornyloxymethyl)urea.

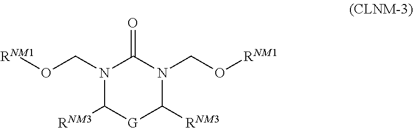

In formula (CLNM-3), each R^{NM1} independently has the same meaning as R^{NM1} in formula (CLNM-1).

Each R^{NM3} independently represents a hydrogen atom, a hydroxyl group, a linear or branched alkyl group (preferably having a carbon number of 1 to 6), a cycloalkyl group (preferably having a carbon number of 5 to 6), an oxoalkyl group (preferably having a carbon number of 3 to 6), an alkoxy group (preferably having a carbon number of 1 to 6) or an oxoalkoxy group (preferably having a carbon number of 1 to 6).

G represents a single bond, an oxygen atom, a sulfur atom, an alkylene group (preferably having a carbon number of 1 to 3) or a carbonyl group. Specific examples thereof include a methylene group, an ethylene group, a propylene group, a 1-methylethylene group, a hydroxymethylene group and a cyanomethylene group.

Specific examples of the alkylene urea-based crosslinking agent represented by formula (CLNM-3) include N,N-di(methoxymethyl)-4,5-di(methoxymethyl)ethylene urea, N,N-di(ethoxymethyl)-4,5-di(ethoxymethyl)ethylene urea, N,N-di(propoxymethyl)-4,5-di(propoxymethyl)ethylene urea, N,N-di(isopropoxymethyl)-4,5-di(isopropoxymethyl)ethyleneurea, N,N-di(butoxymethyl)-4,5-di(butoxymethypethylene urea, N,N-di(tert-butoxymethyl)-4,5-di(tert-butoxymethypethylene urea, N,N-di(cyclohexyloxymethyl)-4,5-di(cyclohexyloxymethyl)ethylene urea, N,N-di(cyclopentyloxymethyl)-4,5-di(cyclopentyloxymethyl)ethylene urea, N,N-di(adamantyloxymethyl)-4,5-di(adamantyloxymethyl)ethylene urea and N,N-di(norbornyloxymethyl)-4,5-di(norbornyloxymethyl)ethylene urea.

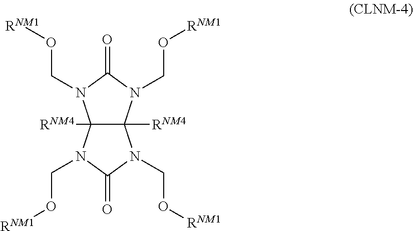

In formula (CLNM-4), each R^{NM1} independently has the same meaning as R^{NM1} in formula (CLNM-1).

Each R^{NM4} independently represents a hydrogen atom, a hydroxyl group, an alkyl group, a cycloalkyl group or an alkoxy group.

Specific examples of the alkyl group (preferably having a carbon number of 1 to 6), cycloalkyl group (preferably having a carbon number of 5 to 6) and alkoxy group (preferably having a carbon number of 1 to 6) of R^{NM4} include a methyl group, an ethyl group, a butyl group, a cyclopentyl group, a cyclohexyl group, a methoxy group, an ethoxy group and a butoxy group.

Specific examples of the glycoluril-based crosslinking agent represented by formula (CLNM-4) include N,N,N,N-tetra(methoxymethyl)glycoluril, N,N,N,N-tetra(ethoxymethyl)glycoluril, N,N,N,N-tetra(propoxymethyl)glycoluril, N,N,N,N-tetra(isopropoxymethyl)glycoluril, N,N,N,N-tetra(butoxymethyl)glycoluril, N,N,N,N-tetra(tert-butoxymethyl)glycoluril, N,N,N,N-tetra(cyclohexyloxymethyl)glycoluril, N,N,N,N-tetra(cyclopentyloxymethyl)glycoluril, N,N,N,N-tetra(adamantyloxymethyl)glycoluril and N,N,N,N-tetra(norbornyloxymethyl)glycoluril.

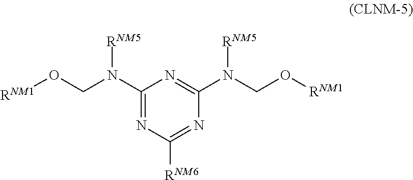

In formula (CLNM-5), each R^{NM1} independently has the same meaning as R^{NM1} in formula (CLNM-1).

Each R^{NM5} independently represents a hydrogen atom, an alkyl group, a cycloalkyl group, an aryl group or an atomic group represented by the following formula (CLNM-5′).

R^{NM6} represents a hydrogen atom, an alkyl group, a cycloalkyl group, an aryl group or an atomic group represented by the following formula (CLNM-5″).

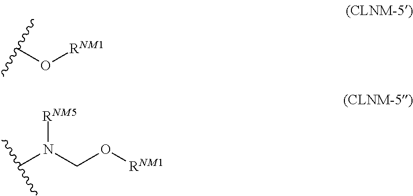

In formula (CLNM-5′), R^{NM1} has the same meaning as R^{NM1} in formula (CLNM-1).

In formula (CLNM-5″), R^{NM1} has the same meaning as R^{NM1} in formula (CLNM-1), and R^{NM5} has the same meaning as R^{NM5} in formula (CLNM-5).

Specific examples of the alkyl group (preferably having a carbon number of 1 to 6), cycloalkyl group (preferably having a carbon number of 5 to 6) and aryl group (preferably having a carbon number of 6 to 10) of R^{NM5} and R^{NM6} include a methyl group, an ethyl group, a propyl group, an isopropyl group, a butyl group, an isobutyl group, a tert-butyl group, a pentyl group, a cyclopentyl group, a hexyl group, a cyclohexyl group, a phenyl group and a naphthyl group.

Examples of the melamine-based crosslinking agent represented by formula (CLNM-5) include N,N,N,N,N,N-hexa(methoxymethyl)melamine, N,N,N,N,N,N-hexa(ethoxymethyl)melamine, N,N,N,N,N,N-hexa(propoxymethyl)melamine, N,N,N,N,N,N-hexa(isopropoxymethyl)melamine, N,N,N,N,N,N-hexa(butoxymethyl)melamine, N,N,N,N,N,N-hexa(tert-butoxymethyl)melamine, N,N,N,N,N,N-hexa(cyclohexyloxymethyl)melamine, N,N,N,N,N,N-hexa(cyclopentyloxymethyl)melamine, N,N,N,N,N,N-hexa(adamantyloxymethyl)melamine, N,N,N,N,N,N-hexa(norbornyloxymethyl)melamine, N,N,N,N,N,N-hexa(methoxymethyl)acetoguanamine, N,N,N,N,N,N-hexa(ethoxymethyl)acetoguanamine, N,N,N,N,N,N-hexa(propoxymethyl)acetoguanamine, N,N,N,N,N,N-hexa(isopropoxymethyl)acetoguanamine, N,N,N,N,N,N-hexa(butoxymethyl)acetoguanamine, N,N,N,N,N,N-hexa(tert-butoxymethyl)acetoguanamine, N,N,N,N,N,N-hexa(methoxymethyl)benzoguanamine, N,N,N,N,N,N-hexa(ethoxymethyl)benzoguanamine, N,N,N,N,N,N-hexa(propoxymethyl)benzoguanamine, N,N,N,N,N,N-hexa(isopropoxymethyl)benzoguanamine, N,N,N,N,N,N-hexa(butoxymethyl)benzoguanamine and N,N,N,N,N,N-hexa(tert-butoxymethyl)benzoguanamine.

The groups represented by R^{NM1} to R^{NM6} in formulae (CLNM-1) to (CLNM-5) may further have a substituent. Examples of the substituent which R^{NM1} to R^{NM6} may have include a halogen atom, a hydroxyl group, a nitro group, a cyano group, a carboxyl group, a cycloalkyl group (preferably having a carbon number of 3 to 20), an aryl group (preferably having a carbon number of 6 to 14), an alkoxy group (preferably having a carbon number of 1 to 20), a cycloalkoxy group (preferably having a carbon number of 4 to 20), an acyl group (preferably having a carbon number of 2 to 20) and an acyloxy group (preferably having a carbon number of 2 to 20).

The crosslinking agent (C) may be a phenol compound having a benzene ring in the molecule.

The phenol compound is preferably a phenol derivative having a molecular weight of 1,200 or less, containing from three to five benzene rings in the molecule and further having two or more hydroxymethyl groups or alkoxymethyl groups in total, where the hydroxymethyl groups or alkoxymethyl groups are bonded in a concentrated manner to at least any one benzene ring or distributed among the benzene rings. By using such a phenol derivative, the effects of the present invention are more remarkably brought out. The alkoxymethyl group bonded to the benzene ring is preferably an alkoxymethyl group having a carbon number of 6 or less. Specifically, a methoxymethyl group, an ethoxymethyl group, an n-propoxymethyl group, an i-propoxymethyl group, an n-butoxymethyl group, an i-butoxymethyl group, a sec-butoxymethyl group, or a tert-butoxymethyl group is preferred. An alkoxy-substituted alkoxy group such as 2-methoxyethoxy group and 2-methoxy-1-propyl group is also preferred.

The phenol compound is preferably a phenol compound containing two or more benzene rings in the molecule and is preferably a phenol compound containing no nitrogen atom.

Specifically, a phenol compound having from two to eight crosslinking groups capable of crosslinking the resin (A) per molecule is preferred, and it is more preferred to have from three to six crosslinking groups.

Out of these phenol derivatives, particularly preferred compounds are illustrated below. In the formulae, each of L¹ to L⁸, which may be the same or different, represents a crosslinking group, and the crosslinking group is preferably a hydroxymethyl group, a methoxymethyl group or an ethoxymethyl group.

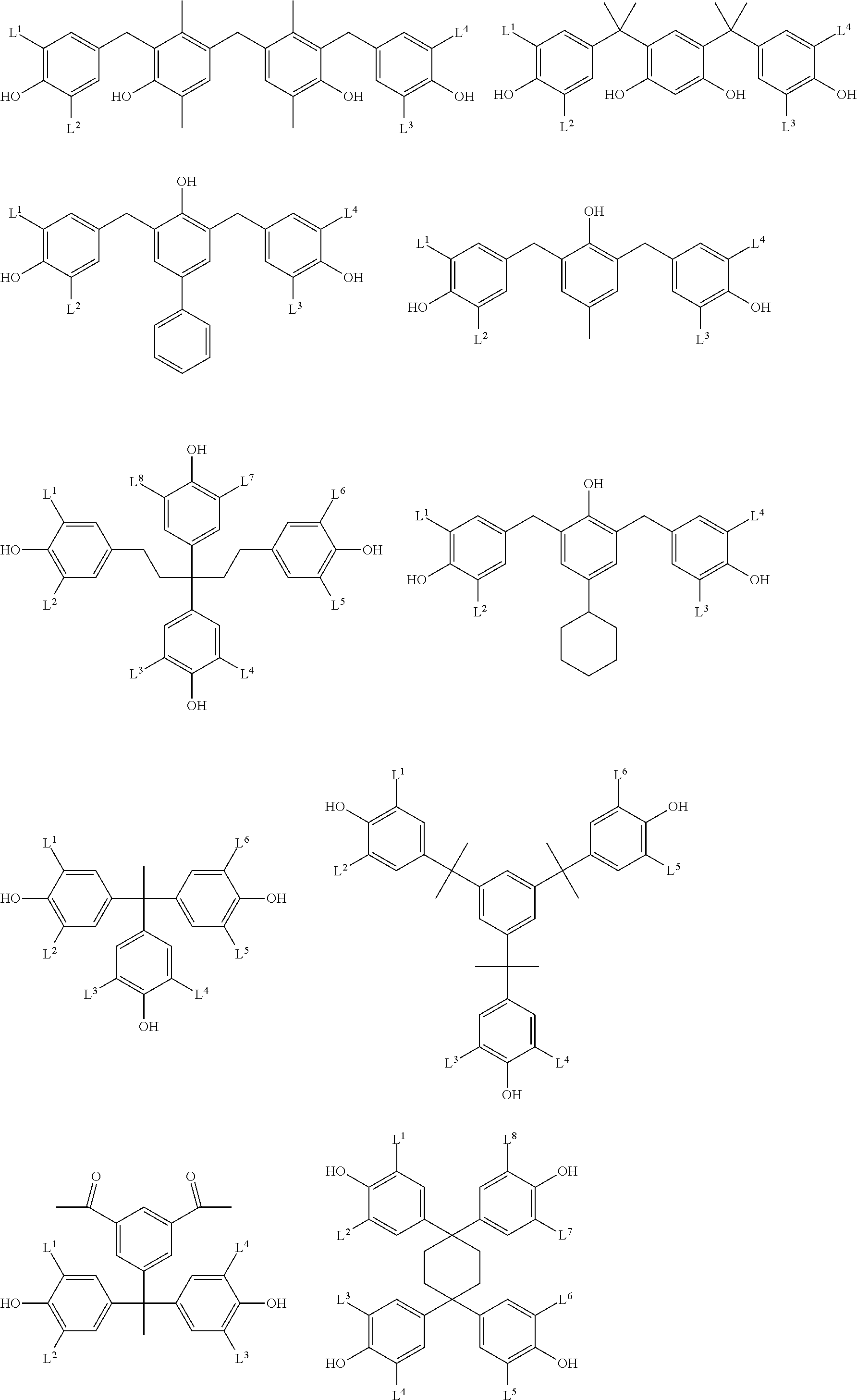

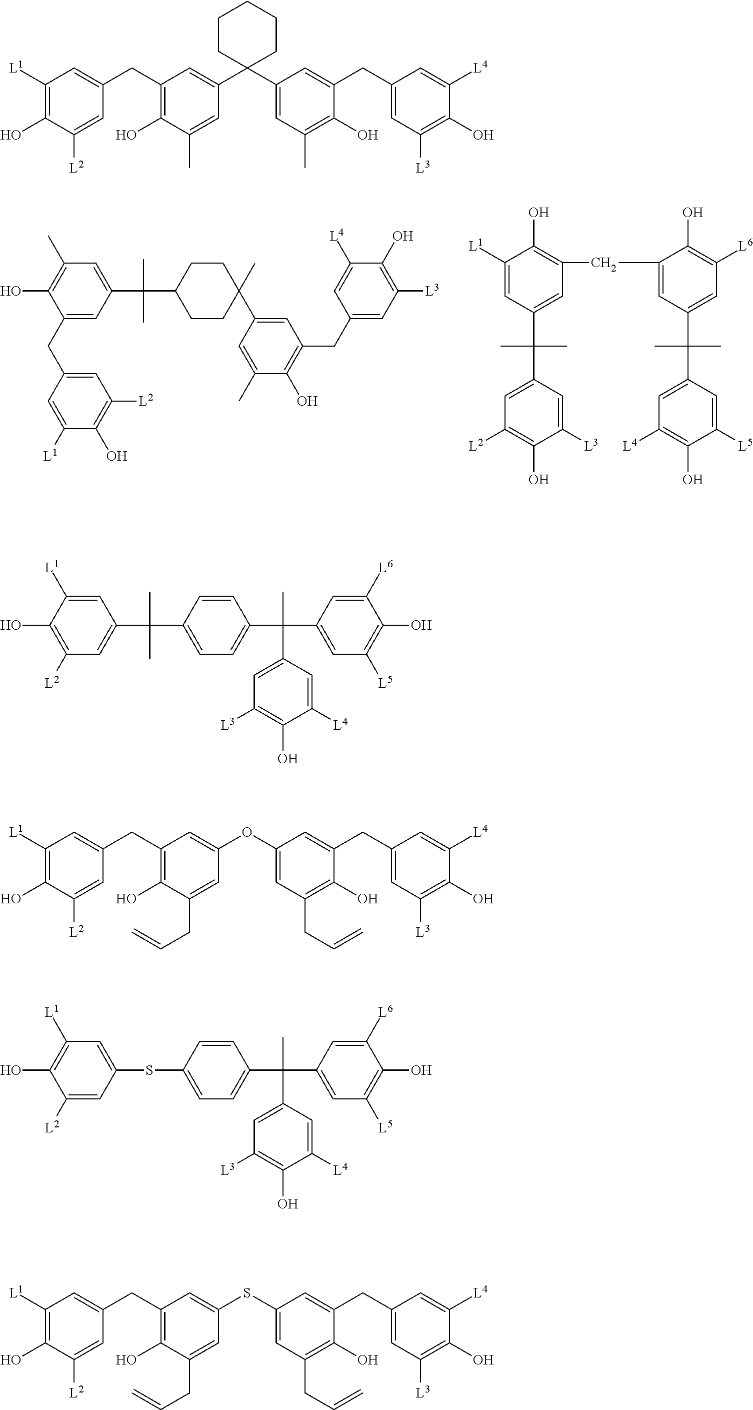

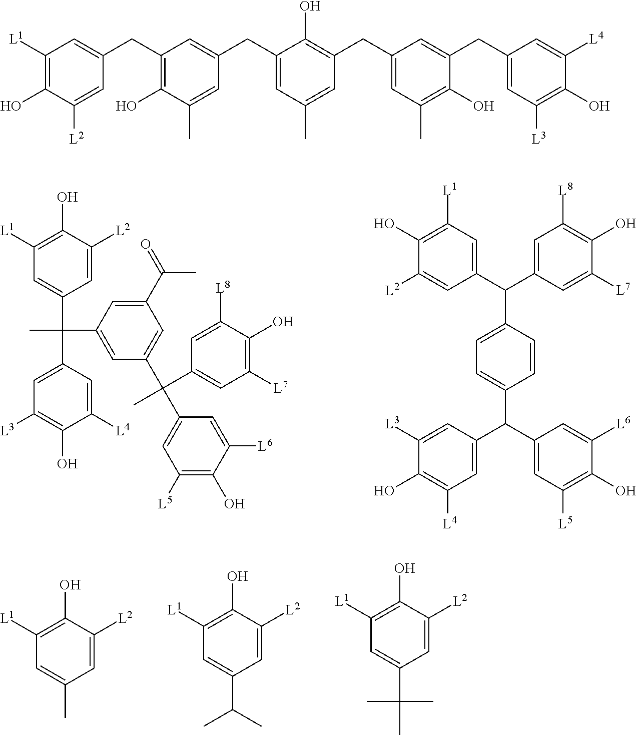

As for the phenol compound, a commercially available product may be used, or the compound may be synthesized by a known method. For example, a phenol derivative having a hydroxymethyl group can be obtained by reacting a phenol compound having no corresponding hydroxymethyl group (a compound where in the formulae above, each of L¹ to L⁸ is a hydrogen atom) with formaldehyde in the presence of a base catalyst. At this time, in order to prevent resinification or gelling, the reaction is preferably performed at a temperature of 60° C. or less. Specifically, the compound can be synthesized by the method described, for example, in JP-A-6-282067 and JP-A-7-64285.

A phenol derivative having an alkoxymethyl group can be obtained by reacting a phenol derivative having a corresponding hydroxymethyl group with an alcohol in the presence of an acid catalyst. At this time, in order to prevent resinification or gelling, the reaction is preferably performed at a temperature of 100° C. or less. Specifically, the compound can be synthesized by the method described, for example, in EP632003A1. The thus-synthesized phenol derivative having a hydroxymethyl group or an alkoxymethyl group is preferred in view of stability during storage, and a phenol derivative having an alkoxymethyl group is particularly preferred in view of stability during storage. One of these phenol derivatives having two or more hydroxymethyl groups or alkoxymethyl groups in total which are bonded in a concentrated manner to any one benzene ring or distributed among the benzene rings, may be used alone, or two or more thereof may be used in combination.

The crosslinking agent (C) may be an epoxy compound having an epoxy group in the molecule.

The epoxy compound includes a compound represented by the following formula (EP2).

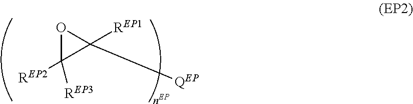

In formula (EP2), each of R^{EP1} to R^{EP3} independently represents a hydrogen atom, a halogen atom, an alkyl group or a cycloalkyl group, and these alkyl group and cycloalkyl group may have a substituent. Also, R^{EP1} and R^{EP2}, or R^{EP2} and R^{EP3} may combine with each other to form a ring structure.

Examples of the substituent which the alkyl group and cycloalkyl group may have include a hydroxyl group, a cyano group, an alkoxy group, an alkylcarbonyl group, an alkoxycarbonyl group, an alkylcarbonyloxy group, an alkylthio group, an alkylsulfone group, an alkylsulfonyl group, an alkylamino group and an alkylamide group.

Q^{EP} represents a single bond or an n^{EP}-valent organic group. R^{EPI} to R^{EP3} may combine not only with each other but also with Q^{EP} to form a ring structure.

n^{EP} represents an integer of 2 or more and is preferably an integer of 2 to 10, more preferably from 2 to 6. However, when Q^{EP} is a single bond, n^{EP} is 2.

In the case where Q^{EP} is an n^{EP}-valent organic group, for example, a chain or cyclic saturated hydrocarbon structure (preferably having a carbon number of 2 to 20), an aromatic ring structure (preferably having a carbon number of 6 to 30), or a structure where these structures are linked by a structure such as ether, ester, amide and sulfonamide, is preferred.

Specific examples of the (B) compound having an epoxy structure are illustrated below, but the present invention is not limited thereto.

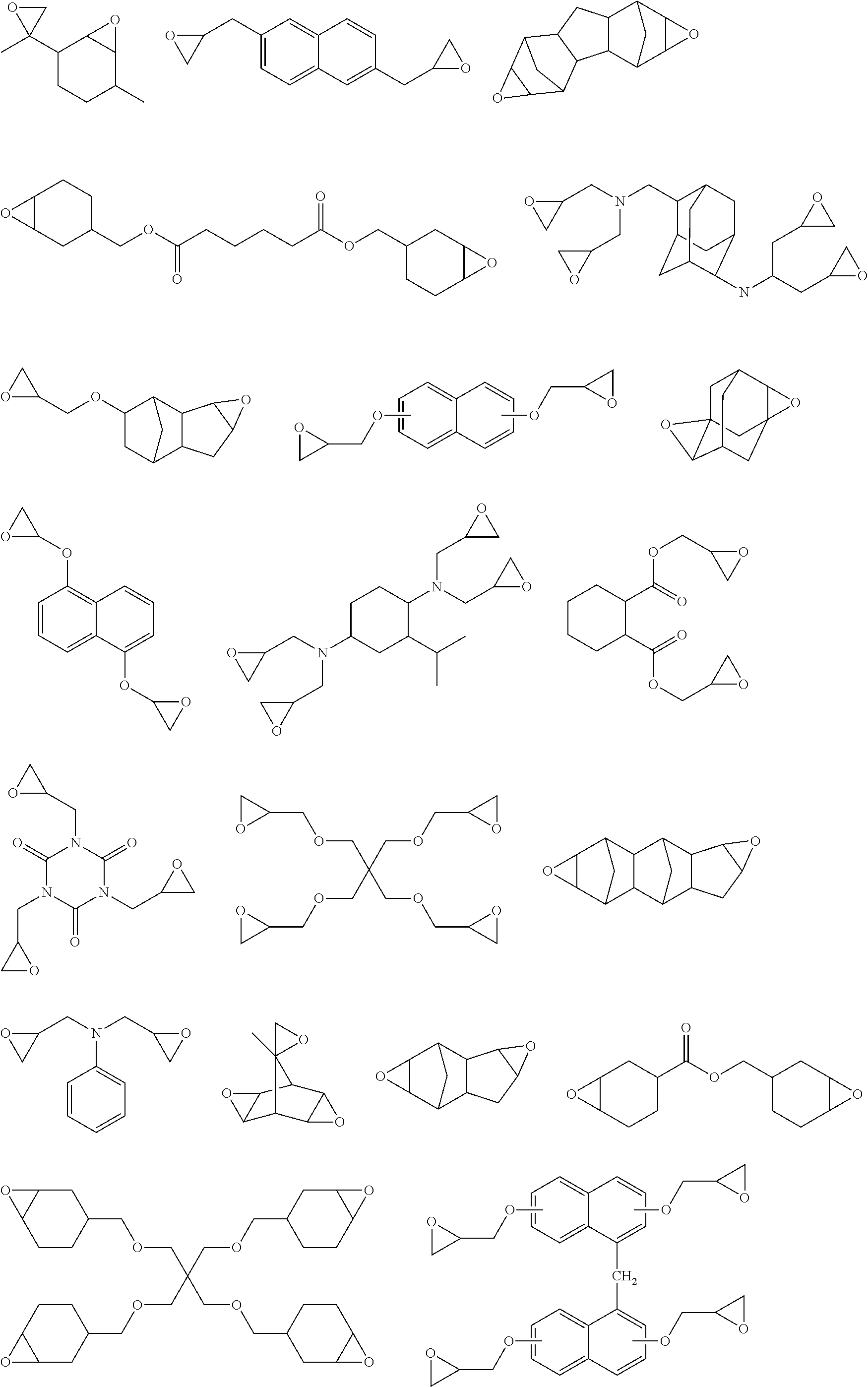

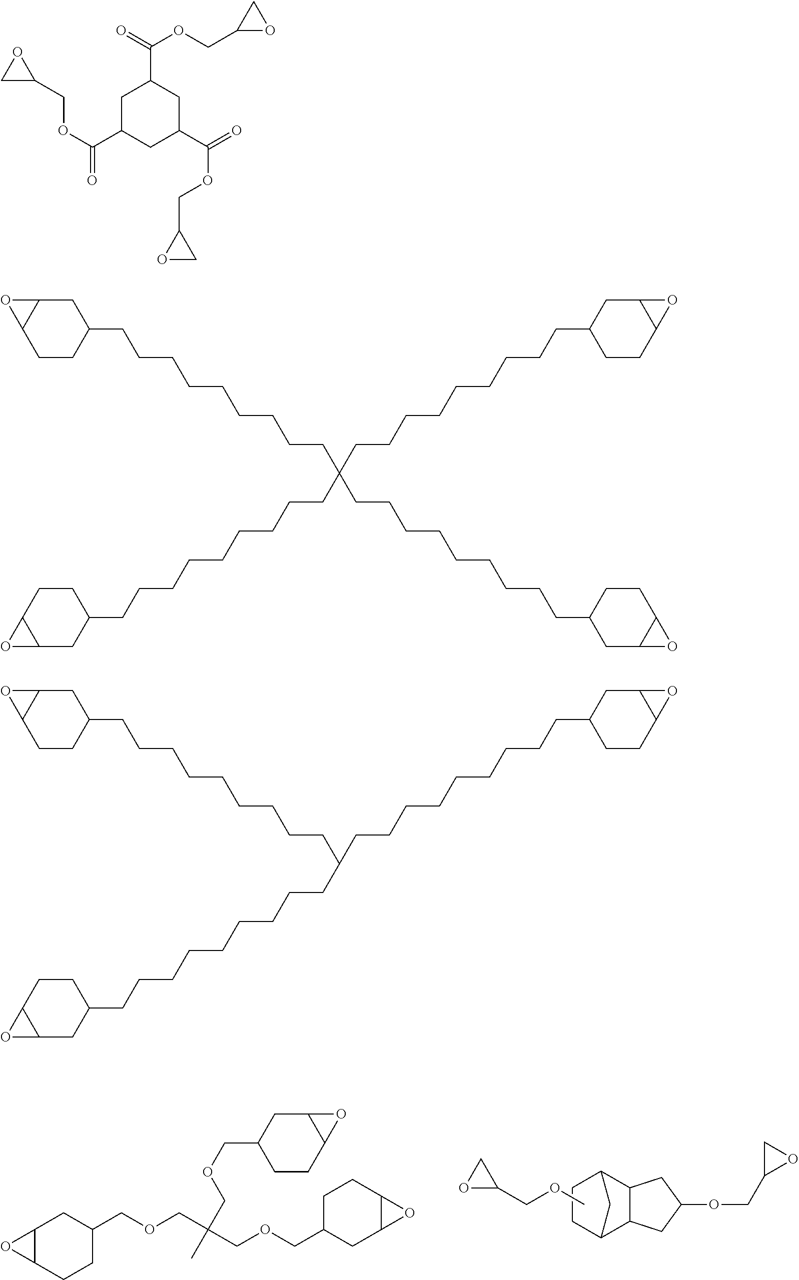

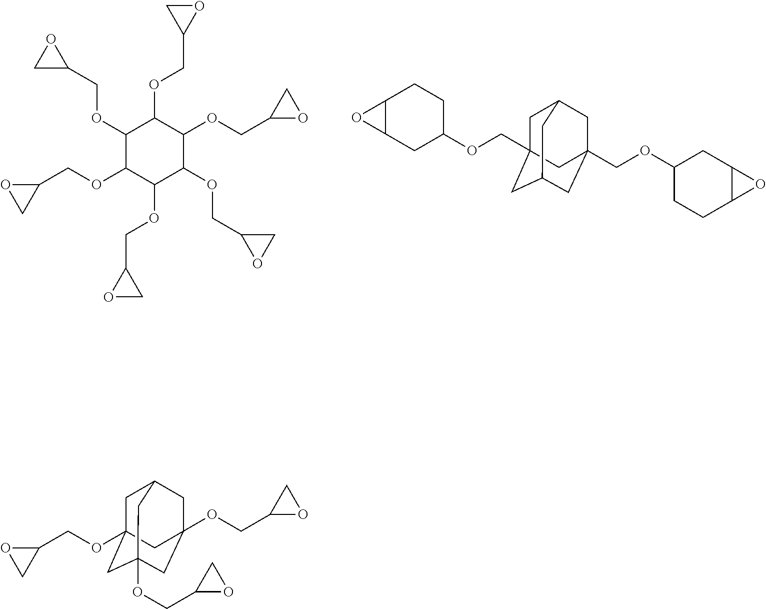

In the present invention, one crosslinking agent may be used alone, or two or more crosslinking agents may be used in combination.

The content of the crosslinking agent in the resist composition is preferably from 3 to 15 mass %, more preferably from 4 to 12 mass %, still more preferably form 5 to 10 mass %, based on the entire solid content of the resist composition.

### [4] Solvent (D)

The resist composition for use in the present invention contains a solvent.

Examples of the solvent which can be used at the time of preparing the resist composition for use in the present invention include an organic solvent such as alkylene glycol monoalkyl ether carboxylate, alkylene glycol monoalkyl ether, alkyl lactate, alkyl alkoxypropionate, cyclic lactone (preferably having a carbon number of 4 to 10), monoketone compound (preferably having a carbon number of 4 to 10) which may contain a ring, alkylene carbonate, alkyl alkoxyacetate and alkyl pyruvate.

Specific examples and preferred examples of these solvents are the same as those described in paragraphs [0244] to [0248] of JP-A-2008-292975.

In the present invention, a mixed solvent prepared by mixing a solvent containing a hydroxyl group in the structure and a solvent not containing a hydroxyl group may be used as the organic solvent.

The solvent containing a hydroxyl group and the solvent not containing a hydroxyl group may be appropriately selected from the compounds exemplified above, but the solvent containing a hydroxyl group is preferably an alkylene glycol monoalkyl ether, an alkyl lactate or the like, more preferably propylene glycol monomethyl ether (PGME, another name: 1-methoxy-2-propanol) or ethyl lactate. The solvent not containing a hydroxyl group is preferably an alkylene glycol monoalkyl ether acetate, an alkyl alkoxypropionate, a monoketone compound which may contain a ring, a cyclic lactone, an alkyl acetate or the like, more preferably propylene glycol monomethyl ether acetate (PGMEA, another name: 1-methoxy-2-acetoxypropane), ethyl ethoxy propionate, 2-heptanone, γ-butyrolactone, cyclohexanone or butyl acetate, and most preferably propylene glycol monomethyl ether acetate, ethyl ethoxypropionate or 2-heptanone.

The mixing ratio (by mass) of the solvent containing a hydroxyl group to the solvent not containing a hydroxyl group is from 1/99 to 99/1, preferably from 10/90 to 90/10, more preferably from 20/80 to 60/40. A mixed solvent in which the solvent not containing a hydroxyl group accounts for 50 mass % or more is particularly preferred in view of coating uniformity.

The solvent is preferably a mixed solvent of two or more kinds of solvents containing propylene glycol monomethyl ether acetate.

### [5] Hydrophobic Resin (HR)

The resist composition for use in the present invention may contain a hydrophobic resin having at least either a fluorine atom or a silicon atom particularly when the resist composition is applied to immersion exposure. The hydrophobic resin (HR) is unevenly distributed to the film surface layer and when the immersion medium is water, the static/dynamic contact angle on the resist film surface for water as well as the followability of immersion liquid can be enhanced.

The hydrophobic resin (HR) is, as described above, unevenly distributed to the interface but unlike a surfactant, need not have necessarily a hydrophilic group in the molecule and may not contribute to uniform mixing of polar/nonpolar substances.

The hydrophobic resin typically contains a fluorine atom and/or a silicon atom. Such a fluorine atom and/or a silicon atom may be contained in the main chain of the resin or contained in the side chain.

In the case where the hydrophobic resin contains a fluorine atom, the resin preferably contains, as the fluorine atom-containing partial structure, a fluorine atom-containing alkyl group, a fluorine atom-containing cycloalkyl group or a fluorine atom-containing aryl group.

The fluorine atom-containing alkyl group is a linear or branched alkyl group with at least one hydrogen atom being substituted for by a fluorine atom. This alkyl group preferably has a carbon number of 1 to 10, more preferably from 1 to 4. The fluorine atom-containing alkyl group may further have a substituent other than fluorine atom.

The fluorine atom-containing cycloalkyl group is a monocyclic or polycyclic cycloalkyl group with at least one hydrogen atom being substituted for by a fluorine atom. This fluorine atom-containing cycloalkyl group may further have a substituent other than fluorine atom.

The fluorine atom-containing aryl group is an aryl group with at least one hydrogen atom being substituted for by a fluorine atom. Examples of this aryl group include a phenyl group and a naphthyl group. The fluorine atom-containing aryl group may further have a substituent other than fluorine atom.

Preferred examples of the fluorine atom-containing alkyl group, fluorine atom-containing cycloalkyl group and fluorine atom-containing aryl group include the groups represented by the following formulae (F2) to (F4):

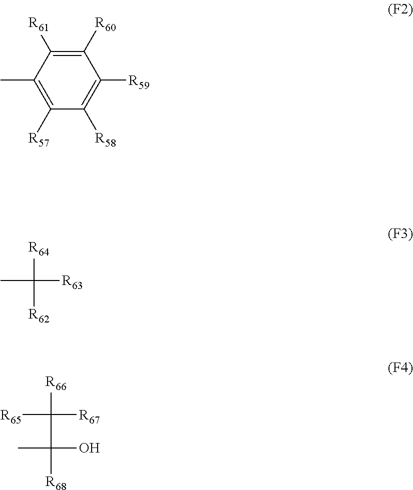

In formulae (F2) to (F4), each of R₅₇ to R₆₈ independently represents a hydrogen atom, a fluorine atom or an alkyl group. However, at least one of R₅₇ to R₆₁ represents a fluorine atom or an alkyl group with at least one hydrogen atom being substituted for by a fluorine atom, at least one of R₆₂ to R₆₄ represents a fluorine atom or an alkyl group with at least one hydrogen atom being substituted for by a fluorine atom, and at least one of R₆₅ to R₆₈ represents a fluorine atom or an alkyl group with at least one hydrogen atom being substituted for by a fluorine atom. The alkyl group preferably has a carbon number of 1 to 4.

It is preferred that all of R₅₇ to R₆₁ and all of R₆₅ to R₆₇ are a fluorine atom.

Each of R₆₂, R₆₃ and R₆₈ is preferably an alkyl group with at least one hydrogen atom being substituted for by a fluorine atom, more preferably a perfluoroalkyl group having a carbon number of 1 to 4. R₆₂ and R₆₃ may combine with each other to form a ring.

Examples of the group represented by formula (F2) include p-fluorophenyl group, pentafluorophenyl group and 3,5-di(trifluoromethyl)phenyl group.

Examples of the group represented by formula (F3) include trifluoromethyl group, pentafluoropropyl group, pentafluoroethyl group, heptafluorobutyl group, hexafluoroisopropyl group, heptafluoroisopropyl group, hexafluoro(2-methyl)isopropyl group, nonafluorobutyl group, octafluoroisobutyl group, nonafluorohexyl group, nonafluoro-tert-butyl group, perfluoroisopentyl group, perfluorooctyl group, perfluoro(trimethyl)hexyl group, 2,2,3,3-tetrafluorocyclobutyl group and perfluorocyclohexyl group. Among these, hexafluoroisopropyl group, heptafluoroisopropyl group, hexafluoro(2-methyl)isopropyl group, octafluoroisobutyl group, nonafluoro-tert-butyl group and perfluoroisopentyl group are preferred, and hexafluoroisopropyl group and heptafluoroisopropyl group are more preferred.

Examples of the group represented by formula (F4) include —C(CF₃)₂OH, —C(C₂F₅)₂OH, —C(CF₃)(CH₃)OH and —CH(CF₃)OH, with —C(CF₃)₂OH being preferred.

Specific examples of the repeating unit containing a fluorine atom are illustrated below.

In specific examples, X₁ represents a hydrogen atom, —CH₃, —F or —CF₃, and X₂ represents —F or —CF₃.

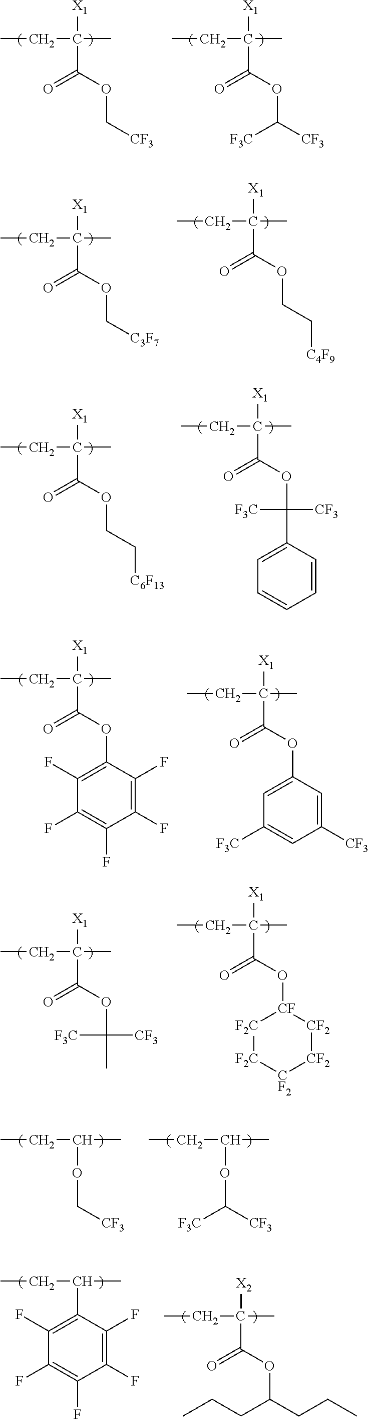

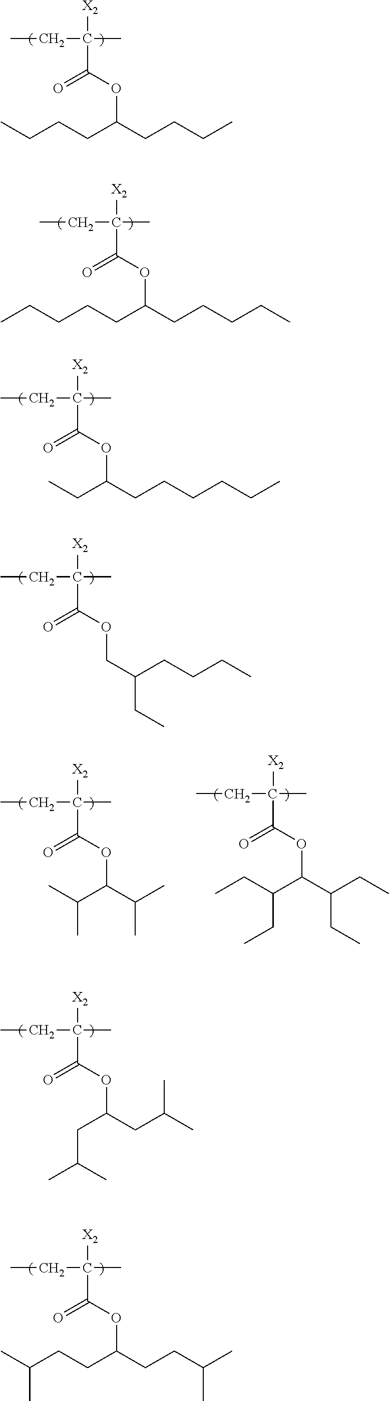

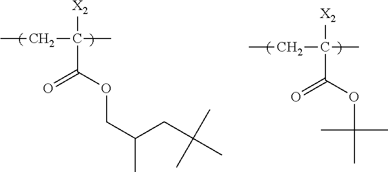

In the case where the hydrophobic resin contains a silicon atom, the resin preferably contains an alkylsilyl structure or a cyclic siloxane structure, as the silicon atom-containing partial structure. The alkylsilyl structure is preferably a trialkylsilyl group-containing structure.

Preferred examples of the alkylsilyl structure and cyclic siloxane structure include the groups represented by the following formulae (CS-1) to (CS-3).

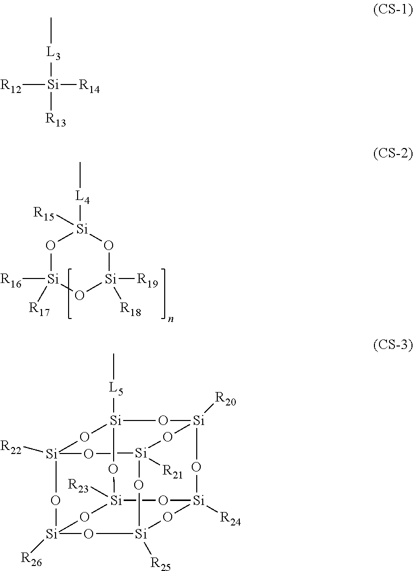

In formulae (CS-1) to (CS-3), each of R₁₂ to R₂₆ independently represents a linear or branched alkyl group or a cycloalkyl group. The alkyl group preferably has a carbon number of 1 to 20. The cycloalkyl group preferably has a carbon number of 3 to 20.

Each of L₃ to L₅ represents a single bond or a divalent linking group. Examples of the divalent linking group include an alkylene group, a phenylene group, an ether bond, a thioether bond, a carbonyl group, an ester bond, an amide bond, a urethane bond, a ureylene bond, and a combination of two or more of these groups and bonds, and a linking group having a total carbon number of 12 or less is preferred.

n represents an integer of 1 to 5. n is preferably an integer of 2 to 4.

Specific examples of the repeating unit having a group represented by formulae (CS-1) to (CS-3) are illustrated below. In specific examples, X₁ represents a hydrogen atom, —CH₃, —F or —CF₃.

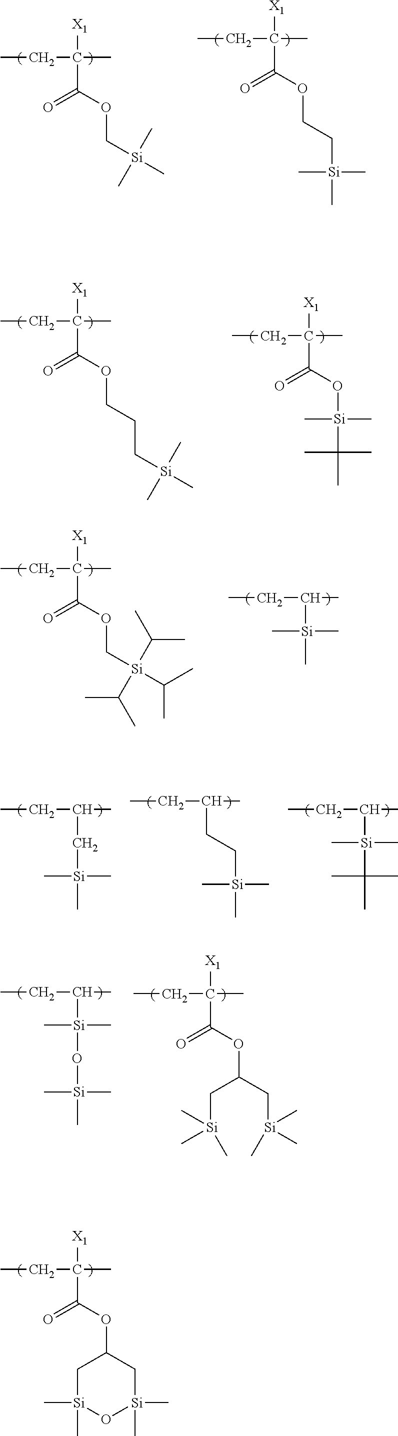

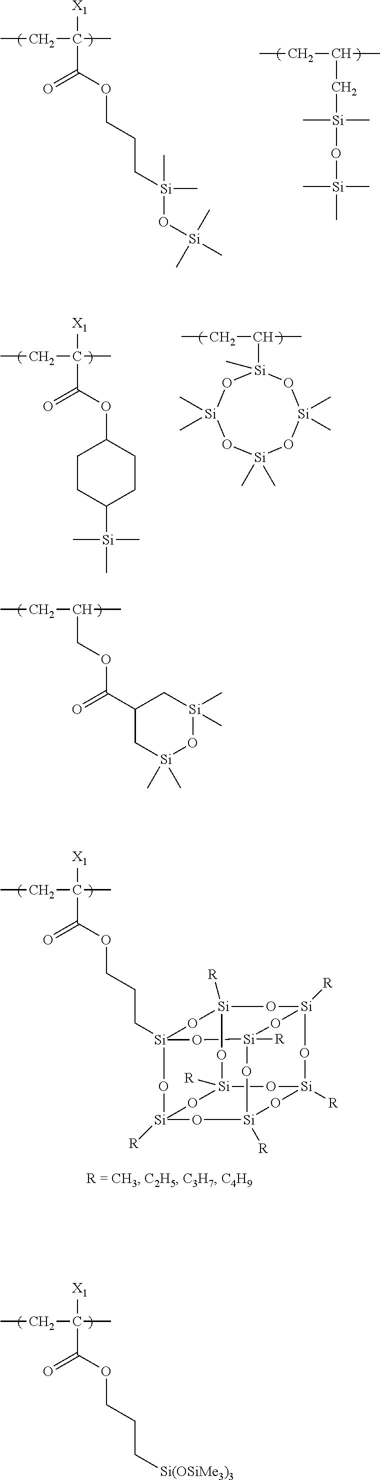

The hydrophobic resin may further contain at least one group selected from the group consisting of the following (x) to (z):

(x) an acid group,

(y) a group having a lactone structure, an acid anhydride group, or an acid imide group, and

(z) an acid-decomposable group.

Examples of the (x) acid group include a phenolic hydroxyl group, a carboxylic acid group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group and a tris(alkylsulfonyl)methylene group. Preferred acid groups include a fluorinated alcohol group, a sulfonimide group and a bis(carbonyl)methylene group. Preferred fluorinated alcohol groups include a hexafluoroisopropanol group.

The repeating unit having an acid group is, for example, a repeating unit where an acid group is directly bonded to the main chain of the resin, such as repeating unit by an acrylic acid or a methacrylic acid. This repeating unit may be a repeating unit where an acid group is bonded to the main chain of the resin through a linking group. Alternatively, in this repeating unit, an acid group may be introduced into the terminal of the resin by using an acid group-containing polymerization initiator or chain transfer agent at the polymerization.

The content of the repeating unit having an acid group is preferably from 1 to 50 mol %, more preferably from 3 to 35 mol %, still more preferably from 5 to 20 mol %, based on all repeating units in the hydrophobic resin.

Specific examples of the repeating unit having an acid group are illustrated below. In the formulae, Rx represents a hydrogen atom, —CH₃, —CF₃ or —CH₂OH.

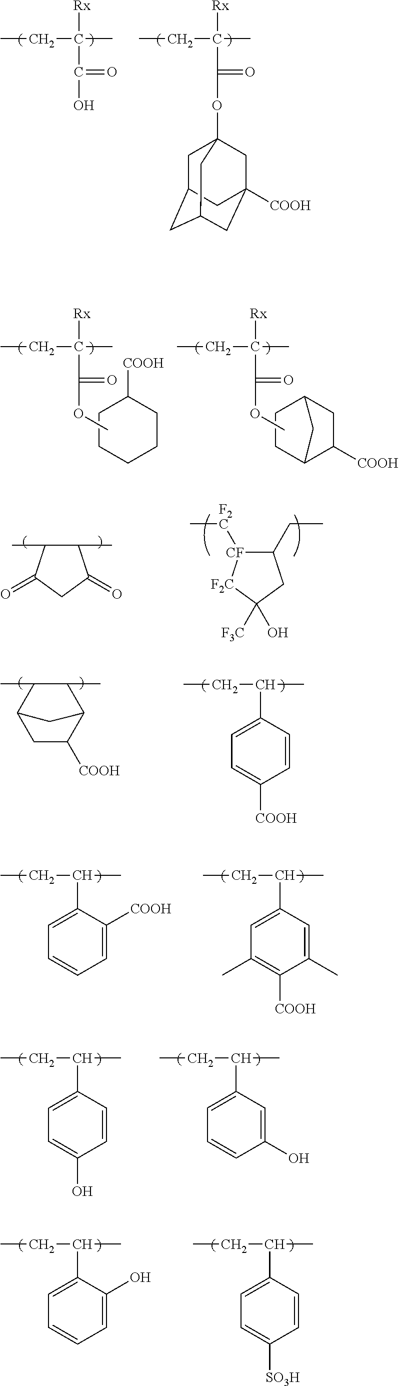

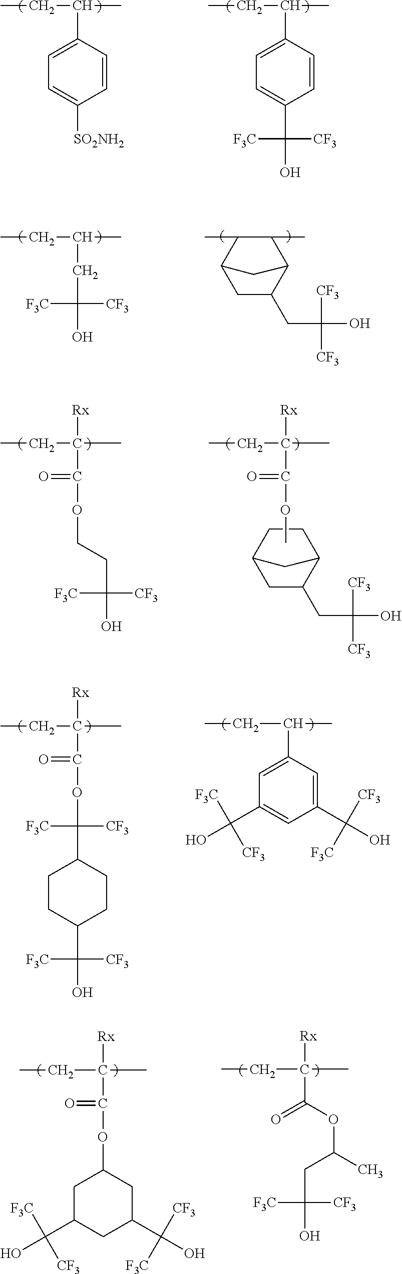

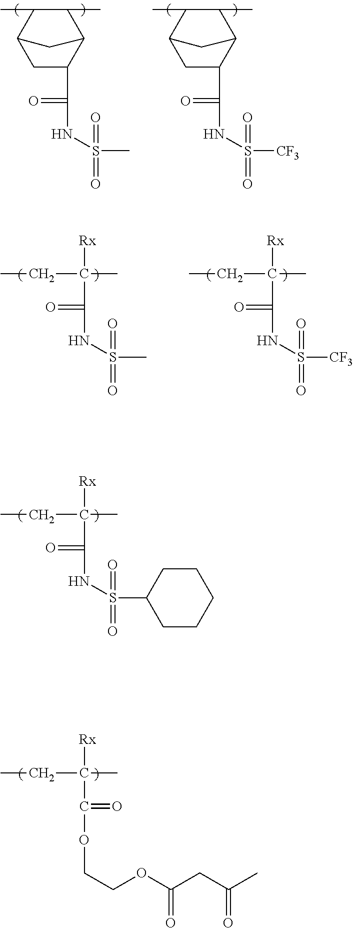

The (y) group having a lactone structure, acid anhydride group or acid imide group is preferably a group having a lactone structure.

The repeating unit having such a group is a repeating unit where the group is directly bonded to the main chain of the resin, such as repeating unit by an acrylic acid ester or a methacrylic acid ester. This repeating unit may also be a repeating unit where the group is bonded to the main chain of the resin through a linking group. Alternatively, in this repeating unit, the group may be introduced into the terminal of the resin by using a polymerization initiator or chain transfer agent containing the group at the polymerization.

Examples of the repeating unit containing a group having a lactone structure are the same as those of the repeating unit having a lactone structure described above in the paragraph of the (A) acid-decomposable resin.

The content of the repeating unit containing a group having a lactone structure, an acid anhydride group or an acid imide group is preferably from 1 to 40 mol %, more preferably from 3 to 30 mol %, still more preferably from 5 to 15 mol %, based on all repeating units in the hydrophobic resin.

Examples of the (z) acid-decomposable group are the same as those described above in the paragraph of the (A) acid-decomposable resin.

The content of the repeating unit having an acid-decomposable group is preferably from 1 to 80 mol %, more preferably from 10 to 80 mol %, still more preferably from 20 to 60 mol %, based on all repeating units in the hydrophobic resin.

The hydrophobic resin may further contain a repeating unit represented by the following formula (III):

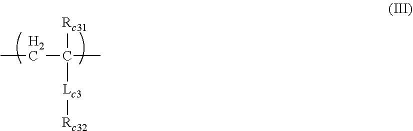

R_{c31} represents a hydrogen atom, an alkyl group (which may be substituted with a fluorine atom or the like), a cyano group or a —CH₂—O-Rac₂ group, wherein Rac₂ represents a hydrogen atom, an alkyl group or an acyl group.

R_{c31} is preferably a hydrogen atom, a methyl group or a trifluoromethyl group, more preferably a hydrogen atom or a methyl group.

R_{c32} represents a group having an alkyl group, a cycloalkyl group, an alkenyl group, a cycloalkenyl group or an aryl group. These groups may be substituted with a silicon atom-containing group, a fluorine atom or the like.

L_{c3} represents a single bond or a divalent linking group.

The alkyl group of R_{c32} is preferably a linear or branched alkyl group having a carbon number of 3 to 20.

The cycloalkyl group preferably has a carbon number of 3 to 20.

The alkenyl group preferably has a carbon number of 3 to 20.

The cycloalkenyl group is preferably a cycloalkenyl group having a carbon number of 3 to 20.

R_{c32} is preferably an unsubstituted alkyl group or an alkyl group with at least one hydrogen atom being substituted for by a fluorine atom.

L_{c3} represents a single bond or a divalent linking group. Examples of the divalent linking group include an alkylene group (preferably having a carbon number of 1 to 5), an ether bond, a phenylene group, an ester bond (a group represented by —COO—), and a combination of two or more of these groups or bonds, and a linking group having a total carbon number of 12 or less is preferred.

The content of the repeating unit represented by formula (III) is preferably from 1 to 100 mol %, more preferably from 10 to 90 mol %, still more preferably from 30 to 70 mol %, based on all repeating units in the hydrophobic resin.

The hydrophobic resin may further contain a repeating unit represented by the following formula (CII-AB):

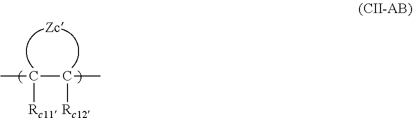

In formula (CII-AB), each of R_{c11′} and R_{c12′} independently represents a hydrogen atom, a cyano group, a halogen atom or an alkyl group. Z_{c′} represents an atomic group necessary for forming an alicyclic structure together with two carbon atoms (C—C) to which R_{c11′} and R_{c12′} are bonded.

The content of the repeating unit represented by formula (C11-AB) is preferably from 1 to 100 mol %, more preferably from 10 to 90 mol %, still more preferably from 30 to 70 mol %, based on all repeating units in the hydrophobic resin.

Specific examples of the repeating units represented by formulae (III) and (CII-AB) are illustrated below. In specific examples, Ra represents H, —CH₃, —CH₂OH, —CF₃ or a cyano group.

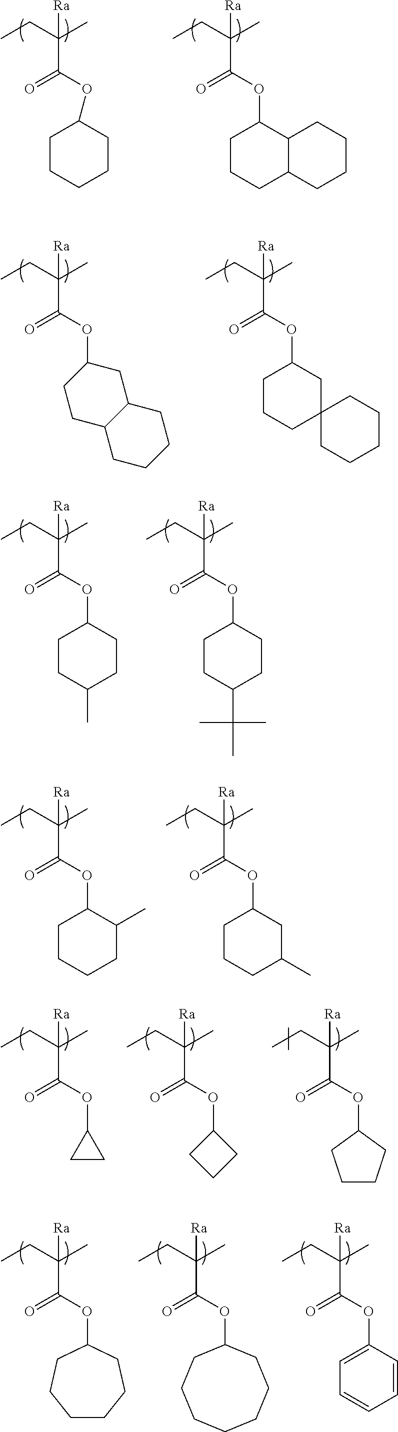

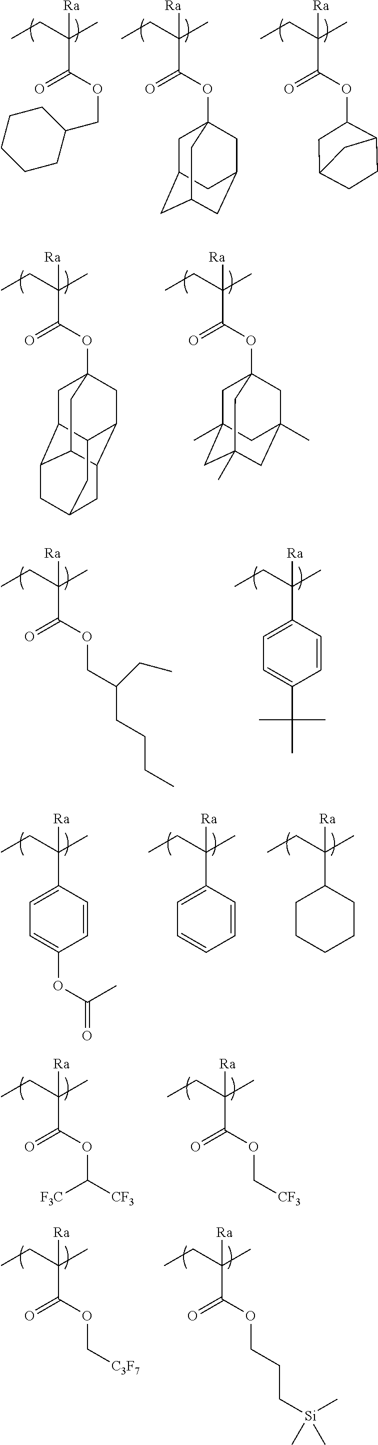

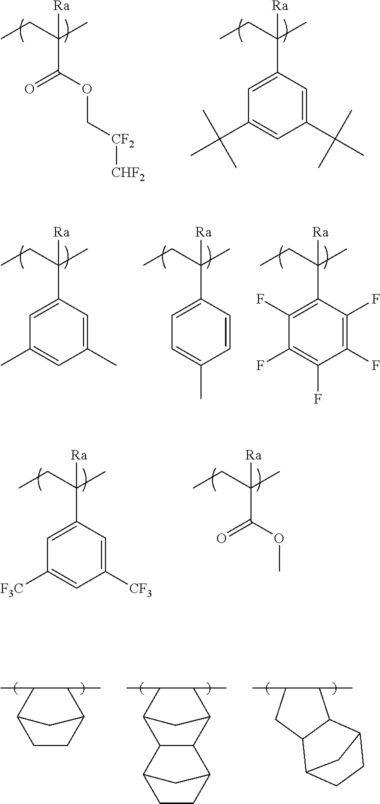

Specific examples of the hydrophobic resin are illustrated below. Also, the molar ratio of repeating units (corresponding to repeating units starting from the left), weight average molecular weight and polydispersity (Mw/Mn) of each resin are shown in Table 1.

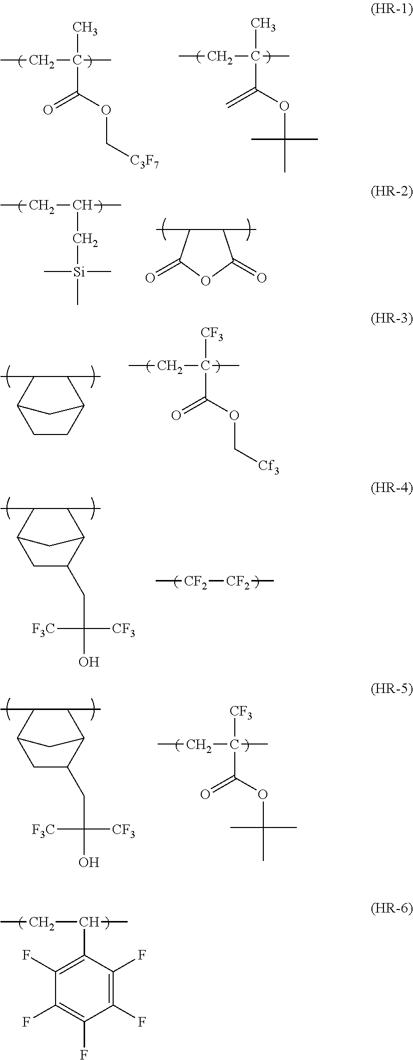

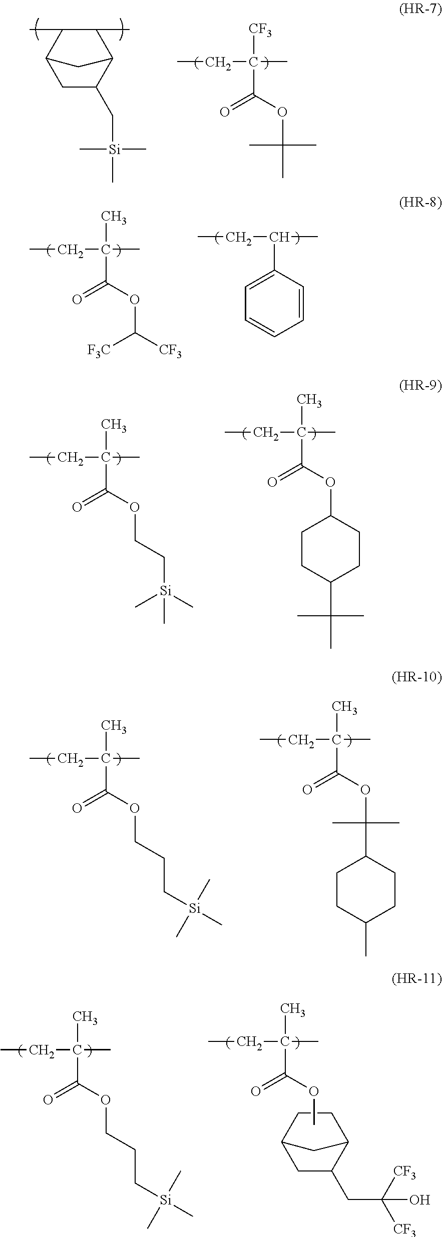

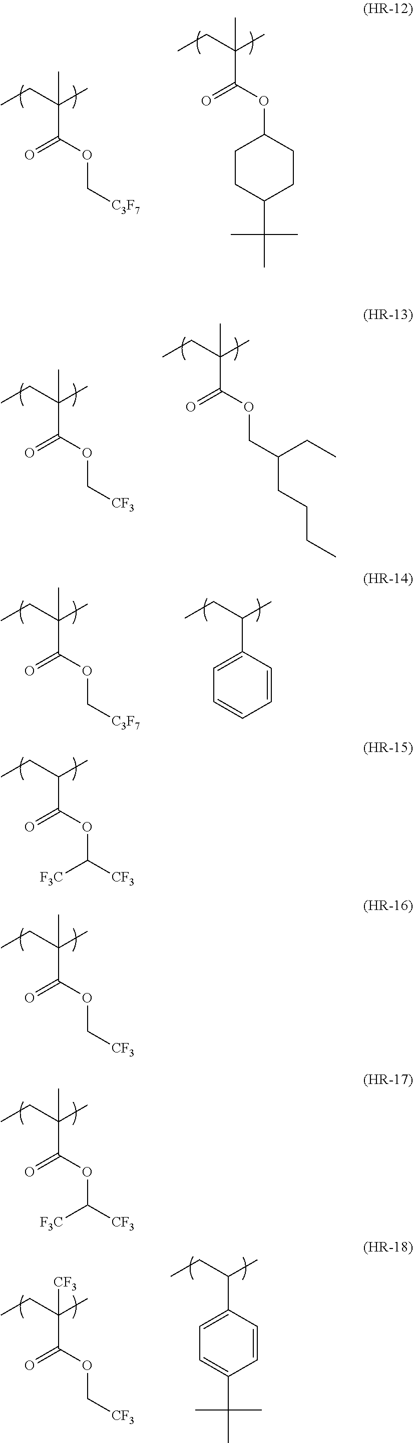

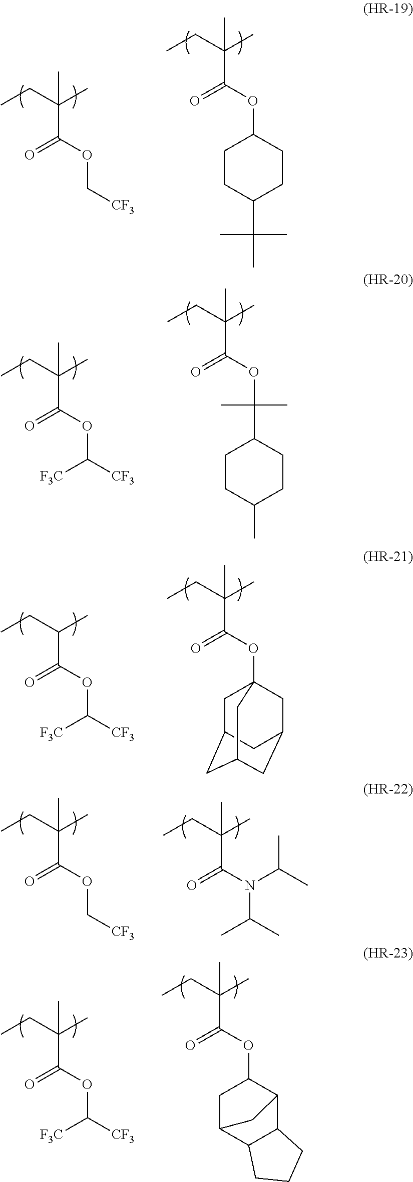

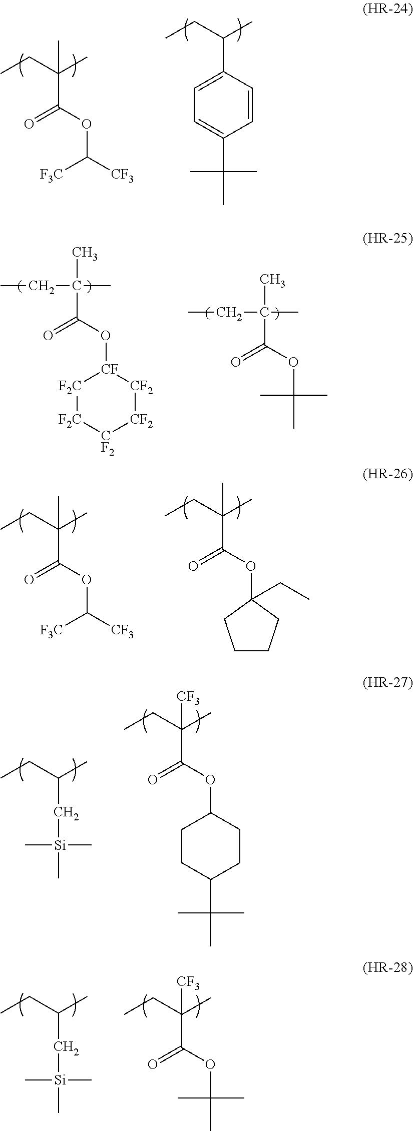

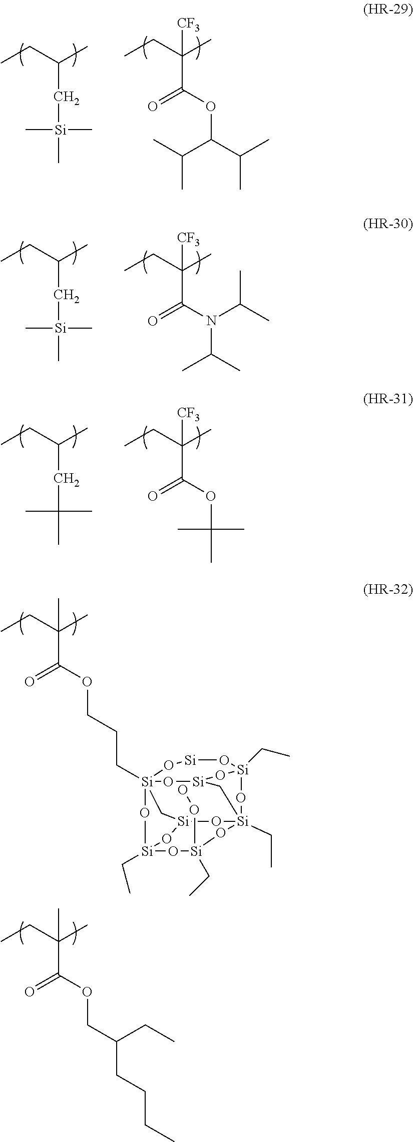

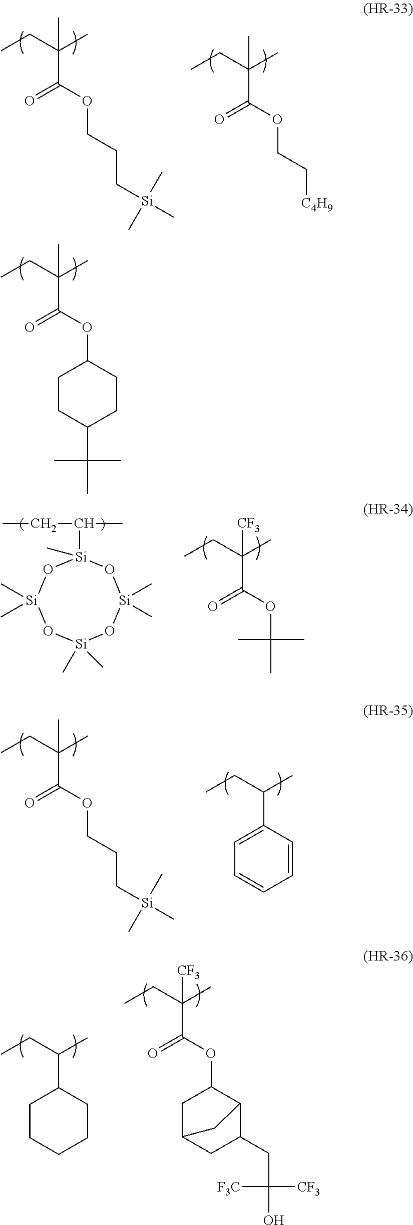

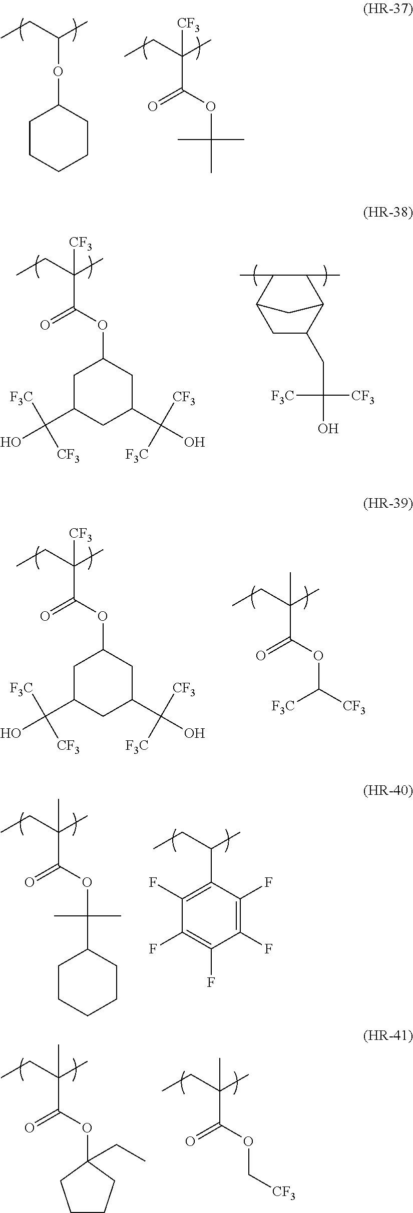

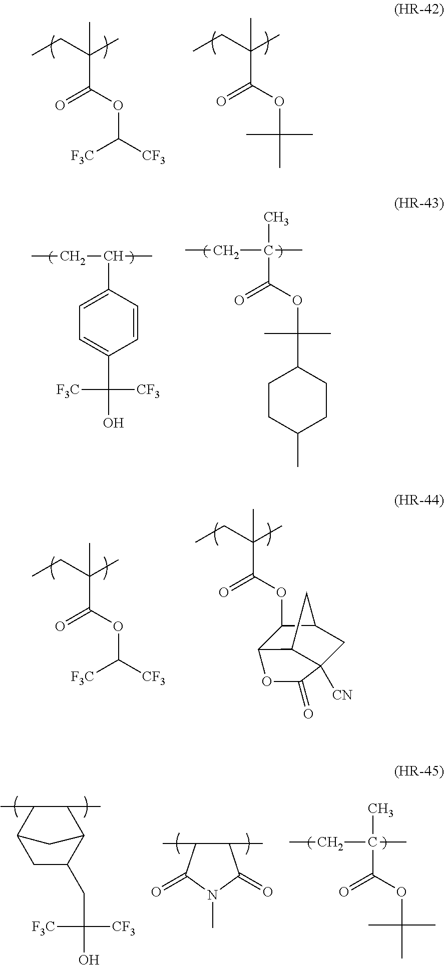

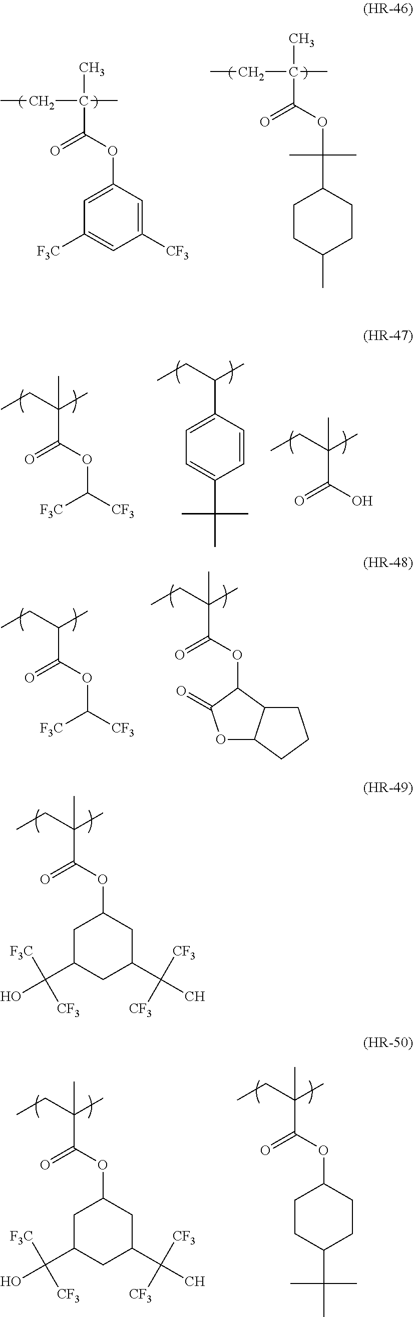

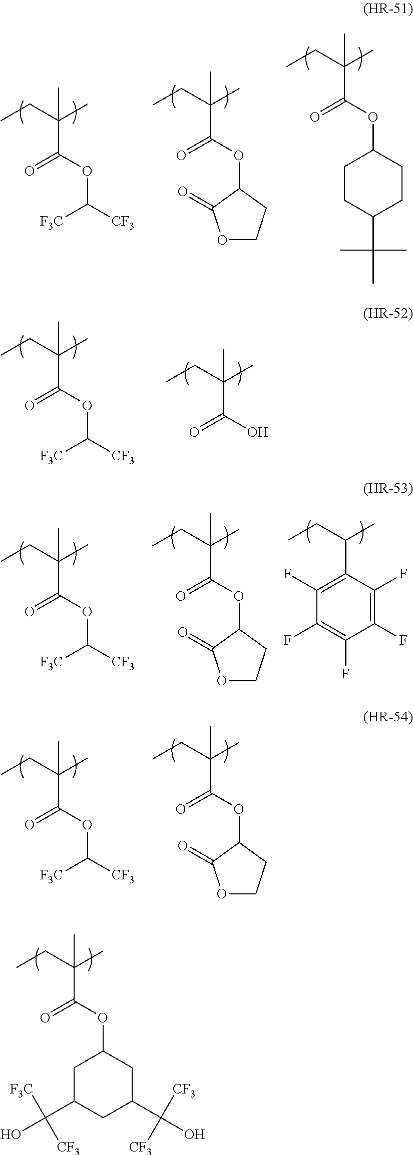

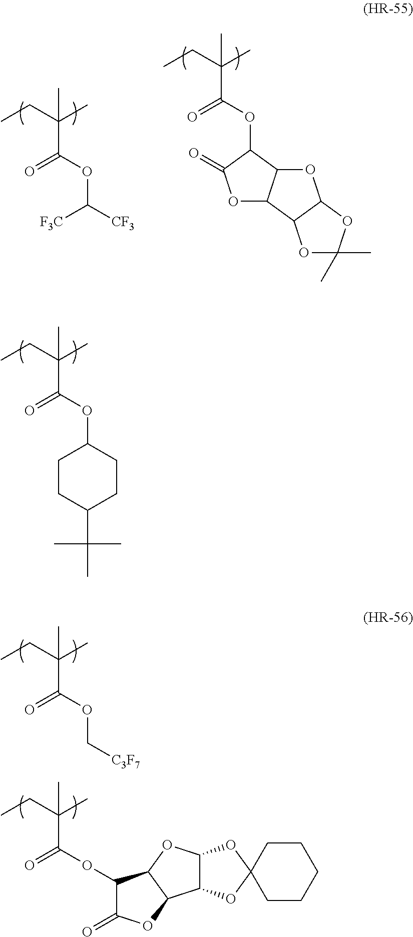

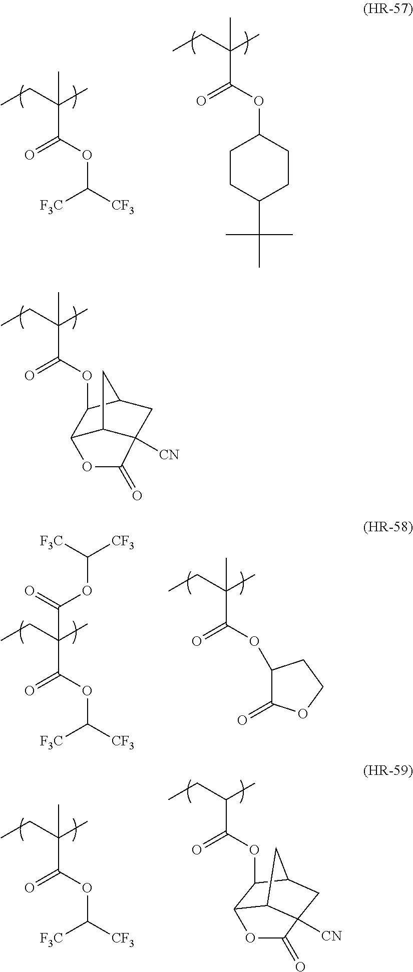

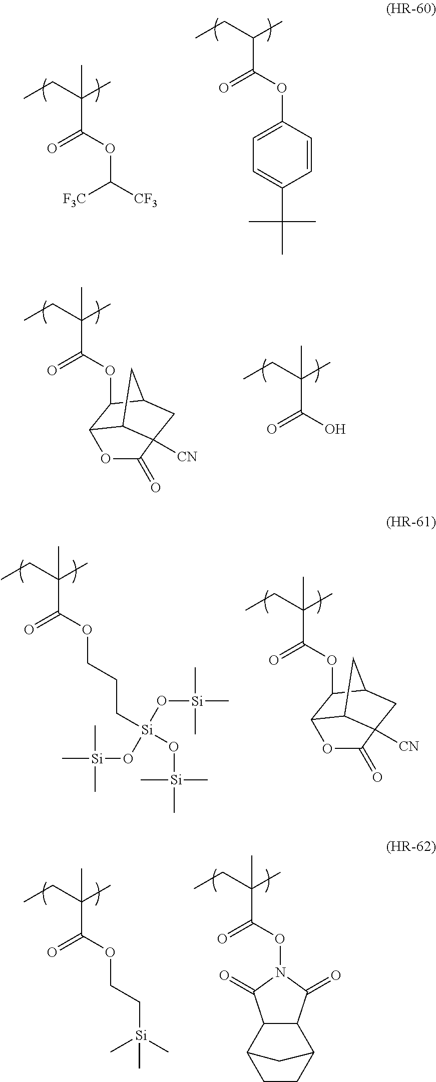

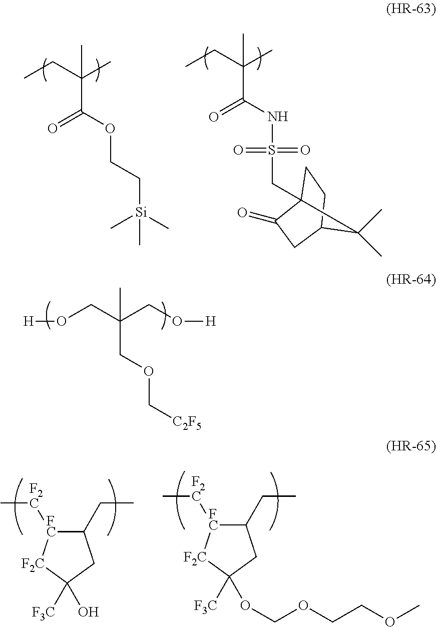

TABLE 1

| Resin | Composition | Mw | Mw/Mn |
|---|---|---|---|
| HR-1 | 50/50 | 4900 | 1.4 |
| HR-2 | 50/50 | 5100 | 1.6 |
| HR-3 | 50/50 | 4800 | 1.5 |
| HR-4 | 50/50 | 5300 | 1.6 |
| HR-5 | 50/50 | 4500 | 1.4 |
| HR-6 | 100 | 5500 | 1.6 |
| HR-7 | 50/50 | 5800 | 1.9 |
| HR-8 | 50/50 | 4200 | 1.3 |
| HR-9 | 50/50 | 5500 | 1.8 |
| HR-10 | 40/60 | 7500 | 1.6 |
| HR-11 | 70/30 | 6600 | 1.8 |
| HR-12 | 40/60 | 3900 | 1.3 |
| HR-13 | 50/50 | 9500 | 1.8 |
| HR-14 | 50/50 | 5300 | 1.6 |
| HR-15 | 100 | 6200 | 1.2 |
| HR-16 | 100 | 5600 | 1.6 |
| HR-17 | 100 | 4400 | 1.3 |
| HR-18 | 50/50 | 4300 | 1.3 |
| HR-19 | 50/50 | 6500 | 1.6 |
| HR-20 | 30/70 | 6500 | 1.5 |
| HR-21 | 50/50 | 6000 | 1.6 |
| HR-22 | 50/50 | 3000 | 1.2 |
| HR-23 | 50/50 | 5000 | 1.5 |
| HR-24 | 50/50 | 4500 | 1.4 |
| HR-25 | 30/70 | 5000 | 1.4 |
| HR-26 | 50/50 | 5500 | 1.6 |
| HR-27 | 50/50 | 3500 | 1.3 |
| HR-28 | 50/50 | 6200 | 1.4 |
| HR-29 | 50/50 | 6500 | 1.6 |
| HR-30 | 50/50 | 6500 | 1.6 |
| HR-31 | 50/50 | 4500 | 1.4 |
| HR-32 | 30/70 | 5000 | 1.6 |
| HR-33 | 30/30/40 | 6500 | 1.8 |
| HR-34 | 50/50 | 4000 | 1.3 |
| HR-35 | 50/50 | 6500 | 1.7 |
| HR-36 | 50/50 | 6000 | 1.5 |
| HR-37 | 50/50 | 5000 | 1.6 |
| HR-38 | 50/50 | 4000 | 1.4 |
| HR-39 | 20/80 | 6000 | 1.4 |
| HR-40 | 50/50 | 7000 | 1.4 |
| HR-41 | 50/50 | 6500 | 1.6 |
| HR-42 | 50/50 | 5200 | 1.6 |
| HR-43 | 50/50 | 6000 | 1.4 |
| HR-44 | 70/30 | 5500 | 1.6 |
| HR-45 | 50/20/30 | 4200 | 1.4 |
| HR-46 | 30/70 | 7500 | 1.6 |
| HR-47 | 40/58/2 | 4300 | 1.4 |
| HR-48 | 50/50 | 6800 | 1.6 |
| HR-49 | 100 | 6500 | 1.5 |
| HR-50 | 50/50 | 6600 | 1.6 |
| HR-51 | 30/20/50 | 6800 | 1.7 |
| HR-52 | 95/5 | 5900 | 1.6 |
| HR-53 | 40/30/30 | 4500 | 1.3 |
| HR-54 | 50/30/20 | 6500 | 1.8 |
| HR-55 | 30/40/30 | 7000 | 1.5 |
| HR-56 | 60/40 | 5500 | 1.7 |
| HR-57 | 40/40/20 | 4000 | 1.3 |
| HR-58 | 60/40 | 3800 | 1.4 |
| HR-59 | 80/20 | 7400 | 1.6 |
| HR-60 | 40/40/15/5 | 4800 | 1.5 |
| HR-61 | 60/40 | 5600 | 1.5 |
| HR-62 | 50/50 | 5900 | 2.1 |
| HR-63 | 80/20 | 7000 | 1.7 |
| HR-64 | 100 | 5500 | 1.8 |
| HR-65 | 50/50 | 9500 | 1.9 |

In the case where the hydrophobic resin contains a fluorine atom, the fluorine atom content is preferably from 5 to 80 mass %, more preferably from 10 to 80 mass %, based on the weight average molecular weight of the hydrophobic resin. Also, the content of the fluorine atom-containing repeating unit is preferably from 10 to 100 mol %, more preferably from 30 to 100 mol %, based on all repeating units in the hydrophobic resin.

In the case where the hydrophobic resin contains a silicon atom, the silicon atom content is preferably from 2 to 50 mass %, more preferably from 2 to 30 mass %, based on the weight average molecular weight of the hydrophobic resin. Also, the content of the silicon atom-containing repeating unit is preferably from 10 to 100 mol %, more preferably from 20 to 100 mol %, based on all repeating units in the hydrophobic resin.

The weight average molecular weight of the hydrophobic resin is preferably from 1,000 to 100,000, more preferably from 1,000 to 50,000, still more preferably from 2,000 to 15,000.

The polydispersity of the hydrophobic resin is preferably from 1 to 5, more preferably from 1 to 3, still more preferably from 1 to 2. Within this range, more excellent resolution, pattern profile and roughness property can be achieved.

One kind of a hydrophobic resin may be used alone, or two or more kinds of hydrophobic resins may be used in combination.

The content of the hydrophobic resin is preferably from 0.01 to 10 mass %, more preferably from 0.05 to 8 mass %, still more preferably from 0.1 to 5 mass %, based on the entire solid content of the composition.

As for the hydrophobic resin, a commercially available product may be used or a resin synthesized by a conventional method may be used. Examples of the general synthesis method of this resin include the same methods as described above for the acid-decomposable resin.

In the hydrophobic resin, it is of course preferred that the content of impurities such as metal is small, and in addition, the residual amount of monomers or oligomer components is also preferably from 0 to 10 mass %, more preferably from 0 to 5 mass %, still more preferably from 0 to 1 mass %. When these conditions are satisfied, the amount of extraneous substances in liquid and the change with aging of sensitivity or the like can be reduced.

### [6] Surfactant (F)

The resist composition for use in the present invention may or may not further contain a surfactant and in the case of containing a surfactant, it is preferred to contain any one fluorine-containing and/or silicon-containing surfactant (a fluorine-containing surfactant, a silicon-containing surfactant or a surfactant containing both a fluorine atom and a silicon atom) or two or more kinds thereof.

When the composition for use in the present invention contains the surfactant above, a resist pattern with good sensitivity, resolution and adherence as well as little development defect can be obtained in using an exposure light source of 250 nm or less, particularly 220 nm or less.

Examples of the fluorine-containing and/or silicon-containing surfactant include the surfactants described in paragraph [0276] of U.S. Patent Application Publication 2008/0248425, such as EFtop EF301 and EF303 (produced by Shin-Akita Kasei K.K.); Florad FC430, 431 and 4430 (produced by Sumitomo 3M Inc.); Megaface F171, F173, F176, F189, F113, F110, F177, F120 and R08 (produced by Dainippon Ink & Chemicals, Inc.); Surflon S-382, SC101, 102, 103, 104, 105 and 106 (produced by Asahi Glass Co., Ltd.); Troysol S-366 (produced by Troy Chemical); GF-300 and GF-150 (produced by Toagosei Chemical Industry Co., Ltd.); Surflon S-393 (produced by Seimi Chemical Co., Ltd.); EFtop EF121, EF122A, EF122B, RF122C, EF125M, EF135M, EF351, EF352, EF801, EF802 and EF601 (produced by JEMCO Inc.); PF636, PF656, PF6320 and PF6520 (produced by OMNOVA); and FTX-204G, 208G, 218G, 230G, 204D, 208D, 212D, 218D and 222D (produced by NEOS Co., Ltd.). In addition, polysiloxane polymer KP-341 (produced by Shin-Etsu Chemical Co., Ltd.) may also be used as the silicon-containing surfactant.

Other than those known surfactants, a surfactant using a polymer having a fluoro-aliphatic group derived from a fluoro-aliphatic compound which is produced by a telomerization process (also called a telomer process) or an oligomerization process (also called an oligomer process), may be used. The fluoro-aliphatic compound can be synthesized by the method described in JP-A-2002-90991.

Examples of the above-described type of surfactant include Megaface F178, F-470, F-473, F-475, F-476 and F-472 (produced by Dainippon Ink & Chemicals, Inc.), a copolymer of a —C₆F₁₃ group-containing acrylate (or methacrylate) with a (poly(oxyalkylene)) acrylate (or methacrylate), and a copolymer of a —C₃F₇ group-containing acrylate (or methacrylate) with a (poly(oxyethylene)) acrylate (or methacrylate) and a (poly(oxypropylene)) acrylate (or methacrylate).

In the present invention, a surfactant other than the fluorine-containing and/or silicon-containing surfactant, described in paragraph [0280] of U.S. Patent Application Publication 2008/0248425, may also be used.

One of these surfactants may be used alone, or some of them may be used in combination.

In the case where the resist composition contains a surfactant, the amount of the surfactant used is preferably from 0.0001 to 2 mass %, more preferably from 0.0005 to 1 mass %, based on the entire amount of the resist composition (excluding the solvent).

On the other hand, by setting the amount added of the surfactant to 10 ppm or less based on the entire amount of the resist composition (excluding the solvent), the hydrophobic resin is more unevenly distributed to the surface, so that the resist film surface can be made more hydrophobic and the followability of water at the immersion exposure can be enhanced.

### [7] Basic Compound

The resist composition for use in the present invention may contain a basic compound so as to reduce the change in performance with aging from exposure to heating.

Specific examples of the basic compound include a basic compound having a structure represented by the following formulae (A) to (E):

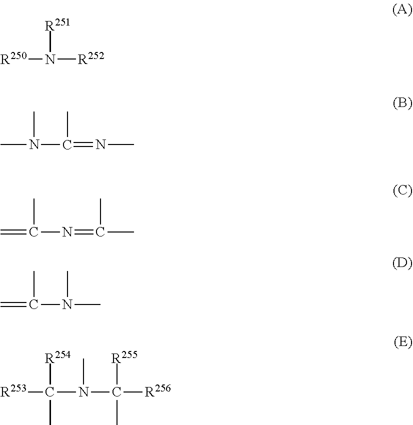

In the formulae, each of R²⁵⁰, R²⁵¹ and R²⁵² independently represents a hydrogen atom, an alkyl group (preferably having a carbon number of 1 to 20), a cycloalkyl group (preferably having a carbon number of 3 to 20) or an aryl group (preferably having a carbon number of 6 to 20), and R²⁵⁰ and R²⁵¹ may combine with each other to form a ring (R²⁵⁰ and R²⁵¹ may combine with each other through a heteroatom such as oxygen atom to form a ring).

These groups may have a substituent, and examples of the substituent include an alkyl group, a cycloalkyl group, an alkoxy group, an aryloxy group, an alkylcarbonyloxy group, an alkoxyalkyl group and an aryloxyalkyl group. The alkyl chain of these groups may contain one or more atoms selected from an oxygen atom, a sulfur atom, a nitrogen atom and the like.

The alkyl having a substituent or the cycloalkyl group having a substituent is preferably an aminoalkyl group having a carbon number of 1 to 20, an aminocycloalkyl group having a carbon number of 3 to 20, a hydroxyalkyl group having a carbon number of 1 to 20, or a hydroxycycloalkyl group having a carbon number of 3 to 20.

These groups may contain an oxygen atom, a sulfur atom or a nitrogen atom in the alkyl chain.

As for the aryl group having a substituent, an aryl group having one or more alkyl groups as the substituent is preferred.

In the formulae, each of R²⁵³, R²⁵⁴, R²⁵⁵ and R²⁵⁶ independently represents an alkyl group (preferably having a carbon number of 1 to 6) or a cycloalkyl group (preferably having a carbon number of 3 to 6).

Preferred examples of the compound include guanidine, aminopyrrolidine, pyrazole, pyrazoline, piperazine, aminomorpholine, aminoalkylmorpholine and piperidine, and these may have a substituent. More preferred examples of the compound include a compound having an imidazole structure, a diazabicyclo structure, an onium hydroxide structure (particularly preferably a tetraalkylammonium hydroxide such as tetrabutylammonium hydroxide), an onium carboxylate structure, a trialkylamine structure, an aniline structure or a pyridine structure; an alkylamine derivative having a hydroxyl group and/or an ether bond; and an aniline derivative having a hydroxyl group and/or an ether bond.

Furthermore, the compound may be at least one kind of a nitrogen-containing compound selected from the group consisting of a phenoxy group-containing amine compound, a phenoxy group-containing ammonium salt compound, a sulfonic acid ester group-containing amine compound and a sulfonic acid ester group-containing ammonium salt compound. Examples of these compounds include, but are not limited to, Compounds (C1-1) to (C3-3) illustrated in paragraph [0066] of U.S. Patent Application Publication 2007/0224539.

In addition, a nitrogen-containing organic compound having a group capable of leaving by the action of an acid, which is a kind of a basic compound, can also be used. Examples of this compound include a compound represented by the following formula (F). Incidentally, the compound represented by the following formula (F) exhibits an effective basicity in the system as a result of elimination of the group capable of leaving by the action of an acid.

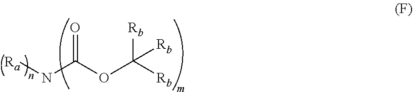

In formula (F), each Ra independently represents a hydrogen atom, an alkyl group, a cycloalkyl group, an aryl group or an aralkyl group. Also, when n=2, two Ra's may be the same or different, and two Ra's may combine with each other to form a divalent heterocyclic hydrocarbon group (preferably having a carbon number of 20 or less) or a derivative thereof.

Each Rb independently represents a hydrogen atom, an alkyl group, a cycloalkyl group, an aryl group or an aralkyl group, provided that in —C(Rb)(Rb)(Rb), when one or more Rb's are a hydrogen atom, at least one of remaining Rb's is a cyclopropyl group or a 1-alkoxyalkyl group.

At least two Rb's may combine to form an alicyclic hydrocarbon group, an aromatic hydrocarbon group, a heterocyclic hydrocarbon group or a derivative thereof.

n represents an integer of 0 to 2, m represents an integer of 1 to 3, and n+m=3.

In formula (F), each of the alkyl group, cycloalkyl group, aryl group and aralkyl group represented by Ra and Rb may be substitute with a functional group such as hydroxyl group, cyano group, amino group, pyrrolidino group, piperidino group, morpholino group and oxo group, an alkoxy group or a halogen atom.

Examples of the alkyl group, cycloalkyl group, aryl group and aralkyl group (each of these alkyl, cycloalkyl, aryl and aralkyl groups may be substituted with the above-described functional group, an alkoxy group or a halogen atom) of R include:

a group derived from a linear or branched alkane such as methane, ethane, propane, butane, pentane, hexane, heptane, octane, nonane, decane, undecane and dodecane, or a group where the group derived from an alkane is substituted with one or more kinds of or one or more in number of cycloalkyl groups such as cyclobutyl group, cyclopentyl group and cyclohexyl group;

a group derived from a cycloalkane such as cyclobutane, cyclopentane, cyclohexane, cycloheptane, cyclooctane, norbornane, adamantane and noradamantane, or a group where the group derived from a cycloalkane is substituted with one or more kinds of or one or more in number of linear or branched alkyl groups such as methyl group, ethyl group, n-propyl group, i-propyl group, n-butyl group, 2-methylpropyl group, 1-methylpropyl group and tert-butyl group;

a group derived from an aromatic compound such as benzene, naphthalene and anthracene, or a group where the group derived from an aromatic compound is substituted with one or more kinds of or one or more in number of linear or branched alkyl groups such as methyl group, ethyl group, n-propyl group, i-propyl group, n-butyl group, 2-methylpropyl group, 1-methylpropyl group and tert-butyl group;

a group derived from a heterocyclic compound such as pyrrolidine, piperidine, morpholine, tetrahydropyran, tetrahydropyran, indole, indoline, quinoline, perhydroquinoline, indazole and benzimidazole, or a group where the group derived from a heterocyclic compound is substituted with one or more kinds of or one or more in number of linear or branched alkyl groups and aromatic compound-derived groups; a group where the group derived from a linear or branched alkane or the group derived from a cycloalkane is substituted with one or more kinds of or one or more in number of aromatic compound-derived groups such as phenyl group, naphthyl group and anthracenyl group; and a group where the substituent above is substituted with a functional group such as hydroxyl group, cyano group, amino group, pyrrolidino group, piperidino group, morpholino group and oxo group.

Examples of the divalent heterocyclic hydrocarbon group (preferably having a carbon number of 1 to 20) formed by combining Ra's with each other or a derivative thereof include a group derived from a heterocyclic compound such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1S,4S)-(+)-2,5-diazabicyclo [2.2.1]heptane, 1,5,7-triazabicyclo [4.4.0] dec-5-ene, indole, indoline, 1,2,3,4-tetrahydroquinoxaline, perhydroquinoline and 1,5,9-triazacyclododecane, and a group where the group derived from a heterocyclic compound is substituted with one or more kinds of or one or more in number of linear or branched alkane-derived groups, cycloalkane-derived groups, aromatic compound-derived groups, heterocyclic compound-derived groups and functional groups such as hydroxyl group, cyano group, amino group, pyrrolidino group, piperidino group, morpholino group and oxo group.

Specific examples particularly preferred in the present invention include N-tert-butoxycarbonyldi-n-octylamine, N-tert-butoxycarbonyldi-n-nonylamine, N-tert-butoxycarbonyldi-n-decyl amine, N-tert-butoxycarbonyldicyclohexylamine, N-tert-butoxycarbonyl-1-adamantylamine, N-tert-butoxycarbonyl-2-adamantylamine, N-tert-butoxycarbonyl-N-methyl-1-adamantylamine, (S)-(−)-1-(tert-butoxycarbonyl)-2-pyrrolidinemethanol, (R)-(+)-1-(tert-butoxycarbonyl)-2-pyrrolidinemethanol, N-tert-butoxycarbonyl-4-hydroxypiperidine, N-tert-butoxycarbonylpyrrolidine, N-tert-butoxycarbonylmorpholine, N-tert-butoxycarbonylpiperazin, N,N-di-tert-butoxycarbonyl-1-adamantylamine, N,N-di-tert-butoxycarbonyl-N-methyl-1-adamantylamine, N-tert-butoxycarbonyl-4,4′-diaminodiphenylmethane, N,N′-di-tert-butoxycarbonylhexamethylenediamine, N,N,N′,N′-tetra-tert-butoxycarbonylhexamethylenediamine, N,N′-di-tert-butoxycarbonyl-1,7-diaminoheptane, N,N-di-tert-butoxycarbonyl-1,8-diaminooctane, N,N′-di-tert-butoxycarbonyl-1,9-diaminononane, N,N′-di-tert-butoxycarbonyl-1,10-diaminodecane, N,N-di-tert-butoxycarbonyl-1,12-diaminododecane, N,N-di-tert-butoxycarbonyl-4,4′-diaminodiphenylmethane, N-tert-butoxycarbonylbenzimidazole, N-tert-butoxycarbonyl-2-methylbenzimidazole and N-tert-butoxycarbonyl-2-phenylbenzimidazole.

As for the compound represented by formula (F), a commercial product may be used, or the compound may be synthesized from a commercially available amine by the method described, for example, in Protective Groups in Organic Synthesis, 4th edition. A most general method is a method of causing a dicarbonic acid ester or a haloformic acid ester to act on a commercially available amine to obtain the compound. In the formulae, X represents a halogen atom, and Ra and Rb have the same meanings as in formula (F).

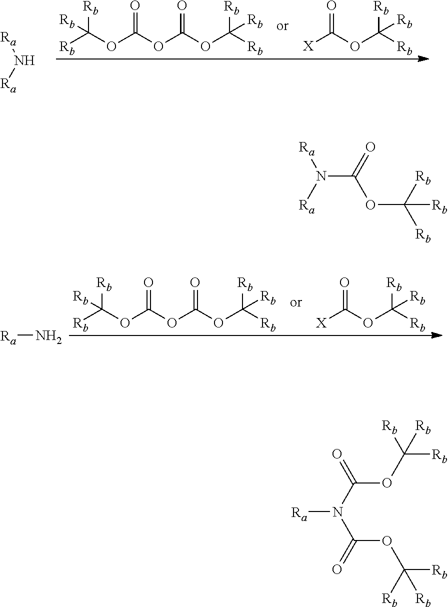

The molecular weight of the basic compound is preferably from 250 to 2,000, more preferably from 400 to 1,000.

One of these basic compounds is used alone, or two or more thereof are used.

In the case of containing a basic compound, the content thereof is preferably from 0.05 to 8.0 mass %, more preferably from 0.05 to 5.0 mass %, still more preferably from 0.05 to 4.0 mass %, based on the entire solid content of the resist composition.

[8] Basic Compound or Ammonium Salt Compound Whose Basicity Decreases Upon Irradiation with Actinic Ray or Radiation

The resist composition for use in the present invention may contain a basic compound or ammonium salt compound whose basicity decreases upon irradiation with an actinic ray or radiation (hereinafter sometimes referred to as a “compound (PA)”).

The compound (PA) is preferably (PA′) a compound having a basic functional group or an ammonium group and a group capable of generating an acidic functional group upon irradiation with an actinic ray or radiation. That is, the compound (PA) is preferably a basic compound having a basic functional group and a group capable of generating an acidic functional group upon irradiation with an actinic ray or radiation, or an ammonium salt compound having an ammonium group and a group capable of generating an acidic functional group upon irradiation with an actinic ray or radiation.

The compound which is generated due to decomposition of the compound (PA) or (PA′) upon irradiation with an actinic ray or radiation and whose basicity is decreased includes compounds represented by the following formulae (PA-I), (PA-II) and (PA-III), and from the standpoint that excellent effects can be attained in a high level in terms of both LWR and DOF, compounds represented by formulae (PA-II) and (PA-III) are preferred.

The compound represented by formula (PA-I) is described below.

Q-A₁-(X)ₙ—B—R (PA-I)

In formula (PA-I), A₁ represents a single bond or a divalent linking group.

Q represents —SO₃H or —CO₂H. Q corresponds to an acidic functional group which is generated upon irradiation with an actinic ray or radiation.

X represents —SO₂— or —CO—.

n represents 0 or 1.

B represents a single bond, an oxygen atom or —N(Rx)—.

Rx represents a hydrogen atom or a monovalent organic group.

R represents a monovalent organic group having a basic functional group, or a monovalent organic group having an ammonium group.

The divalent linking group of A₁ is preferably a divalent linking group having a carbon number of 2 to 12, and examples thereof include an alkylene group and a phenylene group. An alkylene group having at least one fluorine atom is more preferred, and the carbon number thereof is preferably from 2 to 6, more preferably from 2 to 4. The alkylene chain may contain a linking group such as oxygen atom and sulfur atom. The alkylene group is preferably an alkylene group where from 30 to 100% by number of the hydrogen atom is replaced by a fluorine atom, more preferably an alkylene group where the carbon atom bonded to the Q site has a fluorine atom, still more preferably a perfluoroalkylene group, yet still more preferably a perfluoroethylene group, a perfluoropropylene group or a perfluorobutylene group.

The monovalent organic group in Rx is preferably a monovalent organic group having a carbon number of 4 to 30, and examples thereof include an alkyl group, a cycloalkyl group, an aryl group, an aralkyl group and an alkenyl group.

The alkyl group in Rx may have a substituent and is preferably a linear or branched alkyl group having a carbon number of 1 to 20, and the alkyl chain may contain an oxygen atom, a sulfur atom or a nitrogen atom.

Here, the alkyl group having a substituent includes particularly a group where a cycloalkyl group is substituted on a linear or branched alkyl group (for example, an adamantylmethyl group, an adamantylmethyl group, a cyclohexylethyl group and a camphor residue structure).

The cycloalkyl group in Rx may have a substituent and is preferably a cycloalkyl group having a carbon number of 3 to 20, and the cycloalkyl group may contain an oxygen atom in the ring.

The aryl group in Rx may have a substituent and is preferably an aryl group having a carbon number of 6 to 14.

The aralkyl group in Rx may have a substituent and is preferably an aralkyl group having a carbon number of 7 to 20.

The alkenyl group in Rx may have a substituent and includes, for example, a group having a double bond at an arbitrary position of the alkyl group described as Rx.

Preferred examples of the partial structure of the basic functional group include a crown ether structure, a primary to tertiary amine structure, and a nitrogen-containing heterocyclic structure (e.g., pyridine, imidazole, pyrazine).

Preferred examples of the partial structure of the ammonium group include a primary to tertiary ammonium structure, a pyridinium structure, an imidazolinium structure and a pyrazinium structure.

The basic functional group is preferably a functional group having a nitrogen atom, more preferably a structure having a primary to tertiary amino group or a nitrogen-containing heterocyclic structure. From the standpoint of enhancing the basicity, it is preferred that all atoms adjacent to nitrogen atom contained in the structure are a carbon atom or a hydrogen atom. Also, in view of enhancing the basicity, an electron-withdrawing functional group (e.g., carbonyl group, sulfonyl group, cyano group, halogen atom) is preferably not bonded directly to nitrogen atom.

The monovalent organic group in the monovalent organic group (group R) containing such a structure is preferably an organic group having a carbon number of 4 to 30, and examples thereof include an alkyl group, a cycloalkyl group, an aryl group, an aralkyl group and an alkenyl group. These groups each may have a substituent.

The alkyl group, cycloalkyl group, aryl group, aralkyl group and alkenyl group in the basic functional group- or ammonium group-containing alkyl, cycloalkyl, aryl, aralkyl and alkenyl groups of R have the same meanings as the alkyl group, cycloalkyl group, aryl group, aralkyl group and alkenyl group described for Rx.

Examples of the substituent which each of the groups above may have include a halogen atom, a hydroxyl group, a nitro group, a cyano group, a carboxy group, a carbonyl group, a cycloalkyl group (preferably having a carbon number of 3 to 10), an aryl group (preferably having a carbon number of 6 to 14), an alkoxy group (preferably having a carbon number of 1 to 10), an acyl group (preferably having a carbon number of 2 to 20), an acyloxy group (preferably having a carbon number of 2 to 10), an alkoxycarbonyl group (preferably having a carbon number of 2 to 20), and an aminoacyl group (preferably having a carbon number of 2 to 20). As for the cyclic structure in the aryl group, cycloalkyl group and the like, examples of the substituent further include an alkyl group (preferably having a carbon number of 1 to 20). As for the aminoacyl group, examples of the substituent further include one or two alkyl groups (preferably having a carbon number of 1 to 20, more preferably a carbon number of 1 to 10). Examples of the alkyl group having a substituent include a perfluoroalkyl group such as perfluoromethyl group, perfluoroethyl group, perfluoropropyl group and perfluorobutyl group.

In the case where B is —N(Rx)—, R and Rx preferably combine together to form a ring. By virtue of forming a ring structure, the stability is enhanced and the composition using this compound is also enhanced in the storage stability. The number of carbons forming the ring is preferably from 4 to 20, and the ring may be monocyclic or polycyclic and may contain an oxygen atom, a sulfur atom or a nitrogen atom.

Examples of the monocyclic structure include a 4- to 8-membered ring containing a nitrogen atom. Examples of the polycyclic structure include a structure composed of a combination of two monocyclic structures or three or more monocyclic structures. The monocyclic structure and polycyclic structure may have a substituent, and preferred examples of the substituent include a halogen atom, a hydroxyl group, a cyano group, a carboxy group, a carbonyl group, a cycloalkyl group (preferably having a carbon number of 3 to 10), an aryl group (preferably having a carbon number of 6 to 14), an alkoxy group (preferably having a carbon number of 1 to 10), an acyl group (preferably having a carbon number of 2 to 15), an acyloxy group (preferably having a carbon number of 2 to 15), an alkoxycarbonyl group (preferably having a carbon number of 2 to 15), and an aminoacyl group (preferably having a carbon number of 2 to 20). As for the cyclic structure in the aryl group, cycloalkyl group and the like, examples of the substituent further include an alkyl group (preferably having a carbon number of 1 to 15). As for the aminoacyl group, the substituent includes one or two alkyl groups (preferably having a carbon number of 1 to 15).

Out of the compounds represented by formula (PA-I), a compound where the Q site is a sulfonic acid can be synthesized using a general sulfonamidation reaction. For example, this compound can be obtained by a method of selectively reacting one sulfonyl halide moiety of a bis-sulfonyl halide compound with an amine compound to form a sulfonamide bond and then hydrolyzing the other sulfonyl halide moiety, or a method of ring-opening a cyclic sulfonic anhydride through a reaction with an amine compound.

The compound represented by formula (PA-II) is described below.

Q₁-X₁—NH—X₂—Q₂ (PA-II)

In formula (PA-II), each of Q₁ and Q₂ independently represents a monovalent organic group, provided that either one of Q₁ and Q₂ has a basic functional group. It is also possible that Q₁ and Q₂ combine together to form a ring and the ring formed has a basic functional group.

Each of X₁ and X₂ independently represents —CO— or —SO₂—.

Here, —NH— corresponds to an acidic functional group generated upon irradiation with an actinic ray or radiation.

The monovalent organic group as Q₁ and Q₂ in formula (PA-II) is preferably a monovalent organic group having a carbon number of 1 to 40, and examples thereof include an alkyl group, a cycloalkyl group, an aryl group, an aralkyl group, and an alkenyl group.

The alkyl group in Q₁ and Q₂ may have a substituent and is preferably a linear or branched alkyl group having a carbon number of 1 to 30, and the alkyl chain may contain an oxygen atom, a sulfur atom or a nitrogen atom.

The cycloalkyl group in Q₁ and Q₂ may have a substituent and is preferably a cycloalkyl group having a carbon number of 3 to 20, and the ring may contain an oxygen atom or a nitrogen atom.

The aryl group in Q₁ and Q₂ may have a substituent and is preferably an aryl group having a carbon number of 6 to 14.

The aralkyl group in Q₁ and Q₂ may have a substituent and is preferably an aralkyl group having a carbon number of 7 to 20.

The alkenyl group in Q₁ and Q₂ may have a substituent and includes a group having a double bond at an arbitrary position of the alkyl group above.

Examples of the substituent which each of these groups may have include the same groups as those exemplified as the substituent which each of the groups in formula (PA-1) may have.

Preferred partial structures of the basic functional group which at least either Q₁ or Q₂ has are the same as those of the basic functional group in R of formula (PA-I).

In the case where Q₁ and Q₂ combine together to form a ring and the ring formed has a basic functional group, examples of the structure thereof include a structure where the organic group of Q₁ or Q₂ is further bonded with an alkylene group, an oxy group, an imino group or the like.

In formula (PA-II), at least either one of X₁ and X₂ is preferably —SO₂—.

The compound represented by formula (PA-III) is described below.

Q₁-X₁—NH—X₂-A₂-(X₃)ₘ—B-Q₃ (PA-III)

In formula (PA-III), each of Q₁ and Q independently represents a monovalent organic group, provided that either one of Q₁ and Q₃ has a basic functional group. It is also possible that Q₁ and Q₃ combine together to form a ring and the ring formed has a basic functional group.

Each of X₁, X₂ and X₃ independently represents —CO— or —SO₂—.

A₂ represents a divalent linking group.

B represents a single bond, an oxygen atom or —N(Qx)-.

Qx represents a hydrogen atom or a monovalent organic group.

In the case where B is —N(Qx)-, Q₃ and Qx may combine together to form a ring.

m represents 0 or 1.

Here, —NH— corresponds to an acidic functional group generated upon irradiation with an actinic ray or radiation.

Q₁ has the same meaning as Q₁ in formula (PA-II).

Examples of the organic group of Q are the same as those of the organic group of Q₁ and Q₂ in formula (PA-II).

The divalent linking group in A₂ is preferably a divalent linking group having a carbon number of 1 to 8 and containing a fluorine atom, and examples thereof include a fluorine atom-containing alkylene group having a carbon number of 1 to 8, and a fluorine atom-containing phenylene group. A fluorine atom-containing alkylene group is more preferred, and the carbon number thereof is preferably from 2 to 6, more preferably from 2 to 4. The alkylene chain may contain a linking group such as oxygen atom and sulfur atom. The alkylene group is preferably an alkylene group where from 30 to 100% by number of the hydrogen atom is substituted for by a fluorine atom, more preferably a perfluoroalkylene group, still more preferably a perfluoroalkylene group having a carbon number of 2 to 4.

The monovalent organic group in Qx is preferably an organic group having a carbon number of 4 to 30, and examples thereof include an alkyl group, a cycloalkyl group, an aryl group, an aralkyl group and an alkenyl group. Examples of the alkyl group, cycloalkyl group, aryl group, aralkyl group and alkenyl group are the same as those for Rx in formula (PA-I).

In formula (PA-III), each of X₁, X₂ and X₃ is preferably —SO₂—.

The compound (PA) is preferably a sulfonium salt compound of the compound represented by formula (PA-I), (PA-II) or (PA-III), or an iodonium salt compound of the compound represented by formula (PA-I), (PA-II) or (PA-III), more preferably a compound represented by the following formula (PA1) or (PA2):

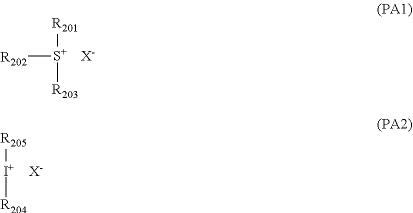

In formula (PA1), each of R₂₀₁, R₂₀₂ and R₂₀₃ independently represents an organic group, and specific examples thereof are the same as those for R₂₀₁, R₂₀₂ and R₂₀₃ of formula ZI in the acid generator above.

X⁻ represents a sulfonate or carboxylate anion resulting from elimination of a hydrogen atom in the —SO₃H moiety or —COOH moiety of the compound represented by formula (PA-I), or an anion resulting from elimination of a hydrogen atom in the —NH-moiety of the compound represented by formula (PA-II) or (PA-III).

In formula (PA2), each of R₂₀₄ and R₂₀₅ independently represents an aryl group, an alkyl group or a cycloalkyl group. Specific examples thereof are the same as those for R₂₀₄ and R₂₀₅ of formula ZII in the acid generator above.

X⁻ represents a sulfonate or carboxylate anion resulting from elimination of a hydrogen atom in the —SO₃H moiety or —COOH moiety of the compound represented by formula (PA-I), or an anion resulting from elimination of a hydrogen atom in the —NH-moiety of the compound represented by formula (PA-II) or (PA-III).

The compound (PA) decomposes upon irradiation with an actinic ray or radiation and generates, for example, a compound represented by formula (PA-I), (PA-II) or (PA-III).

The compound represented by formula (PA-I) is a compound having a sulfonic or carboxylic acid group together with a basic functional group or an ammonium group and thereby being reduced in or deprived of the basicity or changed from basic to acidic as compared with the compound (PA).

The compound represented by formula (PA-II) or (PA-III) is a compound having an organic sulfonylimino or organic carbonylimino group together with a basic functional group and thereby being reduced in or deprived of the basicity or changed from basic to acidic as compared with the compound (PA).

In the present invention, the expression “reduced in the basicity upon irradiation with an actinic ray or radiation” means that the acceptor property for a proton (an acid generated upon irradiation with an actinic ray or radiation) of the compound (PA) is decreased by the irradiation with an actinic ray or radiation. The expression “reduced in the acceptor property” means that when an equilibrium reaction of producing a noncovalent bond complex as a proton adduct from a basic functional group-containing compound and a proton takes place or when an equilibrium reaction of causing the counter cation of the ammonium group-containing compound to be exchanged with a proton takes place, the equilibrium constant in the chemical equilibrium decreases.

A compound (PA) whose basicity decreases in this way upon irradiation with an actinic ray or radiation is contained in the resist film, so that in the unexposed area, the acceptor property of the compound (PA) can be sufficiently brought out and an unintended reaction between an acid diffused from the exposed area or the like and the resin (A) can be inhibited, whereas in the exposed area, the acceptor property of the compound (PA) can be decreased and the intended reaction of an acid with the resin (A) can more unfailingly occur. Such an operation mechanism is considered to contribute to obtaining a pattern excellent in terms of line width variation (LWR), focus latitude (DOF) and pattern profile.

Incidentally, the basicity can be confirmed by measuring the pH, or a calculated value can be computed using a commercially available software.

Specific examples of the compound (PA) whose basicity decreases upon irradiation with an actinic ray or radiation include those described in JP-A-2006-208781 and JP-A-2006-330098.

Specific examples of the compound (PA) capable of generating a compound represented by formula (PA-I) upon irradiation with an actinic ray or radiation are illustrated below, but the present invention is not limited thereto.

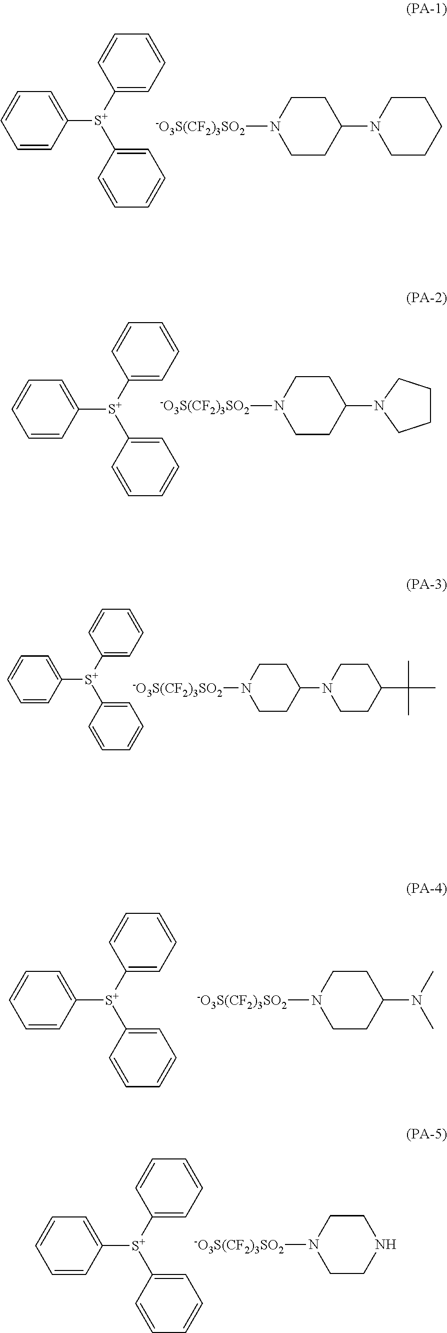

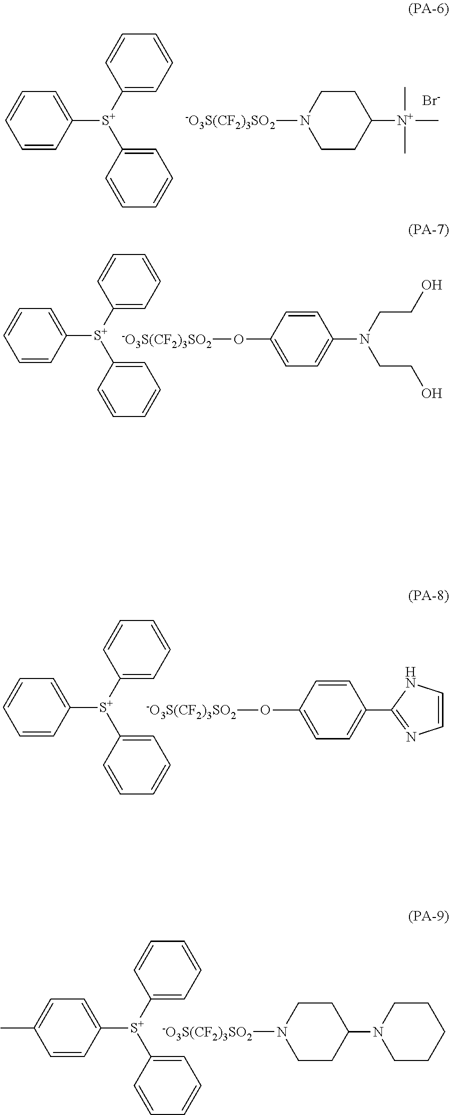

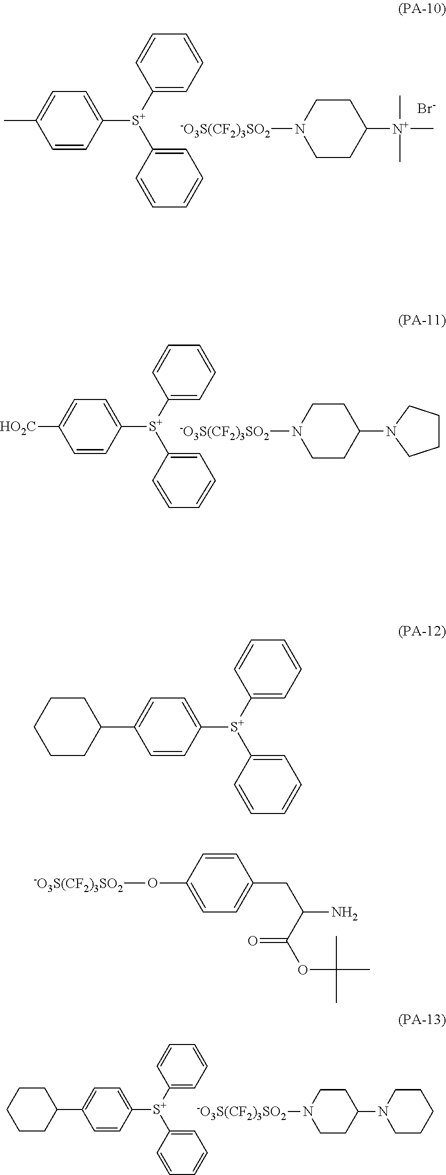

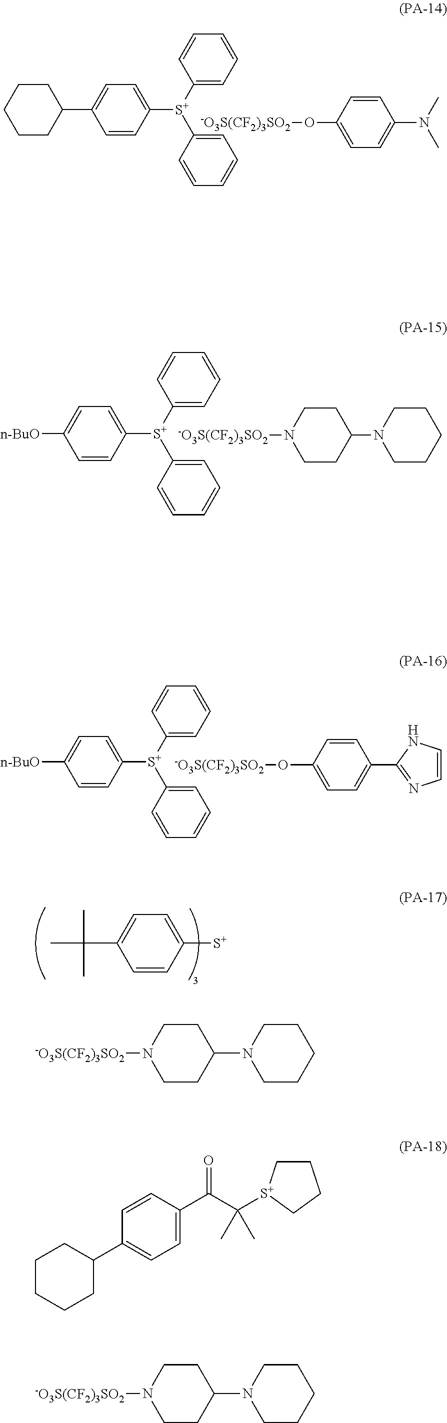

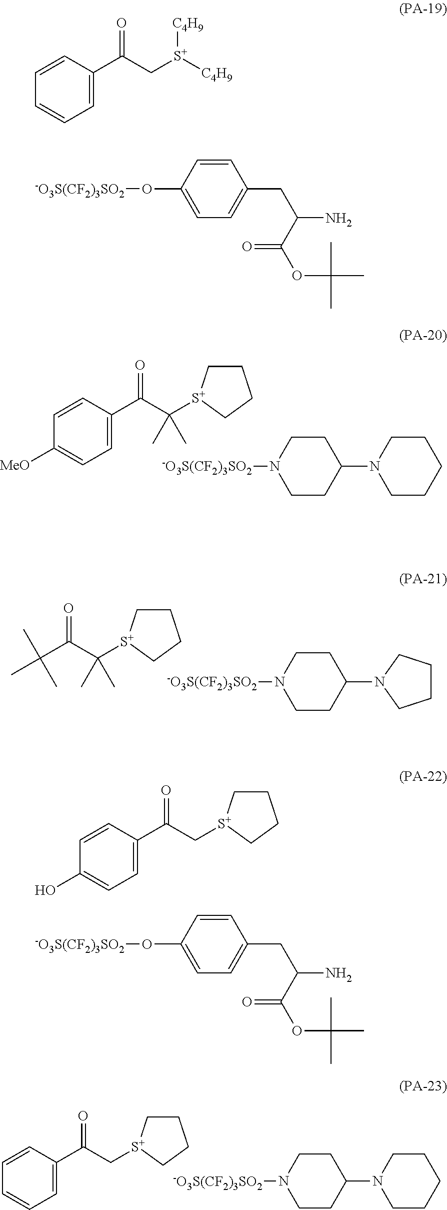

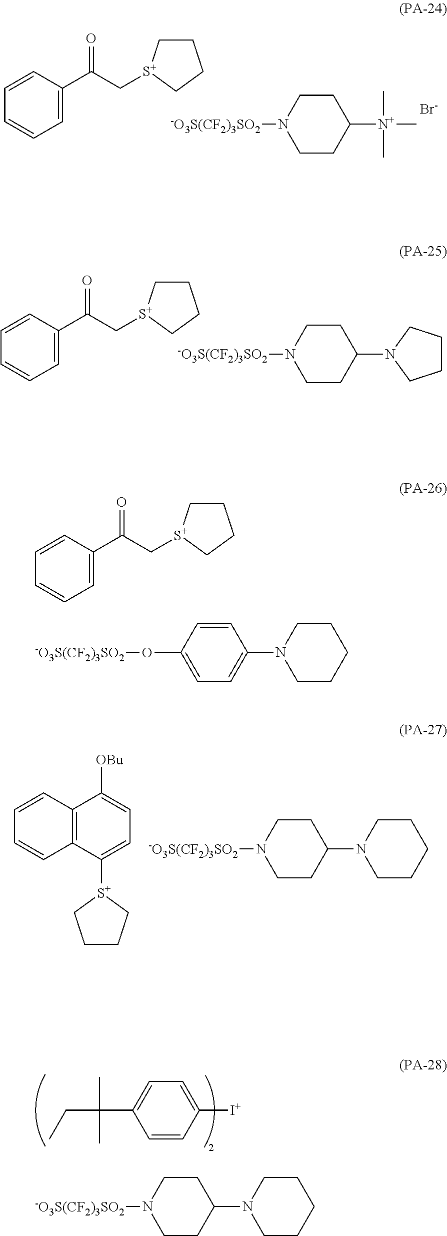

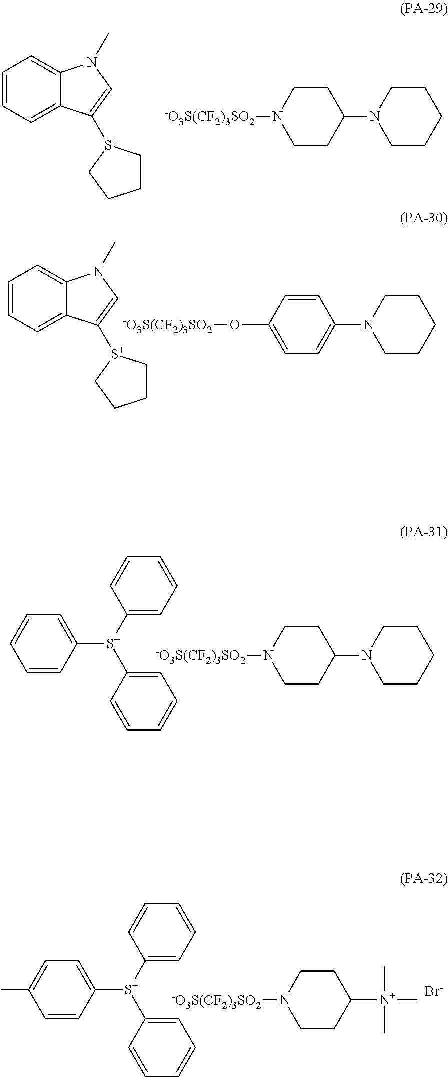

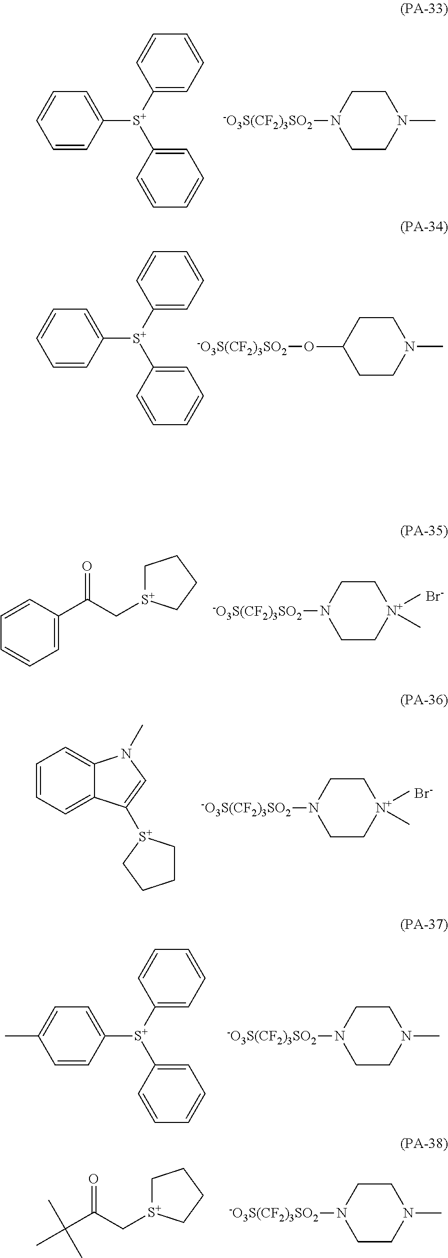

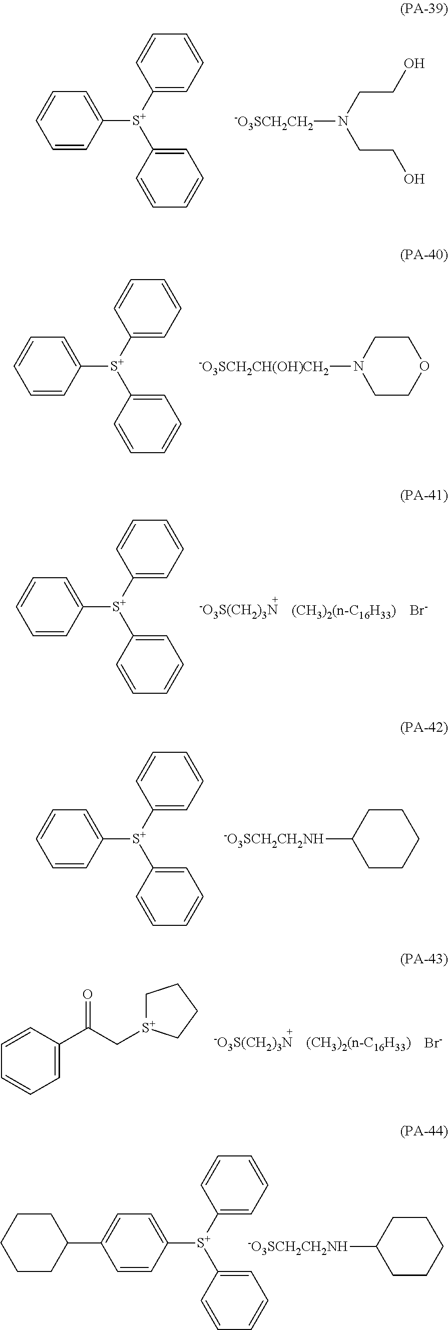

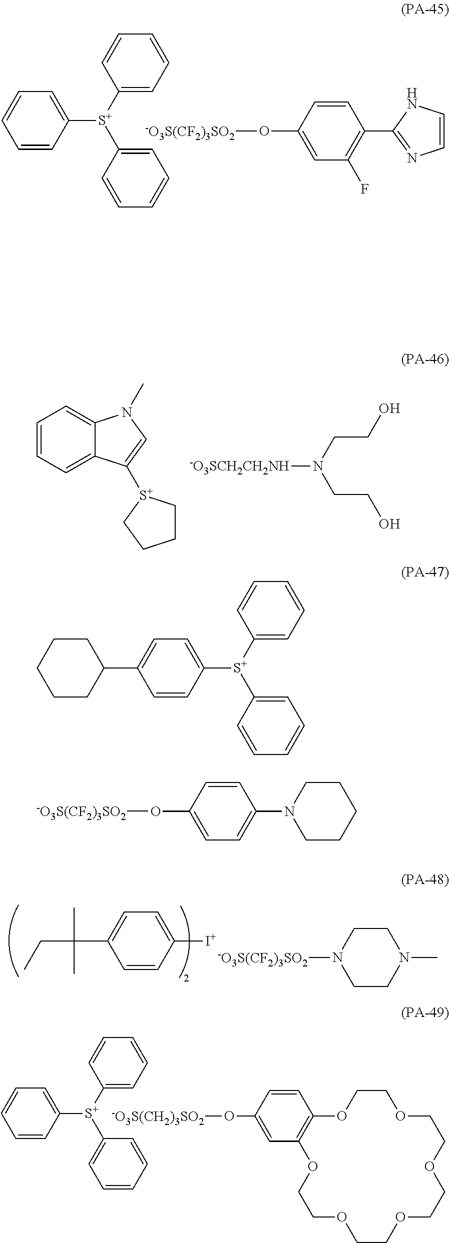

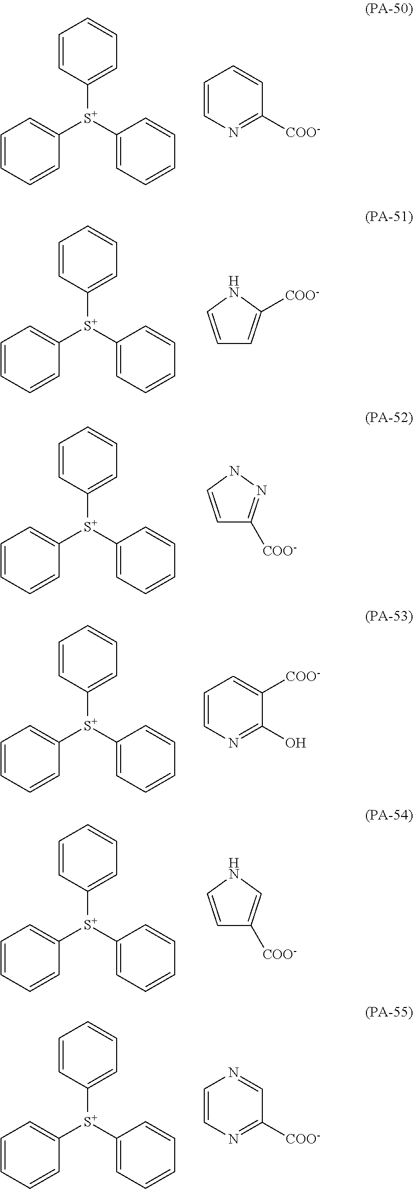

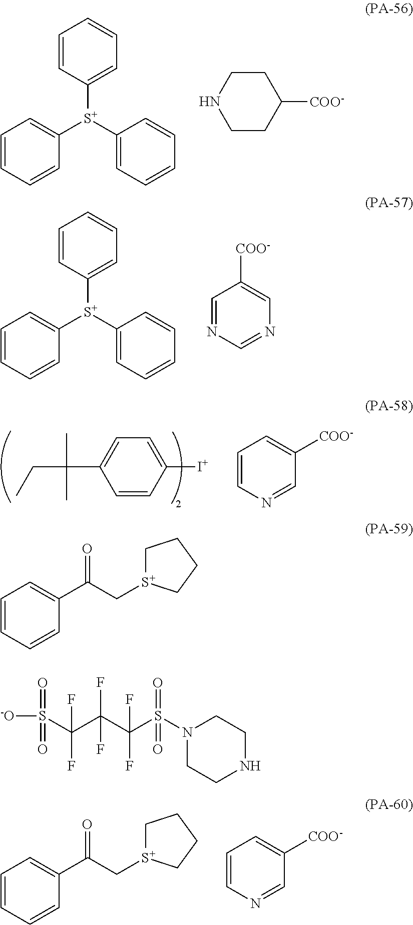

These compounds can be easily synthesized from a compound represented by formula (PA-I) or a lithium, sodium or potassium salt thereof and a hydroxide, bromide, chloride or the like of iodonium or sulfonium, by utilizing the salt exchange method described in JP-T-11-501909 (the term “JP-T” as used herein means a “published Japanese translation of a PCT patent application”) or JP-A-2003-246786. The synthesis may also be performed in accordance with the synthesis method described in JP-A-7-333851.

Specific examples of the compound (PA) capable of generating a compound represented by formula (PA-II) or (PA-III) upon irradiation with an actinic ray or radiation are illustrated below, but the present invention is not limited thereto.

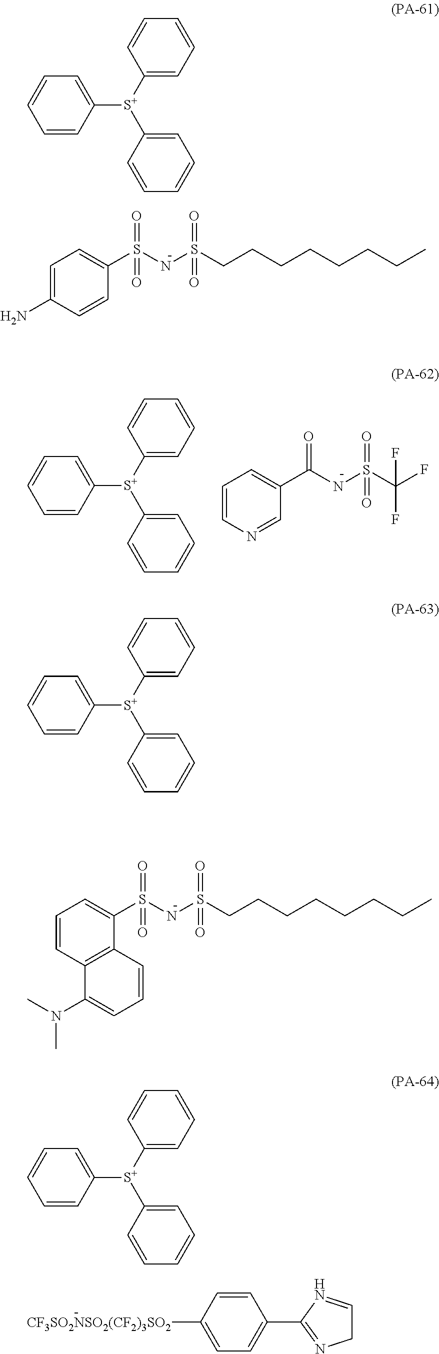

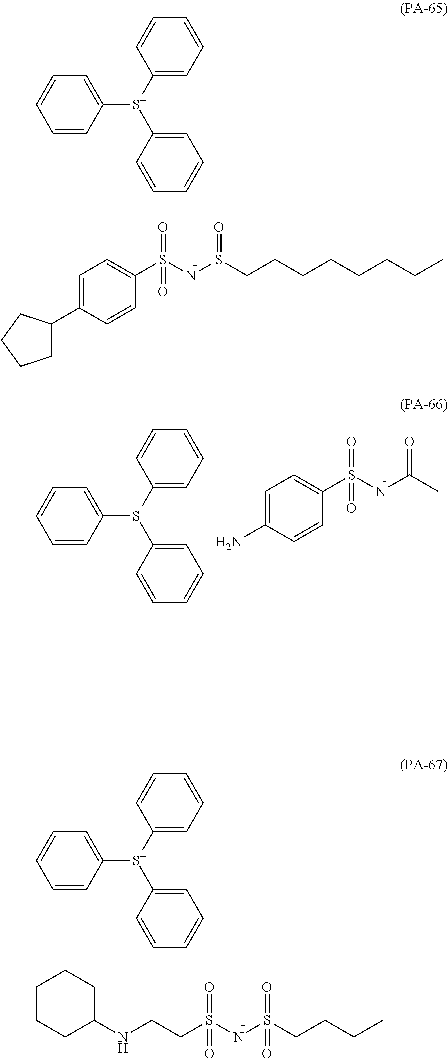

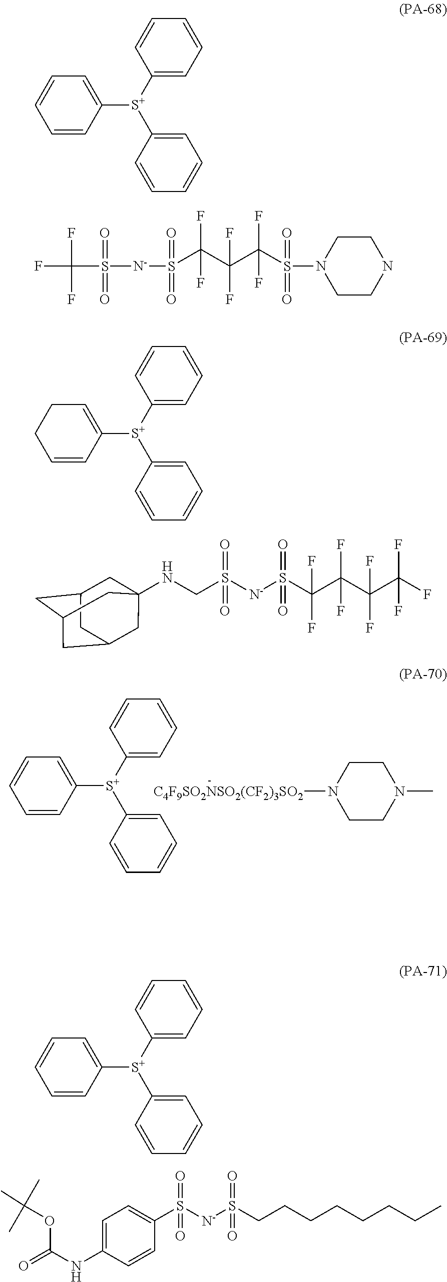

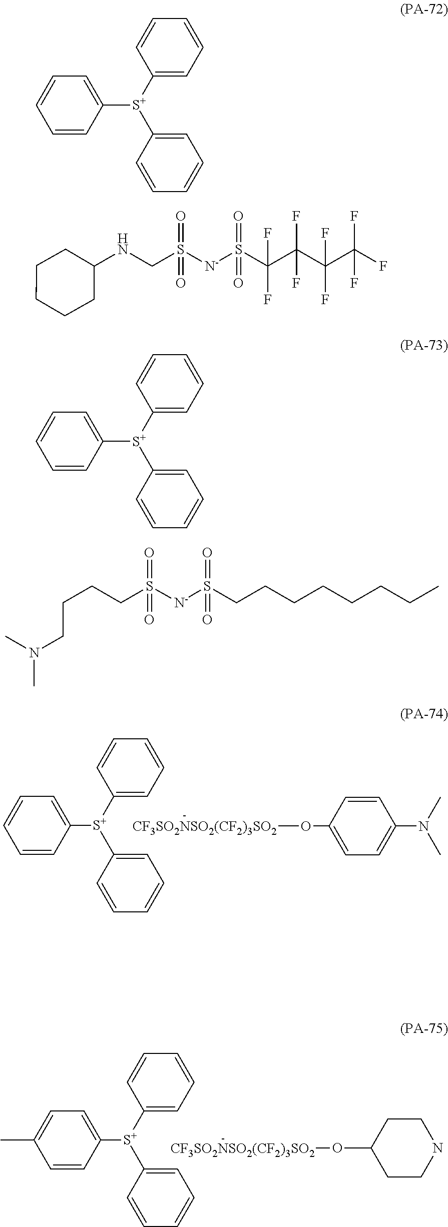

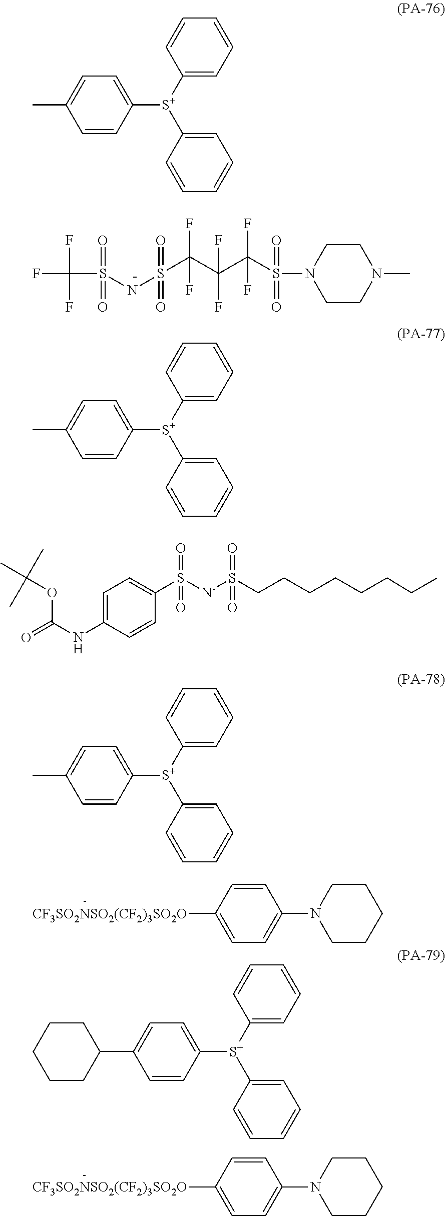

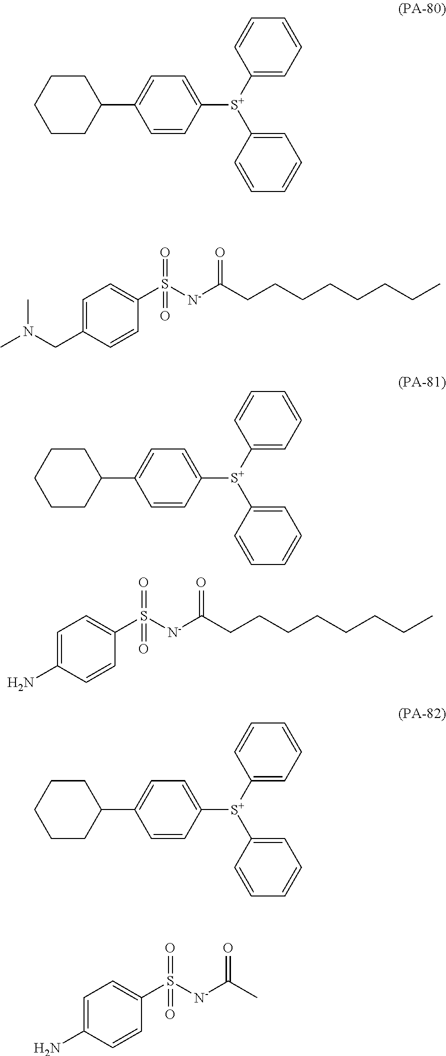

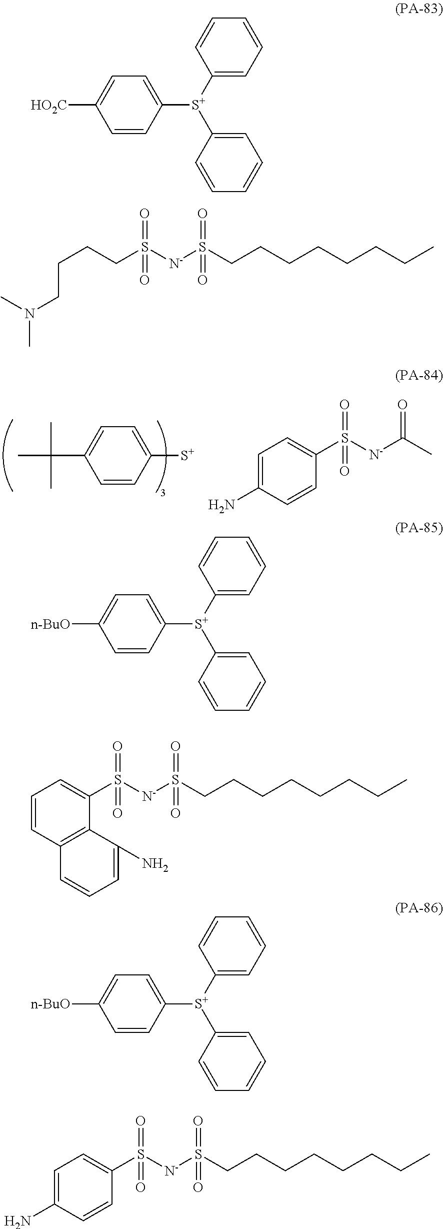

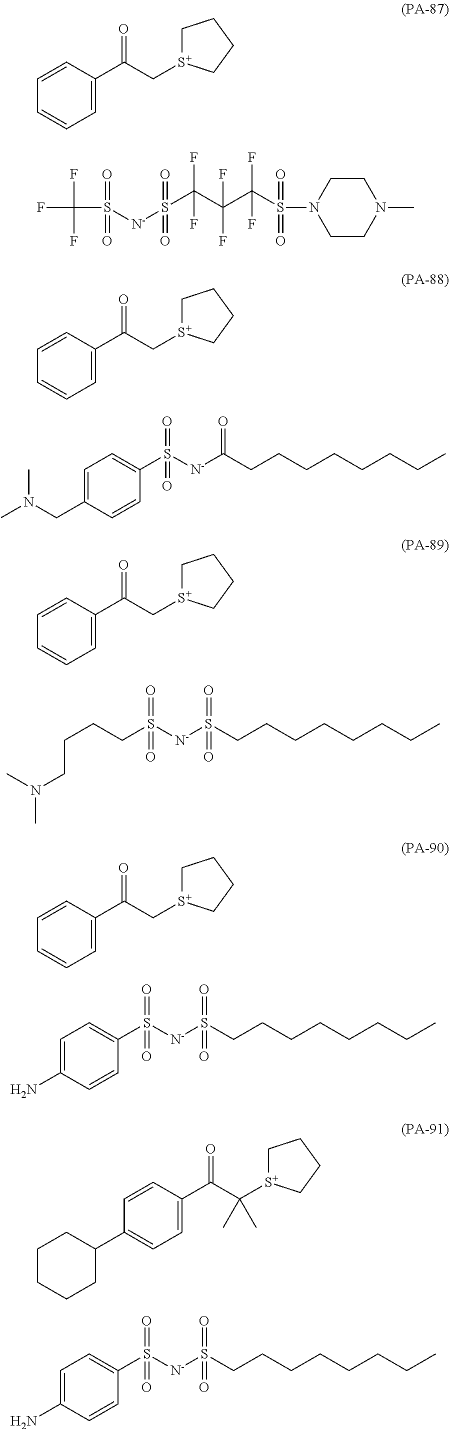

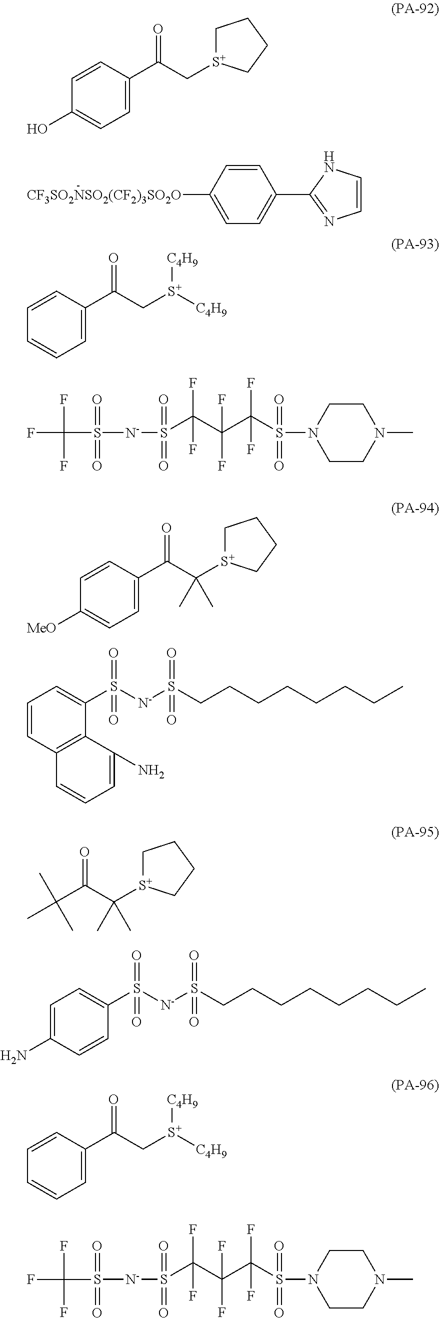

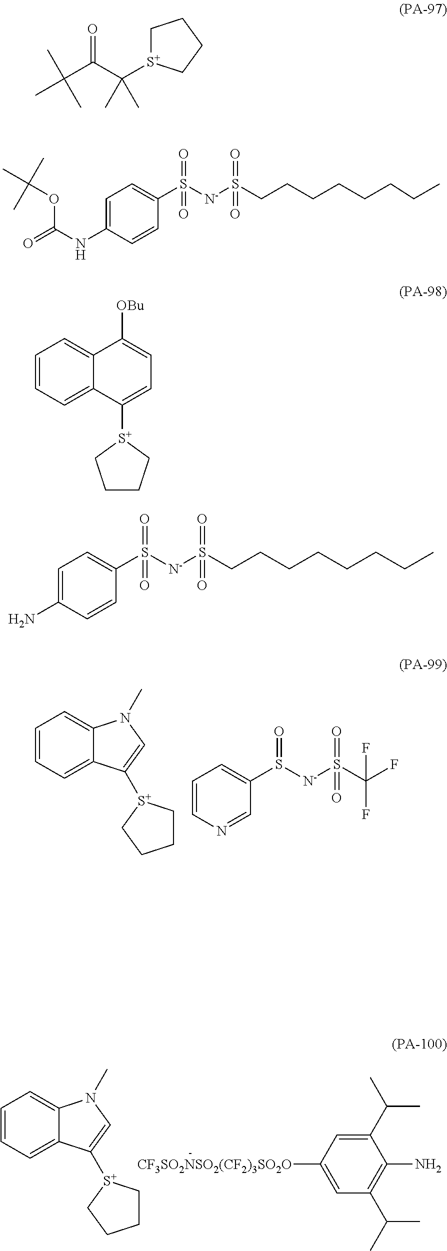

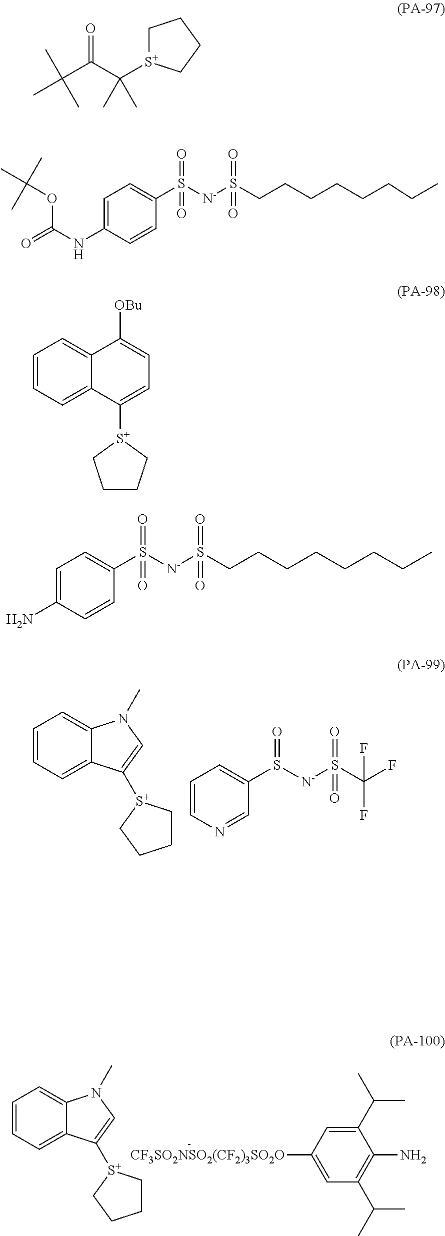

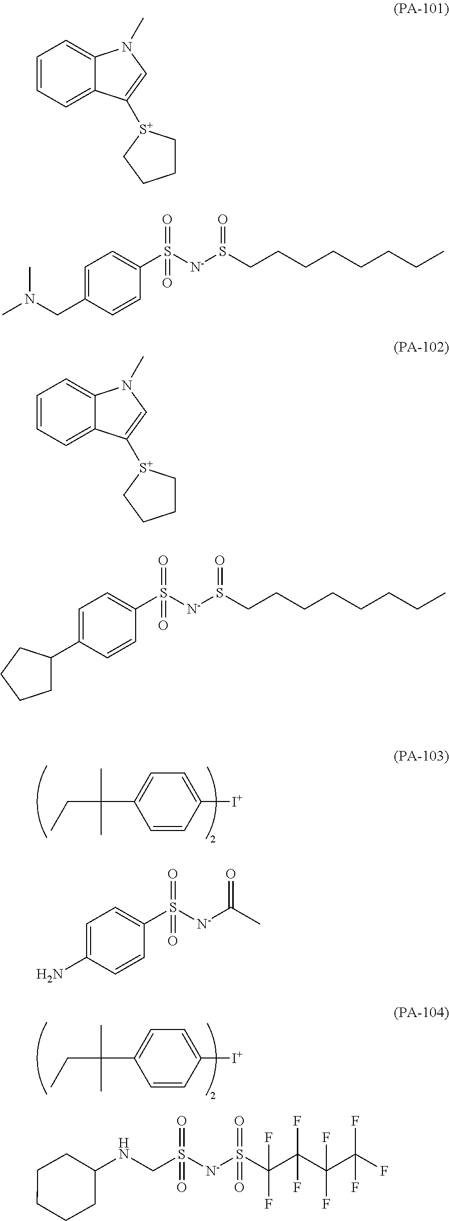

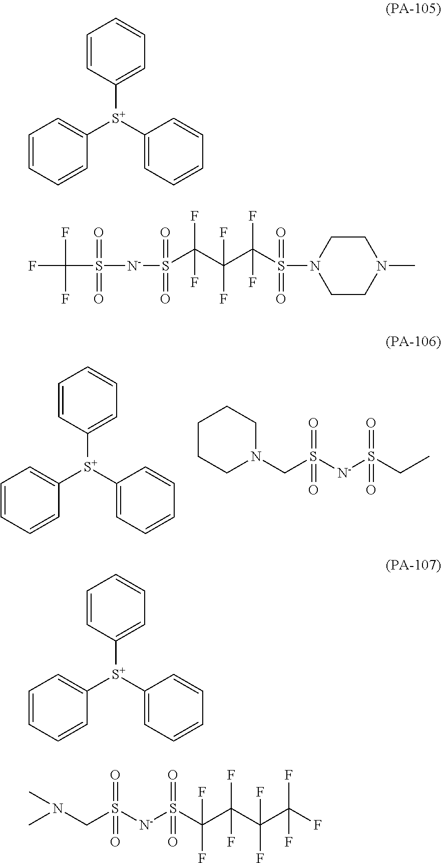

These compounds can be easily synthesized using a general sulfonic acid esterification reaction or sulfonamidation reaction. For example, the compound may be obtained by a method of selectively reacting one sulfonyl halide moiety of a bis-sulfonyl halide compound with an amine, alcohol or the like containing a partial structure represented by formula (PA-II) or (PA-III) to form a sulfonamide bond or a sulfonic acid ester bond and then hydrolyzing the other sulfonyl halide moiety, or a method of ring-opening a cyclic sulfonic anhydride by an amine or alcohol containing a partial structure represented by formula (PA-II). The amine or alcohol containing a partial structure represented by formula (PA-II) or (PA-III) can be synthesized by reacting an amine or alcohol with an anhydride (e.g., (R′O₂C)₂O, (R′SO₂)₂O) or an acid chloride compound (e.g., R′O₂CCl, R′SO₂Cl) (R′ is, for example, a methyl group, an n-octyl group, a trifluoromethyl group) under a basic condition. In particular, the synthesis may be performed in accordance with synthesis examples and the like of JP-A-2006-330098.

The molecular weight of the compound (PA) is preferably from 500 to 1,000.

In the case where the resist composition of the present invention contains a compound (PA), the content of the compound (PA) is preferably from 0.1 to 20 mass %, more preferably from 0.1 to 10 mass %, based on the solid content of the composition.

As for the compound (PA), one kind of a compound is used alone, or two or more kinds of compounds are used. Also, the compound (PA) may be used in combination with a basic compound described above.

### [9] Other Additives (G)

The resist composition for use in the present invention may further contain, for example, a dye, a plasticizer, a photosensitizer, a light absorber, a dissolution inhibitor and a dissolution accelerator, if desired.

The solid content concentration of the resist composition for use in the present invention is usually from 1.0 to 10 mass %, preferably from 2.0 to 5.7 mass %, more preferably from 2.0 to 5.3 mass %. When the solid content concentration is in this range, the resist solution can be uniformly coated on a substrate and moreover, a resist pattern improved in the line edge roughness can be formed. The reasons therefor are not clearly know, but it is considered that by setting the solid content concentration to 10 mass % or less, preferably 5.7 mass % or less, the materials, particularly the photo-acid generator, in the resist solution are prevented from aggregation and as a result, a uniform resist film can be formed.

The solid content concentration is a mass percentage of the mass of resist components excluding solvents, based on the total mass of the resist composition.

### [10] Pattern Forming Method

The pattern forming method (negative pattern forming method) of the present invention includes at least:

a step of forming a film (resist film) from a chemical amplification resist composition,

(ii) a step of exposing the film, and

(iii) a step of developing the exposed film by using an organic solvent-containing developer.

The resist film is formed from the above-described chemical amplification resist composition of the present invention and more specifically, is preferably formed on a substrate.

In the pattern forming method of the present invention, the step of forming a film from a resist composition on a substrate, the step of exposing the film, and the development step can be performed by a generally known method.

The pattern forming method also preferably contains, after film formation, a prebaking step (PB; Prebake) before entering the exposure step.

Furthermore, the pattern forming method also preferably contains a post-exposure baking step (PEB; Post Exposure Bake) after the exposure step but before the development step.

As for the heating temperature, both PB and PEB are preferably performed at 70 to 120° C., more preferably at 80 to 110° C.

The heating time is preferably from 30 to 300 seconds, more preferably from 30 to 180 seconds, still more preferably from 30 to 90 seconds.

The heating can be performed using a device attached to an ordinary exposure/developing machine or may be performed using a hot plate or the like.

Thanks to baking, the reaction in the exposed area is accelerated, and the sensitivity and pattern profile are improved.

The light source wavelength of the exposure apparatus for use in the present invention is not limited, but, for example, a KrF excimer laser wavelength (248 nm), an ArF excimer laser wavelength (193 nm) and an F₂ excimer laser wavelength (157 nm) are applicable.

In the present invention, the exposure of the resist film may be performed by filling a liquid (immersion medium) having a refractive index higher than that of air between the film and the lens at the irradiation with an actinic ray or radiation (immersion exposure). By this exposure, the resolution can be enhanced. The immersion medium used may be any liquid as long as it has a refractive index higher than that of air, but pure water is preferred.

In this case, the above-described hydrophobic resin may be previously added to the resist composition, or after forming a resist film, a sparingly immersion liquid-soluble film (hereinafter, sometimes referred to as a “topcoat”) may be provided thereon.

The performance required of the topcoat, the use method thereof and the like are described in Ekishin Lithography no Process to Zairyo (Process and Material of Immersion Lithography), Chapter 7, CMC Shuppan.

In view of transparency to laser at a wavelength of 193 nm, the topcoat is preferably a polymer not abundantly containing an aromatic, and specific examples thereof include a hydrocarbon polymer, an acrylic acid ester polymer, a polymethacrylic acid, a polyacrylic acid, a polyvinyl ether, a silicon-containing polymer and a fluorine-containing polymer. The above-described hydrophobic resin (HR) is suitable also as the topcoat. Furthermore, a commercially available topcoat material can also be appropriately used.

On peeling off the topcoat after exposure, a developer may be used or a releasing agent may be separately used. The releasing agent is preferably a solvent less permeating the film. From the standpoint that the peeling step can be performed simultaneously with the development step of the film, the topcoat is preferably peelable with a developer.

In the present invention, the substrate on which the film is formed is not particularly limited, and a substrate generally used in the production process of a semiconductor such as IC, in the production process of a liquid crystal device or a circuit board such as thermal head or in the lithography of other photo-fabrication processes, such as inorganic substrate (e.g., silicon, SiN, SiO₂, SiN) and coating-type inorganic substrate (e.g., SOG), can be used. If desired, an organic antireflection film may be formed between the film and the substrate.

### Development Step:

As for the organic developer which can be used in performing development with an organic solvent-containing developer, a developer containing a polar solvent such as ketone-based solvent, ester-based solvent, alcohol-based solvent, amide-based solvent and ether-based solvent, or a hydrocarbon-based solvent can be used. It is preferred to contain at least one kind of an organic solvent selected from a ketone-based solvent, an ester-based solvent, an alcohol-based solvent, an amide-based solvent and an ether-based solvent.

Examples of the ketone-based solvent include 1-octanone, 2-octanone, 1-nonanone, 2-nonanone, acetone, 4-heptanone, 1-hexanone, 2-hexanone, diisobutyl ketone, cyclohexanone, methylcyclohexanone, phenylacetone, methyl ethyl ketone, methyl isobutyl ketone, acetyl acetone, acetonyl acetone, ionone, diacetonyl alcohol, acetyl carbinol, acetophenone, methyl naphthyl ketone, isophorone and propylene carbonate.

Examples of the ester-based solvent include methyl acetate, butyl acetate, ethyl acetate, isopropyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate and propyl lactate. Above all, an alkyl acetate such as methyl acetate, butyl acetate, ethyl acetate, isopropyl acetate and amyl acetate is preferred.

Examples of the alcohol-based solvent include an alcohol such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, 4-methyl-2-pentanol, n-heptyl alcohol, n-octyl alcohol and n-decanol; a glycol-based solvent such as ethylene glycol, diethylene glycol and triethylene glycol; and a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethyl butanol.

Examples of the ether-based solvent include, in addition to the glycol ether-based solvents above, dioxane and tetrahydrofuran.

Examples of the amide-based solvent which can be used include N-methyl-2-pyrrolidone, N,N-dimethylacetamide, N,N-dimethylformamide, hexamethylphosphoric triamide and 1,3-dimethyl-2-imidazolidinone.

Examples of the hydrocarbon-based solvent include an aromatic hydrocarbon-based solvent such as toluene and xylene, and an aliphatic hydrocarbon-based solvent such as pentane, hexane, octane and decane.

A plurality of these solvents may be mixed, or within a range keeping the performance, the solvent may be used by mixing it with a solvent other than those described above or with water. However, in order to sufficiently bring out the effects of the present invention, the water content of the entire developer is preferably less than 10 mass %, and it is more preferred to contain substantially no water.

That is, the amount of the organic solvent used in the developer is preferably from 90 to 100 mass %, more preferably from 95 to 100 mass %, based on the entire amount of the developer.

In particular, the organic solvent-containing developer is preferably a developer containing at least one kind of a solvent selected from a ketone-based solvent, an ester-based solvent, an alcohol-based solvent, an amide-based solvent and an ether-based solvent.

The vapor pressure at 20° C. of the organic solvent-containing developer is preferably 5 kPa or less, more preferably 3 kPa or less, still more preferably 2 kPa or less. By setting the vapor pressure of the developer to 5 kPa or less, evaporation of the developer on a substrate or in a development cup is suppressed and the temperature uniformity in the wafer plane is enhanced, as a result, the dimensional uniformity in the wafer plane is improved.

Specific examples of the solvent having a vapor pressure of 5 kPa or less include a ketone-based solvent such as 1-octanone, 2-octanone, 1-nonanone, 2-nonanone, 4-heptanone, 2-hexanone, diisobutyl ketone, cyclohexanone, methylcyclohexanone, phenylacetone and methyl isobutyl ketone; an ester-based solvent such as butyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, butyl formate, propyl formate, ethyl lactate, butyl lactate and propyl lactate; an alcohol-based solvent such as n-propyl alcohol, isopropyl alcohol, n-butyl alcohol, sec-butyl alcohol, tert-butyl alcohol, isobutyl alcohol, n-hexyl alcohol, 4-methyl-2-pentanol, n-heptyl alcohol, n-octyl alcohol and n-decanol; a glycol-based solvent such as ethylene glycol, diethylene glycol and triethylene glycol; a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethylbutanol; an ether-based solvent such as tetrahydrofuran; an amide-based solvent such as N-methyl-2-pyrrolidone, N,N-dimethylacetamide and N,N-dimethylformamide; an aromatic hydrocarbon-based solvent such as toluene and xylene; and an aliphatic hydrocarbon-based solvent such as octane and decane.

Specific examples of the solvent having a vapor pressure of 2 kPa or less that is a particularly preferred range include a ketone-based solvent such as 1-octanone, 2-octanone, 1-nonanone, 2-nonanone, 4-heptanone, 2-hexanone, diisobutyl ketone, cyclohexanone, methylcyclohexanone and phenylacetone; an ester-based solvent such as butyl acetate, amyl acetate, propylene glycol monomethyl ether acetate, ethylene glycol mono ethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, ethyl lactate, butyl lactate and propyl lactate; an alcohol-based solvent such as n-butyl alcohol, sec-butyl alcohol, tert-butyl alcohol, isobutyl alcohol, n-hexyl alcohol, 4-methyl-2-pentanol, n-heptyl alcohol, n-octyl alcohol and n-decanol; a glycol-based solvent such as ethylene glycol, diethylene glycol and triethylene glycol; a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethylbutanol; an amide-based solvent such as N-methyl-2-pyrrolidone, N,N-dimethylacetamide and N,N-dimethylformamide; an aromatic hydrocarbon-based solvent such as xylene; and an aliphatic hydrocarbon-based solvent such as octane and decane.

### Surfactant:

In the developer, a surfactant can be added in an appropriate amount, if desired.

As for the surfactant, those described above as the surfactant used in the resist composition can be used.

The amount of the surfactant used is usually from 0.001 to 5 mass %, preferably from 0.005 to 2 mass %, more preferably from 0.01 to 0.5 mass %, based on the entire amount of the developer.

### Resin (A′):

The organic solvent-containing developer and the later-described rinsing solution may contain (A′) a resin soluble in an organic solvent. In this case, it is presumed that the resin (A′) is previously dissolved in the processing solution and the dissolution of resist film in the processing solution or the permeation of processing solution into the resist film is thereby accelerated.

The resin (A′) is not particularly limited as long as it is soluble in an organic solvent, and resins for use in the resist composition may be suitably used, but an epoxy resin, a melamine resin, a urea resin, a polyester resin, a polyurethane resin, a polyimide resin and the like can also be used.

Examples of the (A′) resin soluble in an organic solvent include a resin containing the following repeating units:
a repeating unit having an alcoholic hydroxyl group (a1),
a repeating unit having a nonpolar group and being free from an acid-decomposable group and a lactone structure (a2),
a repeating unit having a lactone structure (a3),
a repeating unit having an acid-decomposable group (a4),
a repeating unit having an acid group,
a repeating unit derived from hydroxystyrene or a derivative thereof, and
a (meth)acryl ester repeating unit having an aromatic ring in the side chain.

Specific examples of this resin are the same as those of the resin contained in the resist composition.

The weight average molecular weight of the resin (A′) for use in the present invention is preferably from 3,000 to 25,000, more preferably from 5,000 to 15,000, in terms of polystyrene as measured by the GPC method.

The polydispersity (molecular weight distribution) of the resin (A′) is preferably from 1.2 to 3.0, more preferably from 1.4 to 1.8.

The blending amount of the resin (A′) in the entire processing solution is preferably from 0.0001 to 10 mass %, more preferably from 0.001 to 5 mass %, based on the entire amount of the processing solution.

In the processing solution, one kind of resin (A′) may be contained, or a plurality of kinds thereof may be contained.

The resin (A′) for use in the present invention can be synthesized by a conventional method (for example, radical polymerization).

Examples of the developing method which can be applied include a method of dipping the substrate in a bath filled with the developer for a fixed time (dipping method), a method of raising the developer on the substrate surface by the effect of a surface tension and keeping it still for a fixed time, thereby performing the development (puddle method), a method of spraying the developer on the substrate surface (spraying method), and a method of continuously ejecting the developer on the substrate spinning at a constant speed while scanning the developer ejecting nozzle at a constant rate (dynamic dispense method).

In the case where the above-described various developing methods include a step of ejecting the developer toward the resist film from a development nozzle of a developing apparatus, the ejection pressure of the developer ejected (the flow velocity per unit area of the developer ejected) is preferably 2 mL/sec/mm² or less, more preferably 1.5 mL/sec/mm² or less, still more preferably 1 mL/sec/mm² or less. The flow velocity has no particular lower limit but in view of throughput, is preferably 0.2 mL/sec/mm² or more.

By setting the ejection pressure of the ejected developer to the range above, pattern defects attributable to the resist residue after development can be greatly reduced.

Details of this mechanism are not clearly known, but it is considered that thanks to the ejection pressure in the above-described range, the pressure imposed on the resist film by the developer possibly becomes small and the resist film or resist pattern is kept from inadvertent chipping or collapse.

Here, the ejection pressure (mL/sec/mm²) of the developer is a value at the outlet of a development nozzle in a developing apparatus.

Examples of the method for adjusting the ejection pressure of the developer include a method of adjusting the ejection pressure by a pump or the like, and a method of supplying the developer from a pressurized tank and thereby adjusting the pressure.

### Rinsing Step:

After the step of performing the development, a step of stopping the development by replacement with another solvent may be practiced.

A step of rinsing the resist film with a rinsing solution is preferably provided after the development with an organic solvent-containing developer. The rinsing solution is preferably a rinsing solution containing an organic solvent.

The rinsing solution for use in the rinsing step after the development with an organic solvent-containing developer is not particularly limited as long as it does not dissolve the resist pattern, and a solution containing a general organic solvent may be used. As for the rinsing solution, a rinsing solution containing at least one kind of an organic solvent selected from a hydrocarbon-based solvent, a ketone-based solvent, an ester-based solvent, an alcohol-based solvent, an amide-based solvent and an ether-based solvent is preferably used. The rinsing solution more preferably contains at least one kind of an organic solvent selected from a ketone-based solvent, an ester-based solvent, an alcohol-based solvent and an amide-based solvent, still more preferably contains an alcohol-based solvent or an ester-based solvent, yet still more preferably contains a monohydric alcohol, and even yet still more preferably contains a monohydric alcohol having a carbon number of 5 or more. The monohydric alcohol used in the rinsing step after the development includes a linear, branched or cyclic monohydric alcohol, and specific examples of the monohydric alcohol which can be used include 1-butanol, 2-butanol, 3-methyl-1-butanol, tert-butyl alcohol, 1-pentanol, 2-pentanol, 1-hexanol, 4-methyl-2-pentanol, 1-heptanol, 1-octanol, 2-hexanol, cyclopentanol, 2-heptanol, 2-octanol, 3-hexanol, 3-heptanol, 3-octanol and 4-octanol. As for the particularly preferred monohydric alcohol having a carbon number of 5 or more, 1-hexanol, 2-hexanol, 4-methyl-2-pentanol, 1-pentanol, 3-methyl-1-butanol and the like can be used. Among these, a branched alkyl alcohol having a carbon number of 5 or more is preferred.

A plurality of these components may be mixed, or the solvent may be used by mixing it with an organic solvent other than those described above.

The water content in the rinsing solution is preferably less than 10 mass %, more preferably less than 5 mass %, still more preferably less than 3 mass %. By setting the water content to less than 10 mass %, good development characteristics can be obtained.

In other words, the amount of the organic solvent used in the rinsing solution is preferably from 90 to 100 mass %, more preferably from 95 to 100 mass %, and most preferably from 97 to 100 mass %, based on the entire amount of the rinsing solution.

The vapor pressure at 20° C. of the rinsing solution used after the development with an organic solvent-containing developer is preferably from 0.05 to 5 kPa, more preferably from 0.1 to 5 kPa, and most preferably from 0.12 to 3 kPa. By setting the vapor pressure of the rinsing solution to be from 0.05 to 5 kPa, the temperature uniformity in the wafer plane is enhanced and moreover, swelling due to permeation of the rinsing solution is suppressed, as a result, the dimensional uniformity in the wafer plane is improved.

The rinsing solution may also be used after adding thereto a surfactant and the resin (A′) each in an appropriate amount. The kinds and amounts added of the surfactant and the resin (A′) which can be contained are the same as those in the developer.

In the rinsing step, the wafer after development is washed using the above-described organic solvent-containing rinsing solution. The method for washing treatment is not particularly limited, but examples of the method which can be applied include a method of continuously ejecting the rinsing solution on the substrate spinning at a constant speed (spin coating method), a method of dipping the substrate in a bath filled with the rinsing solution for a fixed time (dipping method), and a method of spraying the rinsing solution on the substrate surface (spraying method). Above all, it is preferred to perform the washing treatment by the spin coating method and after the washing, remove the rinsing solution from the substrate surface by spinning the substrate at a rotational speed of 2,000 to 4,000 rpm. It is also preferred to contain a heating step (Post Bake) after the rinsing step. The developer and rinsing solution remaining between patterns and in the inside of the pattern are removed by the baking. The heating step after the rinsing step is performed at usually from 40 to 160° C., preferably from 70 to 95° C., and for usually from 10 seconds to 3 minutes, preferably from 30 to 90 seconds.

### EXAMPLES

The present invention is described below by referring to Examples, but the present invention should not be construed as being limited thereto.

### Synthesis Example

### Synthesis of Acid Generator

### Compound (PAG-14):

Aluminum chloride (6.83 g) was added to 20.0 g of benzene, and the mixture was stirred under cooling at 3° C. Thereto, 40.4 g of cyclohexyl chloride was slowly added dropwise. After the dropwise addition, the mixture was stirred at room temperature for 5 hours and then poured in ice water. The organic layer was extracted with ethyl acetate, and the obtained organic layer was distilled at 40° C. under reduced pressure, further distilled at 170° C. under reduced pressure, then cooled to room temperature, and recrystallized by charging 50 ml of acetone. The precipitated crystal was collected by filtration to obtain 14 g of tricyclohexylbenzene.

Subsequently, 30 g of tricyclohexylbenzene was dissolved in 50 ml of methylene chloride, and the solution was stirred under cooling at 3° C. Thereto, 15.2 g of chlorosulfonic acid was slowly added dropwise. After the dropwise addition, the mixture was stirred at room temperature for 5 hours, charged with 10 g of ice and then charged with 40 g of an aqueous 50% sodium hydroxide solution. Furthermore, 20 g of ethanol was added, and the mixture was stirred at 50° C. for 1 hour. Insoluble matters were removed by filtration, and the residue was distilled at 40° C. under reduced pressure. The precipitated crystal was collected by filtration and washed with hexane to obtain 30 g of sodium 1,3,5-tricyclohexylbenzenesulfonate.

Thereafter, 4.0 g of triphenylsulfonium bromide was dissolved in 20 ml of methanol, and 5.0 g of sodium 1,3,5-tricyclohexylbenzenesulfonate dissolved in 20 ml of methanol was added. The mixture was stirred at room temperature for 2 hours and after adding 50 ml of ion-exchanged water, the reaction solution was extracted with chloroform. The obtained organic layer was washed with water and then distilled at 40° C. under reduced pressure, and the obtained crystal was recrystallized from a methanol/ethyl acetate solvent to obtain 5.0 g of PAG-14.

¹H-1-NMR (400 MHz, CDCl₃) δ=7.85 (d, 6H), 7.68 (t, 3H), 7.59 (t, 6H), 6.97 (s, 2H), 4.36-4.27 (m, 2H), 2.48-2.38 (m, 1H), 1.97-1.16 (m, 30H).

Photoacid Generators (PAG-1) to (PAG-14) and (PAG-ref) of the following formulae were synthesized in the same manner.

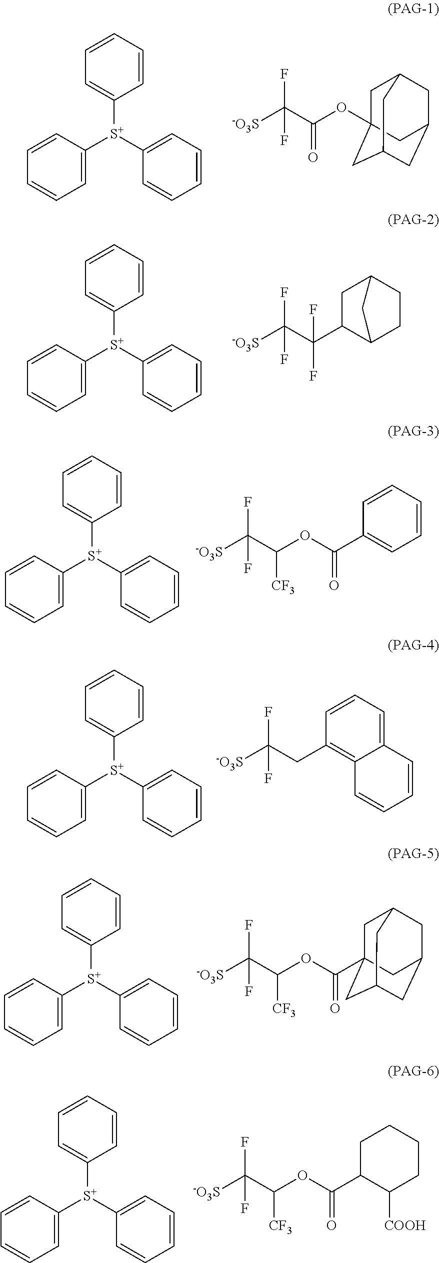

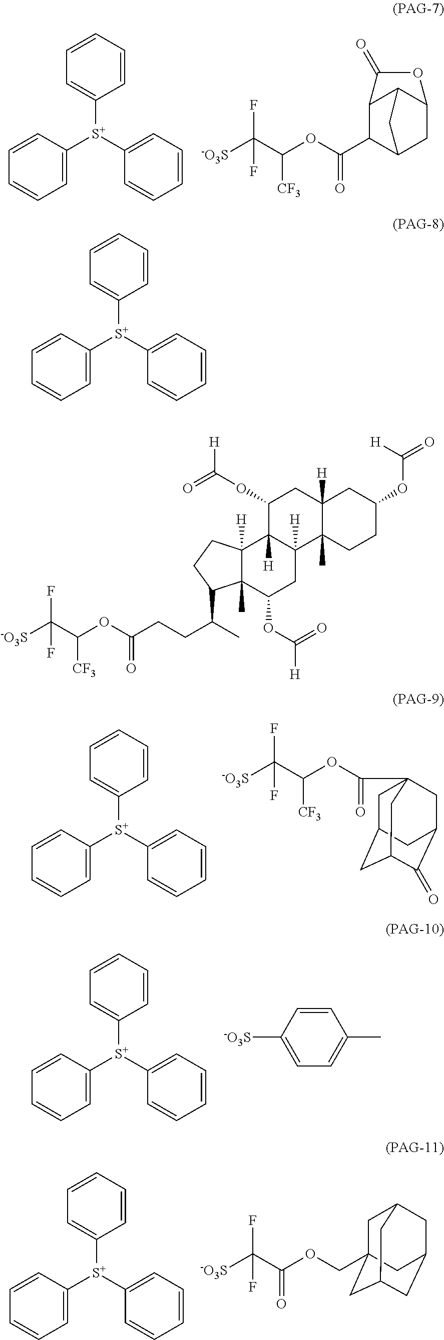

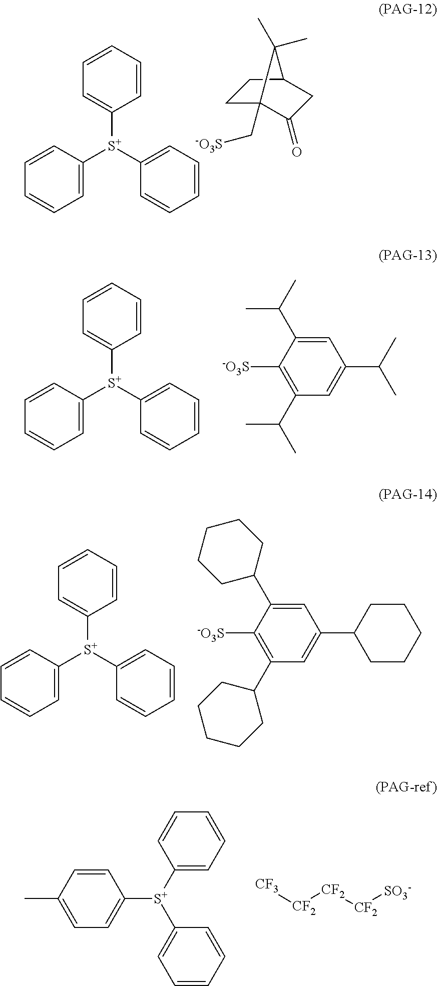

### <Preparation of Resist Composition>

The components shown in the Table 2 below were dissolved to prepare a solution having a solid content concentration of 6 mass %, and the solution was filtered through a polyethylene filter having a pore size of 0.03 μm. In this way, Resist Compositions Ar-01 to Ar-17 were prepared.

TABLE 2

| Resist | Resin | Acid | Basic | Surfactant | Hydrophobic | Crosslinking | Solvent |
|---|---|---|---|---|---|---|---|
| Composition | (A) (g) | Generator (g) | Compound (g) | (g) | Resin (g) | Agent (g) | (mass ratio) |
| Ar-01 | Resin 1 | PAG-2 | TPI | W-1 | 1b | X-1 | A1/B1 |
| | (10) | (0.5) | (0.03) | (0.03) | (0.05) | (1.00) | (70/30) |
| Ar-02 | Resin 6 | PAG-5 | Photobase | W-2 | 2b | X-2 | A1/B1 |
| | (10) | (0.5) | (0.03) | (0.03) | (0.05) | (1.00) | (60/40) |
| Ar-03 | Resin 7 | PAG-6 | DPA | W-3 | 3b | X-3 | A1/B1 |
| | (10) | (0.5) | (0.03) | (0.03) | (0.05) | (1.00) | (70/30) |
| Ar-04 | Resin 4 | PAG-3 | PBI | W-1 | 1b | X-4 | A1/B1 |
| | (10) | (0.5) | (0.03) | (0.03) | (0.05) | (1.00) | (70/30) |
| Ar-05 | Resin 3 | PAG-7 | TPI | W-2 | None | X-5 | A1/B2 |
| | (10) | (0.5) | (0.03) | (0.03) | | (1.00) | (60/40) |
| Ar-06 | Resin 2 | PAG-9 | TPI/DPA | W-1 | 2b | X-2 | A2/B2 |
| | (10) | (0.5) | (0.02/0.01) | (0.03) | (0.05) | (1.00) | (60/40) |
| Ar-07 | Resin 4/ | PAG-8 | DPA | W-3 | 1b | X-2 | A1/B1 |
| | Resin 7 | (0.5) | (0.03) | (0.03) | (0.05) | (1.00) | (70/30) |
| | (7/3) | | | | | | |
| Ar-08 | Resin 8 | PAG-1 | TPI | W-2 | 2b | X-1 | A2/B1 |
| | (10) | (0.5) | (0.03) | (0.03) | (0.05) | (1.00) | (60/40) |
| Ar-09 | Resin 6 | PAG-11 | TPI | W-2 | 2b | X-1 | A3/B2 |
| | (10) | (0.5) | (0.03) | (0.03) | (0.05) | (1.00) | (60/40) |
| Ar-10 | Resin 2 | PAG-4 | TPI/DPA | W-1 | 1b | X-2 | A1/B1 |
| | (10) | (0.5) | (0.02/0.01) | (0.03) | (0.05) | (1.00) | (70/30) |
| Ar-11 | Resin 3 | PAG-5/ | TPI | W-2 | 2b | X-1 | A3/B2 |
| | (10) | PAG-3 | (0.03) | (0.03) | (0.05) | (1.00) | (60/40) |
| | | (0.3/0.2) | | | | | |
| Ar-12 | Resin 1/ | PAG-9/ | DPA/PBI | W-3 | 1b | X-1 | A2/B2 |
| | Resin 8 | PAG-10 | (0.015/0.015) | (0.03) | (0.05) | (1.00) | (60/40) |
| | (7/3) | (0.3/0.2) | | | | | |
| Ar-13 | Resin 5 | PAG-12 | TPI | W-1 | 1b | X-2 | A1/B1 |
| | (10) | (0.5) | (0.03) | (0.03) | (0.05) | (1.00) | (70/30) |
| Ar-14 | Resin 2 | PAG-14 | PBI | W-3 | 2b | X-1 | A1/B2 |
| | (10) | (0.5) | (0.03) | (0.03) | (0.05) | (1.00) | (60/40) |
| Ar-15 | Resin 4 | PAG-13 | TPI | W-2 | None | X-4 | A2/B2 |
| | (10) | (0.5) | (0.03) | (0.03) | | (1.00) | (70/30) |
| Ar-16 | Resin 6 | PAG-6 | DPA | W-1 | 2b | X-2 | A1/B1 |
| | (10) | (0.5) | (0.03) | (0.03) | (0.05) | (1.00) | (60/40) |
| Ar-17 | Resin 9 | PAG-ref | PBI | W-2 | 1b | X-1 | A1/B1 |
| | (10) | (0.5) | (0.03) | (0.03) | (0.05) | (1.00) | (60/40) |

Abbreviations in Tables 2 and 4 are as follows.

### [Resin (A)]

Structures of the resin (A) are shown below. Also, the compositional ratio, molecular weight (weight average) and polydispersity (Mw/Mn) of the resin (A) are shown in the Table.

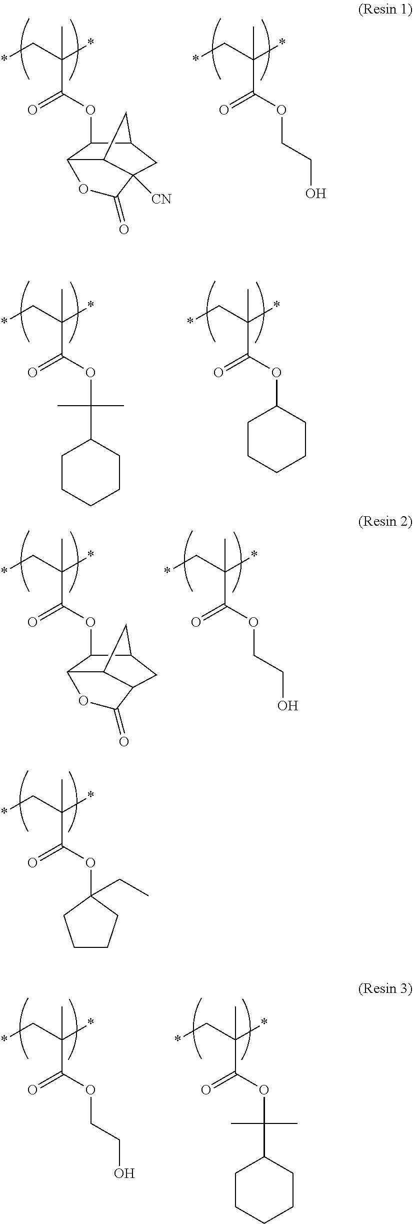

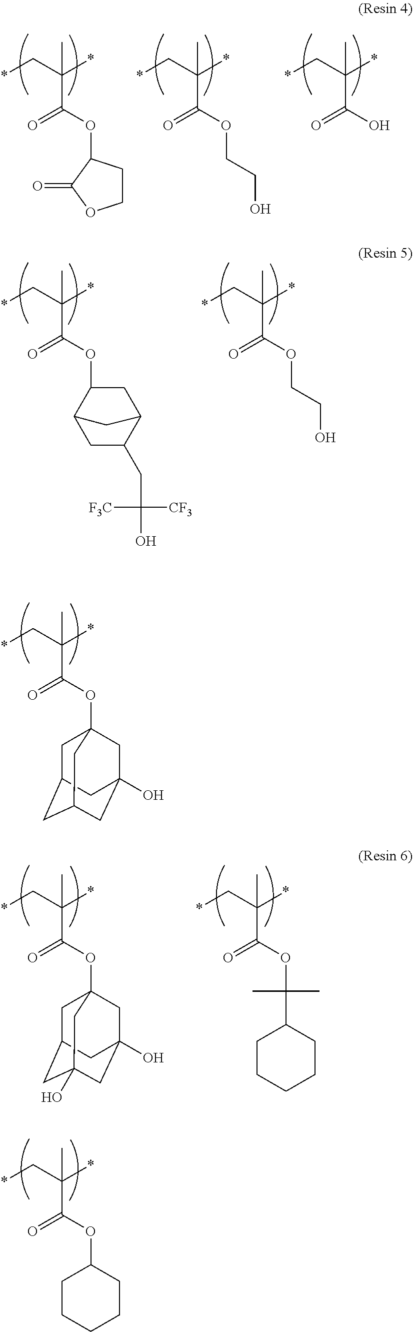

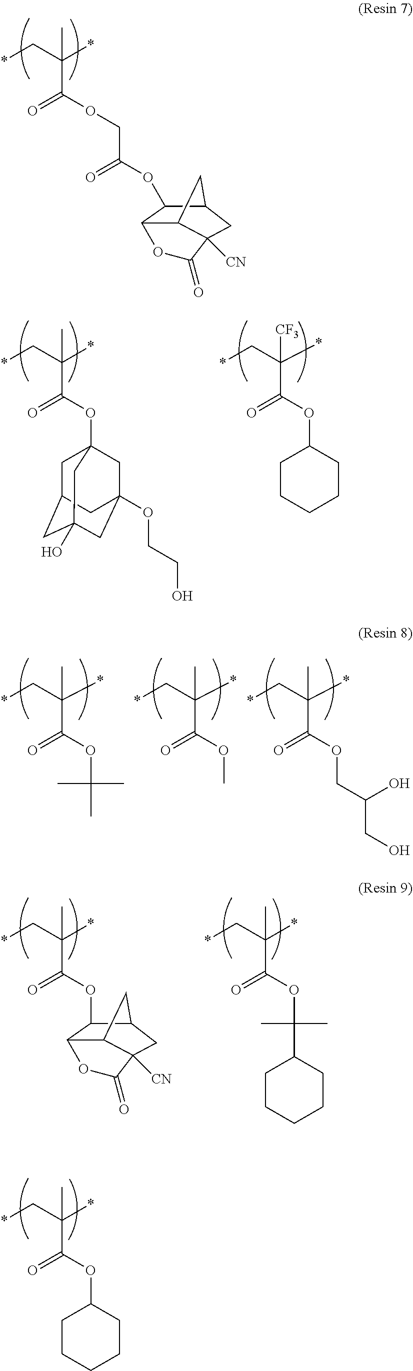

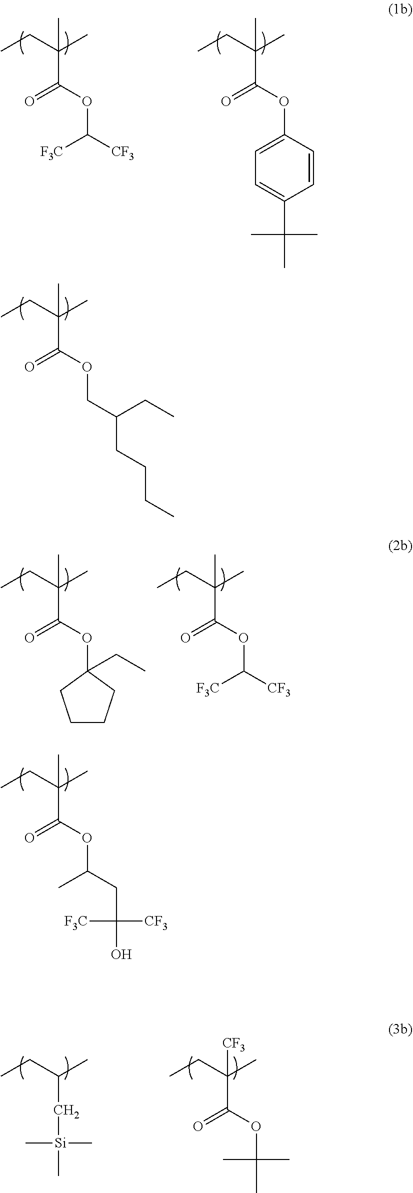

TABLE 3

| | Composition (molar ratio) | Mw | Mw/Mn |
|---|---|---|---|
| Resin 1 | 40/10/40/10 | 10000 | 1.8 |
| Resin 2 | 40/20/40 | 8000 | 1.6 |
| Resin 3 | 40/60 | 10000 | 1.7 |
| Resin 4 | 50/40/10 | 8500 | 1.7 |
| Resin 5 | 20/50/30 | 9500 | 1.5 |
| Resin 6 | 30/50/20 | 8000 | 1.6 |
| Resin 7 | 40/40/20 | 9000 | 1.7 |
| Resin 8 | 50/30/20 | 10000 | 1.8 |
| Resin 9 | 30/60/10 | 11000 | 1.7 |
| 1b | 30/60/10 | 5000 | 1.4 |
| 2b | 50/40/10 | 6500 | 1.5 |
| 3b | 50/50 | 4000 | 1.3 |

### [Basic Compound]

### TPI: 2,4,5-Triphenylimidazole

DPA: 2,6-Diisopropylphenyl alcohol

### PBI: 2-Phenylbenzimidazole

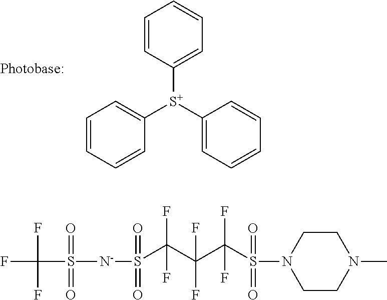

### [Surfactant]

W-1: Megaface F176 (produced by Dainippon Ink & Chemicals, Inc.) (fluorine-containing)
W-2: Megaface R08 (produced by Dainippon Ink & Chemicals, Inc.) (fluorine- and silicon-containing)
W-3: Polysiloxane Polymer KP-341 (produced by Shin-Etsu Chemical Co., Ltd.) (silicon-containing)

### [Crosslinking Agent]

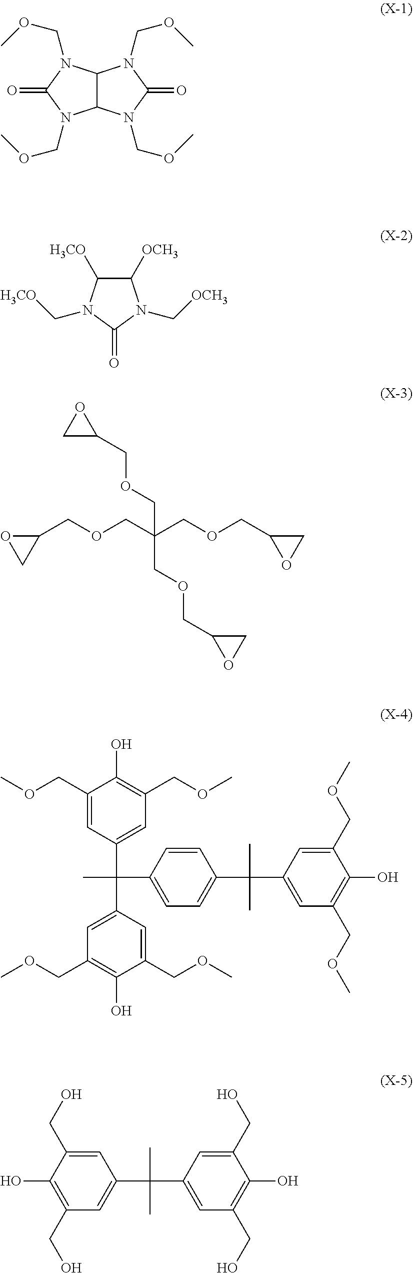

### [Solvent]

A1: Propylene glycol monomethyl ether acetate (PGMEA)

### A2: γ-Butyrolactone

### A3: Cyclohexanone

B1: Propylene glycol monomethyl ether (PGME)
B2: Ethyl lactate

### Example 1

An organic antireflection film, ARC29A (produced by Nissan Chemical Industries, Ltd.), was coated on a silicon wafer and baked at 205° C. for 60 seconds to form a 86 nm-thick antireflection film, and the resist composition was coated thereon and baked at 120° C. for 60 seconds (Pre Bake; PB) to form a 100 nm-thick resist film. The obtained wafer was subjected to pattern exposure using an ArF excimer laser scanner (NA: 0.75), then heated at 110° C. for 60 seconds (Post Exposure Bake; PEB), developed with the developer shown in the Table 4 for 30 seconds, and rinsed with a rinsing solution. Furthermore, the wafer was spun at a rotational speed of 4,000 rpm for 30 seconds and baked at 90° C. for 60 seconds to obtain a 1:1 line-and-space resist pattern with a line width of 75 nm.

Patterns of Examples 2 to 16 and Comparative Example 1 were obtained in the same manner as in Example 1 except for changing the PB/PEB temperature, the composition used, the developer and the rinsing solution as shown in the Tables 2 to 4.

### <Evaluation Method>

### [Limiting Resolution]

The 1:1 line-and-space resist pattern was observed using a Critical Dimension scanning electron microscope (SEM, S-9380-II, manufactured by Hitachi Ltd.), and the minimum dimension of a separated/resolved line-and-space pattern was defined as the limiting resolution.

### [Line Width Roughness (LWR)]

The 1:1 line-and-space resist pattern with a line width of 75 nm was observed using a Critical Dimension scanning electron microscope (SEM, S-938011, manufactured by Hitachi Ltd.). With respect to the range of 2 μm in the longitudinal direction of the space pattern, the line width was measured at 50 points at regular intervals and from its standard deviation, 3σ was computed, whereby the line width roughness was measured. A smaller value indicates better performance.

The results are shown in the Table 4.

TABLE 4

| | | | | | Rinsing | Limiting | |
|---|---|---|---|---|---|---|---|
| | Resist | PB | PEB | Developer | Solution | Resolution | LWR |
| | Composition | Temperature | Temperature | (mass ratio) | (mass ratio) | (nm) | (nm) |
| Example 1 | Ar-01 | 120° C. | 110° C. | butyl acetate | 4-methyl- | 62 | 6.0 |
| | | | | | 2-pentanol | | |
| Example 2 | Ar-02 | 120° C. | 110° C. | butyl acetate | 4-methyl- | 62 | 6.3 |
| | | | | | 2-pentanol | | |
| Example 3 | Ar-03 | 90° C. | 100° C. | pentyl acetate | 4-methyl- | 64 | 7.1 |
| | | | | | 2-pentanol | | |
| Example 4 | Ar-04 | 90° C. | 100° C. | isopentyl | 4-methyl- | 65 | 6.4 |
| | | | | acetate | 2-pentanol | | |
| Example 5 | Ar-05 | 100° C. | 110° C. | butyl acetate | decane | 65 | 6.6 |
| Example 6 | Ar-06 | 100° C. | 110° C. | butyl acetate | 1-hexanol/ | 66 | 6.3 |
| | | | | | decane | | |
| | | | | | (50:50) | | |
| Example 7 | Ar-07 | 100° C. | 110° C. | butyl acetate | 1-hexanol | 67 | 6.7 |
| Example 8 | Ar-08 | 100° C. | 110° C. | butyl acetate | 1-octanol | 68 | 6.6 |
| Example 9 | Ar-09 | 100° C. | 110° C. | butyl acetate | 1-hexanol | 69 | 7.1 |
| Example 10 | Ar-10 | 120° C. | 100° C. | pentyl acetate/ | 4-methyl- | 70 | 6.8 |
| | | | | A2 (70:30) | 2-pentanol | | |
| Example 11 | Ar-11 | 110° C. | 110° C. | butyl acetate | decane | 70 | 6.9 |
| Example 12 | Ar-12 | 100° C. | 100° C. | butyl acetate | 1-octanol | 72 | 7.0 |
| Example 13 | Ar-13 | 100° C. | 110° C. | butyl acetate/ | 1-hexanol | 73 | 7.3 |
| | | | | A1 (80:20) | | | |
| Example 14 | Ar-14 | 100° C. | 110° C. | butyl acetate/ | 1-hexanol | 75 | 7.6 |
| | | | | A2 (80:20) | | | |
| Example 15 | Ar-15 | 120° C. | 110° C. | butyl acetate | 4-methyl- | 79 | 7.7 |
| | | | | | 2-pentanol | | |
| Example 16 | Ar-16 | 100° C. | 110° C. | butyl acetate | 1-hexanol | 77 | 7.6 |
| Comparative | Ar-17 | 100° C. | 110° C. | butyl acetate | 1-hexanol | 83 | 7.8 |
| Example 1 | | | | | | | |

As seen from these results, a fine resist pattern excellent in terms of LWR can be formed by developing the resist composition of the present invention with an organic solvent-containing developer.

### INDUSTRIAL APPLICABILITY

According to the present invention, a pattern forming method, a chemical amplification resist composition and a resist film formed using the composition, enabling formation of a pattern with excellent resolution and small line width variation (LWR), can be provided.

The entire disclosure of Japanese Patent Application No. 2010-35463 filed on Feb. 19, 2010, and Japanese Patent Application No. 2011-31438 filed on Feb. 16, 2011, from which the benefit of foreign priority has been claimed in the present application, is incorporated herein by reference, as if fully set forth.

1. A pattern forming method comprising:
(i) a step of forming a film from a chemical amplification resist composition,
(ii) a step of exposing the film, and
(iii) a step of developing the exposed film by using a developer containing an organic solvent,
wherein the resist composition contains:
(A) a resin,
(B) a compound capable of generating an acid represented by the following formula (I) upon irradiation with an actinic ray or radiation,
(C) a crosslinking agent, and
(D) a solvent: 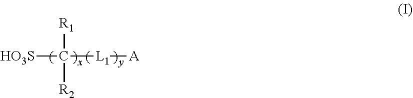
wherein each of R₁ and R₂ independently represents a hydrogen atom, a fluorine atom or an alkyl group, and when a plurality of R₁'s or R₂'s are present, each R₁ or R₂ may be the same as or different from every other R₁ or R₂,
L₁ represents a divalent linking group and when a plurality of L₁'s are present, each L₁ may be the same as or different from every other L₁,
A represents a cyclic organic group,
x represents an integer of 0 to 20, and
y represents an integer of 0 to 10.

2. The pattern forming method according to claim 1, wherein the content of the organic solvent in the developer containing the organic solvent is from 90 to 100 mass % based on the entire amount of the developer.

3. The pattern forming method according to claim 1, wherein the compound (B) is a compound capable of generating an acid represented by the following formula (II) or (III) upon irradiation with an actinic ray or radiation: 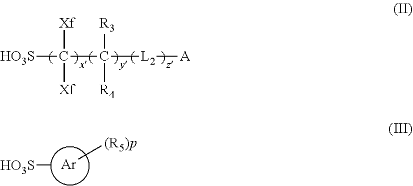
wherein each Xf independently represents a fluorine atom or an alkyl group substituted with at least one fluorine atom,
each of R₃ and R₄ independently represents a hydrogen atom or an alkyl group, and when a plurality of R₃'s or R₄'s are present, each R₃ or R₄ may be the same as or different from every other R₃ or R₄,
L₂ represents a divalent linking group and when a plurality of L₂'s are present, each L₂ may be the same as or different from every other L₂,
A represents a cyclic organic group,
x′ represents an integer of 1 to 20,
y′ represents an integer of 0 to 10,
z′ represents an integer of 0 to 10,
Ar represents an aryl group and may have a substituent other than the sulfonic acid group and R₅,
R₅ represents a group containing a hydrocarbon group, and
p represents an integer of 0 or more.

4. The pattern forming method according to claim 1, wherein the resin (A) contains a repeating unit having an acid-decomposable group.

5. The pattern forming method according to claim 1, wherein the resin (A) does not contain a repeating unit having an acid group or the content of a repeating unit having an acid group is 10 mol % or less based on all repeating units of the resin (A).

6. The pattern forming method according to claim 1, wherein the developer containing an organic solvent is a developer containing at least one kind of a solvent selected from a ketone-based solvent, an ester-based solvent, an alcohol-based solvent, an amide-based solvent and an ether-based solvent.

7. A chemical amplification resist composition used in the pattern forming method according to claim 1.

8. A chemical amplification resist composition comprising:
(A) a resin,
(B) a compound capable of generating an acid represented by the following formula (I) upon irradiation with an actinic ray or radiation,
(C) a crosslinking agent, and
(D) a solvent. 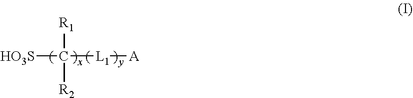
wherein each of R₁ and R₂ independently represents a hydrogen atom, a fluorine atom or an alkyl group, and when a plurality of R₁'s or R₂'s are present, each R₁ or R₂ may be the same as or different from every other R₁ or R₂,
L₁ represents a divalent linking group and when a plurality of L₁'s are present, each L₁ may be the same as or different from every other L₁,
A represents a cyclic organic group,
x represents an integer of 0 to 20, and
y represents an integer of 0 to 10.

9. The chemical amplification resist composition according to claim 8, wherein the compound (B) is a compound capable of generating an acid represented by the following formula (II) or (III) upon irradiation with an actinic ray or radiation: 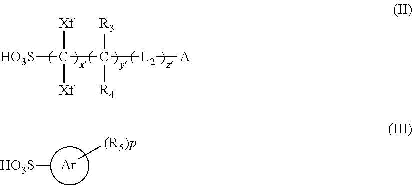
wherein each Xf independently represents a fluorine atom or an alkyl group substituted with at least one fluorine atom,
each of R₃ and R₄ independently represents a hydrogen atom or an alkyl group, and when a plurality of R₃'s or R₄'s are present, each R₃ or R₄ may be the same as or different from every other R₃ or R₄,
L₂ represents a divalent linking group and when a plurality of L₂'s are present, each L₂ may be the same as or different from every other L₂,
A represents a cyclic organic group,
x′ represents an integer of 1 to 20,
y′ represents an integer of 0 to 10,
z′ represents an integer of 0 to 10,
Ar represents an aryl group and may have a substituent other than the sulfonic acid group and R₅,
R₅ represents a group containing a hydrocarbon group, and
p represents an integer of 0 or more.

10. The chemical amplification resist composition according to claim 8, wherein the resin (A) contains a repeating unit having an acid-decomposable group.

11. The chemical amplification resist composition according to claim 8, wherein the resin (A) does not contain a repeating unit having an acid group or the content of a repeating unit having an acid group is 10 mol % or less based on all repeating units of the resin (A).

12. A resist film formed from the chemical amplification resist composition according to claim 8.

13. The pattern forming method according to claim 1, wherein the resin (A) has substantially no aromatic group.

14. The chemical amplification resist composition according to claim 8, wherein the resin (A) has substantially no aromatic group.
